(19) United States
(12) Patent Application Publication
(10) Pub. No.: US 2023/0403934 A1
(43) Pub. Date: Dec. 14, 2023

(54) LIGHT EMITTING ELEMENT AND POLYCYCLIC COMPOUND FOR THE SAME

(71) Applicant: Samsung Display Co., Ltd., Yongin-si (KR)

(72) Inventors: CHANSEOK OH, Yongin-si (KR); SUN YOUNG PAK, Yongin-si (KR); Kyoung SUNWOO, Yongin-si (KR); MUN-KI SIM, Yongin-si (KR)

(73) Assignee: Samsung Display Co., Ltd., Yongin-si (KR)

(21) Appl. No.: 18/122,266

(22) Filed: Mar. 16, 2023

(30) Foreign Application Priority Data
Jun. 10, 2022 (KR) 10-2022-0071018

(51) Int. Cl. H10K 85/60; C07F 5/02; C09K 11/06

(52) U.S. Cl. CPC H10K 85/658; C07F 5/027; C09K 11/06; H10K 50/11

(57) ABSTRACT

Embodiments provide a polycyclic compound and a light emitting element that includes the polycyclic compound. The light emitting element exhibits high efficiency and long service life characteristics. The light emitting element includes a first electrode, a second electrode disposed on the first electrode, and an emission layer disposed between the first electrode and the second electrode and including the polycyclic compound, wherein the polycyclic compound is represented by Formula 1, which is explained in the specification:

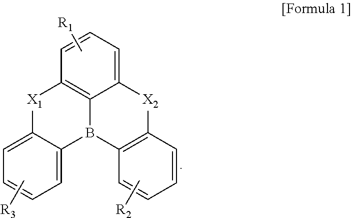

### CROSS-REFERENCE TO RELATED APPLICATION(S)

This application claims priority to and benefits of Korean Patent Application No. 10-2022-0071018 under 35 U.S.C. § 119, filed on Jun. 10, 2022, in the Korean Intellectual Property Office, the entire contents of which are incorporated herein by reference.

### BACKGROUND

### 1. Technical Field

The disclosure relates to a light emitting element including a novel polycyclic compound in an emission layer.

### 2. Description of the Related Art

Active development continues for an organic electroluminescence display device as an image display device. The organic electroluminescence display device includes a so-called self-luminescent light emitting element in which holes and electrons respectively injected from a first electrode and a second electrode recombine in an emission layer, so that a luminescent material of the emission layer emits light to achieve display.

In the application of a light emitting element to a display device, there is a demand for a light emitting element having a low driving voltage, high luminous efficiency, and a long service life, and continuous development is required on materials for a light emitting element that is capable of stably achieving such characteristics.

In order to implement a highly efficient organic electroluminescence device, technologies pertaining to phosphorescence emission using triplet state energy or to delayed fluorescence using triplet-triplet annihilation (TTA) in which singlet excitons are generated by the collision of triplet excitons are being developed, and development is currently directed to thermally activated delayed fluorescence (TADF) materials which utilize a delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element exhibiting high efficiency and long service life characteristics.

The disclosure also provides a polycyclic compound which is a material for a light emitting element having high luminous efficiency and improved service life characteristics.

An embodiment provides a light emitting element which may include a first electrode, a second electrode disposed on the first electrode, and an emission layer disposed between the first electrode and the second electrode, wherein the emission layer may include:
a first compound represented by Formula 1; and at least one of a second compound represented by Formula HT-1, or a third compound represented by Formula ET-1:

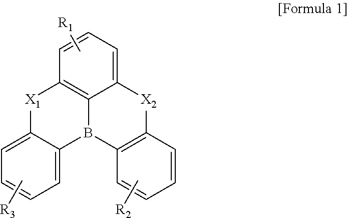

In Formula 1, X₁ and X₂ may each independently be N(R₄) or O, any one or two of R₁ to R₄ may each independently be a group represented by Formula 2, and the remainder of R₁ to R₄ may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

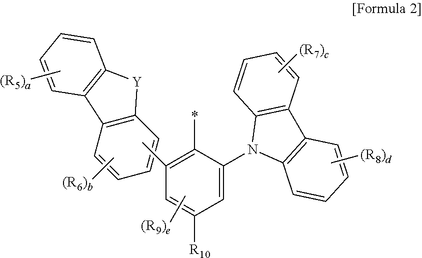

In Formula 2, Y may be N(R₁₁), O, or S; and R₅ to R₈, R₁₀, and R₁₁ may each independently be a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted aryl group having 6 to 60 ring-forming carbon atoms, or a substituted or unsubstituted heteroaryl group having 2 to 60 ring-forming carbon atoms. In Formula 2, R₉ may be a hydrogen atom or a deuterium atom; a, c, and d may each independently be an integer from 0 to 4; b may be an integer from 0 to 3; and e may be an integer from 0 to 2.

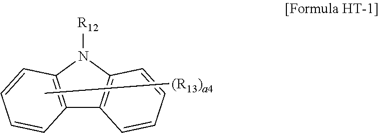

In Formula HT-1, a4 may be an integer from 0 to 8; and R₁₂ and R₁₃ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms.

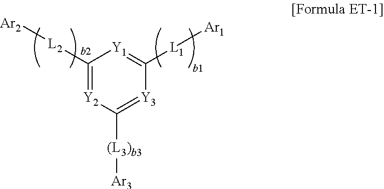

In Formula ET-1, at least one of Y₁ to Y₃ may each be N; and the remainder of Y₁ to Y₃ may each independently be C(Ra). In Formula ET-1, Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; and L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula ET-1, Ar₁ to Arₙ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the emission layer EML may further include a fourth compound represented by Formula M-b:

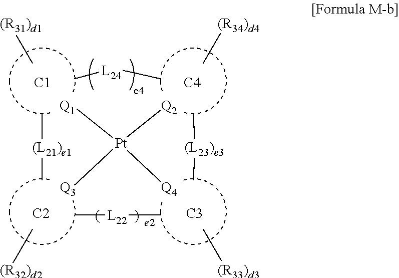

In Formula M-b, Q₁ to Q₄ may each independently be C or N; and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms. In Formula M-b, e1 to e4 may each independently be 0 or 1; and L₂₁ to L₂₄ may each independently be a direct linkage, a substituted or unsubstituted divalent alkyl group

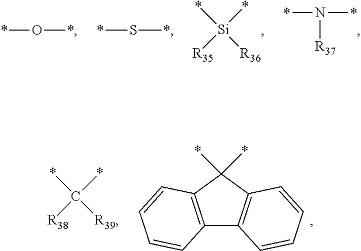

a substituted or unsubstituted arylene group having 6 to 30 ring-forming carbon atoms, or a substituted or unsubstituted heteroarylene group having 2 to 30 ring-forming carbon atoms. In Formula M-b, d1 to d4 may each independently be an integer from 0 to 4; and R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, one or two of R₁ to R₄ may each independently be a group represented by Formula 2; and the remainder of R₁ to R₄ may each independently be a hydrogen atom, a deuterium atom, a t-butyl group, a substituted or unsubstituted phenyl group, a substituted or unsubstituted biphenyl group, a substituted or unsubstituted terphenyl group, or a substituted or unsubstituted carbazole group.

In an embodiment, at least one of R₁ to R₄ may each independently be a deuterium atom, or may each independently include a substituent that includes a deuterium atom.

In an embodiment, the first compound may be represented by any one of Formula 1-1 to Formula 1-3:

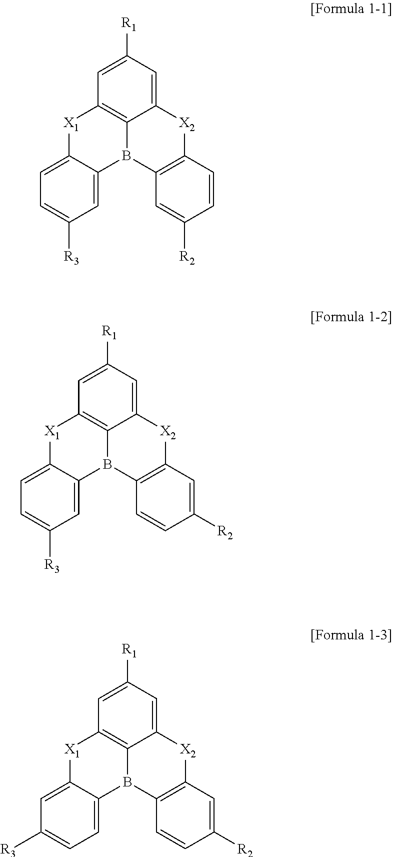

In Formula 1-1 to Formula 1-3, R₁ to R₃, X₁, and X₂ are each the same as defined in Formula 1.

In an embodiment, Formula 1-1 may be represented by any one of Formula 1-1-1 to Formula 1-1-4:

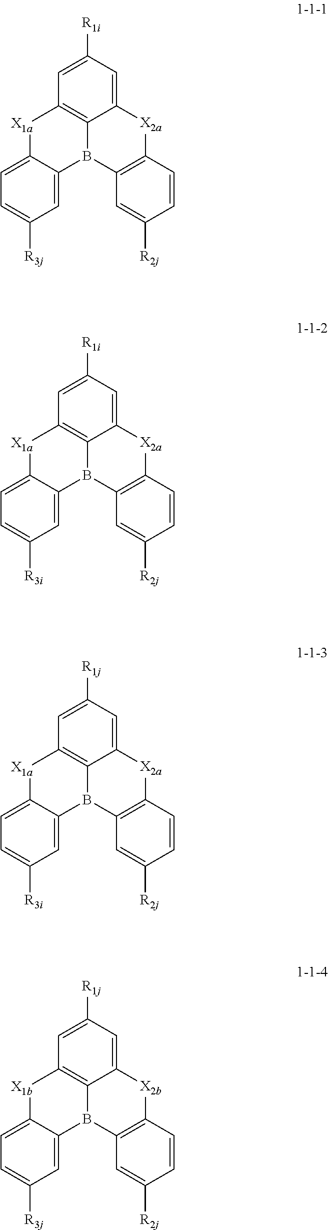

In Formula 1-1-1 to Formula 1-1-4, X₁ₐ and X₂ₐ may each independently be N(R₄ⱼ) or O; and X_{1b} and X_{2b} may each independently be N(R₄ᵢ) or O. In Formula 1-1-1 to Formula 1-1-4, R₁ᵢ, R₃ᵢ, and R₄ᵢ may each independently be a group represented by Formula 2; and R₁ⱼ, R₂ⱼ, R₃ⱼ, and R₄ⱼ may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

In an embodiment, Formula 1-2 may be represented by any one of Formula 1-2-1 to Formula 1-2-3:

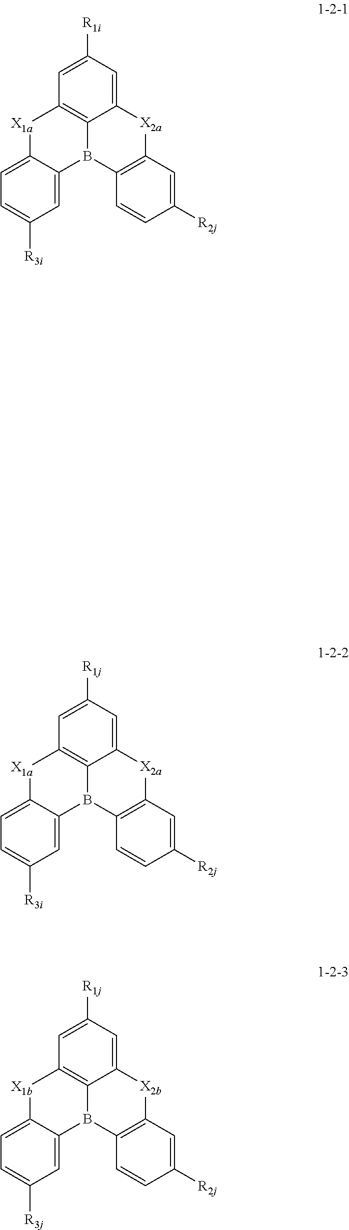

In Formula 1-2-1 to Formula 1-2-3, X₁ₐ and X₂ₐ may each independently be N(R₄ⱼ) or O; and X_{1b} and X_{2b} may each independently be N(R₄ᵢ) or O. In Formula 1-2-1 to Formula 1-2-3, R₁ᵢ, R₃ᵢ, and R₄ᵢ may each independently be a group represented by Formula 2; and R₁ⱼ, R₂ⱼ, R₃ⱼ, and R₄ⱼ may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

In an embodiment, Formula 1-3 may be represented by any one of Formula 1-3-1 to Formula 1-3-4:

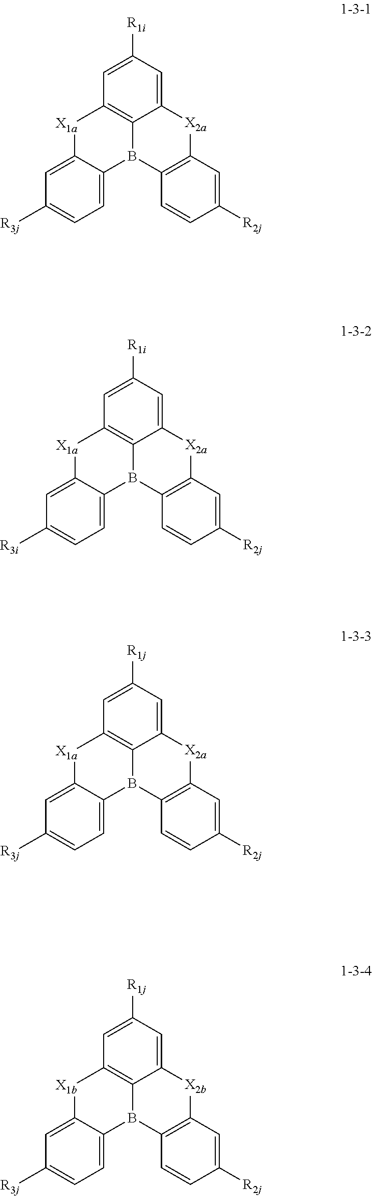

In Formula 1-3-1 to Formula 1-3-4, X₁ₐ and X₂ₐ may each independently be N(R₄ⱼ) or O; and X_{1b} and X_{2b} may each independently be N(R₄ᵢ) or O. In Formula 1-3-1 to Formula 1-3-4, R₁ᵢ, R₃ᵢ, and R₄ᵢ may each independently be a group represented by Formula 2; and R₁ⱼ, R₂ⱼ, R₃ⱼ, and R₄ⱼ may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

In an embodiment, Formula 1 may be represented by any one of Formula 3-A to Formula 3-D:

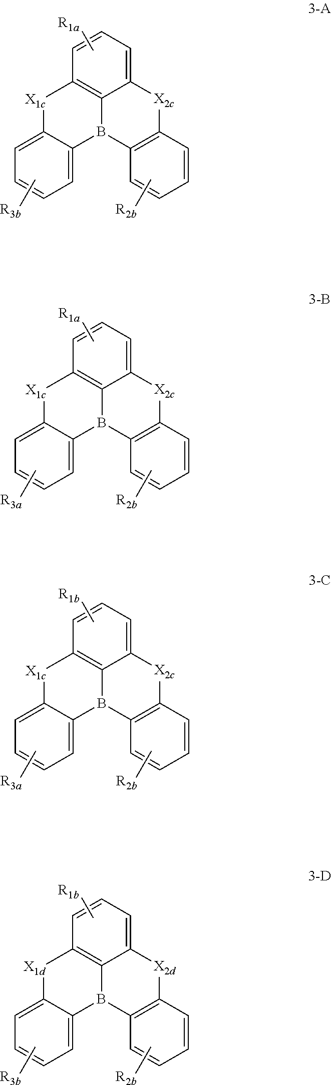

In Formula 3-A to Formula 3-D, X₁, and X₂, may each independently be N(R_{4b}) or O; and X_{1d} and X_{2d} may each independently be N(R₄ₐ) or O. In Formula 3-A to Formula 3-D, R₁ₐ, R₃ₐ, and R₄ₐ may each independently be a group represented by Formula 2; and R_{1b}, R_{2b}, R_{3b}, and R_{4b} may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

In an embodiment, Formula 2 may be represented by any one of Formula 2-1 to Formula 2-4:

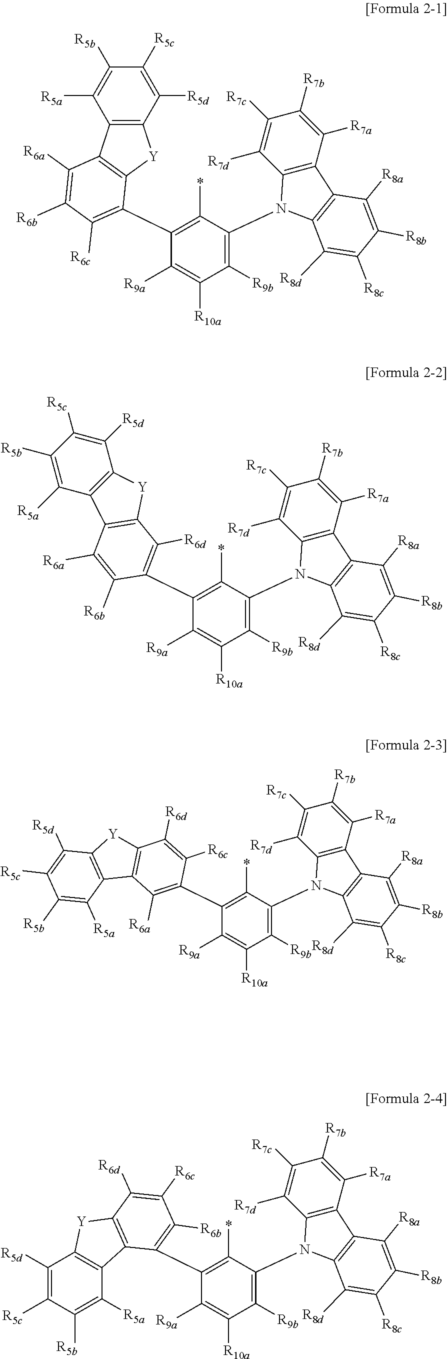

In Formula 2-1 to Formula 2-4, Y may be O or S; R₅ₐ to R_{5d}, R₆ₐ to R_{6d}, R₇ₐ to R_{7d}, R₈ₐ to R_{8d}, and R₁₀ₐ may each independently be a hydrogen atom, a deuterium atom, a cyano group, or a substituted or unsubstituted alkyl group having 1 to 10 carbon atoms; and R₉ₐ and R_{9b} may each independently be a hydrogen atom or a deuterium atom.

In an embodiment, the emission layer may include the first compound, the second compound, and the third compound.

In an embodiment, the emission layer may include the first compound, the second compound, the third compound, and the fourth compound.

In an embodiment, the emission layer may emit thermally activated delayed fluorescence.

In an embodiment, the emission layer may emit light having a central wavelength in a range of about 430 nm to about 490 nm.

In an embodiment, the first compound may be selected from Compound Group 1, which is explained below.

In an embodiment, a polycyclic compound may be represented by Formula 1 as explained herein.

In an embodiment, Formula 1 may be represented by any one of Formula 1-1 to Formula 1-3, as explained herein.

In an embodiment, Formula 1-1 may be represented by any one of Formula 1-1-1 to Formula 1-1-4, as explained herein.

In an embodiment, Formula 1-2 may be represented by any one of Formula 1-2-1 to Formula 1-2-3, as explained herein.

In an embodiment, Formula 1-3 may be represented by any one of Formula 1-3-1 to Formula 1-3-4, as explained herein.

In an embodiment, Formula 1 may be represented by any one of Formula 3-A to Formula 3-D, as explained herein.

In an embodiment, Formula 2 may be represented by any one of Formula 2-1 to Formula 2-4, as explained herein.

In an embodiment, the polycyclic compound represented by Formula 1 may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure principles thereof. The above and other aspects and features of the disclosure will become more apparent by describing in detail embodiments thereof with reference to the accompanying drawings, in which:

FIG. 1 is a schematic plan view illustrating a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment; and

FIG. 10 is a schematic cross-sectional view of a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the phrase “bonded to an adjacent group to form a ring” may be interpreted as a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent substituted for an atom which is substituted with a corresponding substituent, or as a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not specifically limited, but may be 2 to 30, 2 to 20, or 2 to 10. Examples of an alkynyl group may include an ethynyl group, a propynyl group, etc., but embodiments are not limited thereto.

In the specification, the hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, the fluorenyl group may be substituted, and two substituents may be bonded to each other to form a spiro structure. Examples of a substituted fluorenyl group are as follows. However, embodiments are not limited thereto.

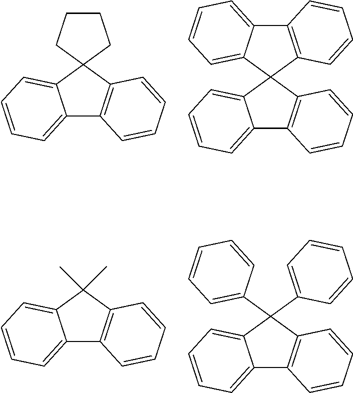

In the specification, a heterocyclic group may be any functional group or substituent derived from a ring that includes at least one of B, O, N, P, Si, S, or Se as a heteroatom. A heterocyclic group may be an aliphatic heterocyclic group or an aromatic heterocyclic group.

An aromatic heterocyclic group may be a heteroaryl group. The aliphatic heterocycle and the aromatic heterocycle may each independently be monocyclic or polycyclic.

In the specification, a heterocyclic group may include at least one of B, O, N, P, Si, S, or Se as a heteroatom. If a heterocyclic group contains two or more heteroatoms, the two or more heteroatoms may be the same as or different from each other. In the specification, a heterocyclic group may be monocyclic or polycyclic. A heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N, P, Si, S, or Se as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, or Se as a heteroatom. When a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of the aryl group may be applied to an arylene group, except that the arylene group is a divalent group. The above description of the heteroaryl group may be applied to a heteroarylene group, except that the heteroarylene group is a divalent group.

In the specification, a boron group may be a boron atom that is bonded to an alkyl group or an aryl group as defined above. A boron group may be an alkyl boron group or an aryl boron group. Examples of a boron group may include a dimethylboron group, a t-butylmethylboron group, a diphenylboron group, a phenylboron group, etc., but embodiments are not limited thereto.

In the specification, a silyl group may be an alkylsilyl group or an arylsilyl group.

Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of ring-forming carbon atoms in a carbonyl group is not specifically limited, but may be 1 to 40, 1 to 30, or 1 to 20. For example, a carbonyl group may have one of the following structures, but embodiments are not limited thereto:

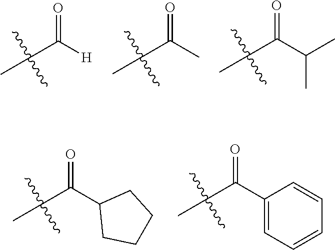

In the specification, the number of carbon atoms in a sulfinyl group or in a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not specifically limited, but may be, for example, 1 to 20 or 1 to 10. Examples of an oxy group may include methoxy, ethoxy, n-propoxy, isopropoxy, butoxy, pentyloxy, hexyloxy, octyloxy, nonyloxy, decyloxy, benzyloxy, etc., but embodiments are not limited thereto.

In the specification, the number of carbon atoms in an amine group is not specifically limited, but may be 1 to 30. An amine group may be an alkyl amine group or an aryl amine group. Examples of an amine group include a methylamine group, a dimethylamine group, a phenylamine group, a diphenylamine group, a naphthylamine group, a 9-methyl-anthracenylamine group, etc., but embodiments are not limited thereto.

In the specification, an alkyl group in an alkylthio group, an alkylsulfoxy group, an alkylaryl group, an alkylamino group, an alkyl boron group, an alkyl silyl group, or an alkyl amine group may be the same as an example of the alkyl group as described above.

In the specification, an aryl group in an aryloxy group, an arylthio group, an arylsulfoxy group, an arylamino group, an arylboron group, an arylsilyl group, or an arylamine group may be the same as an example of the aryl group as described above.

In the specification, a direct linkage may be a single bond.

In the specification, the symbols

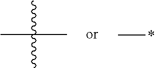

or each represent a bonding site to a neighboring atom.

Hereinafter, embodiments will be described with reference to the accompanying drawings.

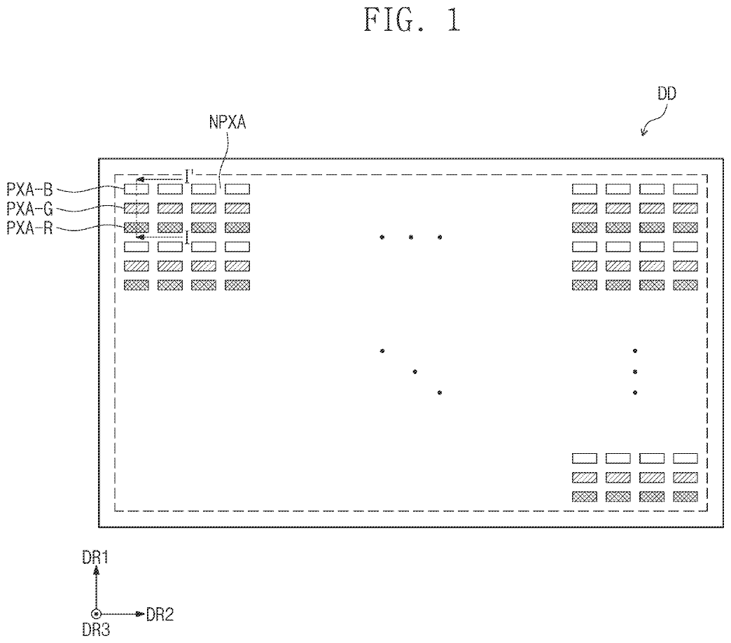

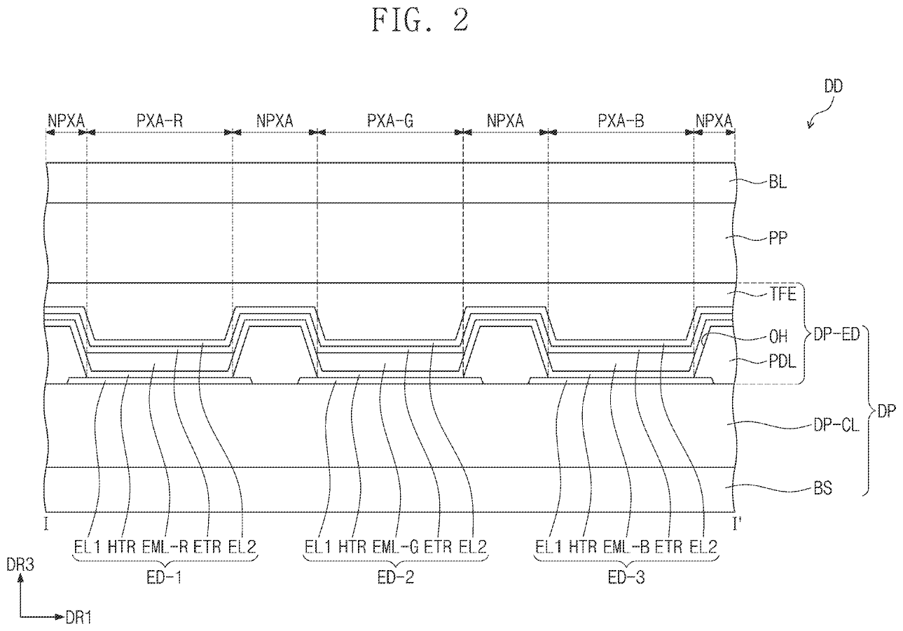

FIG. 1 is a plan view illustrating an embodiment of a display device DD. FIG. 2 is a schematic cross-sectional view of the display device DD according to an embodiment. FIG. 2 is a schematic cross-sectional view illustrating a part taken along line I-I′ of FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP and may control light that is reflected at the display panel DP from an external light. The optical layer PP may include, for example, a polarization layer or a color filter layer. Although not shown in the drawing, in an embodiment, the optical layer PP may be omitted from the display device DD.

A base substrate BL may be disposed on the optical layer PP. The base substrate BL may provide a base surface on which the optical layer PP disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

The light emitting elements ED-1, ED-2, and ED-3 may each have a structure a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and a hole transport region HTR, an electron transport region ETR, and a second electrode EL2 are each provided as a common layer for all of the light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be a single layer or a stack of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display element layer DP-ED from moisture and/or oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region which emits light generated by the respective light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between neighboring light emitting regions PXA-R, PXA-G, and PXA-B, and may correspond to the pixel defining film PDL. For example, in an embodiment, the light emitting regions PXA-R, PXA-G, and PXA-B may each respectively correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in the openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light are illustrated. For example, the display device DD may include the red light emitting region PXA-R, the green light emitting region PXA-G, and the blue light emitting region PXA-B that are separated from each other.

In the display device DD according to an embodiment, the light emitting elements ED-1, ED-2 and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may each emit light in a same wavelength range or at least one light emitting element may emit light in a wavelength range that is different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may each be arranged along a second directional axis DR2. In another embodiment, the red light emitting region PXA-R, the green light emitting region PXA-G, and the blue light emitting region PXA-B may be alternately arranged in this order along a first directional axis DR1.

FIGS. 1 and 2 illustrate that the light emitting regions PXA-R, PXA-G, and PXA-B all have a similar area, but embodiments are not limited thereto. The light emitting regions PXA-R, PXA-G, and PXA-B may have different areas from each other according to a wavelength range of the emitted light. For example, the areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required for the display device DD. For example, the light emitting regions PXA-R, PXA-G, and PXA-B may be arranged in a pentile configuration (such as a PENTILE® configuration) or in a diamond configuration (such as a Diamond Pixel™ configuration).

The areas of the light emitting regions PXA-R, PXA-G, and PXA-B may be different in size from each other. For example, in an embodiment, an area of the green light emitting region PXA-G may be smaller than an area of the blue light emitting region PXA-B, but embodiments are not limited thereto.

In the display device DD according to an embodiment illustrated in FIG. 2, at least one of the first to third light emitting elements ED-1, ED-2, and ED-3 may each include a polycyclic compound according to an embodiment, which will be described below.

FIGS. 3 to 6 are each a schematic cross-sectional view illustrating a light emitting element according to an embodiment. The light emitting elements ED according to embodiments may each include a first electrode EL1, a second electrode EL2 facing the first electrode EL1, and at least one functional layer disposed between the first electrode EL1 and the second electrode EL2. The light emitting element ED may include a polycyclic compound according to an embodiment, which will be described below, in at least one functional layer.

In the specification, the polycyclic compound according to an embodiment may be referred to as a first compound.

Each of the light emitting elements ED may include, as the at least one functional layer, a hole transport region HTR, an emission layer EML, and an electron transport region ETR that are stacked in that order.

Referring to FIG. 3, a light emitting element ED according to an embodiment may include a first electrode EL1, a hole transport region HTR, an emission layer EML, an electron transport region ETR, and a second electrode EL2 that are stacked in that order. In the light emitting element ED, the emission layer EML may include a polycyclic compound according to an embodiment, which will be described below.

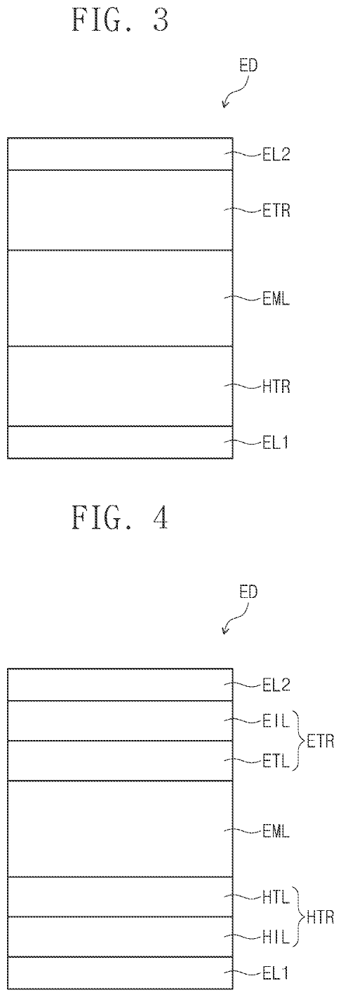

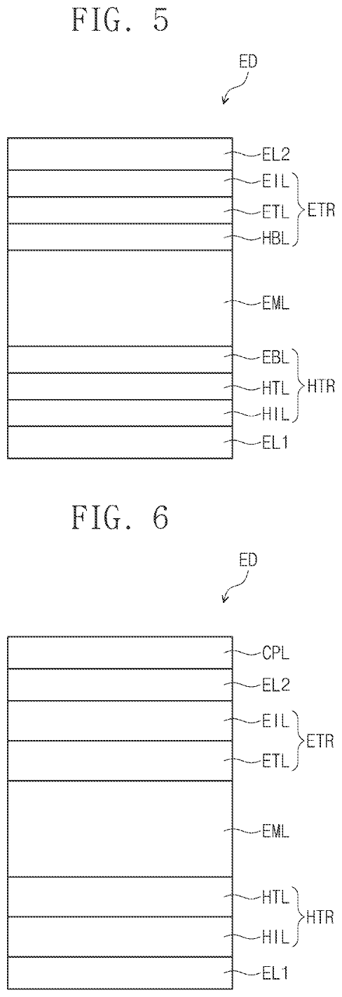

In comparison to FIG. 3, FIG. 4 illustrates a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting element ED according to an embodiment that includes a capping layer CPL disposed on a second electrode EL2.

In an embodiment, the emission layer EML may include a first compound that includes a core moiety that includes a boron atom as a ring-forming atom, and includes at least two substituents having a dibenzoheterole skeleton which is substituted at the core moiety and includes benzene as a linking moiety. The substituent having a dibenzoheterole skeleton in the first compound may be a carbazole derivative, a dibenzofuran derivative, or a dibenzothiophene derivative.

In an embodiment, the emission layer EML may include at least one of a second compound or a third compound, and may further include a fourth compound. The second compound may include a substituted or unsubstituted carbazole group. The third compound may include a hexagonal ring containing at least one nitrogen atom as a ring-forming atom.

The fourth compound may be an organometallic complex compound. The fourth compound may be an organometallic complex compound containing platinum (Pt) or iridium (Ir) as a central metal.

In the light emitting element ED according to an embodiment, the first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. The first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may be a layer consisting of a single material, a layer including different materials, or a structure including multiple layers including different materials.

The hole transport region HTR may include at least one of a hole injection layer HIL, a hole transport layer HTL, a buffer layer (not shown), an emission-auxiliary layer (not shown), or an electron blocking layer EBL. Although not shown in the drawings, the hole transport region HTR may include multiple hole transport layers.

The hole transport region HTR may have a single layer structure of a hole injection layer HIL or a hole transport layer HTL, or may have a single layer structure formed of a hole injection material and a hole transport material. In an embodiment, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), or a hole transport layer HTL/buffer layer (not shown) are stacked in its respective stated order from the first electrode EL1, but embodiments are not limited thereto.

A thickness of the hole transport region HTR may be, for example, in a range of about 50 Å to about 15,000 Å. The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

A hole transport region HTR in the light emitting element ED may include a compound represented by Formula H-1:

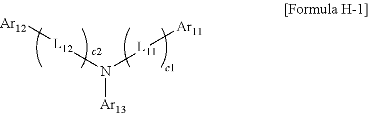

In Formula H-1, L₁₁ and L₁₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, c1 and c2 may be each independently an integer from 0 to 10. When c1 or c2 is 2 or more, multiple groups of L₁₁ or multiple groups of L₁₂ may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁₁ and Ar₁₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₁ may be a substituted or unsubstituted aryl group having 6 to 30 ring-forming carbon atoms.

In an embodiment, a compound represented by Formula H-1 may be a monoamine compound. In another embodiment, the compound represented by Formula H-1 may be a diamine compound in which at least one of Ar₁₁ to Ar₁₃ includes an amine group as a substituent.

In still other embodiments, the compound represented by Formula H-1 may be a carbazole-based compound in which at least one of Ar₁₁ or Ar₁₂ includes a substituted or unsubstituted carbazole group, or may be a fluorene-based compound in which at least one of Ar₁₁ or Ar₁₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H:

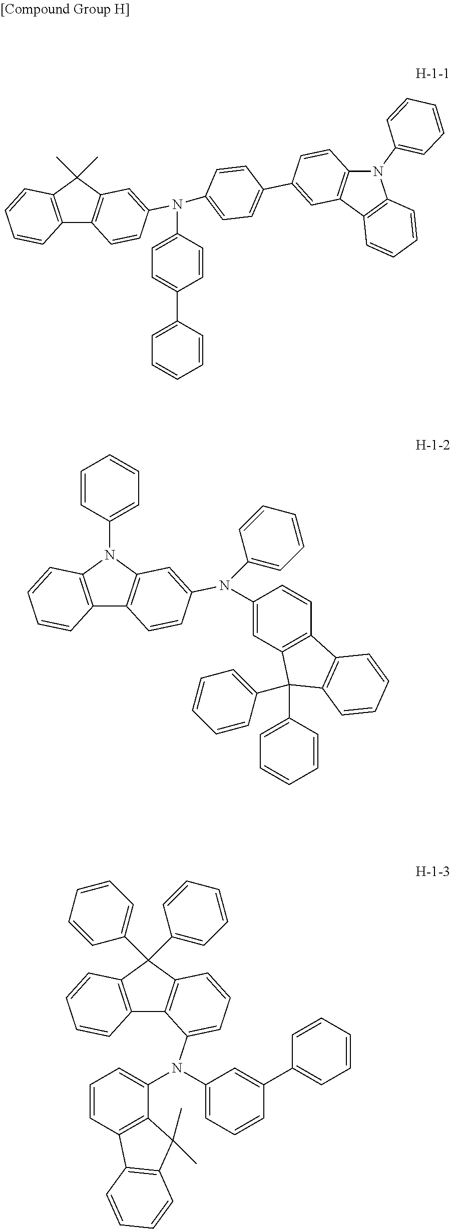 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

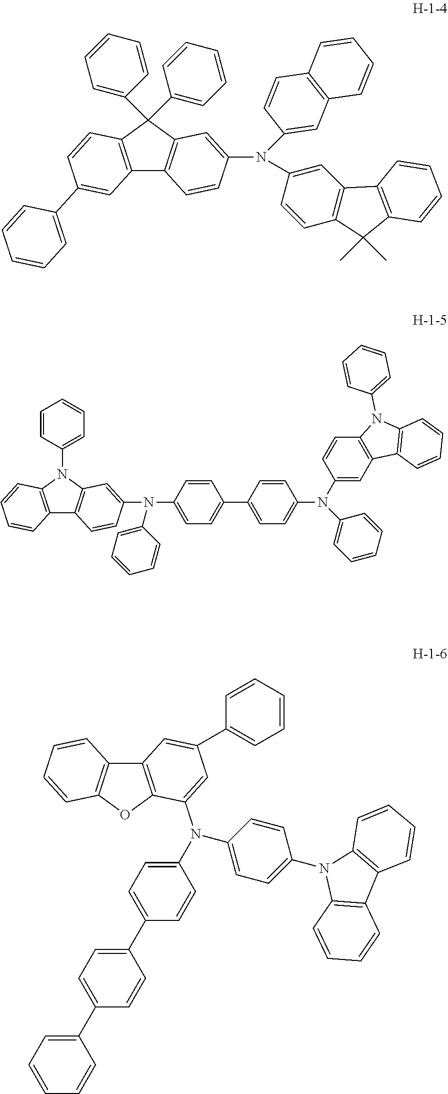 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

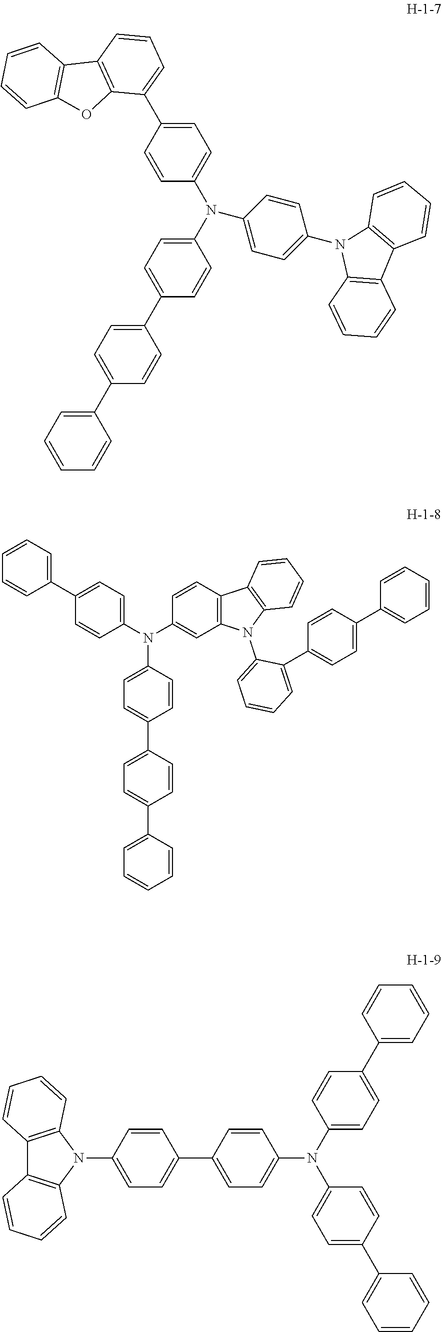 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

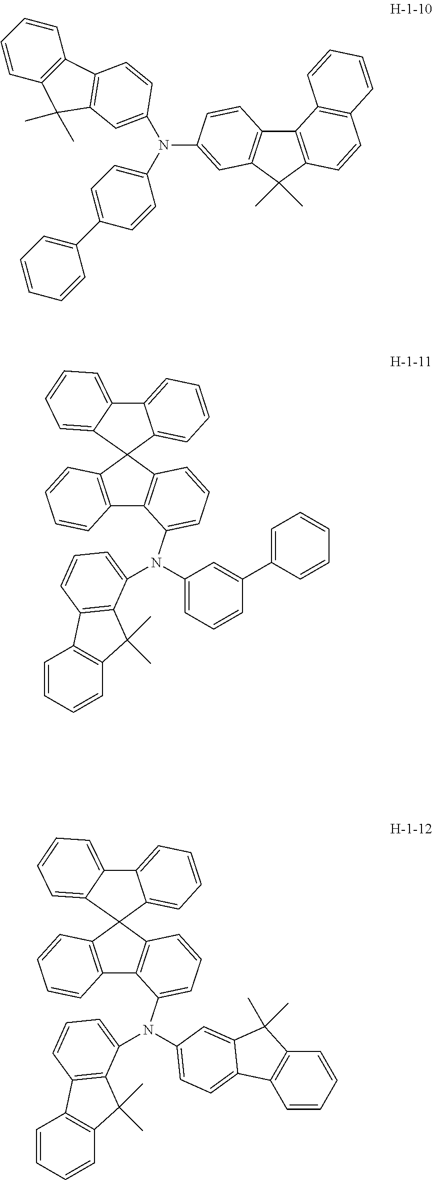 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

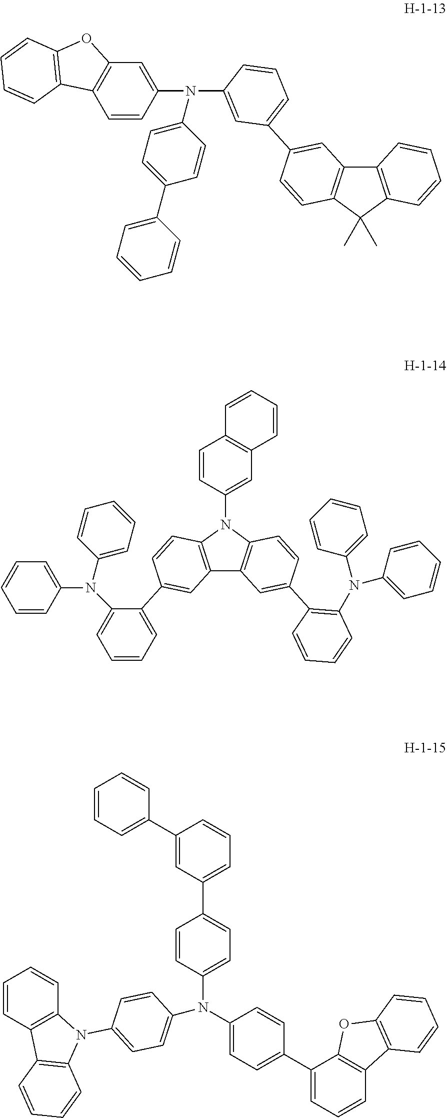 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

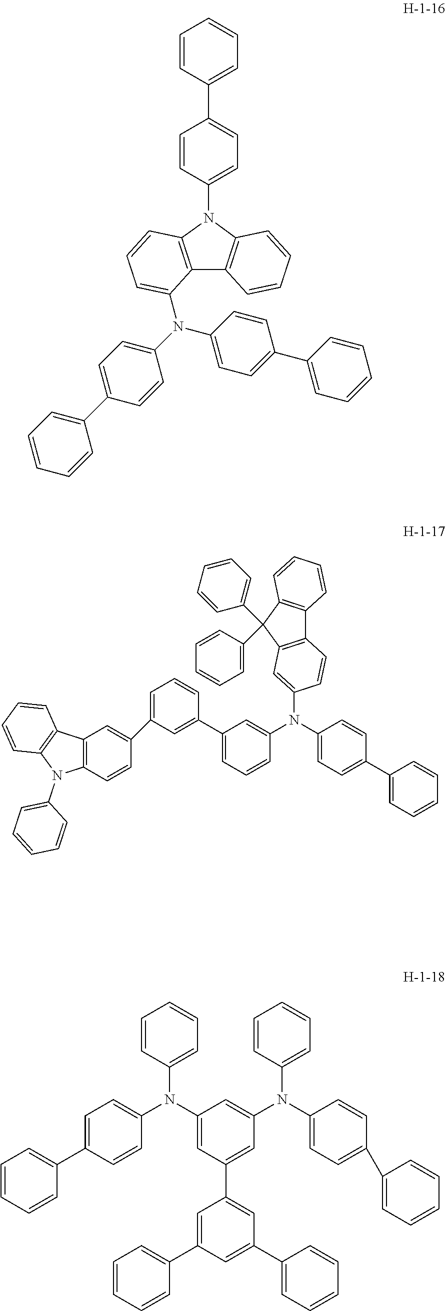 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

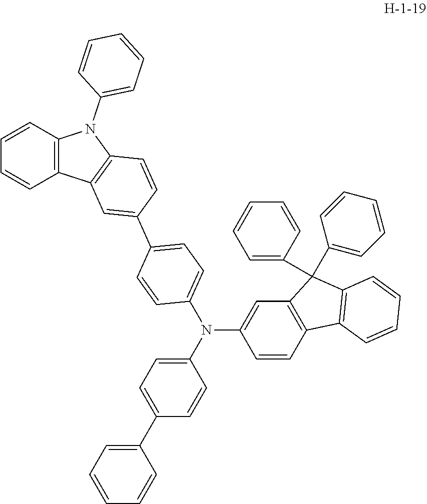 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N-(1-naphthyl)-N-phenylamino]-triphenylamine (1-TNATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB or NPD of α-NPD), triphenylamine-containing polyetherketone (TPAPEK), 4-isopropyl-4′-methyldiphenyliodonium [tetrakis(pentafluorophenyl)borate], dipyrazino[2,3-f:2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenyl amine-based derivative such as 4,4′,4″-tris(N-carbazolyl)triphenylamine (TCTA), or N,N′-bis(3-methylphenyl)-N,N′-diphenyl-[1,1′-biphenyl]-4,4′-diamine (TPD), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 250 Å to about 1,000 Å. For example, when the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f:2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown), an emission-auxiliary layer (not shown), or an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material included in the buffer layer (not shown). The electron blocking layer EBL may prevent electron injection from an electron transport region ETR to the hole transport region HTR. The emission-auxiliary layer (not shown) may improve charge balance between holes and electrons. When the hole transport region HTR includes an electron blocking layer EBL, the electron blocking layer EBL may include the function of an emission-auxiliary layer.

The emission layer EML is provided on the hole transport region HTR. The emission layer EML may have a thickness, for example, in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

In an embodiment, the emission layer EML may include a first compound represented by Formula 1. The first compound corresponds to a polycyclic compound according to an embodiment:

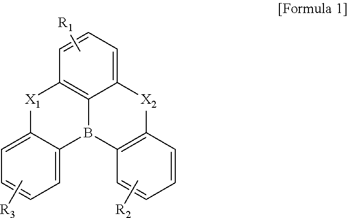

In Formula 1, X₁ and X₂ may each independently be N(R₄) or O. In the polycyclic compound, X₁ and X₂ may be the same as or different from each other. For example, in an embodiment, any one of X₁ and X₂ may be N(R₄), and the other thereof may be O. In another embodiment, X₁ and X₂ may each be N(R₄) or X₁ and X₂ may each be O. When X₁ and X₂ are each N(R₄), each R₄ group may be the same as or different from each other.

In Formula 1, any one or two of R₁ to R₄ may each independently be a group represented by Formula 2. In an embodiment, when X₁ and X₂ are each N(R₄), any one or two selected from R₁ to R₃ and two R₄ groups may each independently be a group represented by Formula 2. When any one of X₁ and X₂ is N(R₄) and the other thereof is O, any one or two of R₁ to R₄ may each independently be a group represented by Formula 2. In an embodiment, when X₁ and X₂ are each O, any one or two of R₁ to R₃ may each independently be a group represented by Formula 2. In Formula 1, the remainder of R₁ to R₄, which are not a group represented by Formula 2, may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms. In an embodiment, any one or two of R₁ to R₄ may each independently be a group represented by Formula 2, and the remainder of R₁ to R₄ may each independently be a hydrogen atom, a deuterium atom, a t-butyl group, a substituted or unsubstituted phenyl group, a substituted or unsubstituted biphenyl group, a substituted or unsubstituted terphenyl group, or a substituted or unsubstituted carbazole group. However, embodiments are not limited thereto.

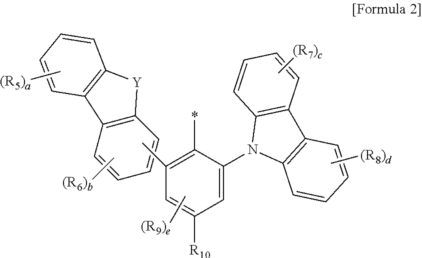

In Formula 2, Y may be N(R₁₁), O, or S. For example, a substituent represented by Formula 2 may include a carbazole derivative, a dibenzofuran derivative, or a dibenzothiophene derivative by respectively including a nitrogen atom (N), an oxygen atom (O), or a sulfur atom (S). In an embodiment, in Formula 2, Y may be O or S. For example, a substituent represented by Formula 2 may include a dibenzofuran group or a dibenzothiophene group, which is unsubstituted or substituted with R₅ and R₆.

In Formula 2, R₅ to R₈, R₁₀, and R₁₁ may each independently be a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted aryl group having 6 to 60 ring-forming carbon atoms, or a substituted or unsubstituted heteroaryl group having 2 to 60 ring-forming carbon atoms. For example, R₅ to R₈, R₁₀, and R₁₁ may each independently be a hydrogen atom, a deuterium atom, a cyano group, or a substituted or unsubstituted alkyl group having 1 to 10 carbon atoms. In Formula 2, R₉ may be a hydrogen atom or a deuterium atom.

In Formula 2, a, c, and d may each independently be an integer from 0 to 4, b may be an integer from 0 to 3, and e may be an integer from 0 to 2. When a is 2 or more, multiple R₅ groups may all be the same or at least one may be different from the rest. For example, in an embodiment, a may be 0, 1, or 4. When c and d are each 2 or more, multiple groups of R₇ and multiple groups of R₈ may each be the same or at least one may be different from the rest. For example, in an embodiment, c and d may each independently be 0, 1, or 4. When b is 2 or more, multiple R₆ groups may all be the same or at least one may be different from the rest. For example, in an embodiment, b may be 0 or 1. When e is 2, two R₉ groups may be the same as or different from each other.

In an embodiment, a case where a is 0 may be the same as a case where a is 4 and R₅ groups are hydrogen atoms. It may be understood that when a is 0, R₅ is not substituted at the polycyclic compound represented by Formula 1. Such a description may also be equally applied to a case where c or d is 0. In an embodiment, a case where b is 0 may be the same as a case where b is 3 and R₆ groups are hydrogen atoms. It may be understood that when b is 0, R₆ is not substituted at the polycyclic compound represented by Formula 1. A case where e is 0 may be the same as a case where e is 2 and R₉ groups are hydrogen atoms. It may be understood that when e is 0, R₉ is not substituted at the polycyclic compound represented by Formula 1.

The polycyclic compound may include at least one deuterium atom as a substituent. For example, in an embodiment, in Formula 1, at least one of R₁ to R₃, X₁, and X₂ may each independently be a deuterium atom, or may each independently include a substituent that includes a deuterium atom. In an embodiment, at least one of R₁ to R₄ may each independently be a deuterium atom, or may each independently include a substituent that includes a deuterium atom. For example, in the polycyclic compound represented by Formula 1, at least one of R₁ to R₁₀ may each independently be a deuterium atom, or may each independently be a substituent that includes a deuterium atom.

The polycyclic compound represented by Formula 1 may include a core moiety of a fused ring that includes a boron atom (B) as a ring-forming atom, and including at least two substituents having a dibenzoheterole skeleton that are each substituted at an ortho-position with the core moiety. The polycyclic compound may include a substituted or unsubstituted benzene derivative between a core moiety that include a boron atom and two substituents having a dibenzoheterole skeleton. Each of the two substituents having a dibenzoheterole skeleton is bonded to a linking moiety, which is the benzene derivative, at an ortho-position with the core moiety that includes a boron atom, and thus the polycyclic compound according to an embodiment may have more activated multiple resonance in the core moiety of the fused ring and high oscillator strength (f) and absorbance. The polycyclic compound may include one or two bulky substituents in which two substituents having a dibenzoheterole skeleton are linked via the benzene derivative as a linking moiety, thereby exhibiting increased molecular stability characteristics.

The bulky substituent included in the polycyclic compound may include a carbazole derivative as a first substituent, and a carbazole derivative, a dibenzothiophene derivative, or a dibenzofuran derivative as a second substituent. In the polycyclic compound, the benzene derivative serves as a linking moiety, a nitrogen atom of the first substituent may bonded to the benzene derivative, and a ring-forming carbon atom of the second substituent may bonded to the benzene derivative. In the polycyclic compound, the first substituent protects a boron atom of the core moiety of the fused ring, and the second substituent controls an intermolecular distance, and thus Dexter energy transfer between molecules may be effectively controlled.

The polycyclic compound includes the first substituent and the second substituent, which further induces HOMO-LUMO separation between the bulky substituent and the core moiety, in addition to HOMO-LUMO separation within the core moiety, and thus may exhibit the characteristics of an increase in delayed fluorescence phenomenon.

For example, the polycyclic compound has a bulky substituent including the first substituent and the second substituent that is bonded to the boron-containing core moiety of the fused ring via the benzene derivative as a linking moiety, and thus may exhibit the characteristics of an increase in the stability of the compound, light extraction efficiency, and delayed fluorescence. Accordingly, the polycyclic compound may contribute to improving luminous efficiency and service life of the light emitting element.

In an embodiment, the polycyclic compound represented by Formula 1 may be represented by any one of Formula 1-1 to Formula 1-3. Formula 1-1 to Formula 1-3 each represent a case wherein a bonding position of a substituent represented by Formula 2 is specified in Formula 1:

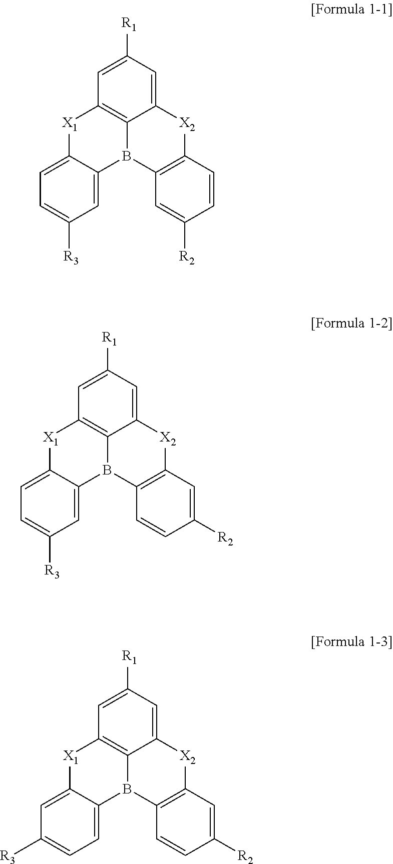

In Formula 1-1 to Formula 1-3, R₁, to R₃, X₁, and X₂ are each the same as described in Formula 1. Thus, any one or two of R₁ to R₄ may be a group represented by Formula 2 as described above.

For example, in the polycyclic compound represented by any one of Formula 1-1 to Formula 1-3, a substituent represented by Formula 2 may be bonded at a para- and/or at a meta-position with the boron atom, which is a ring-forming atom of the fused ring.

In an embodiment, the polycyclic compound represented by Formula 1-1 may be represented by any one of Formula 1-1-1 to Formula 1-1-4.

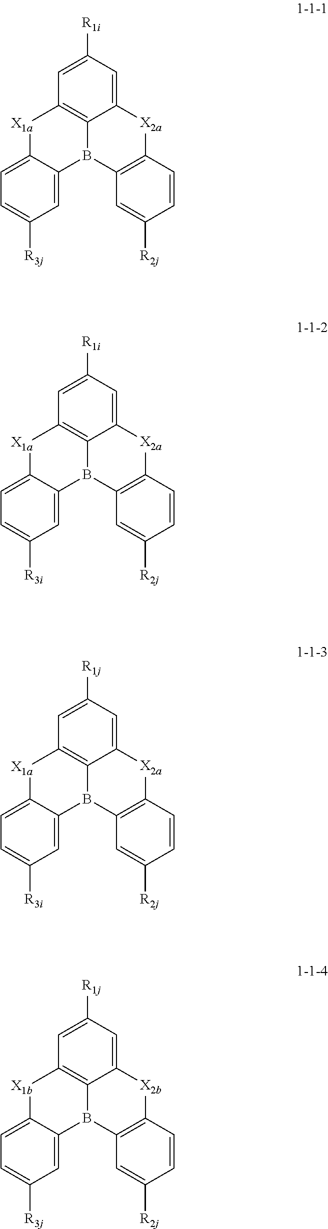

In Formula 1-1-1 to Formula 1-1-4, X₁ₐ and X₂ₐ may each independently be N(R₄ⱼ) or O; and X_{1b} and X_{2b} may each independently be N(R₄ᵢ) or O. For example, in the polycyclic compound represented by any one of Formula 1-1-1 to Formula 1-1-3, X₁ₐ and X₂ₐ may each be N(R₄ⱼ) or may each be an oxygen atom (O), or any one of X₁ₐ and X₂ₐ may be N(R₄ⱼ), and the other thereof may be an oxygen atom (O). In the polycyclic compound represented by Formula 1-1-4, X_{1b} and X_{2b} may each be N(R₄ᵢ) or may each be an oxygen atom (O), or any one of X_{1b} and X_{2b} may be N(R₄ᵢ), and the other thereof may be an oxygen atom (O).

In Formula 1-1-1 to Formula 1-1-4, R₁ᵢ, R₃ᵢ, and R₄ᵢ may each independently be a group represented by Formula 2. In Formula 1-1-1 to Formula 1-1-4, R₁ⱼ, R₂ⱼ, R₃ⱼ, and R₄ⱼ may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms. For example, R₁ⱼ, R₂ⱼ, R₃ⱼ, and R₄ⱼ may each independently be a hydrogen atom, a deuterium atom, a t-butyl group, a substituted or unsubstituted phenyl group, a substituted or unsubstituted biphenyl group, a substituted or unsubstituted terphenyl group, or a substituted or unsubstituted carbazole group. In Formula 1-1-1 to Formula 1-1-4, when R₁ⱼ, R₂ⱼ, R₃ⱼ, and R₄ⱼ are each different substituents, they may each independently be substituted with a deuterium atom, a phenyl group, a t-butyl group, etc. However, these are only examples, and embodiments are not limited thereto.

The polycyclic compound represented by any one of Formula 1-1-1 to Formula 1-1-4 may be represented by any one of Formula 1-1A to Formula 1-1K. For example, Formula 1-1-1 may be represented by one of Formulas 1-1A, 1-1E, or 1-1I, and Formula 1-1-2 may be represented by one of Formulas 1-1B, 1-1H, or 1-1K. For example, Formula 1-1-3 may be represented by one of Formulas 1-1F or 1-1J, and Formula 1-1-4 may be represented by one of Formulas 1-1C, 1-1D, or 1-1G. In Formulas 1-1A to 1-1K, R₁ᵢ, R₃ᵢ, R₄ᵢ₋₁, and R₄ᵢ₋₂ may each independently be a group represented by Formula 2 as described herein. In Formulas 1-1A to 1-1K, R₁ⱼ, R₂ⱼ, and R₃ⱼ are each the same as described in Formulas 1-1-1 to 1-1-4, and R₄ⱼ₋₁ and R₄ⱼ₋₂ are each independently the same as described in connection with R₄ⱼ in Formulas 1-1-1 to 1-1-4.

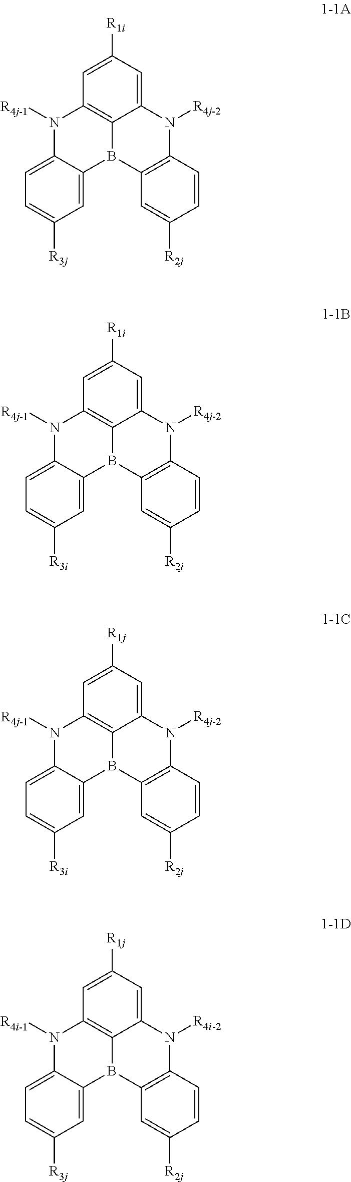

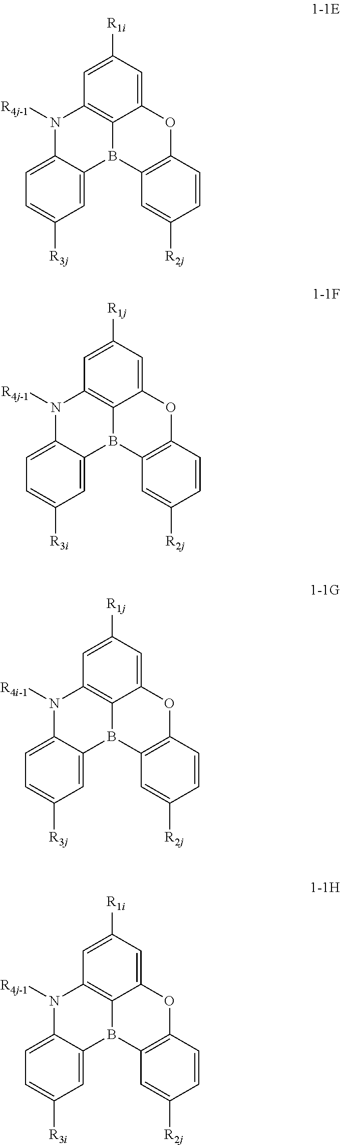

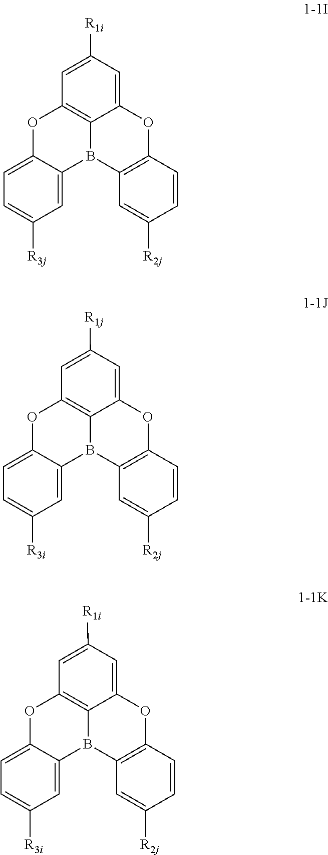

The polycyclic compound represented by one of Formulas 1-1A, 1-1C, 1-1E, 1-1F, 1-1G, 1-1I, or 1-1J may include a substituent represented by Formula 2, and the polycyclic compound represented by one of Formulas 1-1B, 1-1D, 1-1H, or 1-1K may include two substituents each independently represented by Formula 2.

In an embodiment, the polycyclic compound represented by Formula 1-2 may be represented by any one of Formula 1-2-1 to Formula 1-2-3:

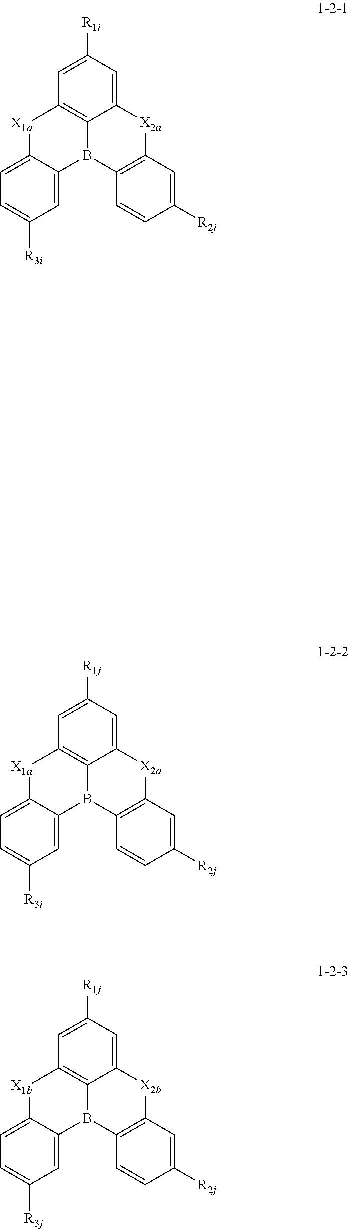

In Formula 1-2-1 to Formula 1-2-3, X₁ₐ and X₂ₐ may each independently be N(R₄ⱼ) or O; and X_{1b} and X_{2b} may each independently be N(R₄ᵢ) or O. For example, in the polycyclic compound represented by any one of Formula 1-2-1 and Formula 1-2-2, X₁ₐ and X₂ₐ may each be N(R₄ⱼ) or may each be an oxygen atom (O), or any one of X₁ₐ and X₂ₐ may be N(R₄ⱼ), and the other thereof may be an oxygen atom (O). In the polycyclic compound represented by Formula 1-2-3, X_{1b} and X_{2b} may each be N(R₄ᵢ) or may each be an oxygen atom (O), or any one of X_{1b} and X_{2b} may be N(R₄ᵢ), and the other thereof may be an oxygen atom (O).

In Formula 1-2-1 to Formula 1-2-3, R₁ᵢ, R₃ᵢ, and R₄ᵢ may each independently be a group represented by Formula 2. In Formula 1-2-1 to Formula 1-2-3, R₁ⱼ, R₂ⱼ, R₃ⱼ, and R₄ⱼ may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms. For example, R₁ⱼ, R₂ⱼ, R₃ⱼ, and R₄ⱼ may each independently be a hydrogen atom, a deuterium atom, a substituted or unsubstituted phenyl group, a substituted or unsubstituted biphenyl group, a substituted or unsubstituted terphenyl group, or a substituted or unsubstituted carbazole group. In Formula 1-2-1 to Formula 1-2-3, when R₁ⱼ, R₂ⱼ, R₃ⱼ, and R₄ⱼ are each different substituents, they may each independently be substituted with a deuterium atom, a phenyl group, a t-butyl group, etc. However, these are only examples, and embodiments are not limited thereto.

The polycyclic compound represented by any one of Formula 1-2-1 to Formula 1-2-3 may be represented by any one of Formulas 1-2A to 1-2H. For example, Formula 1-2-1 may be represented by one of Formulas 1-2A or 1-2F. For example, Formula 1-2-2 may be represented by one of Formulas 1-2B, 1-2D, or 1-2H below. For example, Formula 1-2-3 may be represented by one of Formulas 1-2C, 1-2E or 1-2G. In Formulas 1-2A to 1-2H, R₁ᵢ, R₃ᵢ, R₄ᵢ₋₁, and R₄ᵢ₋₂ may each independently be a group represented by Formula 2 as described herein. In Formulas 1-2A to 1-2H, R₁ⱼ, R₂ⱼ, and R₃ⱼ are each the same as described in Formulas 1-2-1 to 1-2-3, and R₄ⱼ₋₁ and R₄ⱼ₋₂ are each independently the same as described in connection with R₄ⱼ in Formulas 1-2-1 to 1-2-3.

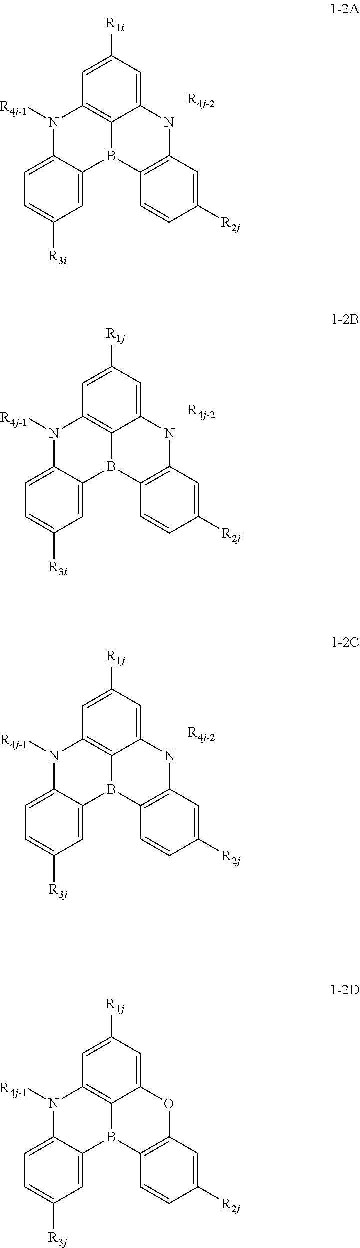

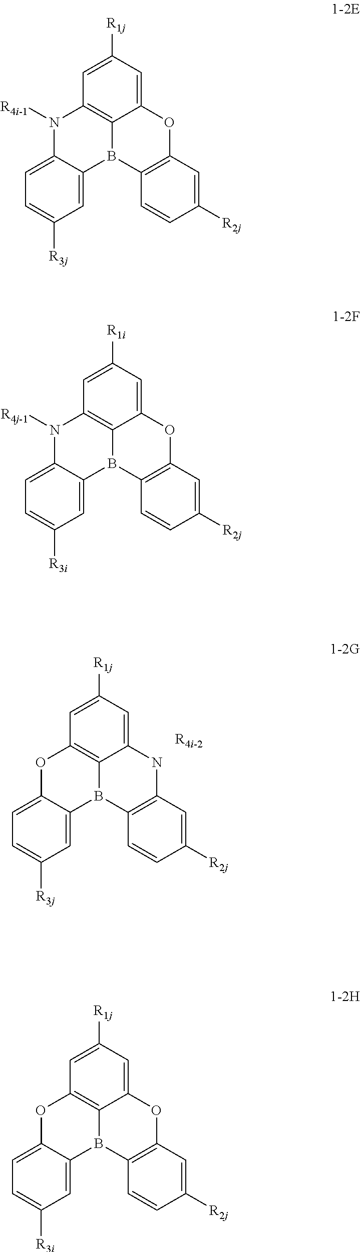

The polycyclic compound represented by one of Formulas 1-2B, 1-2D, 1-2E, 1-2G, or 1-2H may include a substituent represented by Formula 2, and the polycyclic compound represented by one of Formulas 1-2A, 1-2C, or 1-2F may include two substituents each independently represented by Formula 2.

In an embodiment, the polycyclic compound represented by Formula 1-3 may be represented by any one of Formula 1-3-1 to Formula 1-3-4:

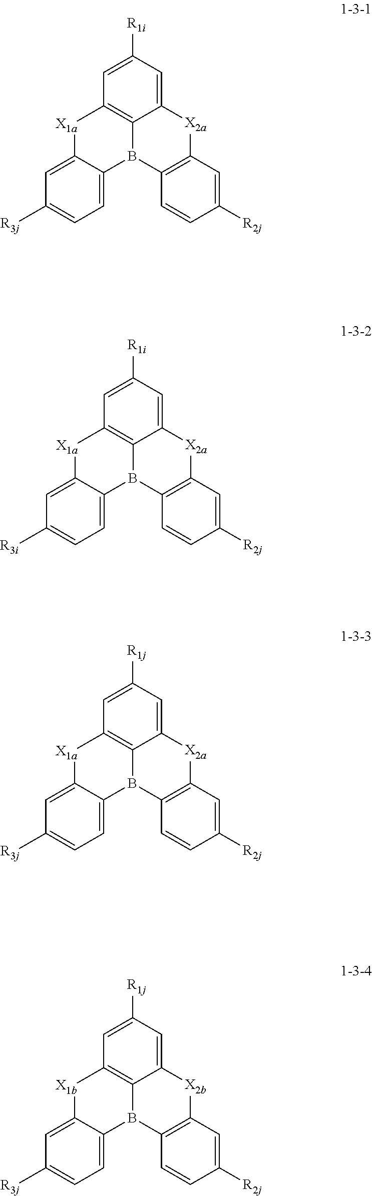

In Formula 1-3-1 to Formula 1-3-4, X₁ₐ and X₂ₐ may each independently be N(R₄ⱼ) or O; and X_{1b} and X_{2b} may each independently be N(R₄ᵢ) or O. For example, in the polycyclic compound represented by any one of Formula 1-3-1 to Formula 1-3-3, X₁ₐ and X₂ₐ may each be N(R₄ⱼ) or may each be an oxygen atom (O), or any one of X₁ₐ and X₂ₐ may be N(R₄ⱼ), and the other thereof may be an oxygen atom (O). In the polycyclic compound represented by Formula 1-3-4, X_{1b} and X_{2b} may each be N(R₄ᵢ) or may each be an oxygen atom (O), or any one of X_{1b} and X_{2b} may be N(R₄ᵢ), and the other thereof may be an oxygen atom (O).

In Formula 1-3-1 to Formula 1-3-4, R₁ᵢ, R₃ᵢ, and R₄ᵢ may each independently be a group represented by Formula 2. In Formula 1-3-1 to Formula 1-3-4, R₁ⱼ, R₂ⱼ, R₃ⱼ, and R₄ⱼ may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms. For example, R₁ⱼ, R₂ⱼ, R₃ⱼ, and R₄ⱼ may each independently be a hydrogen atom, a deuterium atom, a t-butyl group, a substituted or unsubstituted phenyl group, a substituted or unsubstituted biphenyl group, a substituted or unsubstituted terphenyl group, or a substituted or unsubstituted carbazole group. In Formula 1-3-1 to Formula 1-3-4, when R₁ⱼ, R₂ⱼ, R₃ⱼ, and R₄ⱼ are each different substituents, they may each independently be substituted with a deuterium atom, a phenyl group, a t-butyl group, etc. However, these are only examples, and embodiments are not limited thereto.

The polycyclic compound represented by any one of Formula 1-3-1 to Formula 1-3-4 may be represented by any one of Formula 1-3A to Formula 1-3J. For example, Formula 1-3-1 may be represented by one of Formulas 1-3A, 1-3E, or 1-3H, and Formula 1-3-2 may be represented by one of Formulas 1-3B or 1-3I. For example, Formula 1-3-3 maybe represented by one of Formulas 1-3C, 1-3F or 1-3J, and Formula 1-3-4 may be represented by one of Formulas 1-3D or 1-3G. In Formulas 1-3A to 1-3J, R₁ᵢ, R₃ᵢ, R₄ᵢ₋₁, and R₄ᵢ₋₂ may each independently be a group represented by Formula 2 as described herein. In Formulas 1-3A to 1-3J, R₁ⱼ, R₂ⱼ, and R₃ⱼ are each the same as described in Formulas 1-3-1 to 1-3-4 and R₄ⱼ₋₁ and R₄ⱼ₋₂ are each independently the same as described in connection with R₄ⱼ in Formulas 1-3-1 to 1-3-4.

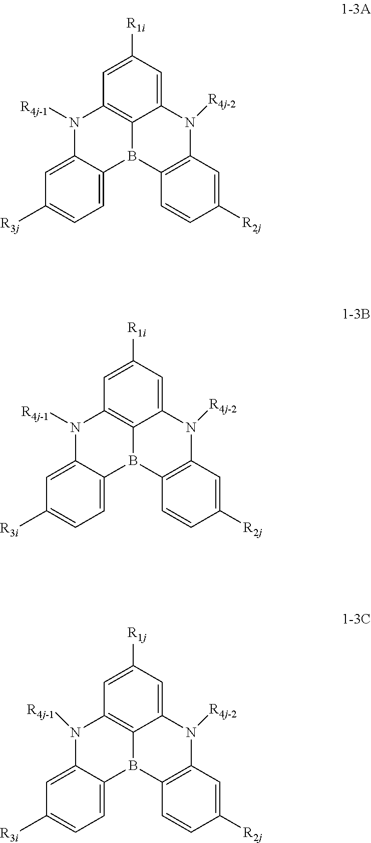

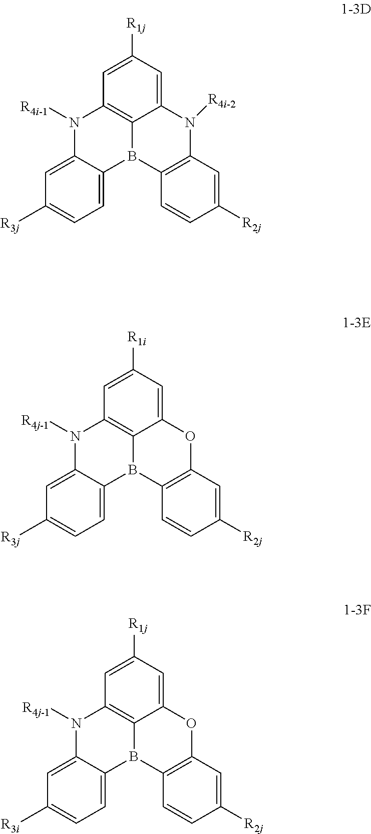

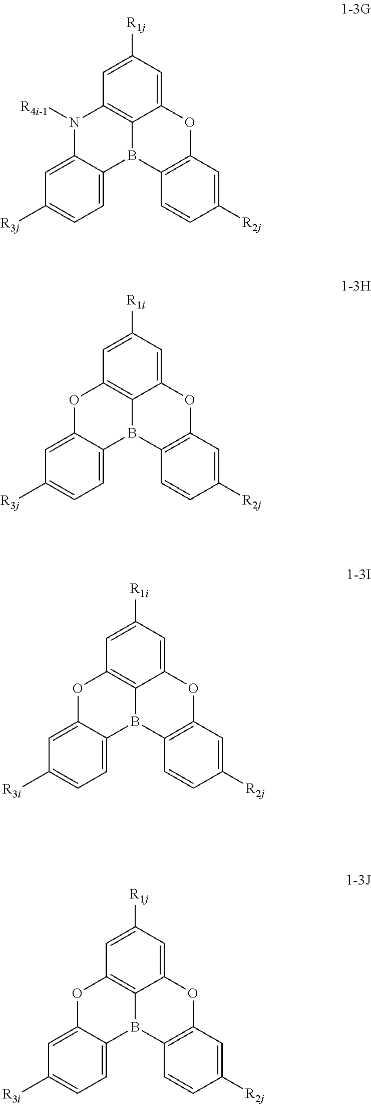

The polycyclic compound represented by one of Formulas 1-3A, 1-3C, 1-3E, 1-3F, 1-3G, 1-3H, or 1-3J may include a substituent represented by Formula 2, and the polycyclic compound represented by one of Formulas 1-3B3, 1-3D), or 1-3I may include two substituents each independently represented by Formula 2.

In an embodiment, the polycyclic compound represented by Formula 1 may be represented by any one of Formula 3-A to Formula 3-D.

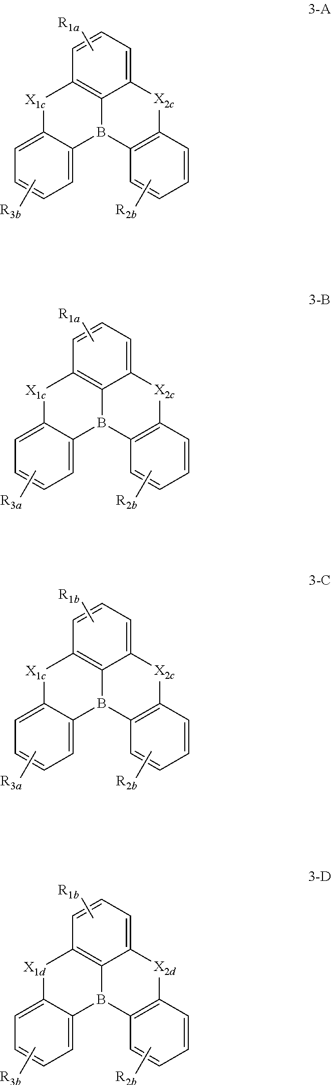

In Formula 3-A to Formula 3-D, X_{1c}, and X_{2c}, may each independently be N(R_{4b}) or O, and X_{1d} and X₂ₐ may each independently be N(R₄ₐ) or O. For example, in the polycyclic compound represented by any one of Formula 3-A to Formula 3-C, X_{1c} and X_{2c} may each be N(R_{4b}) or may each be an oxygen atom (O), or any one of X_{1c}, and X_{2c} may be N(R_{4b}), and the other thereof may be an oxygen atom (O). In the polycyclic compound represented by Formula 3-D, X_{1d} and X₂ₐ may each be N(R₄ₐ) or may each be an oxygen atom (O), or any one of X₁d and X_{2d} may be N(R₄ₐ), and the other thereof may be an oxygen atom (O).

In Formula 3-A to Formula 3-D, R₁ₐ, R₃ₐ, and R₄ₐ may each independently be a group represented by Formula 2 as described herein. In Formula 3-A to Formula 3-D, R_{1b}, R_{2b}, R_{3b}, and R_{4b} may each independently be a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms. For example, R_{1b}, R_{2b}, R_{3b}, and R_{4b} may each independently be a hydrogen atom, a deuterium atom, a t-butyl group, a substituted or unsubstituted phenyl group, a substituted or unsubstituted biphenyl group, a substituted or unsubstituted terphenyl group, or a substituted or unsubstituted carbazole group. In Formula 3-A to Formula 3-D, when R_{1b}, R_{2b}, R_{3b}, and R_{4b} are each different substituents, they may each independently be substituted with a deuterium atom, a phenyl group, a t-butyl group, etc. However, these are only examples, and embodiments are not limited thereto.

The polycyclic compound represented by any one of Formula 3-A to Formula 3-D may be represented by any one of Formula 3-1 to Formula 3-16. For example, Formula 3-A may be represented by one of Formulas 3-1, 3-7, or 3-13, and Formula 3-B may be represented by one of Formulas 3-5, 3-6, 3-11, 3-12, or 3-16. For example, Formula 3-C may be represented by one of Formulas 3-2, 3-3, 3-9, 3-10, 3-14 or 3-15 and Formula 3-D may be represented by one of Formulas 3-4 or 3-8. In Formulas 3-1 to 3-16, R₁ₐ, R₃ₐ, R₄ₐ₁ and R₄ₐ₂ may each independently be a group represented by Formula 2 as described herein. In Formulas 3-1 to 3-16, R_{1b}, R_{2b}, and R_{3b} are each the same as described in Formulas 3-A to 3-D, and R_{4b1} and R_{4b2} are each independently the same as described in connection with R_{4b} in Formulas 3-A to 3-D.

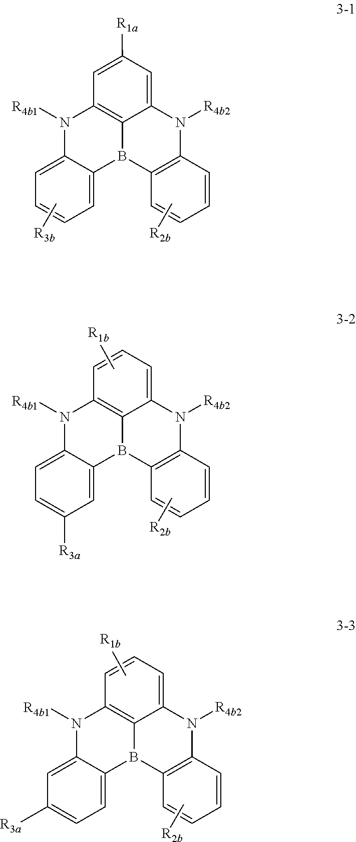

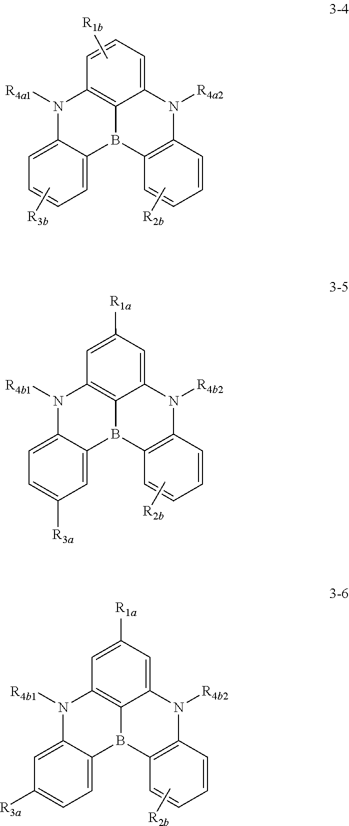

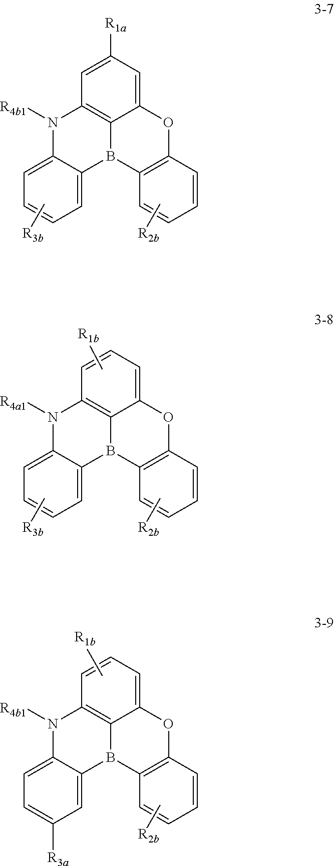

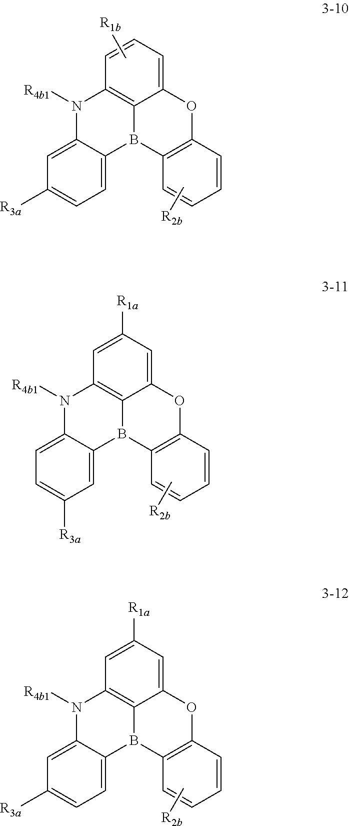

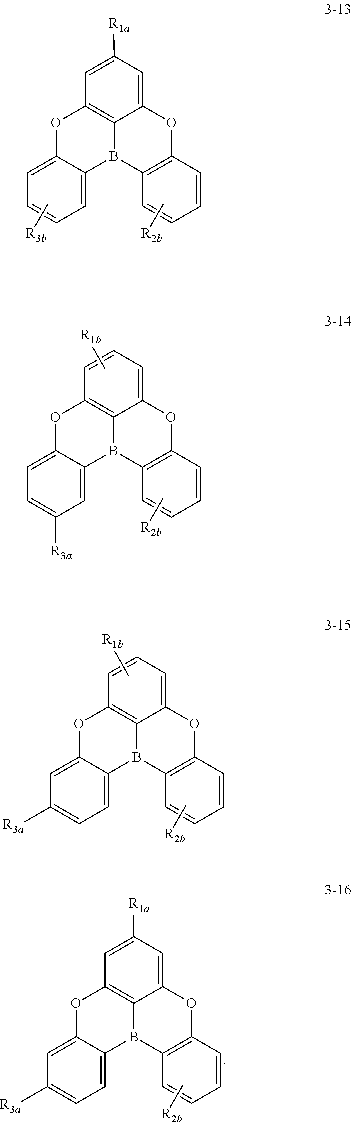

The polycyclic compound represented by one of Formulas 3-1, 3-2, 3-3, 3-7, 3-8, 3-9, 3-10, 3-13, 3-14, or 3-15 may include a substituent represented by Formula 2, and the polycyclic compound represented by one of Formulas 3-4, 3-5, 3-6, 3-11, 3-12, or 3-16 may include two substituents each independently represented by Formula 2.

In an embodiment, the substituent represented by Formula 2 may be represented by any one of Formula 2-1 to Formula 2-4. Formula 2-1 to Formula 2-4 each represent a case where R₅ to R₁₀ in Formula 2 are specified.

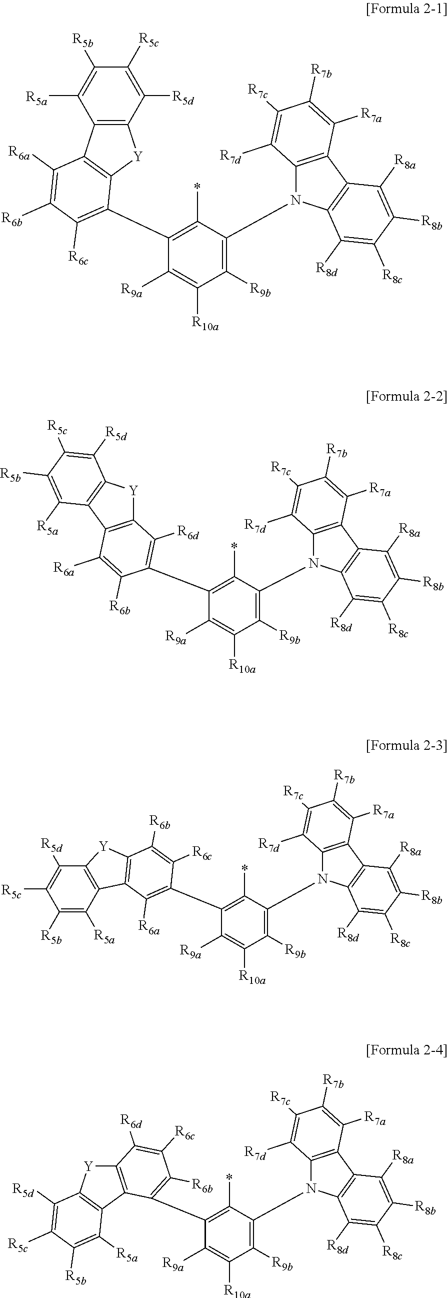

In Formula 2-1 to Formula 2-4, Y may be O or S. For example, in Formula 2-1 to Formula 2-4, among the two substituents having a dibenzoheterole skeleton, a substituent in which a ring-forming carbon atom is bonded to a benzene derivative may include an oxygen atom (O) or a sulfur atom (S) as a ring-forming atom.

In Formula 2-1 to Formula 2-4, R₅ₐ to R_{5d}, R₆ₐ to R_{6d}, R₇ₐ to R_{7d}, R₈ₐ to R_{8d}, and R₁₀ₐ may each independently be a hydrogen atom, a deuterium atom, a cyano group, or a substituted or unsubstituted alkyl group having 1 to 10 carbon atoms. For example, R₅ₐ to R_{5d}, and R₆ₐ to R_{6d} may each independently be a hydrogen atom, a deuterium atom, or a substituted or unsubstituted t-butyl group; and R₇ₐ to R_{7d}, and R₈ₐ to R_{8d} may each independently be a hydrogen atom, a deuterium atom, a cyano group, or a substituted or unsubstituted t-butyl group. For example, R₁₀ₐ may be a hydrogen atom, a deuterium atom, a substituted or unsubstituted methyl group, or a substituted or unsubstituted t-butyl group. When each of R₅ₐ to R_{5d}, R₆ₐ to R_{6d}, R₇ₐ to R_{7d}, R₈ₐ to R_{8d}, and R₁₀ₐ is substituted, each of them may be substituted with, for example, a deuterium atom. However, these are only examples, and embodiments are not limited thereto.

In Formula 2-1 to Formula 2-4, R₉ₐ and R_{9b} may each independently be a hydrogen atom or a deuterium atom. For example, R₉ₐ and R_{9b} may each be a hydrogen atom or may each be a deuterium atom.

In an embodiment, the polycyclic compound may be any compound selected from Compound Group 1. The light emitting element ED may include any compound selected from Compound Group 1. In Compound Group 1, Ph is a phenyl group, and D is a deuterium atom.

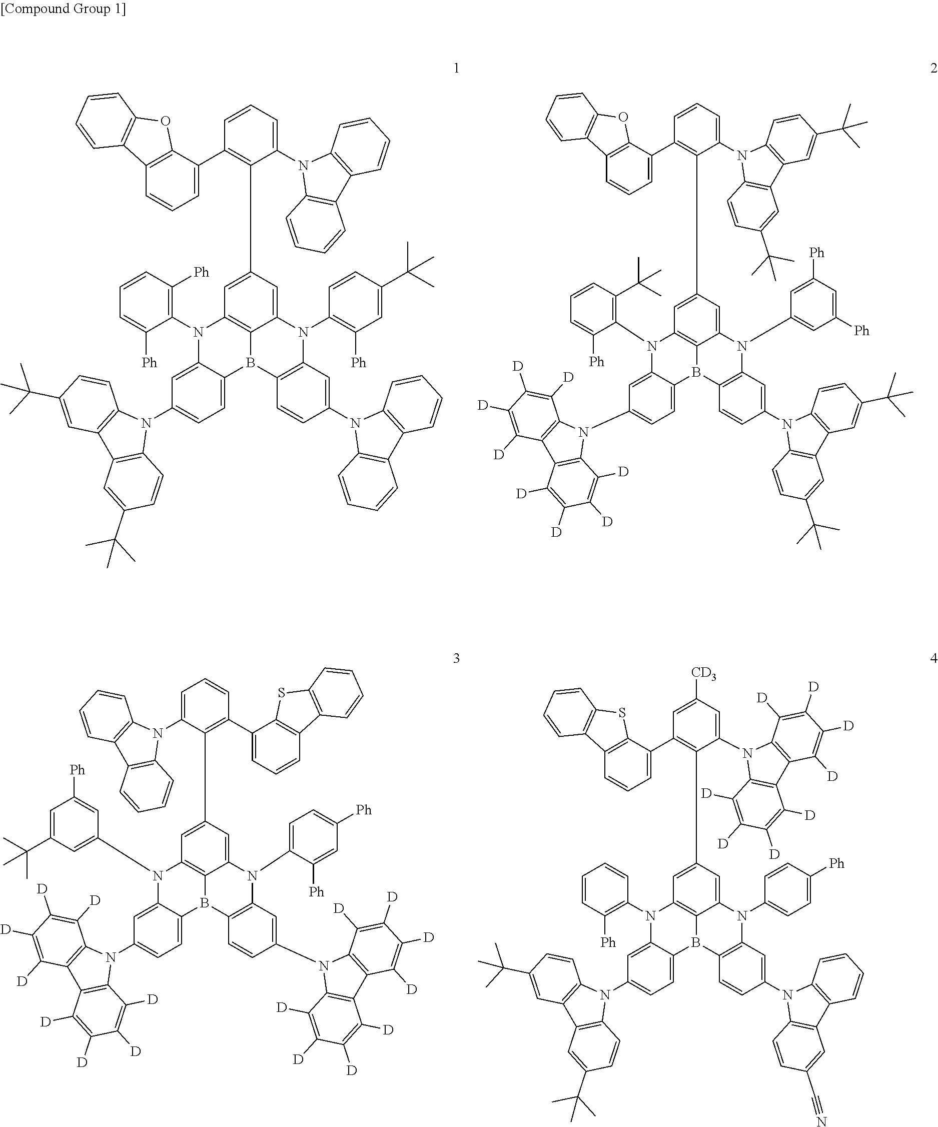

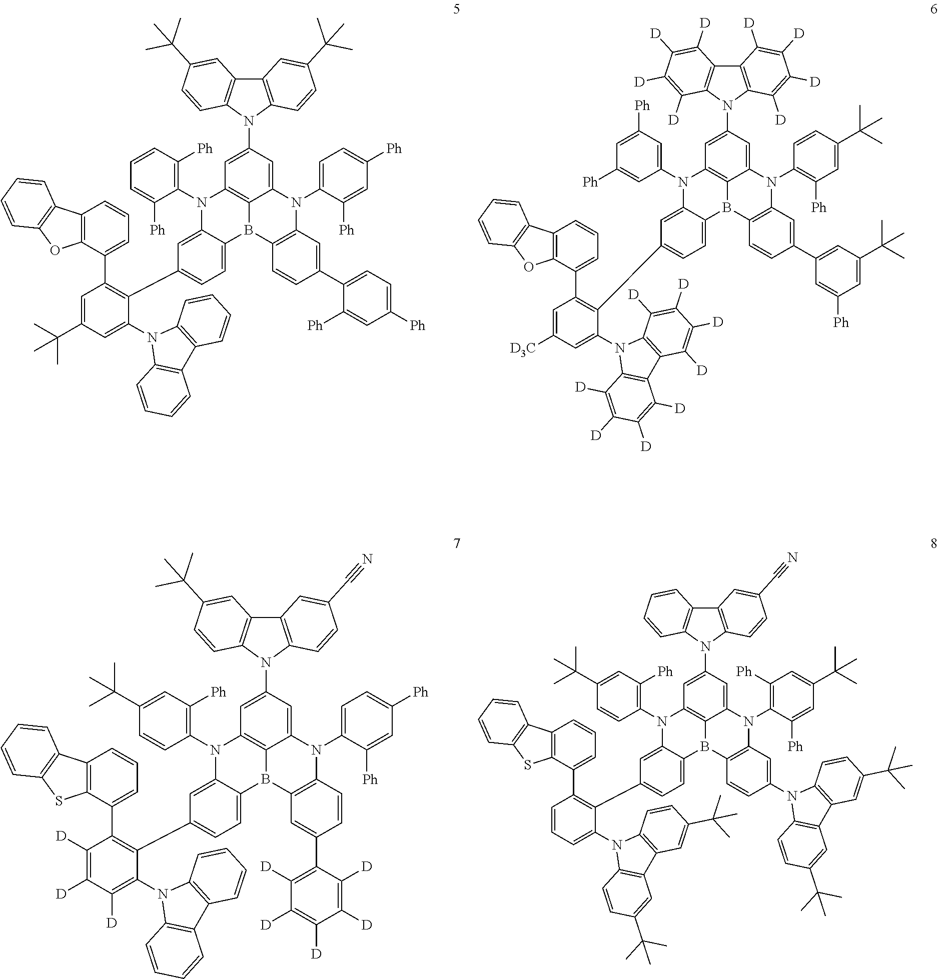

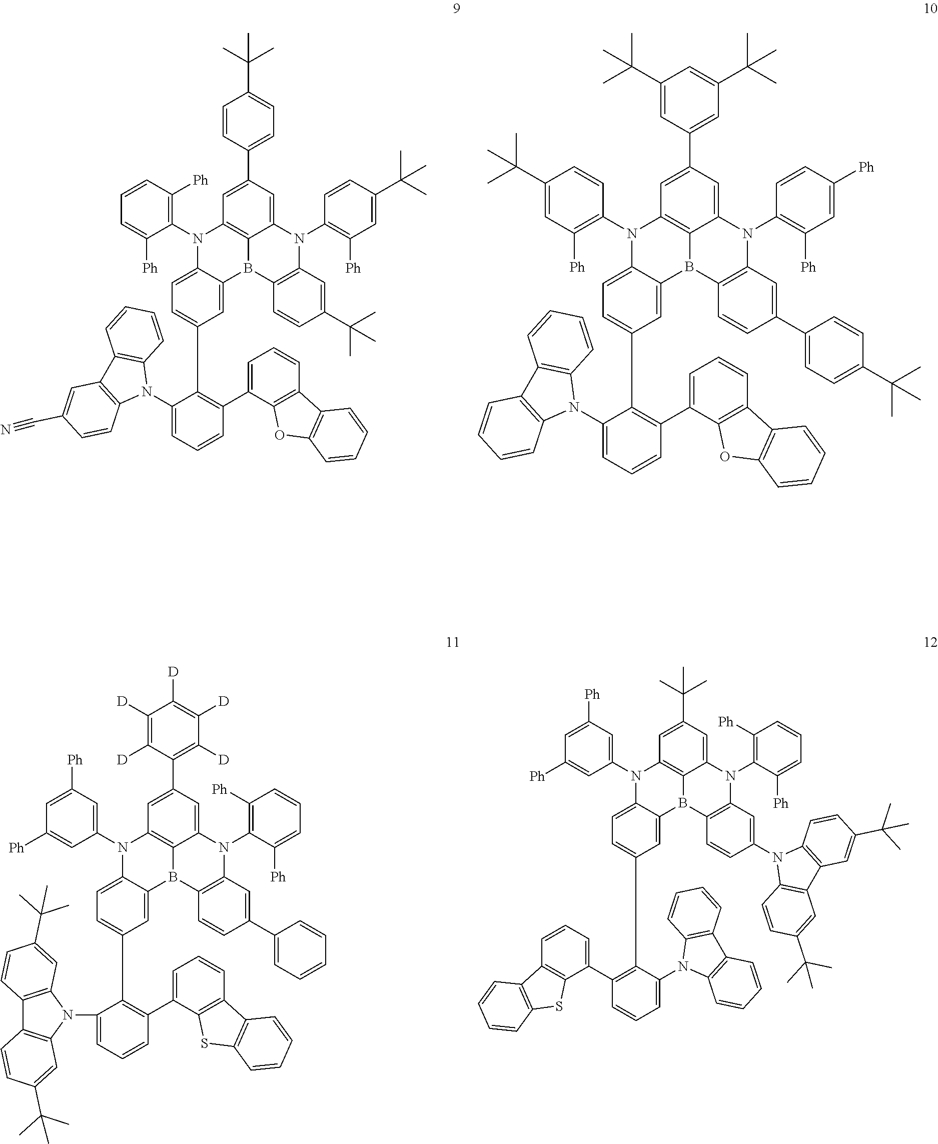

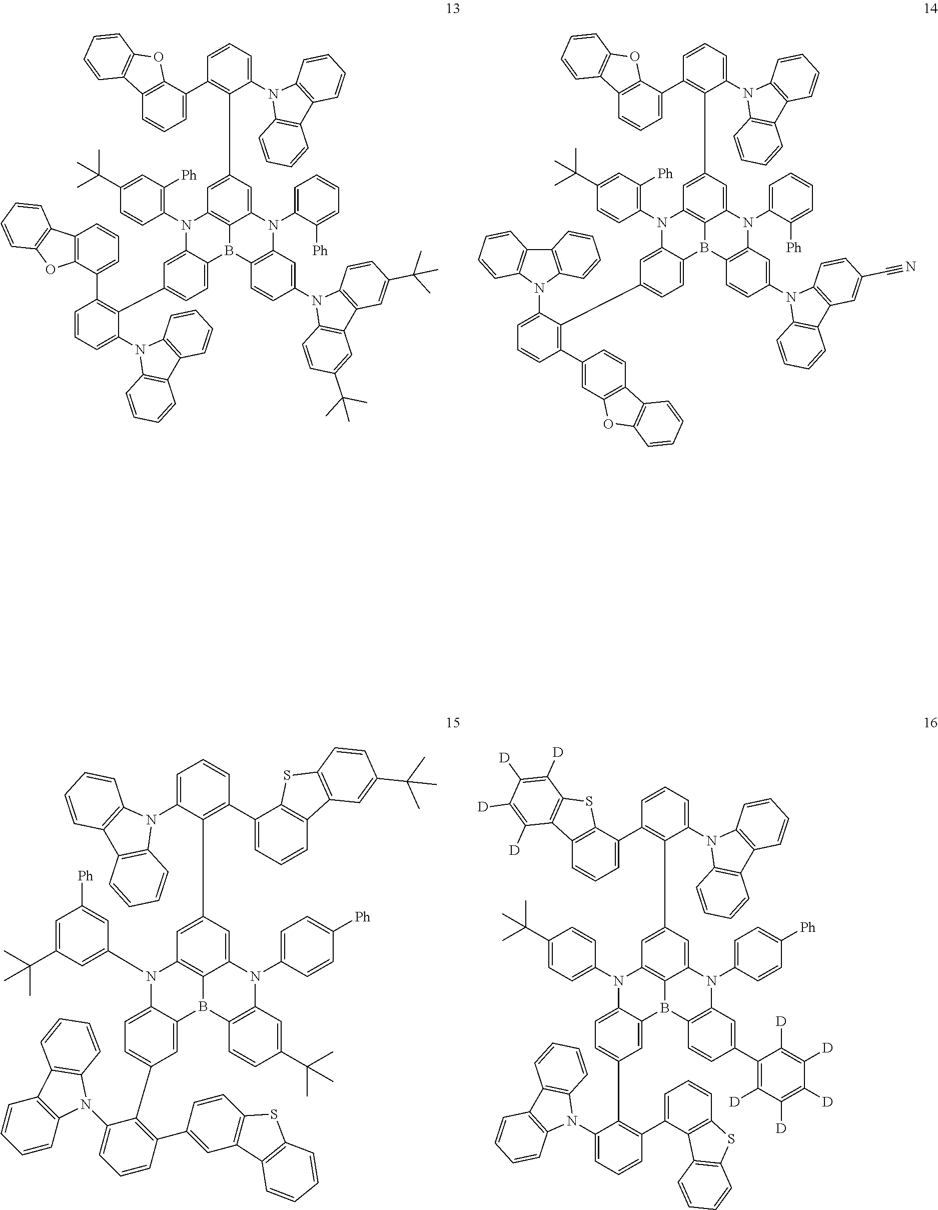

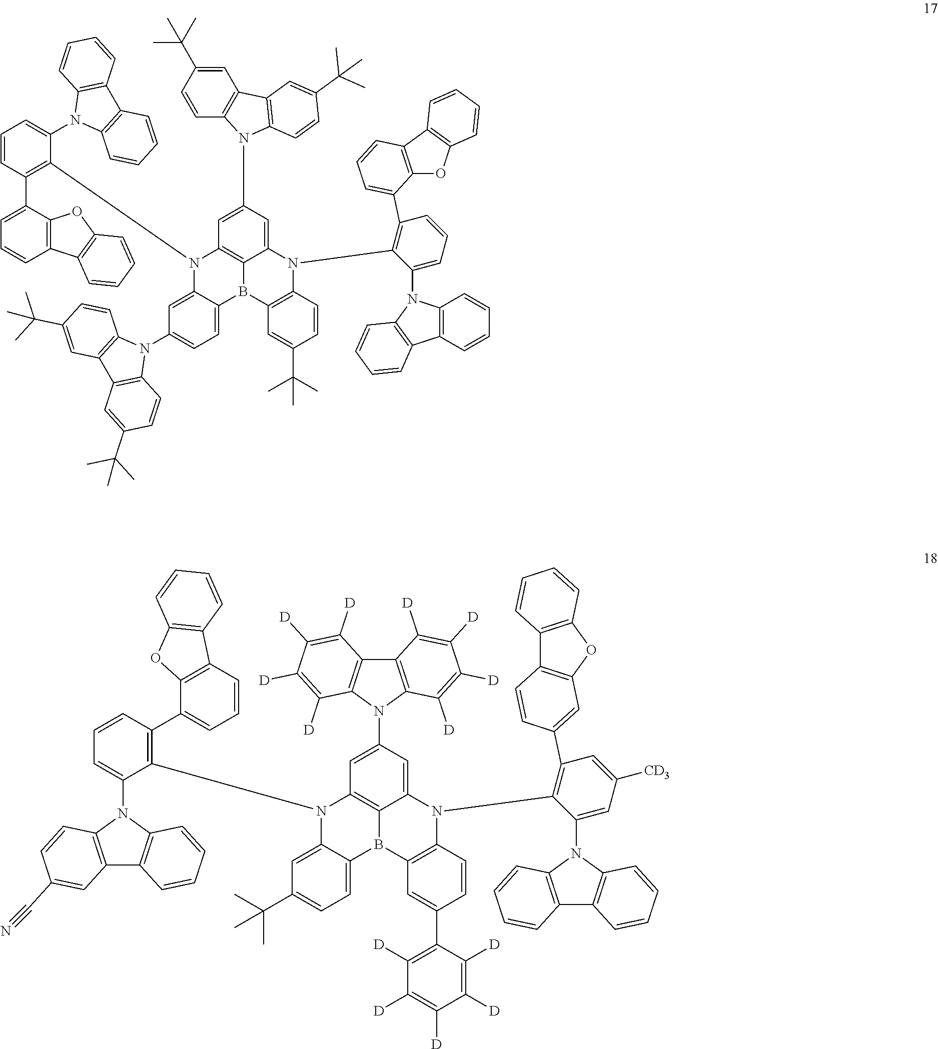

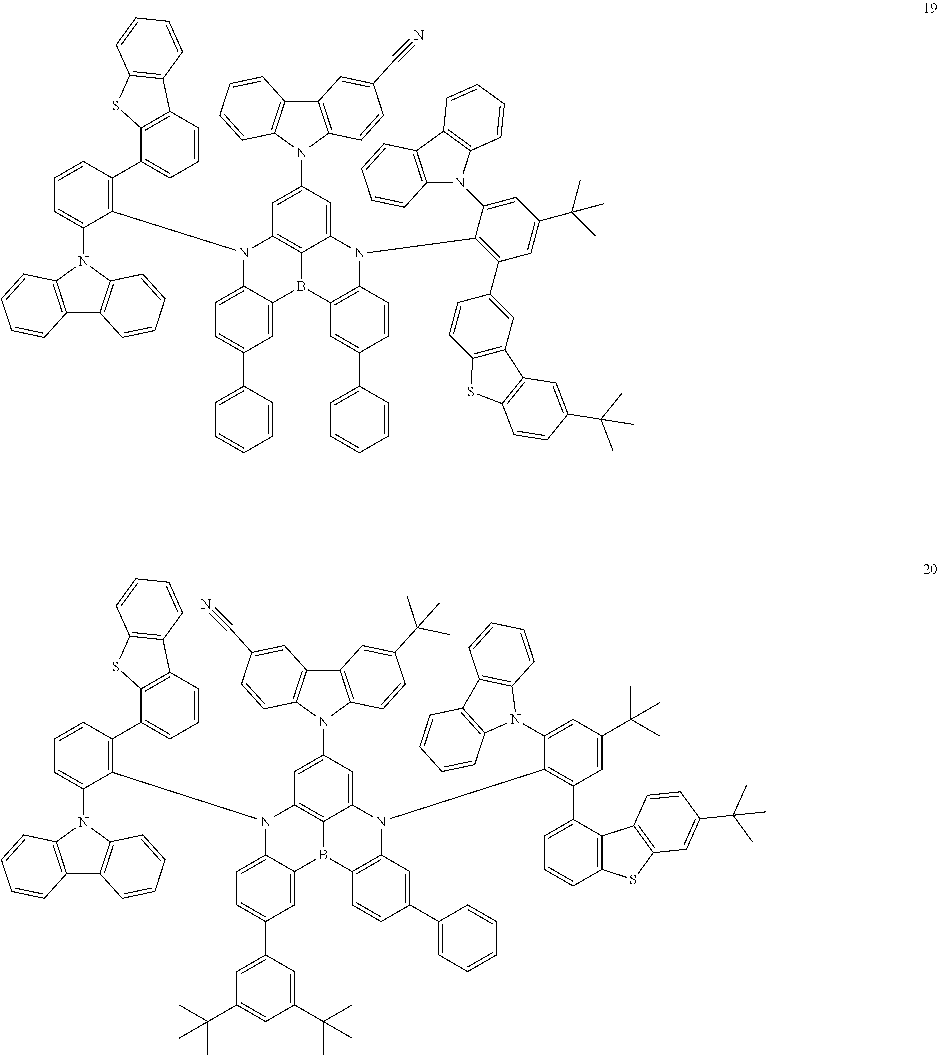 [SMILES: CC(C)(C)c1cc(-c2ccc3sc4ccc(C(C)(C)C)cc4c3c2)c(N2c3ccc(-c4ccccc4)cc3B3c4cc(-c5ccccc5)ccc4N(c4c(-c5cccc6c5sc5ccccc56)cccc4-n4c5ccccc5c5ccccc54)c4cc(-n5c6ccccc6c6cc(C#N)ccc65)cc2c43)c(-n2c3ccccc3c3ccccc32)c1 ; CC(C)(C)c1cc(-c2ccc3c(c2)B2c4ccc(-c5ccccc5)cc4N(c4c(-c5cccc6sc7cc(C(C)(C)C)ccc7c56)cc(C(C)(C)C)cc4-n4c5ccccc5c5ccccc54)c4cc(-n5c6ccc(C#N)cc6c6cc(C(C)(C)C)ccc65)cc(c42)N3c2c(-c3cccc4c3sc3ccccc34)cccc2-n2c3ccccc3c3ccccc32)cc(C(C)(C)C)c1]

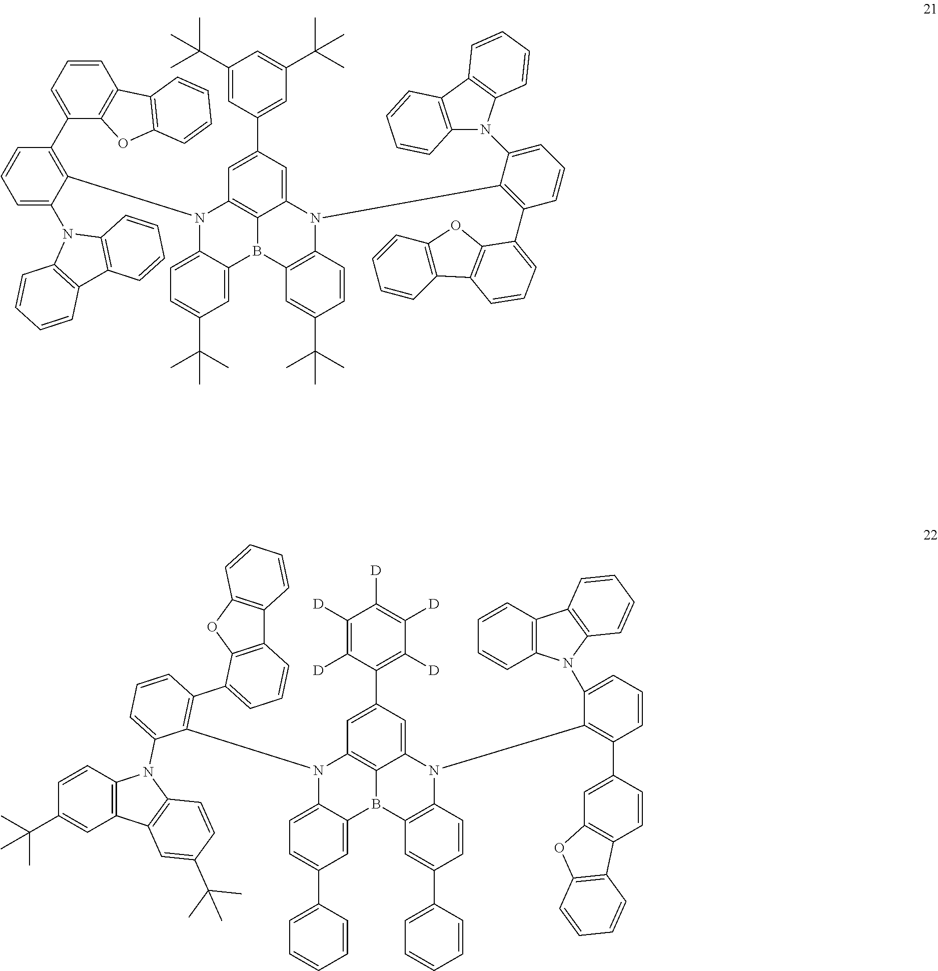 [SMILES: CC(C)(C)c1cc(-c2cc3c4c(c2)N(c2c(-c5cccc6c5oc5ccccc56)cccc2-n2c5ccccc5c5ccccc52)c2ccc(C(C)(C)C)cc2B4c2cc(C(C)(C)C)ccc2N3c2c(-c3cccc4c3oc3ccccc34)cccc2-n2c3ccccc3c3ccccc32)cc(C(C)(C)C)c1 ; [2H]c1c([2H])c([2H])c(-c2cc3c4c(c2)N(c2c(-c5cccc6c5oc5ccccc56)cccc2-n2c5ccc(C(C)(C)C)cc5c5cc(C(C)(C)C)ccc52)c2ccc(-c5ccccc5)cc2B4c2cc(-c4ccccc4)ccc2N3c2c(-c3ccc4c(c3)oc3ccccc34)cccc2-n2c3ccccc3c3ccccc32)c([2H])c1[2H]]

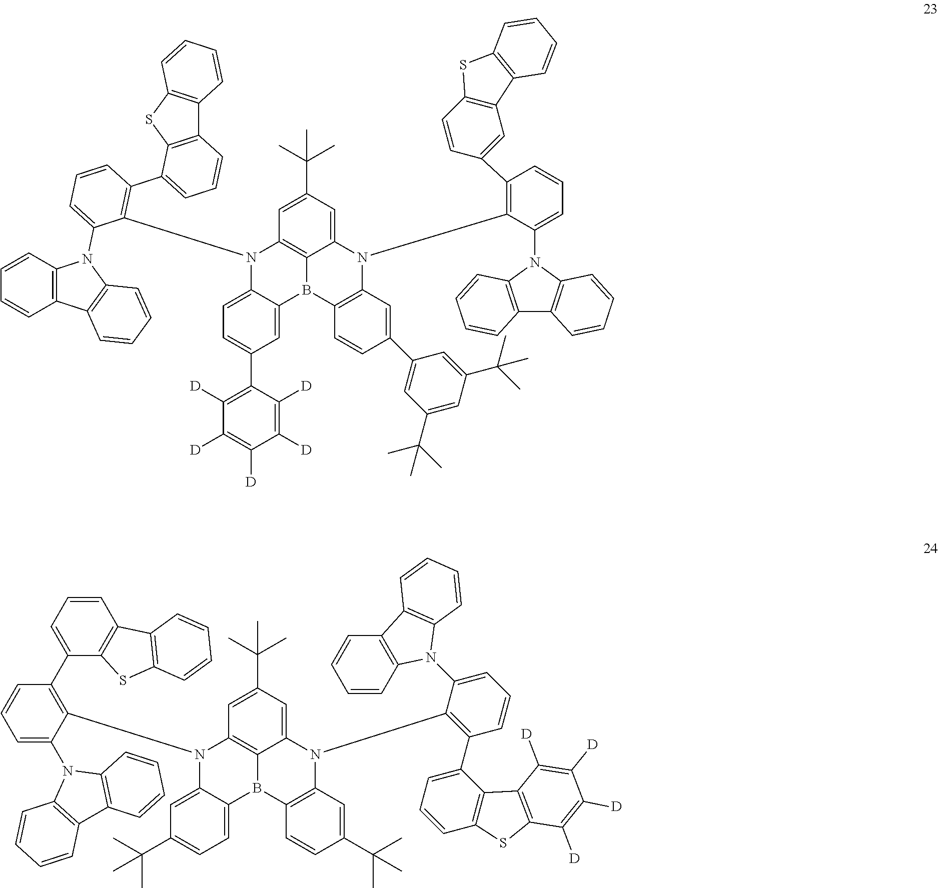 [SMILES: [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3cccc4c3sc3ccccc34)cccc2-n2c3ccccc3c3ccccc32)c([2H])c1[2H] ; [2H]c1c([2H])c([2H])c2c(sc3cccc(-c4cccc(-n5c6ccccc6c6ccccc65)c4N4c5cc(C(C)(C)C)ccc5B5c6ccc(C(C)(C)C)cc6N(c6c(-c7cccc8c7sc7ccccc78)cccc6-n6c7ccccc7c7ccccc76)c6cc(C(C)(C)C)cc4c65)c32)c1[2H]]

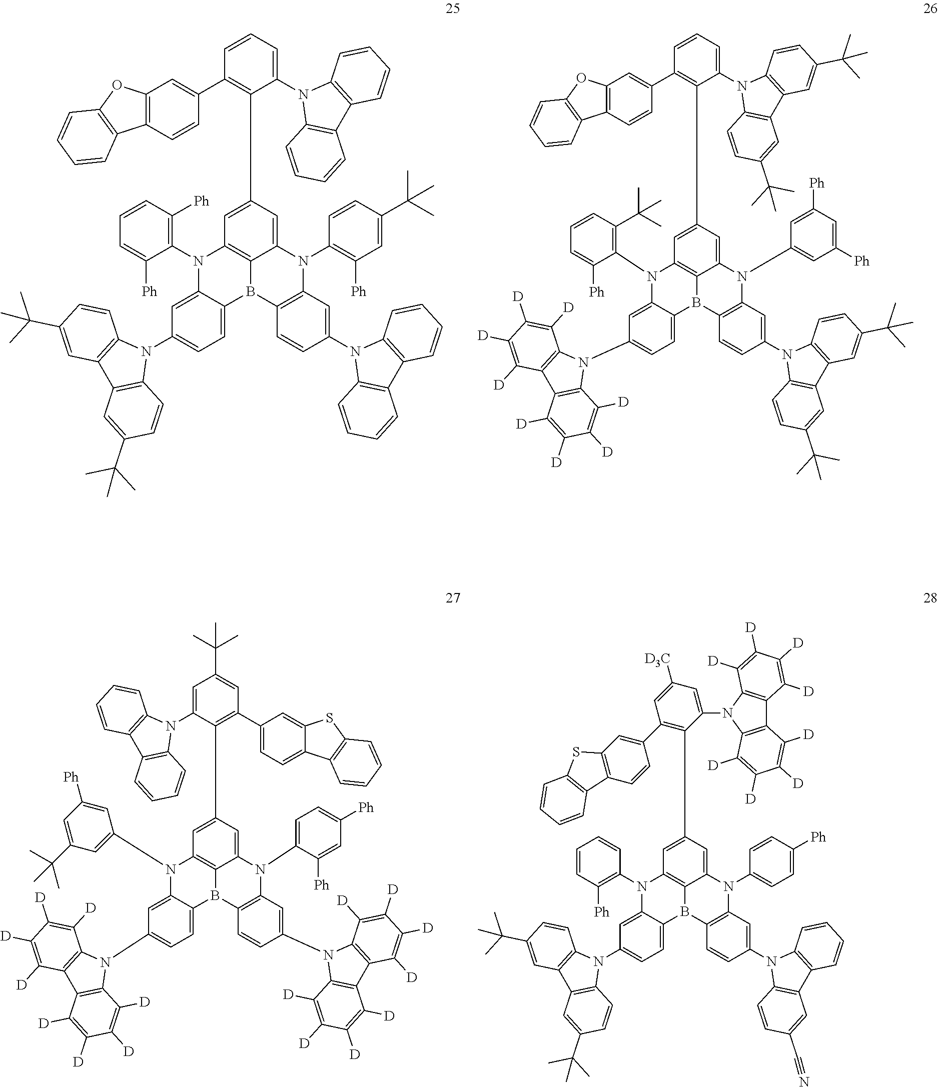

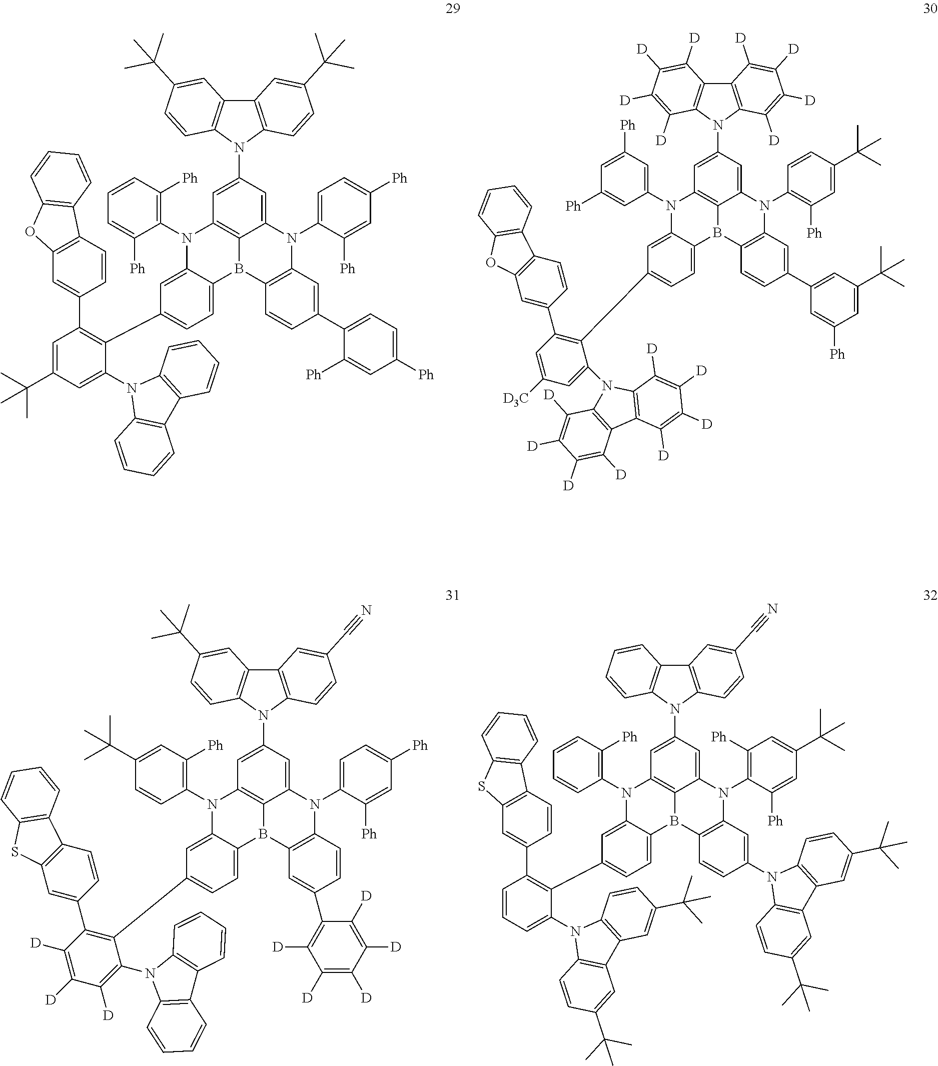

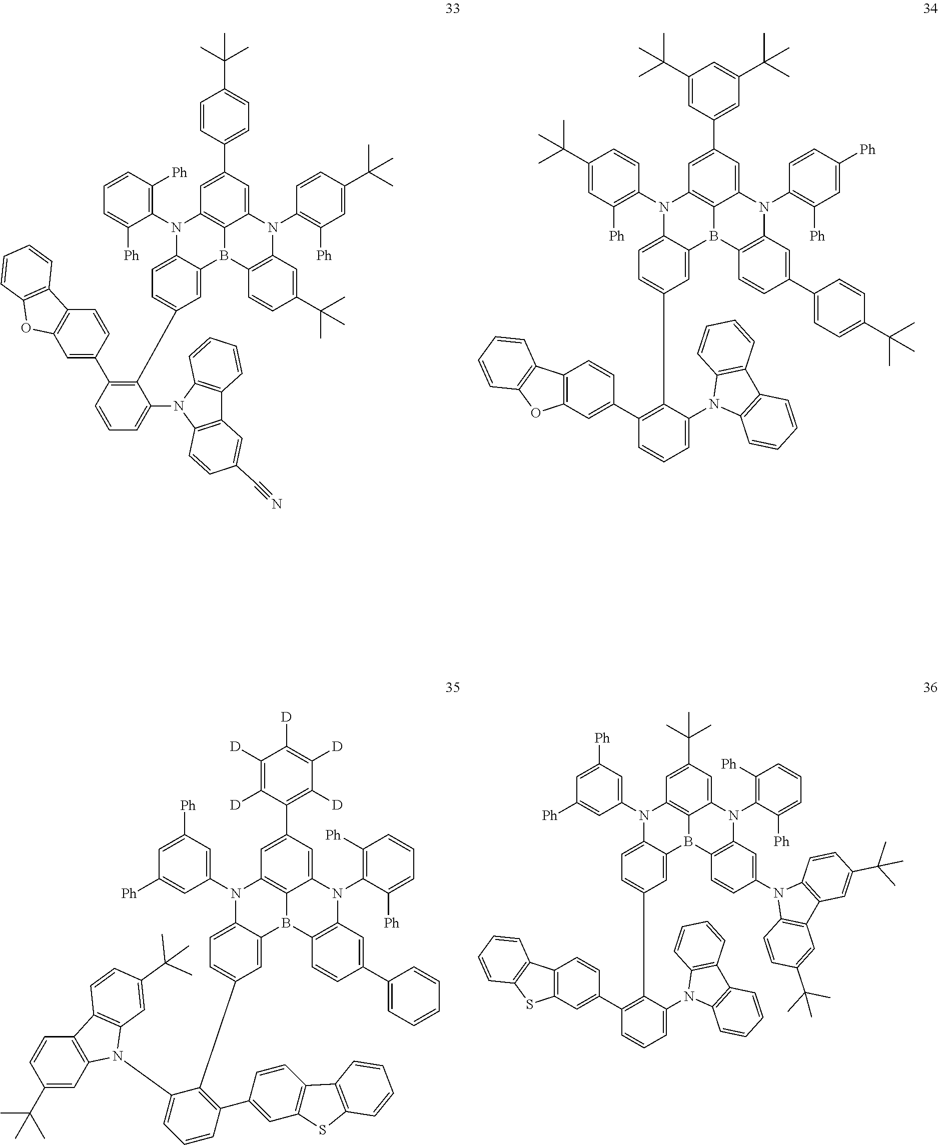

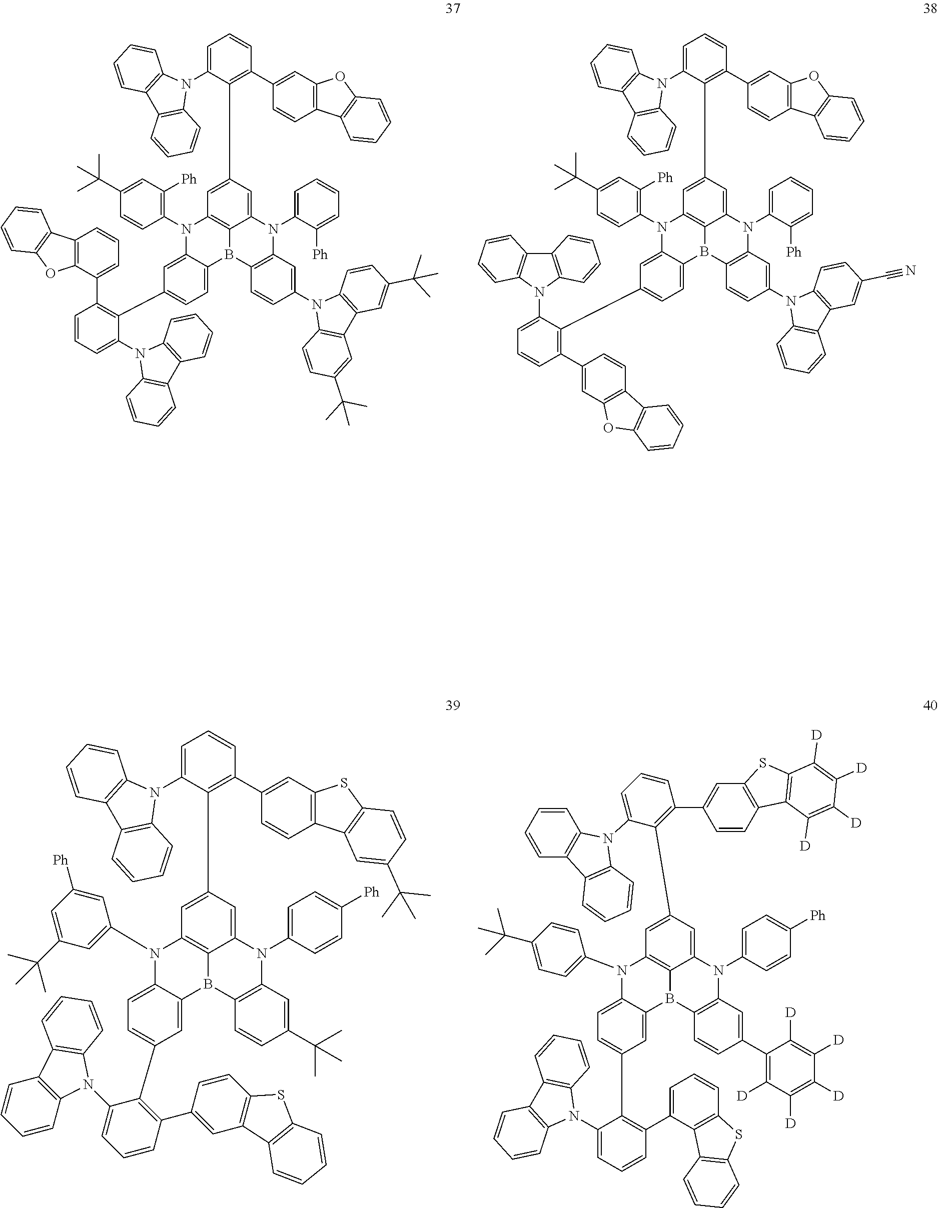

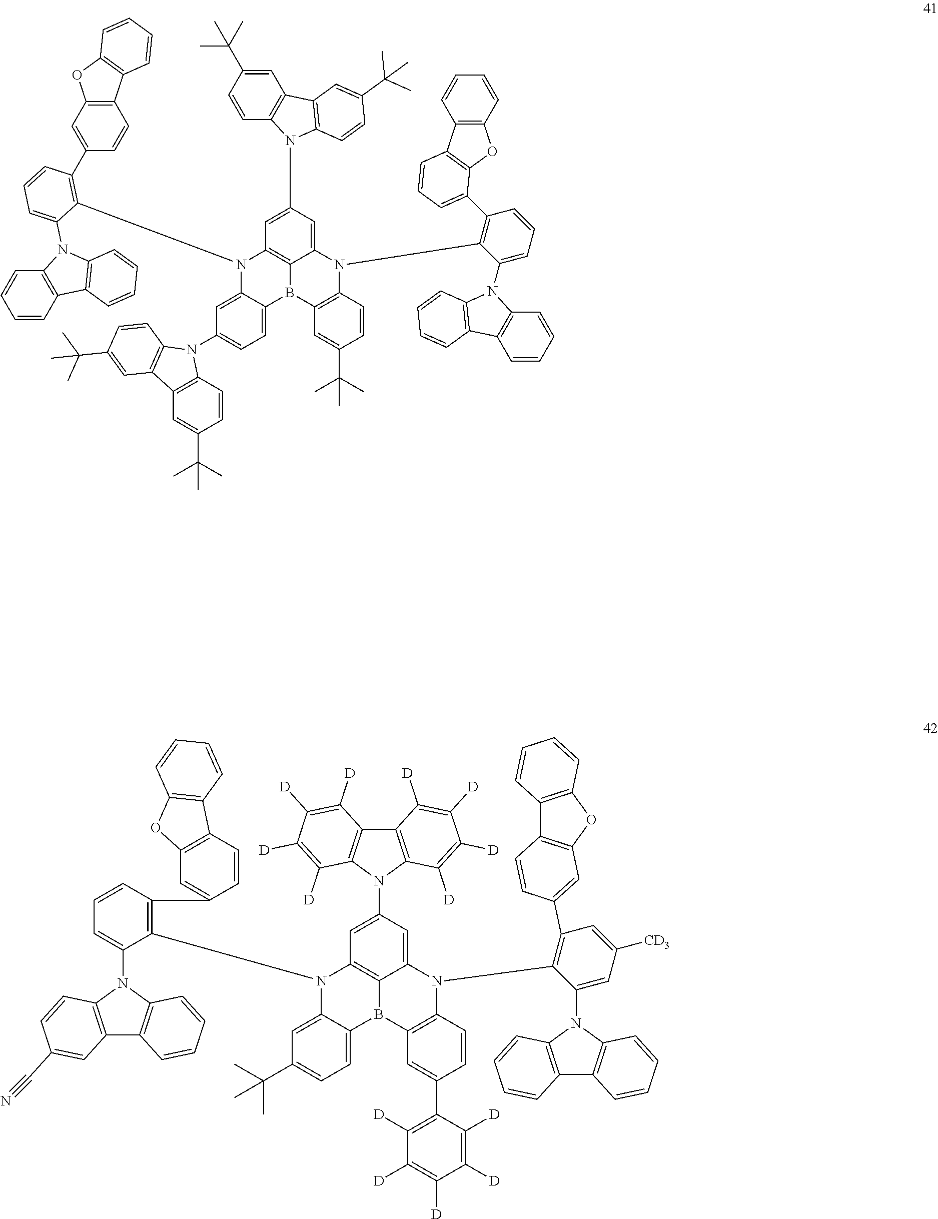

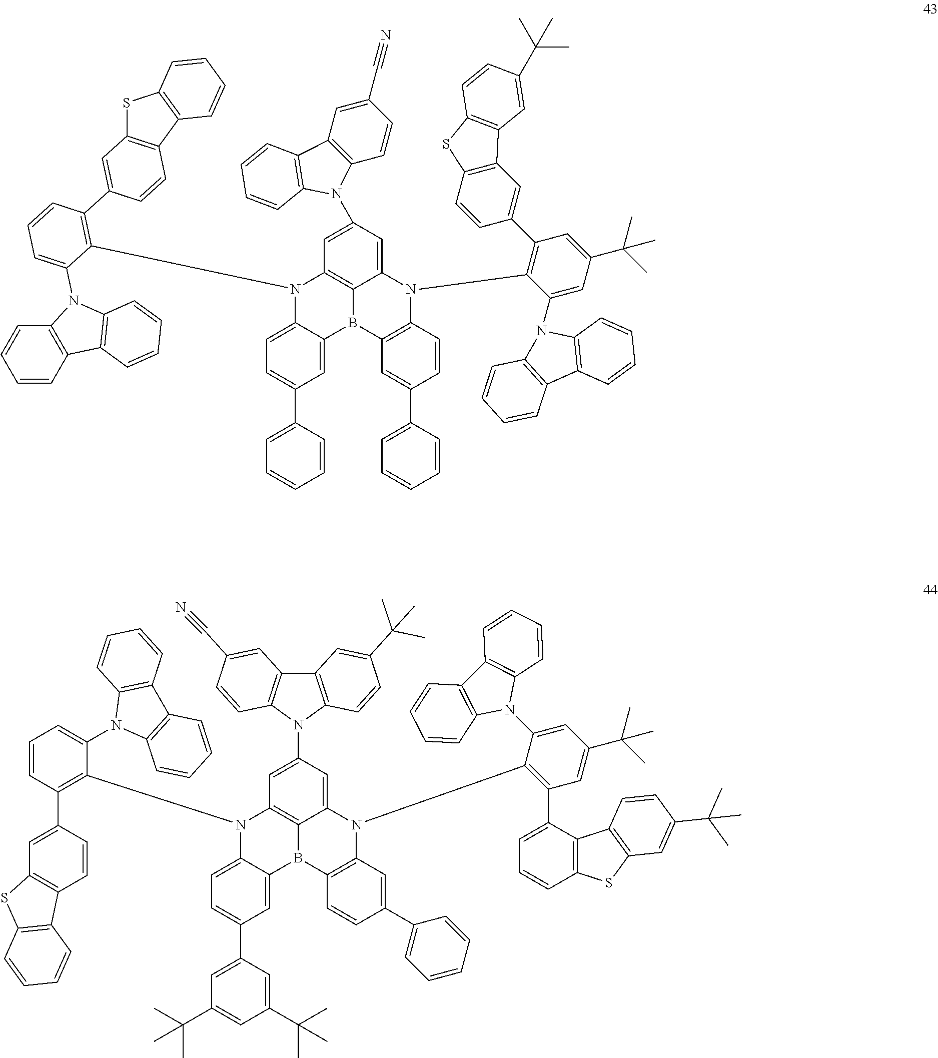 [SMILES: CC(C)(C)c1cc(-c2ccc3sc4ccc(C(C)(C)C)cc4c3c2)c(N2c3ccc(-c4ccccc4)cc3B3c4cc(-c5ccccc5)ccc4N(c4c(-c5ccc6c(c5)sc5ccccc56)cccc4-n4c5ccccc5c5ccccc54)c4cc(-n5c6ccccc6c6cc(C#N)ccc65)cc2c43)c(-n2c3ccccc3c3ccccc32)c1 ; CC(C)(C)c1cc(-c2ccc3c(c2)B2c4ccc(-c5ccccc5)cc4N(c4c(-c5cccc6sc7cc(C(C)(C)C)ccc7c56)cc(C(C)(C)C)cc4-n4c5ccccc5c5ccccc54)c4cc(-n5c6ccc(C#N)cc6c6cc(C(C)(C)C)ccc65)cc(c42)N3c2c(-c3ccc4c(c3)sc3ccccc34)cccc2-n2c3ccccc3c3ccccc32)cc(C(C)(C)C)c1]

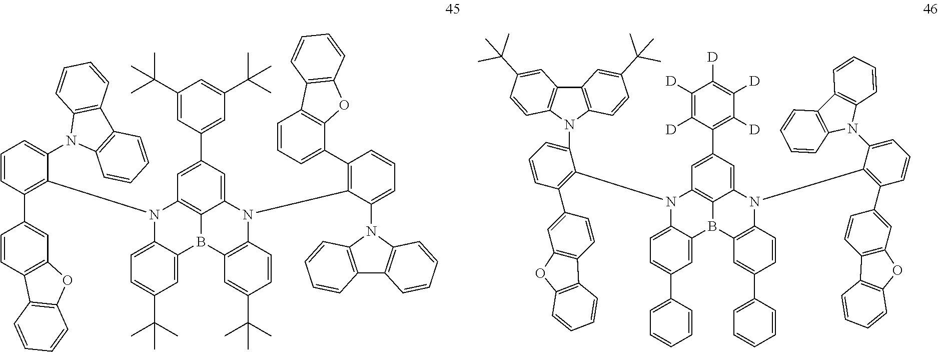 [SMILES: CC(C)(C)c1cc(-c2cc3c4c(c2)N(c2c(-c5cccc6c5oc5ccccc56)cccc2-n2c5ccccc5c5ccccc52)c2ccc(C(C)(C)C)cc2B4c2cc(C(C)(C)C)ccc2N3c2c(-c3ccc4c(c3)oc3ccccc34)cccc2-n2c3ccccc3c3ccccc32)cc(C(C)(C)C)c1 ; [2H]c1c([2H])c([2H])c(-c2cc3c4c(c2)N(c2c(-c5ccc6c(c5)oc5ccccc56)cccc2-n2c5ccc(C(C)(C)C)cc5c5cc(C(C)(C)C)ccc52)c2ccc(-c5ccccc5)cc2B4c2cc(-c4ccccc4)ccc2N3c2c(-c3ccc4c(c3)oc3ccccc34)cccc2-n2c3ccccc3c3ccccc32)c([2H])c1[2H]]

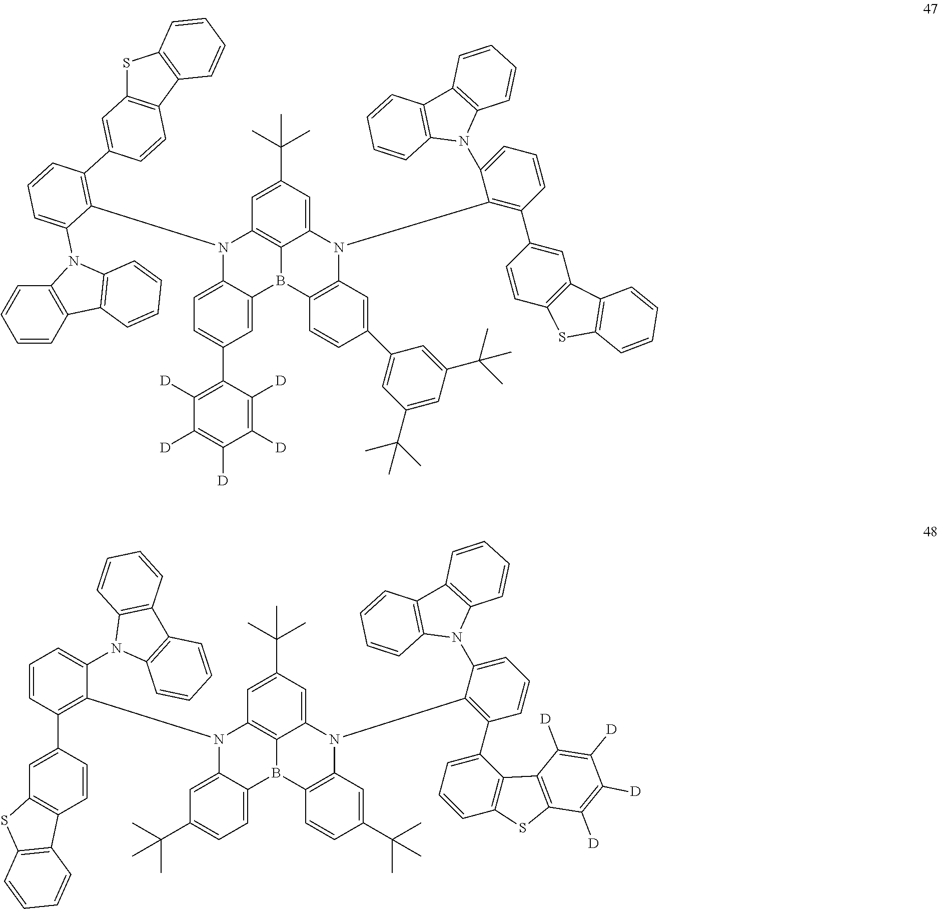 [SMILES: [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3ccc4c(c3)sc3ccccc34)cccc2-n2c3ccccc3c3ccccc32)c([2H])c1[2H] ; [2H]c1c([2H])c([2H])c2c(sc3cccc(-c4cccc(-n5c6ccccc6c6ccccc65)c4N4c5cc(C(C)(C)C)ccc5B5c6ccc(C(C)(C)C)cc6N(c6c(-c7ccc8c(c7)sc7ccccc78)cccc6-n6c7ccccc7c7ccccc76)c6cc(C(C)(C)C)cc4c65)c32)c1[2H]]

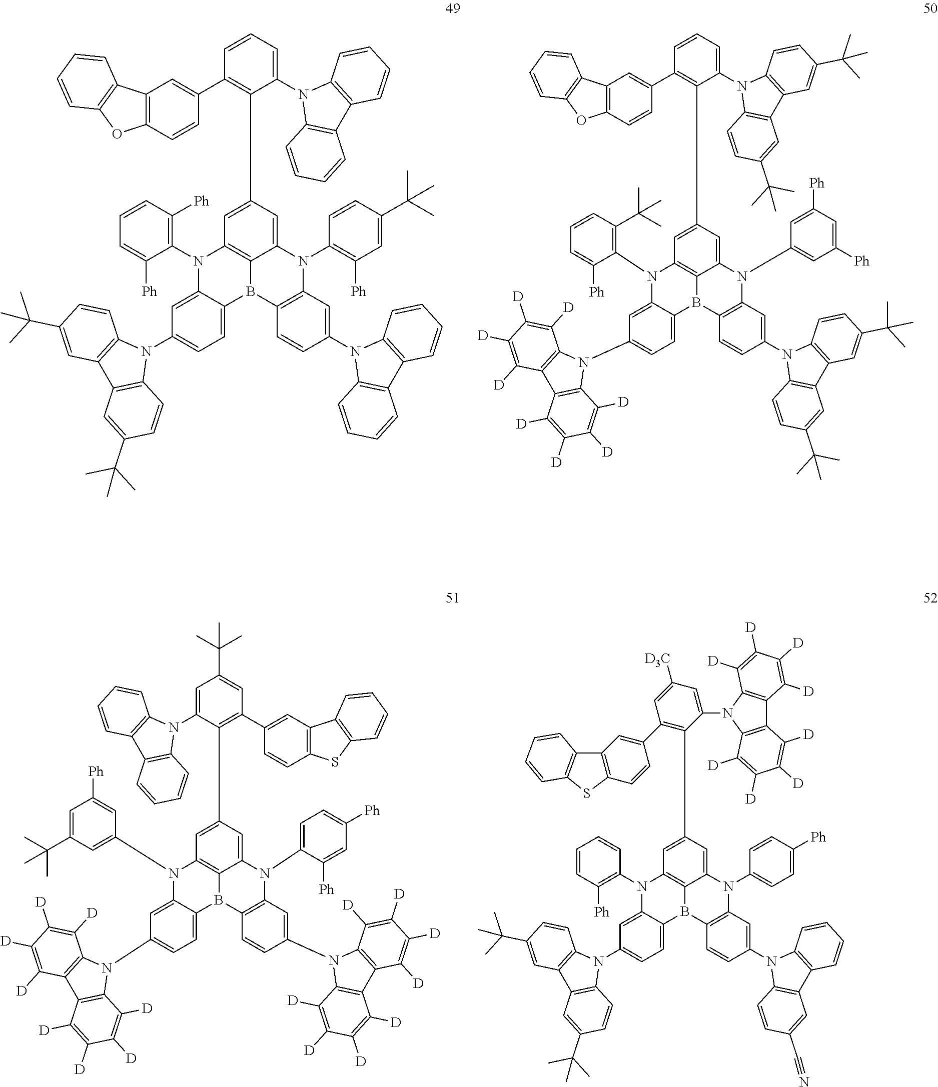

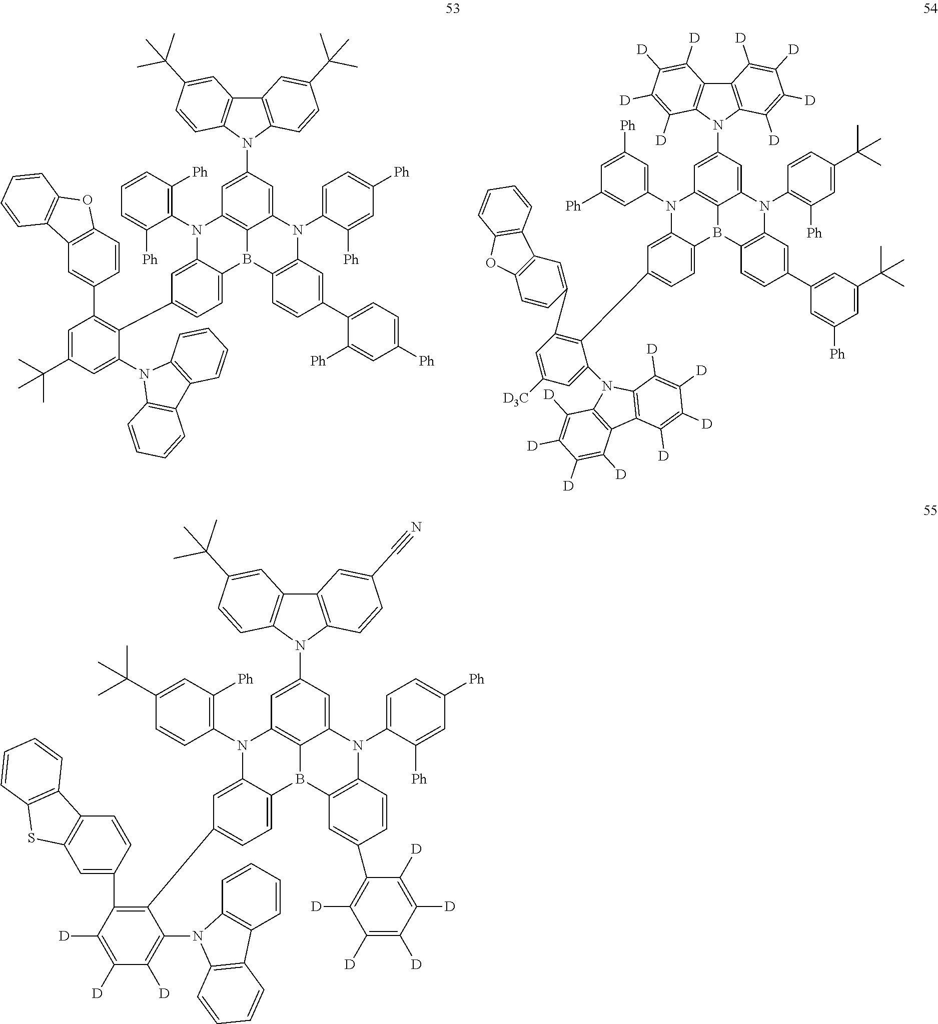

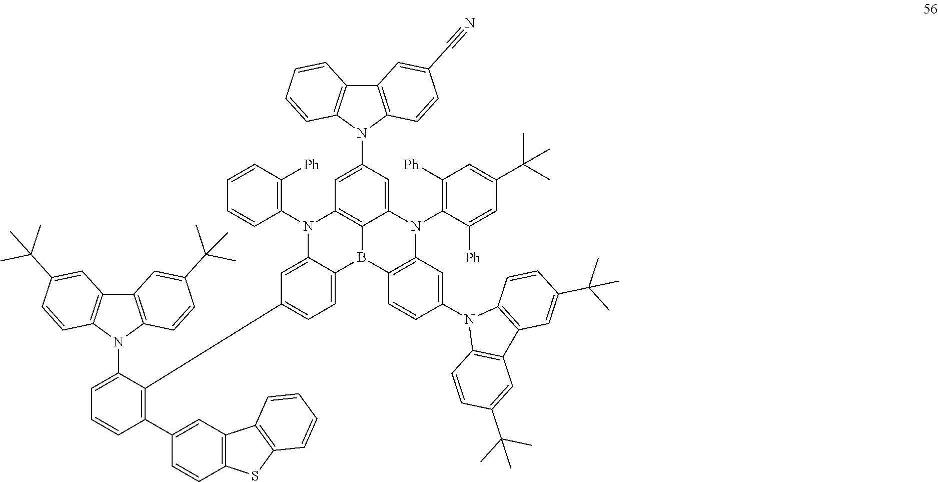 [SMILES: CC(C)(C)c1cc(-c2ccccc2)c(N2c3cc(-n4c5ccc(C(C)(C)C)cc5c5cc(C(C)(C)C)ccc54)ccc3B3c4ccc(-c5c(-c6ccc7sc8ccccc8c7c6)cccc5-n5c6ccc(C(C)(C)C)cc6c6cc(C(C)(C)C)ccc65)cc4N(c4ccccc4-c4ccccc4)c4cc(-n5c6ccccc6c6cc(C#N)ccc65)cc2c43)c(-c2ccccc2)c1]

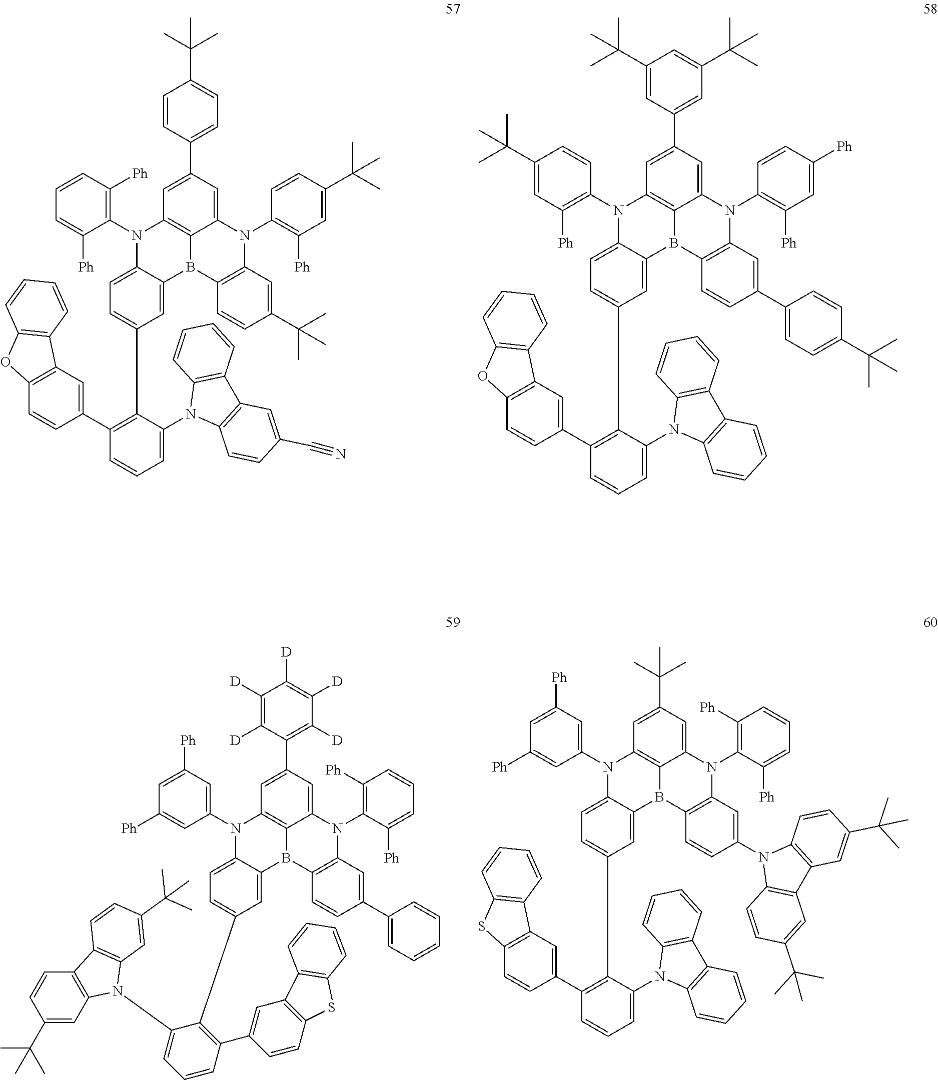

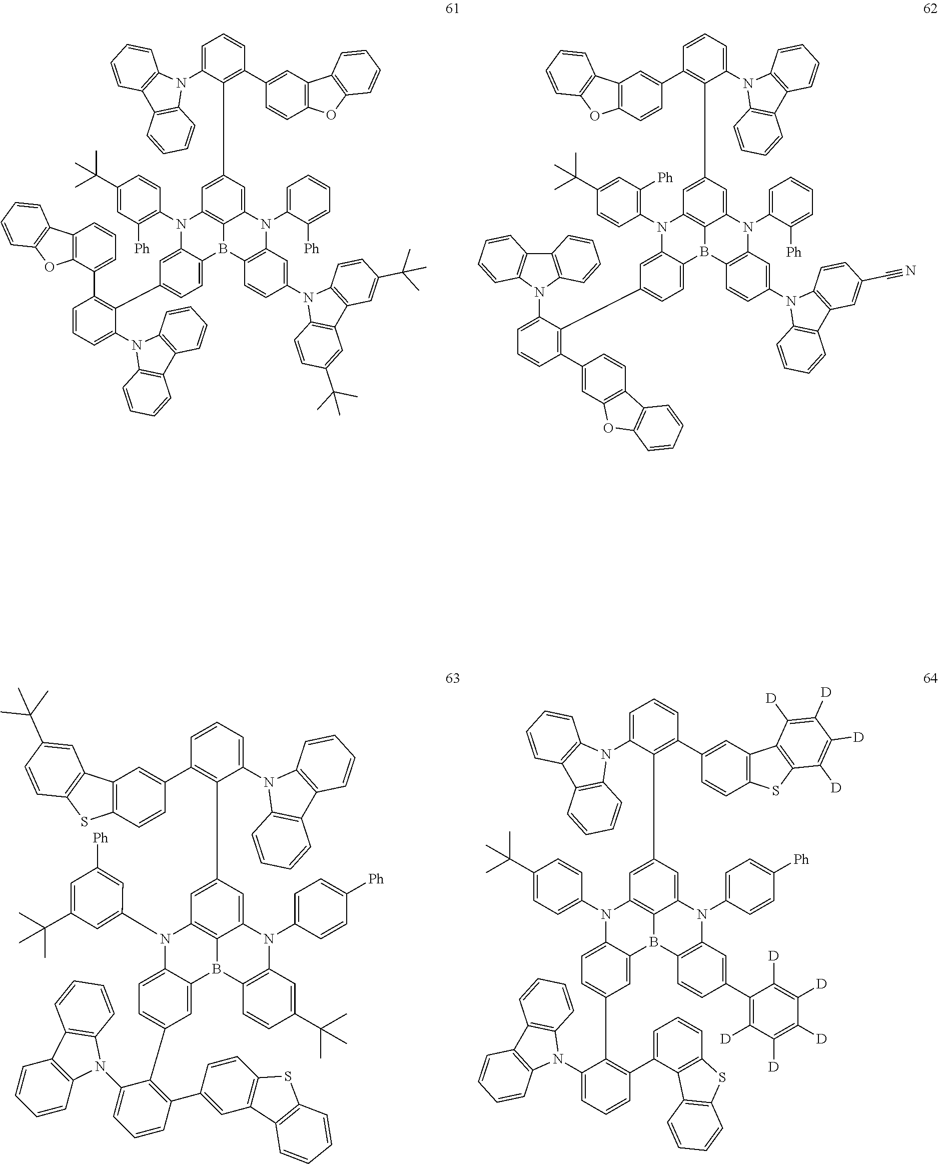

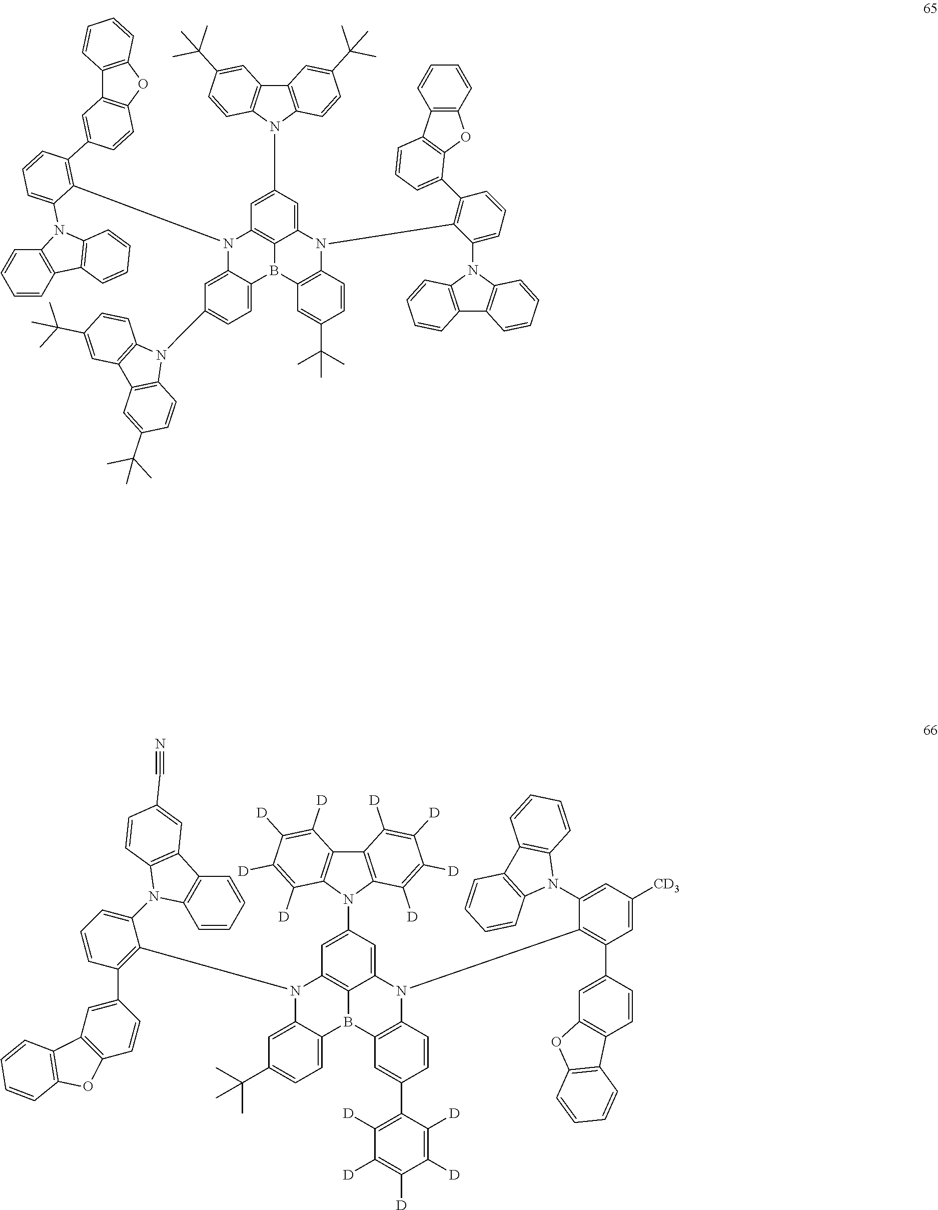

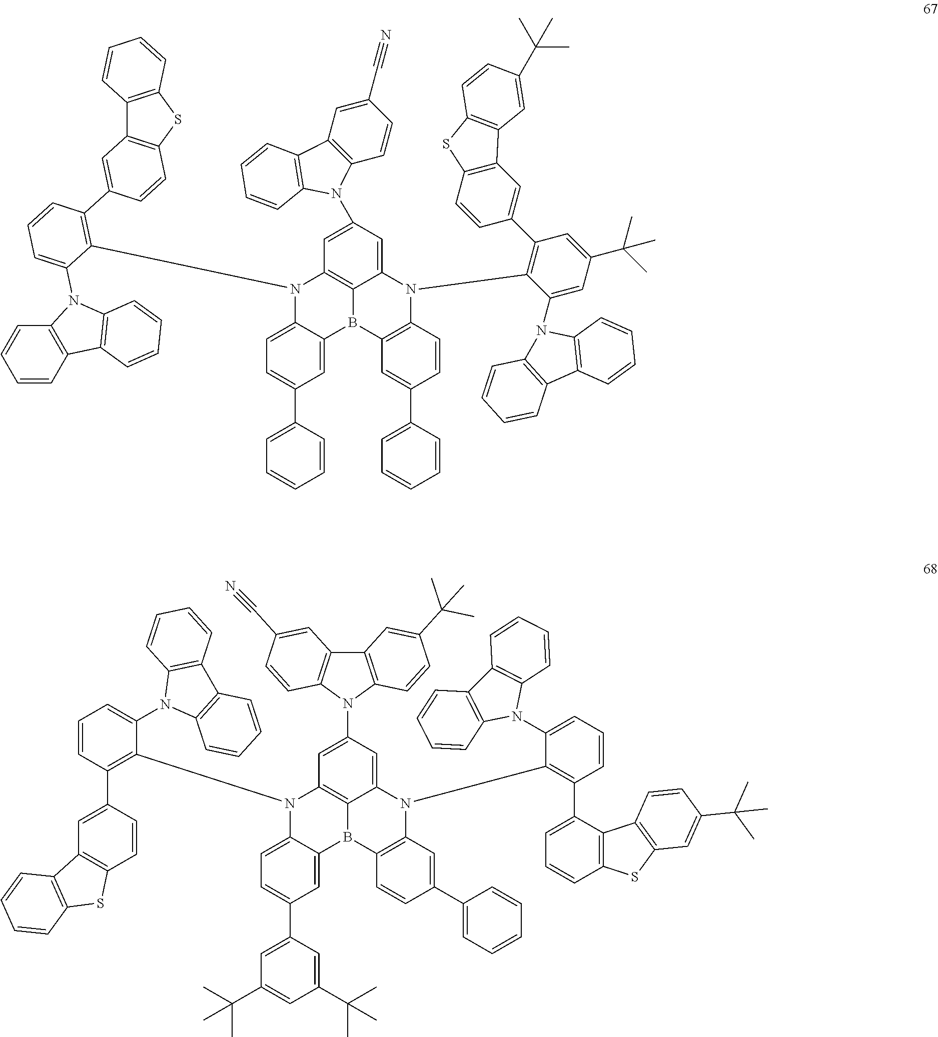 [SMILES: CC(C)(C)c1cc(-c2ccc3sc4ccc(C(C)(C)C)cc4c3c2)c(N2c3ccc(-c4ccccc4)cc3B3c4cc(-c5ccccc5)ccc4N(c4c(-c5ccc6sc7ccccc7c6c5)cccc4-n4c5ccccc5c5ccccc54)c4cc(-n5c6ccccc6c6cc(C#N)ccc65)cc2c43)c(-n2c3ccccc3c3ccccc32)c1 ; CC(C)(C)c1cc(-c2ccc3c(c2)B2c4ccc(-c5ccccc5)cc4N(c4c(-c5cccc6sc7cc(C(C)(C)C)ccc7c56)cccc4-n4c5ccccc5c5ccccc54)c4cc(-n5c6ccc(C#N)cc6c6cc(C(C)(C)C)ccc65)cc(c42)N3c2c(-c3ccc4sc5ccccc5c4c3)cccc2-n2c3ccccc3c3ccccc32)cc(C(C)(C)C)c1]

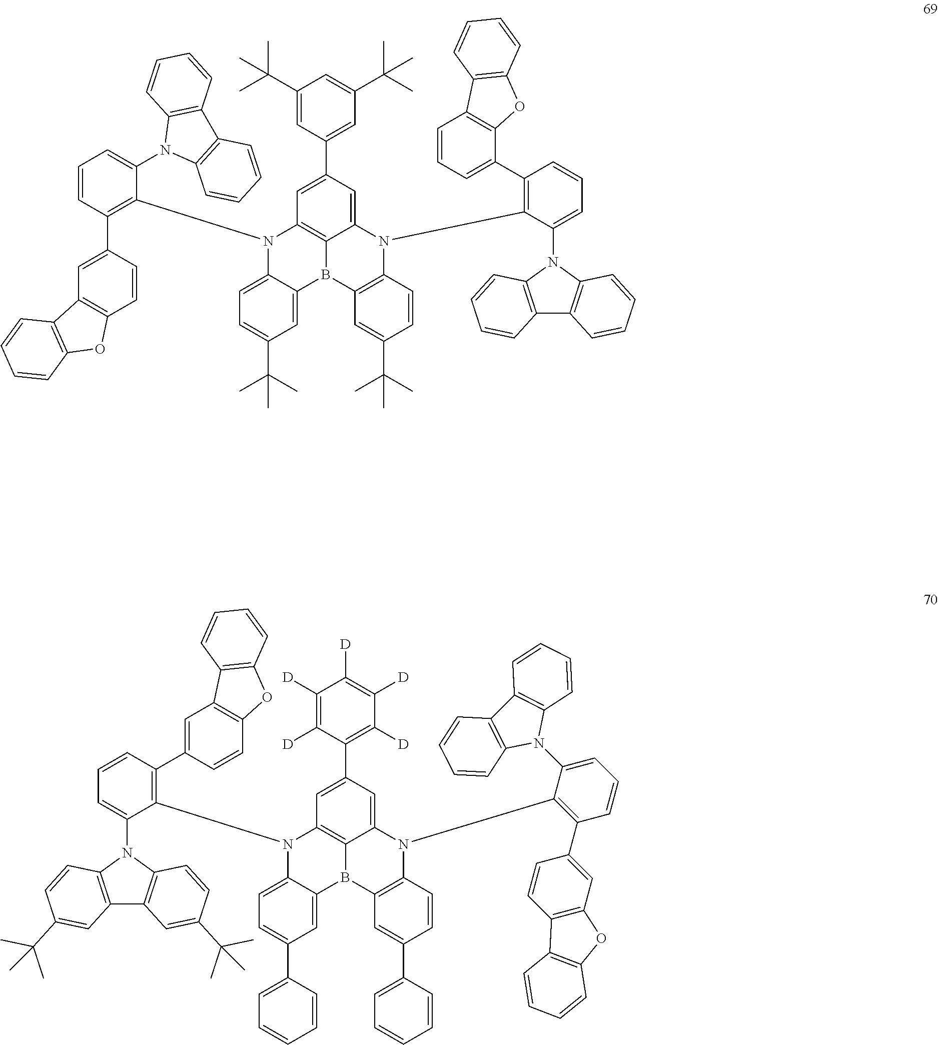 [SMILES: CC(C)(C)c1cc(-c2cc3c4c(c2)N(c2c(-c5cccc6c5oc5ccccc56)cccc2-n2c5ccccc5c5ccccc52)c2ccc(C(C)(C)C)cc2B4c2cc(C(C)(C)C)ccc2N3c2c(-c3ccc4oc5ccccc5c4c3)cccc2-n2c3ccccc3c3ccccc32)cc(C(C)(C)C)c1 ; [2H]c1c([2H])c([2H])c(-c2cc3c4c(c2)N(c2c(-c5ccc6oc7ccccc7c6c5)cccc2-n2c5ccc(C(C)(C)C)cc5c5cc(C(C)(C)C)ccc52)c2ccc(-c5ccccc5)cc2B4c2cc(-c4ccccc4)ccc2N3c2c(-c3ccc4c(c3)oc3ccccc34)cccc2-n2c3ccccc3c3ccccc32)c([2H])c1[2H]]

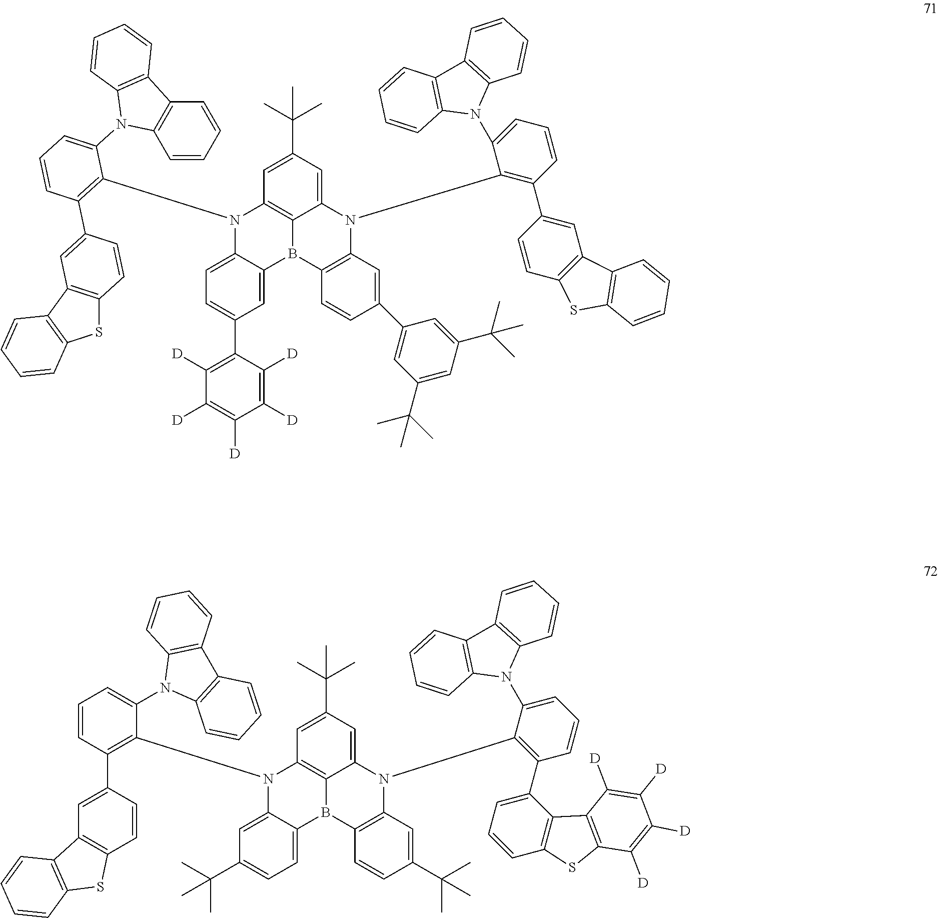 [SMILES: [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3ccc4sc5ccccc5c4c3)cccc2-n2c3ccccc3c3ccccc32)c([2H])c1[2H] ; [2H]c1c([2H])c([2H])c2c(sc3cccc(-c4cccc(-n5c6ccccc6c6ccccc65)c4N4c5cc(C(C)(C)C)ccc5B5c6ccc(C(C)(C)C)cc6N(c6c(-c7ccc8sc9ccccc9c8c7)cccc6-n6c7ccccc7c7ccccc76)c6cc(C(C)(C)C)cc4c65)c32)c1[2H]]

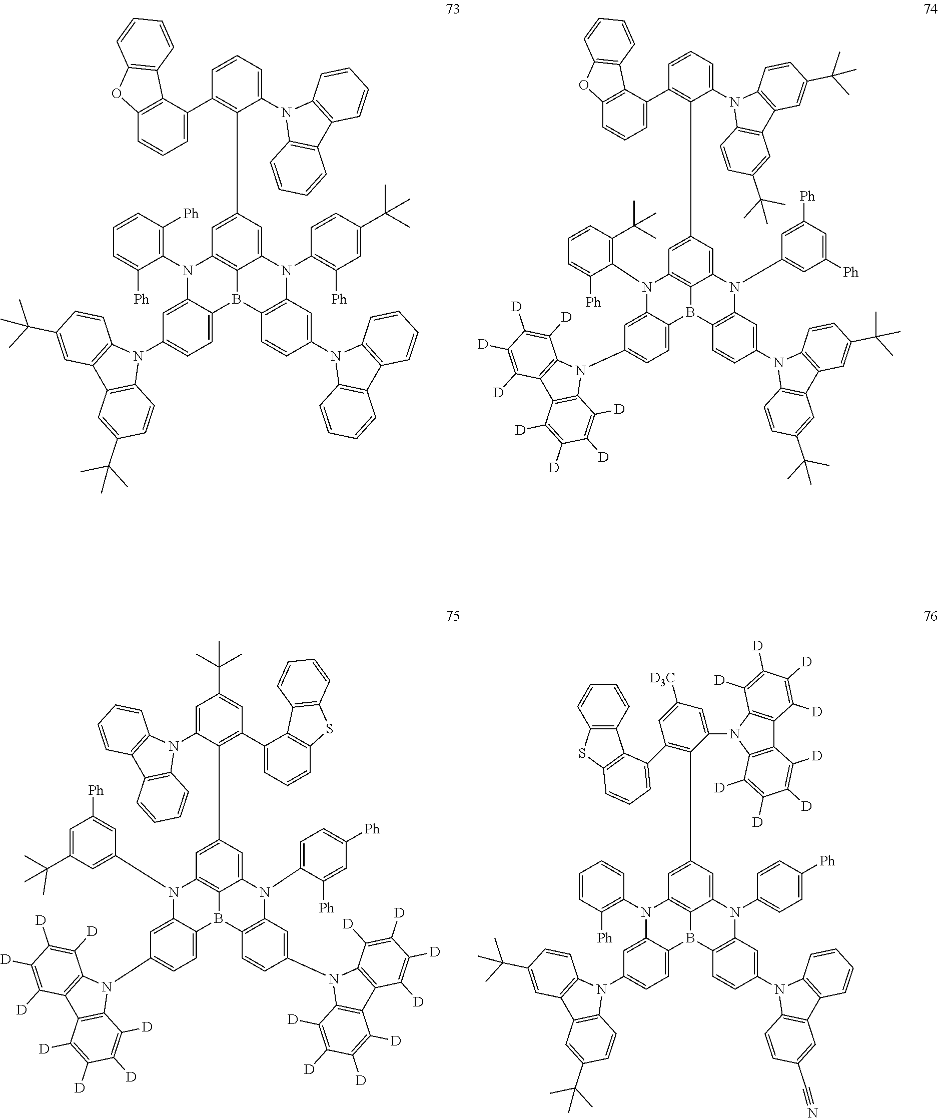

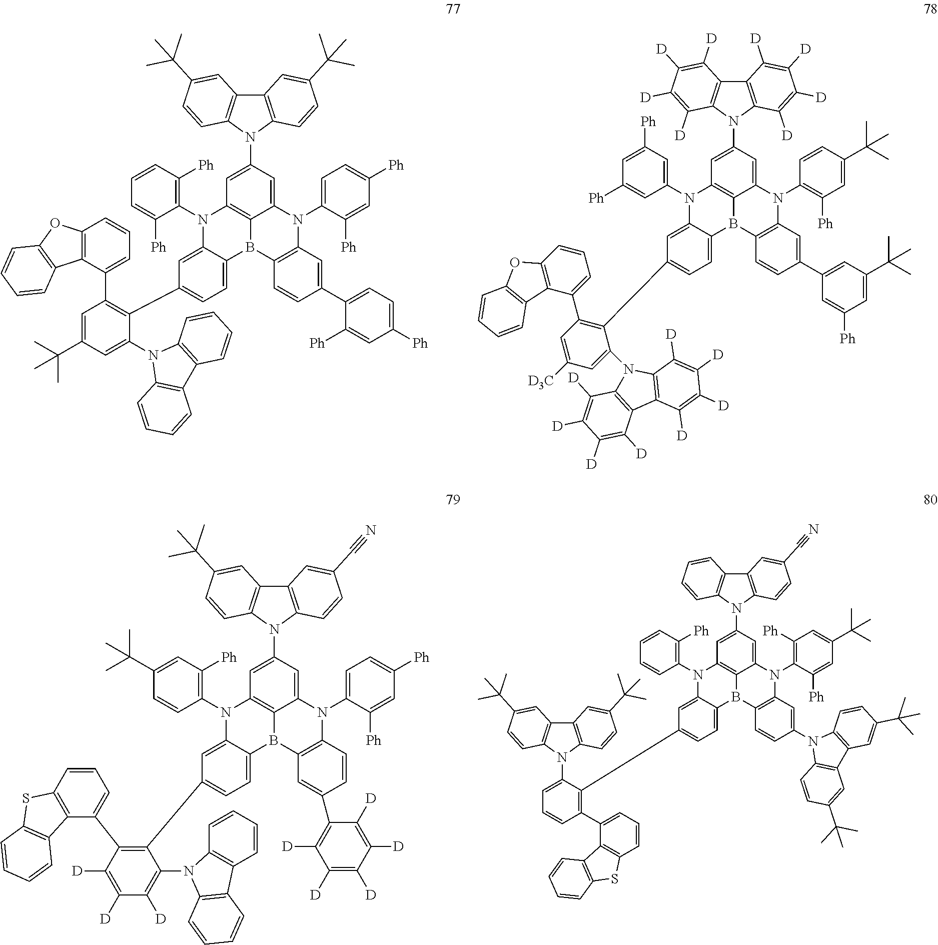

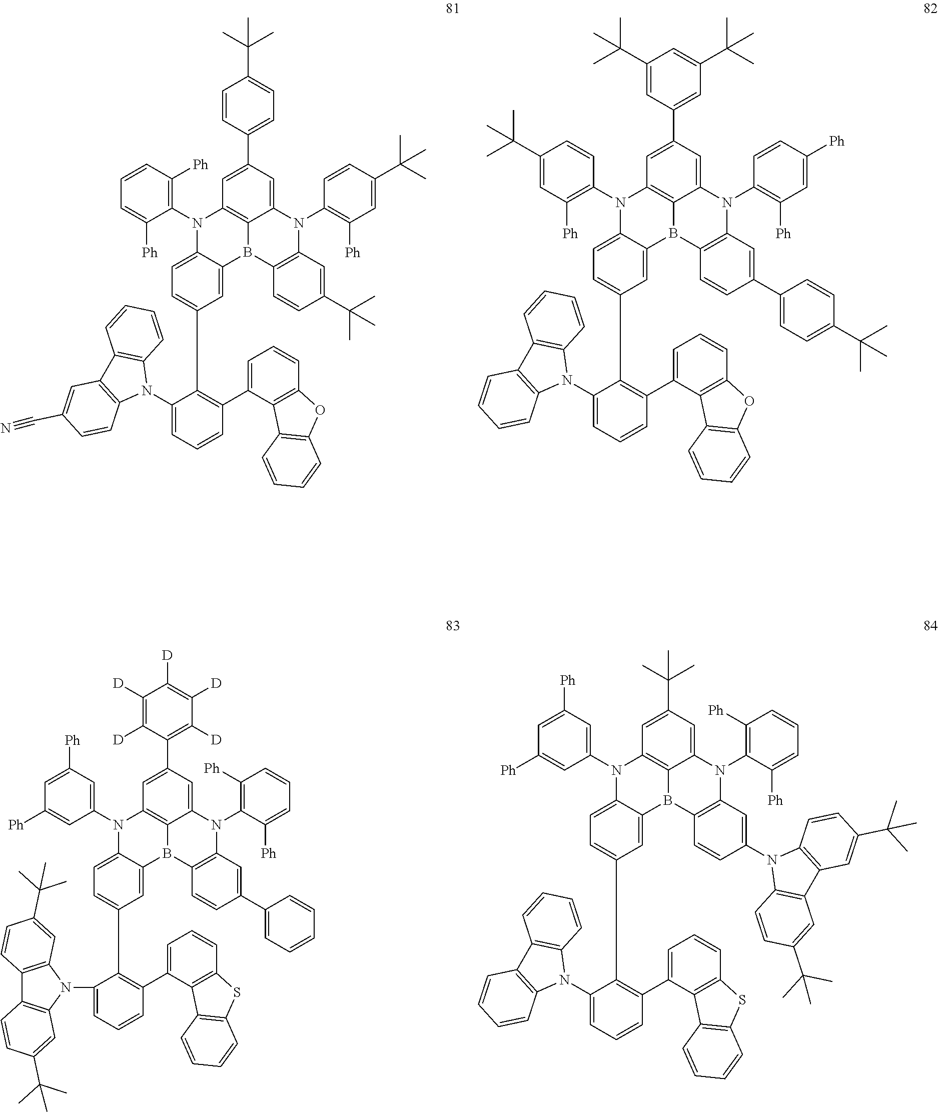

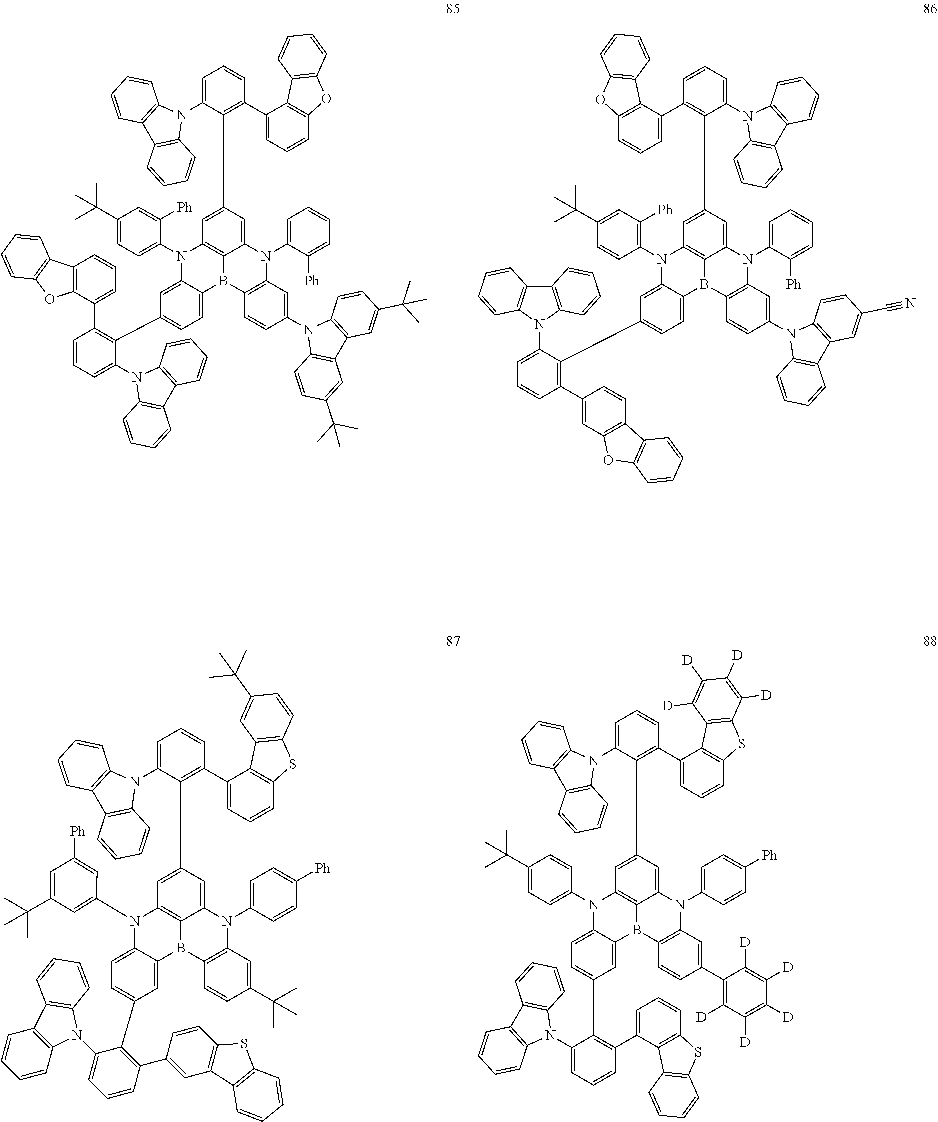

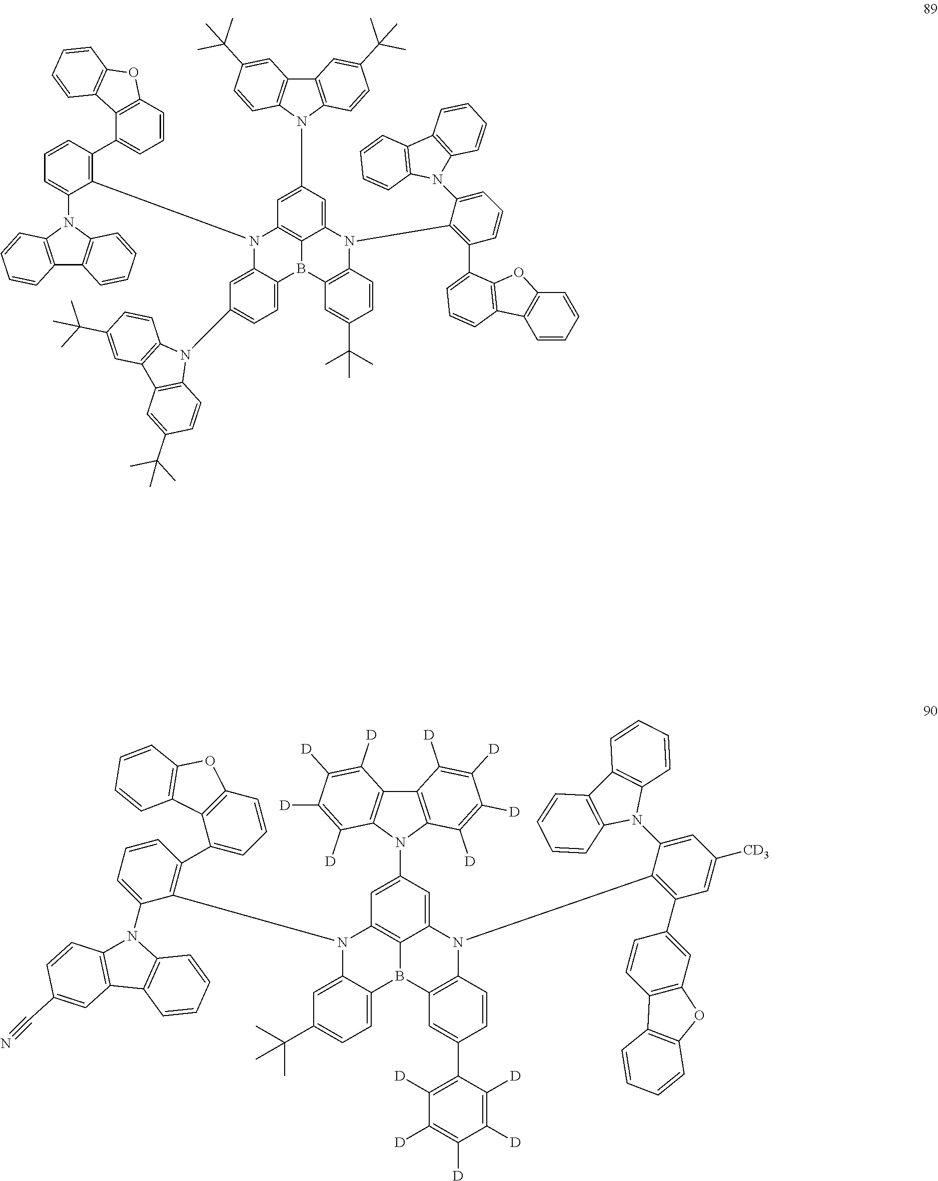

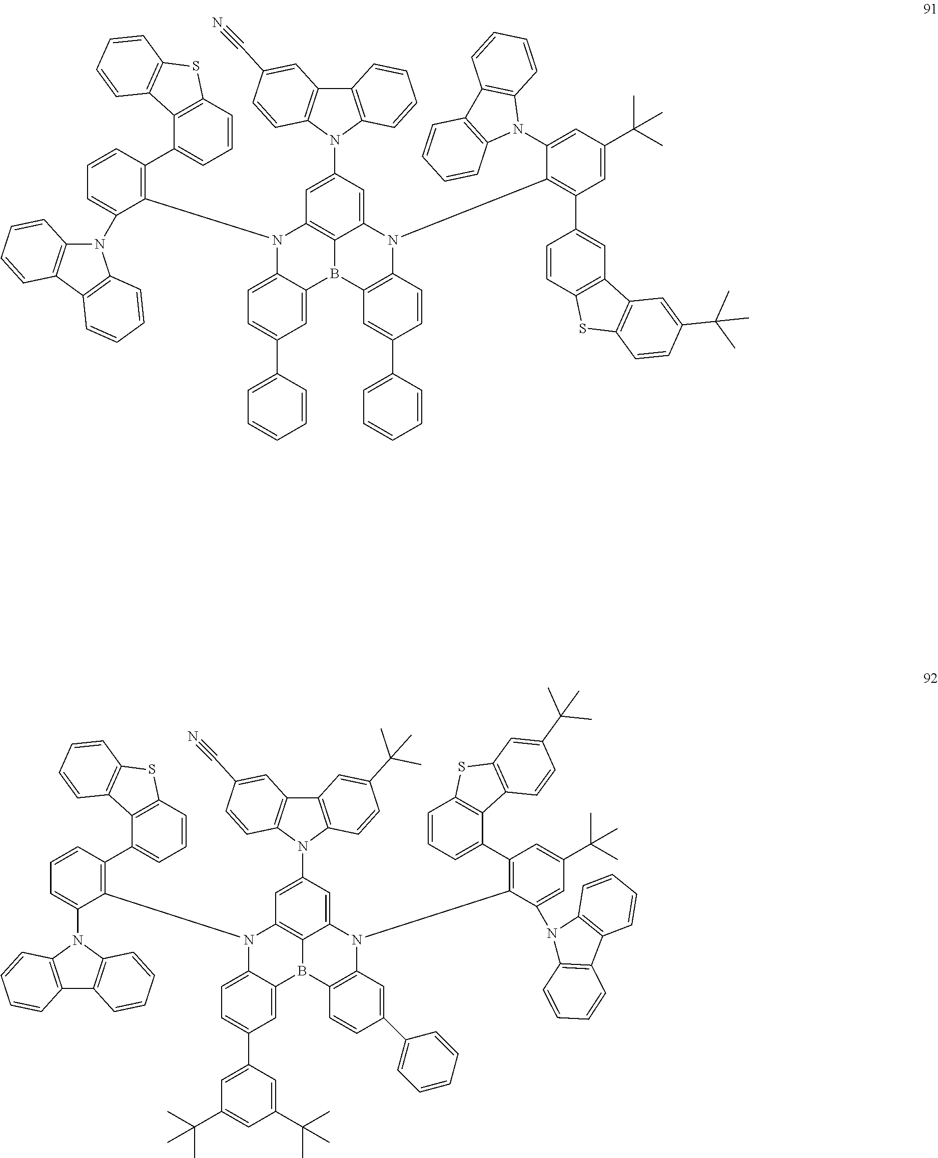 [SMILES: CC(C)(C)c1cc(-c2ccc3sc4ccc(C(C)(C)C)cc4c3c2)c(N2c3ccc(-c4ccccc4)cc3B3c4cc(-c5ccccc5)ccc4N(c4c(-c5cccc6sc7ccccc7c56)cccc4-n4c5ccccc5c5ccccc54)c4cc(-n5c6ccccc6c6cc(C#N)ccc65)cc2c43)c(-n2c3ccccc3c3ccccc32)c1 ; CC(C)(C)c1cc(-c2ccc3c(c2)B2c4ccc(-c5ccccc5)cc4N(c4c(-c5cccc6sc7cc(C(C)(C)C)ccc7c56)cc(C(C)(C)C)cc4-n4c5ccccc5c5ccccc54)c4cc(-n5c6ccc(C#N)cc6c6cc(C(C)(C)C)ccc65)cc(c42)N3c2c(-c3cccc4sc5ccccc5c34)cccc2-n2c3ccccc3c3ccccc32)cc(C(C)(C)C)c1]

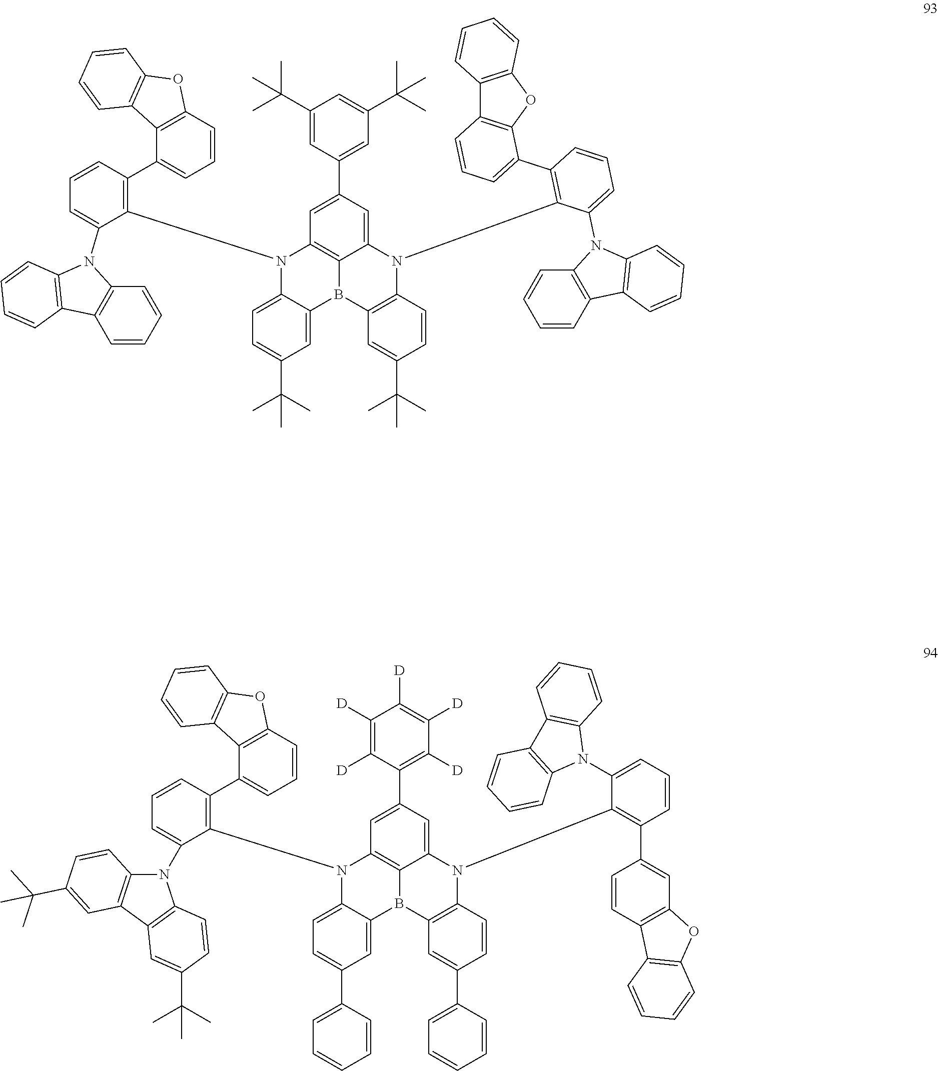 [SMILES: CC(C)(C)c1cc(-c2cc3c4c(c2)N(c2c(-c5cccc6oc7ccccc7c56)cccc2-n2c5ccccc5c5ccccc52)c2ccc(C(C)(C)C)cc2B4c2cc(C(C)(C)C)ccc2N3c2c(-c3cccc4c3oc3ccccc34)cccc2-n2c3ccccc3c3ccccc32)cc(C(C)(C)C)c1 ; [2H]c1c([2H])c([2H])c(-c2cc3c4c(c2)N(c2c(-c5cccc6oc7ccccc7c56)cccc2-n2c5ccc(C(C)(C)C)cc5c5cc(C(C)(C)C)ccc52)c2ccc(-c5ccccc5)cc2B4c2cc(-c4ccccc4)ccc2N3c2c(-c3ccc4c(c3)oc3ccccc34)cccc2-n2c3ccccc3c3ccccc32)c([2H])c1[2H]]

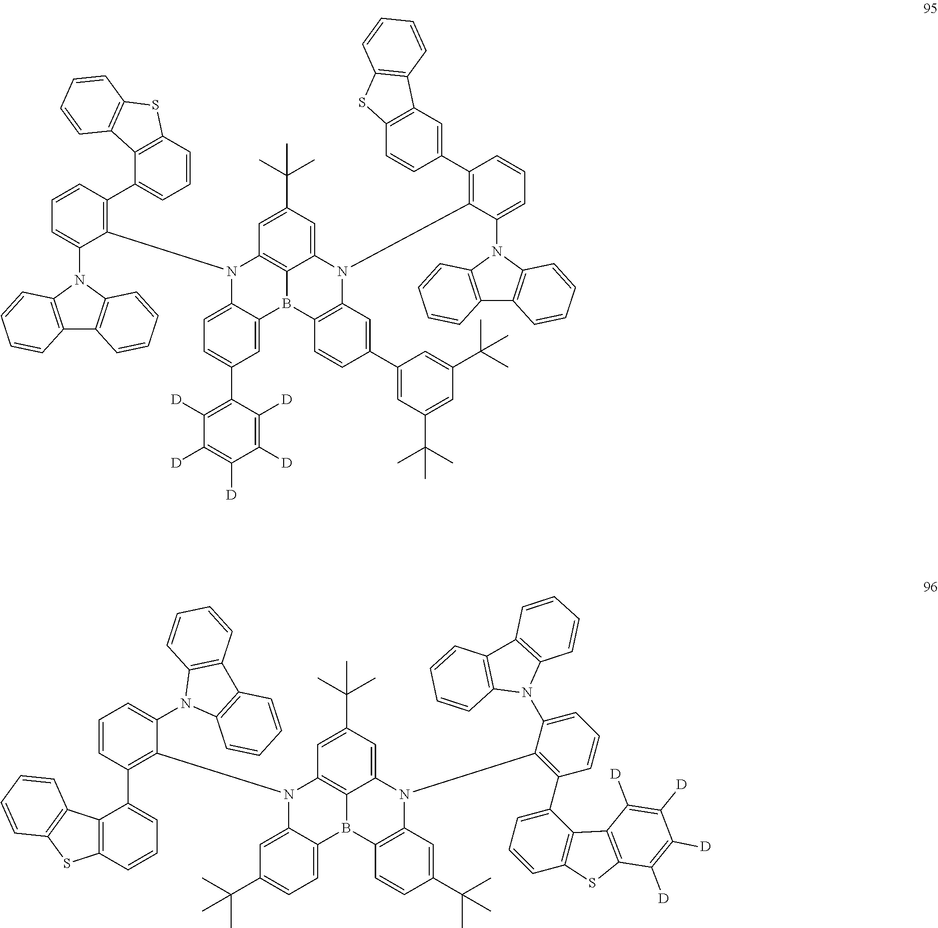 [SMILES: [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3cccc4sc5ccccc5c34)cccc2-n2c3ccccc3c3ccccc32)c([2H])c1[2H] ; [2H]c1c([2H])c([2H])c2c(sc3cccc(-c4cccc(-n5c6ccccc6c6ccccc65)c4N4c5cc(C(C)(C)C)ccc5B5c6ccc(C(C)(C)C)cc6N(c6c(-c7cccc8sc9ccccc9c78)cccc6-n6c7ccccc7c7ccccc76)c6cc(C(C)(C)C)cc4c65)c32)c1[2H]]

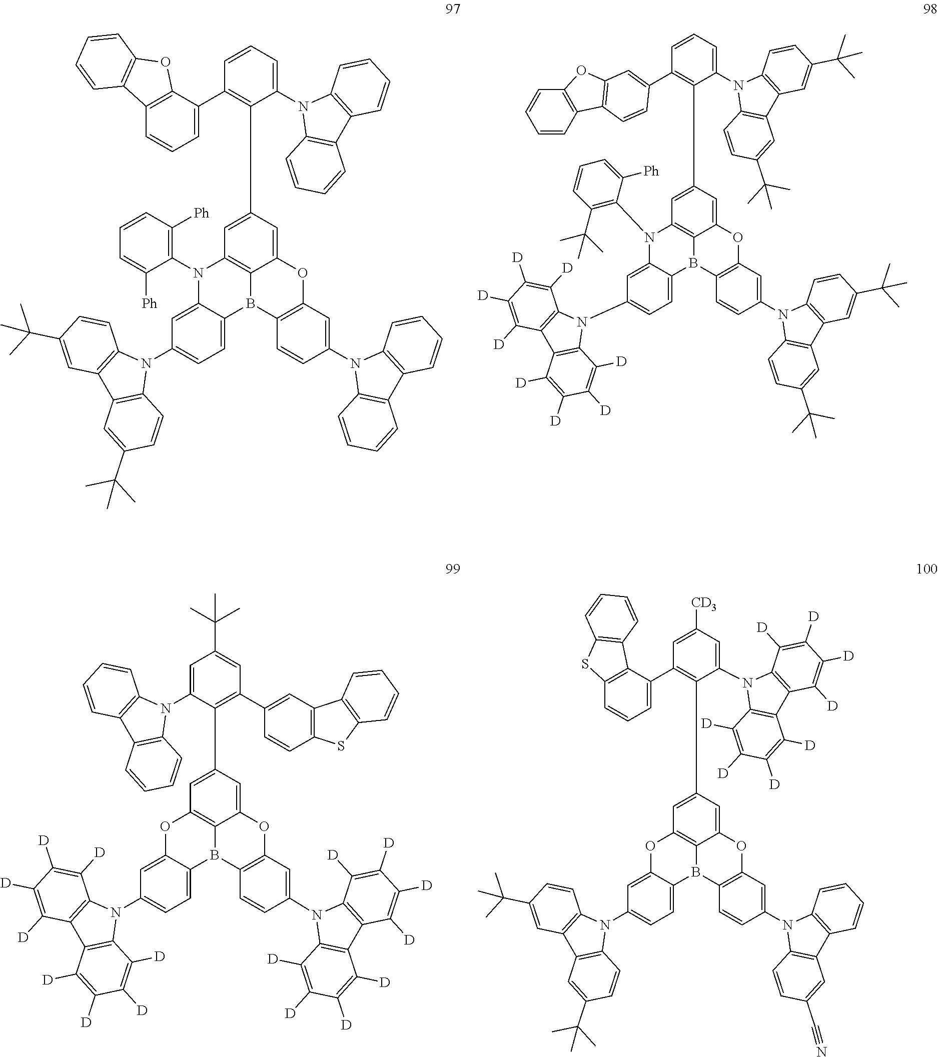

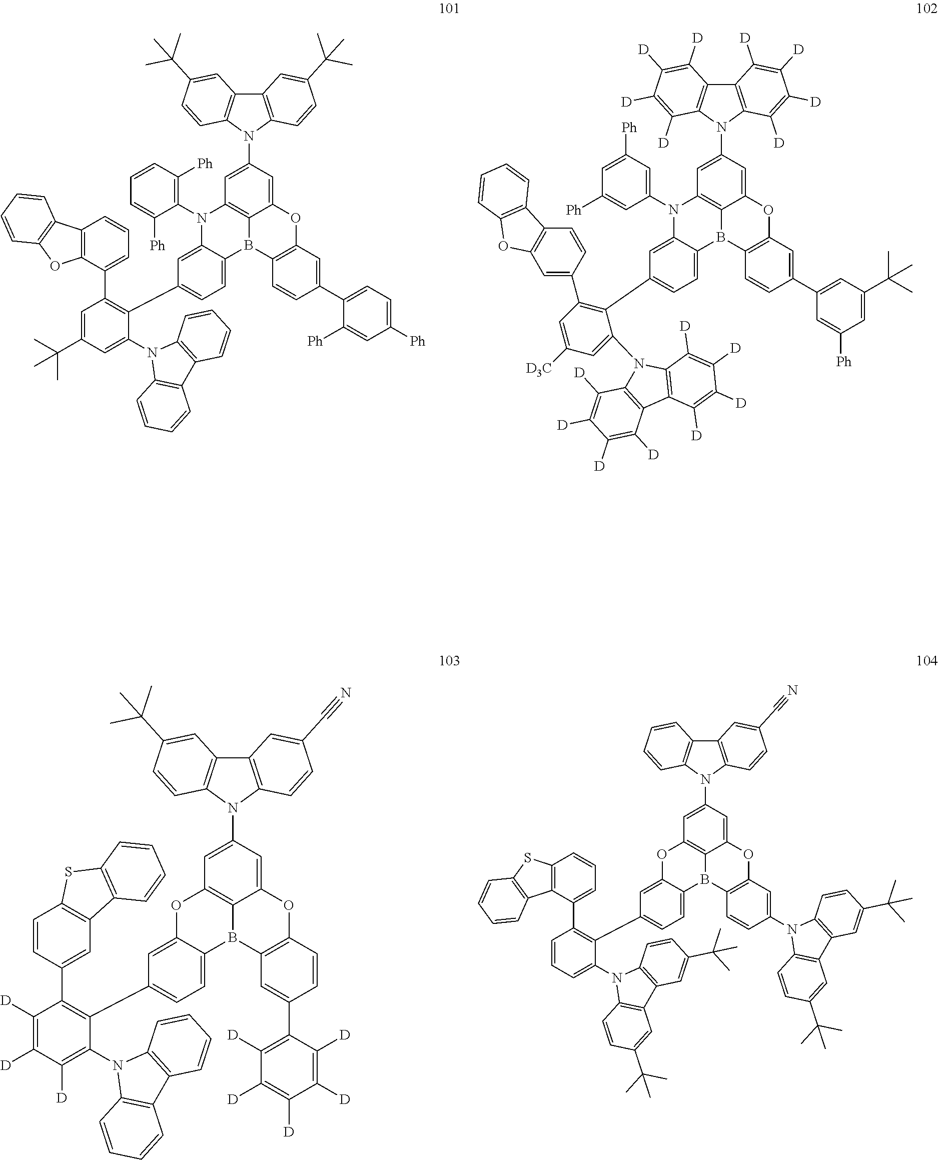

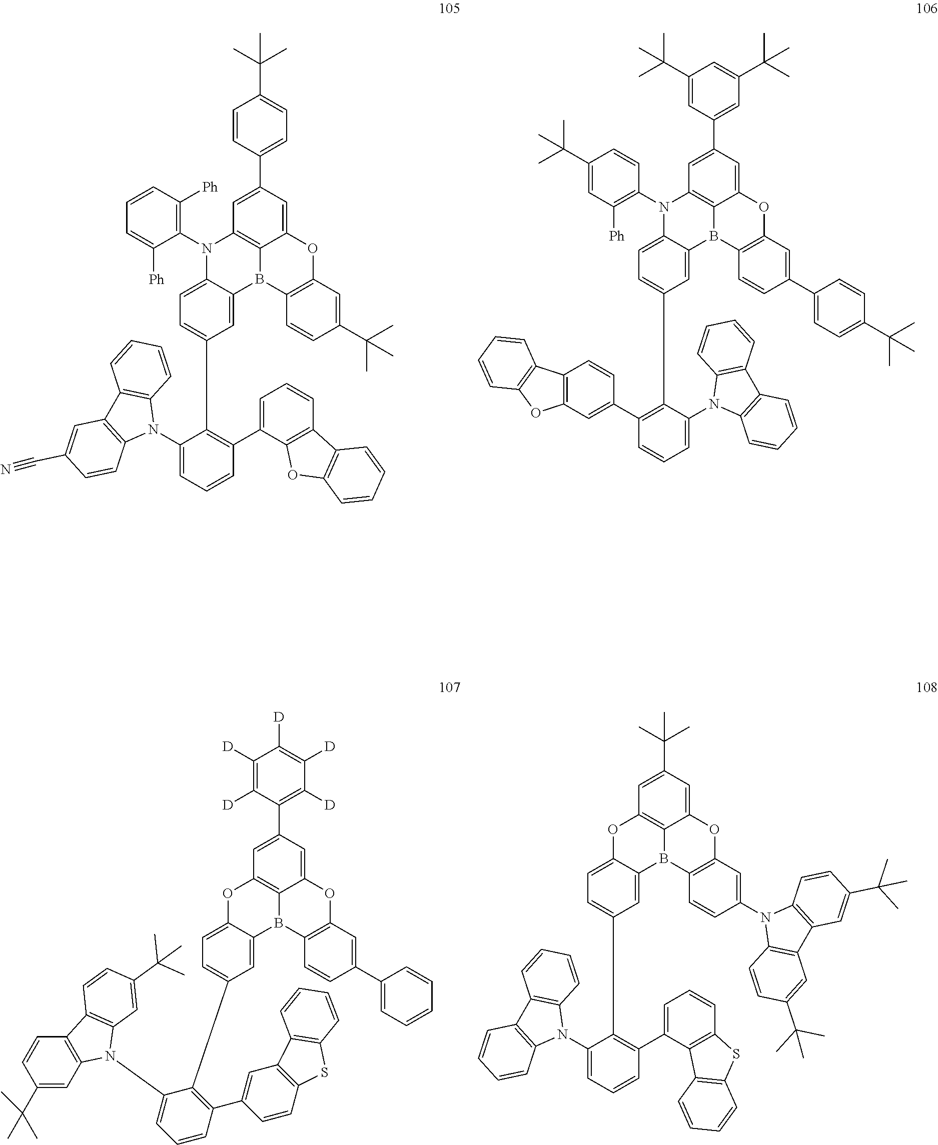

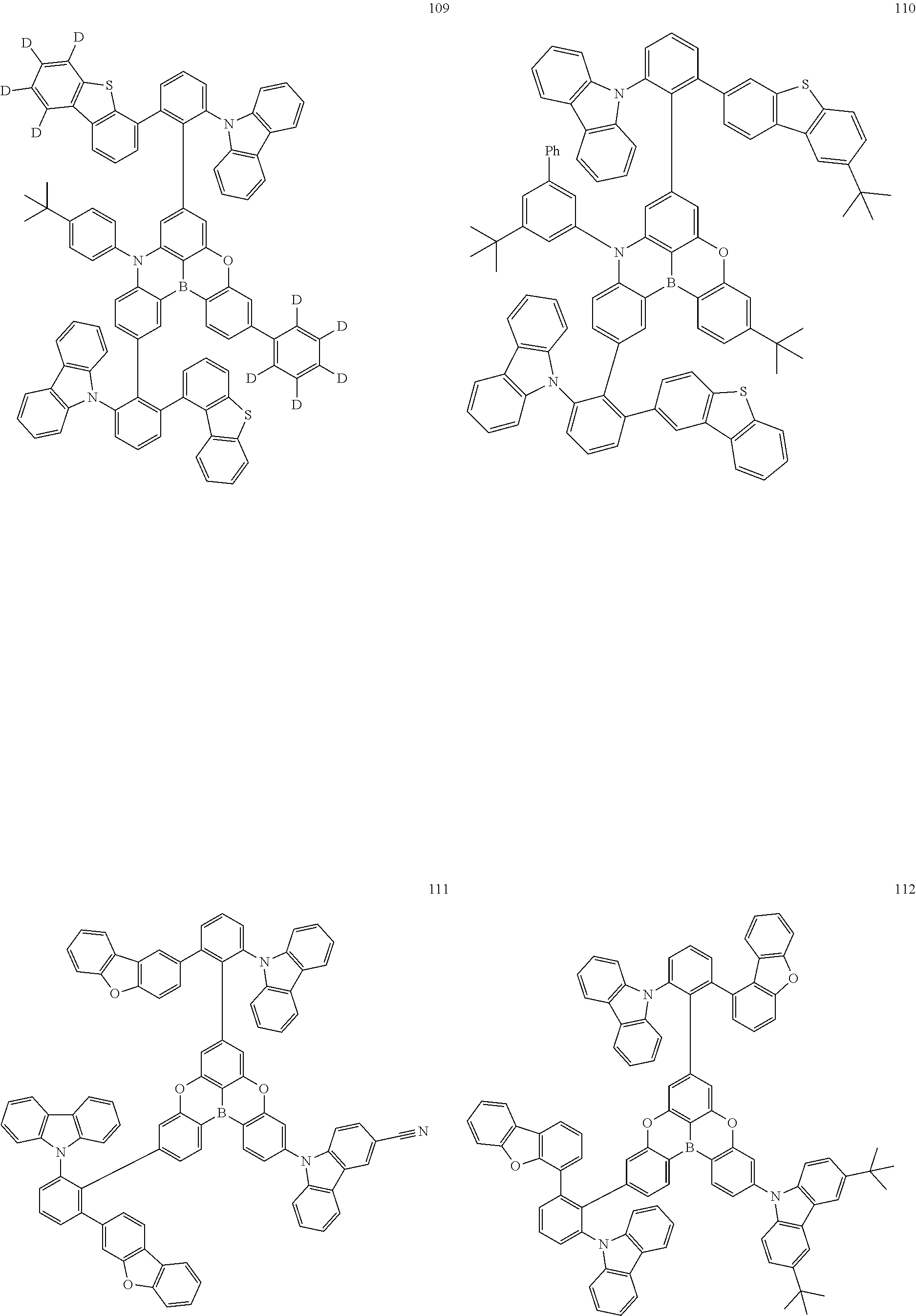

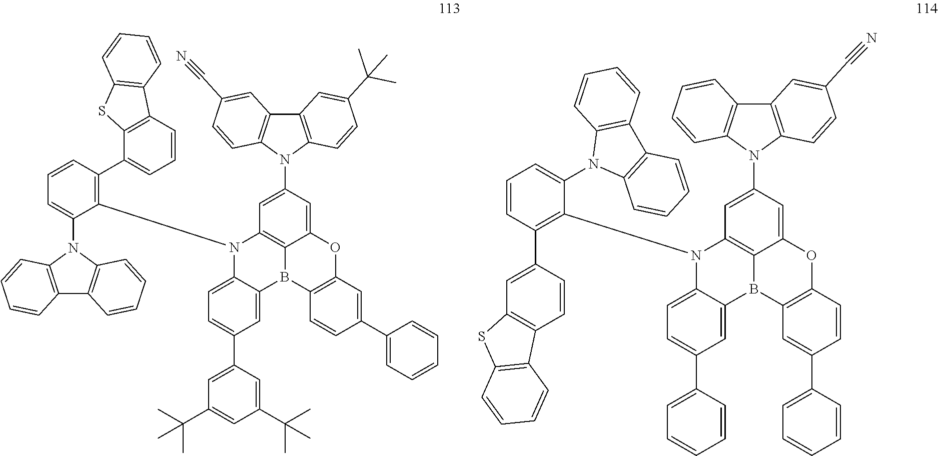 [SMILES: CC(C)(C)c1cc(-c2ccc3c(c2)B2c4ccc(-c5ccccc5)cc4Oc4cc(-n5c6ccc(C#N)cc6c6cc(C(C)(C)C)ccc65)cc(c42)N3c2c(-c3cccc4c3sc3ccccc34)cccc2-n2c3ccccc3c3ccccc32)cc(C(C)(C)C)c1 ; N#Cc1ccc2c(c1)c1ccccc1n2-c1cc2c3c(c1)N(c1c(-c4ccc5c(c4)sc4ccccc45)cccc1-n1c4ccccc4c4ccccc41)c1ccc(-c4ccccc4)cc1B3c1cc(-c3ccccc3)ccc1O2]

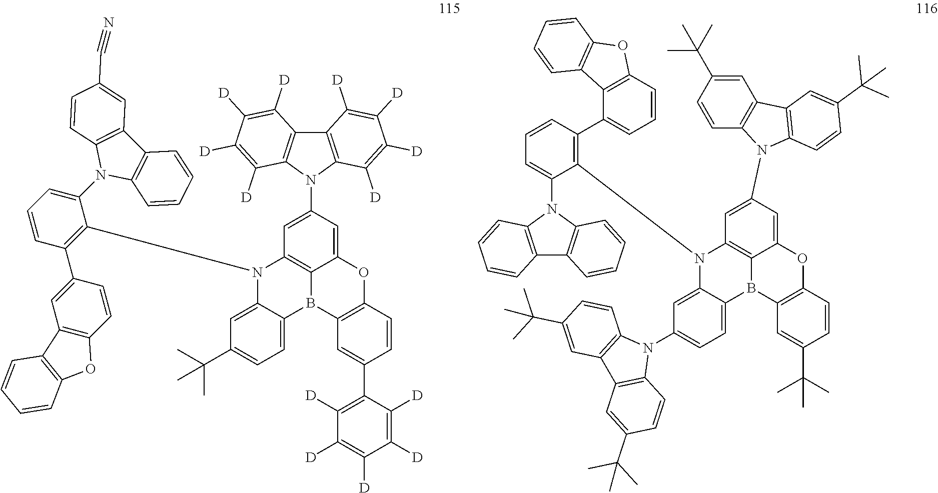

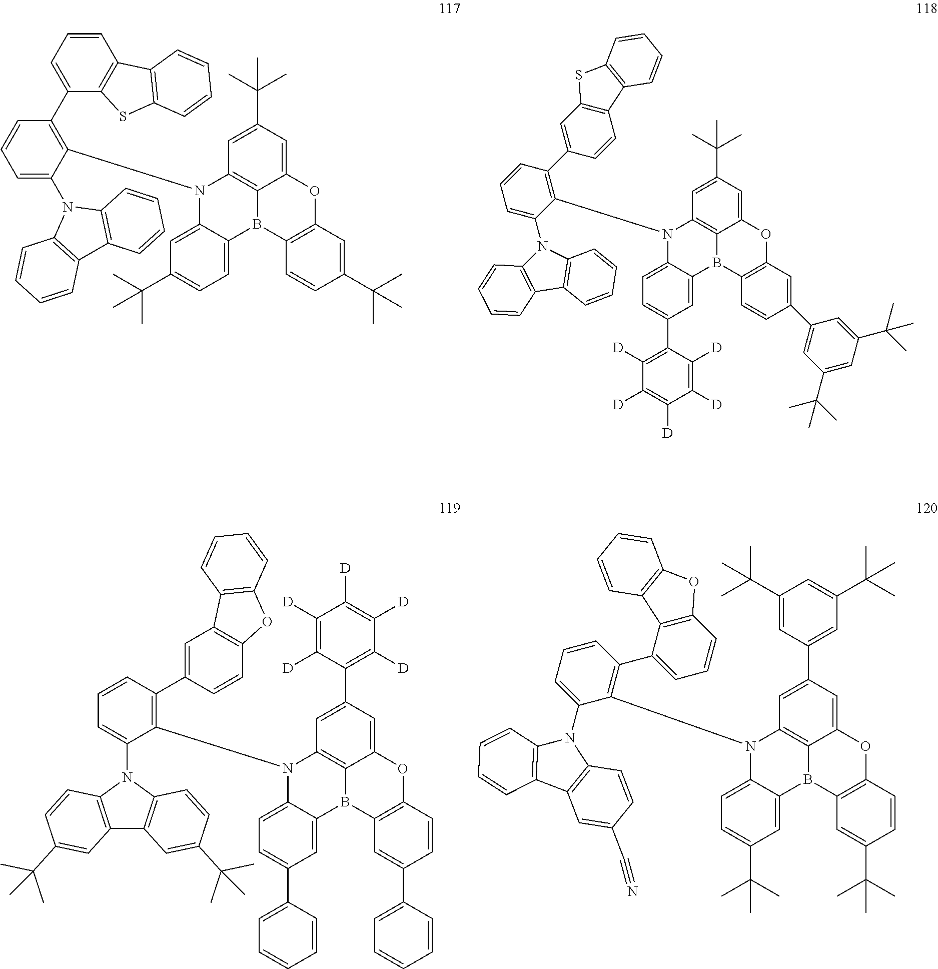

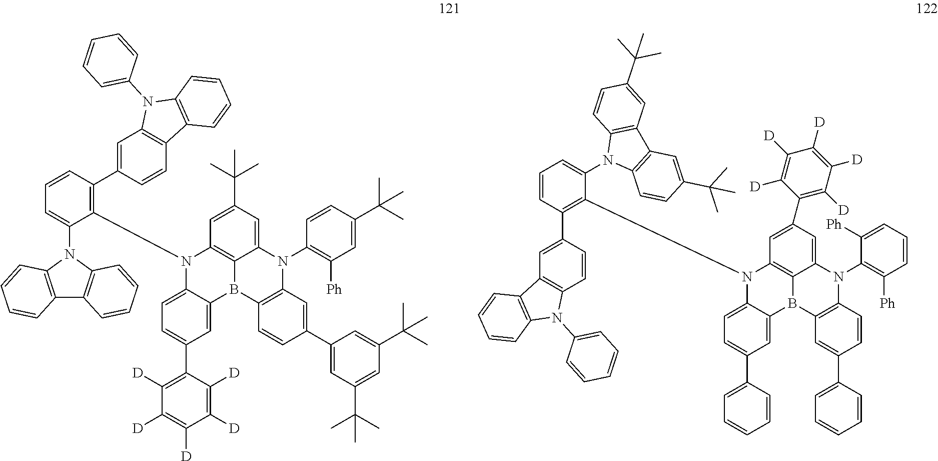

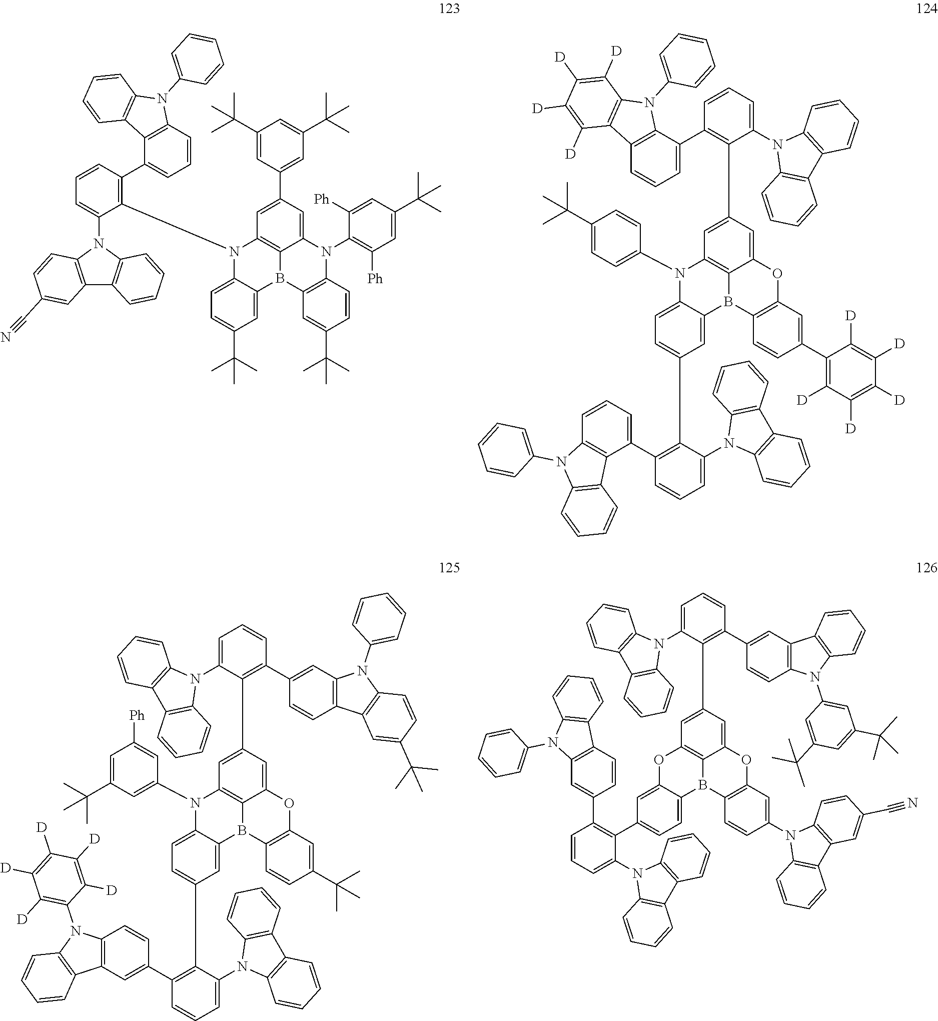

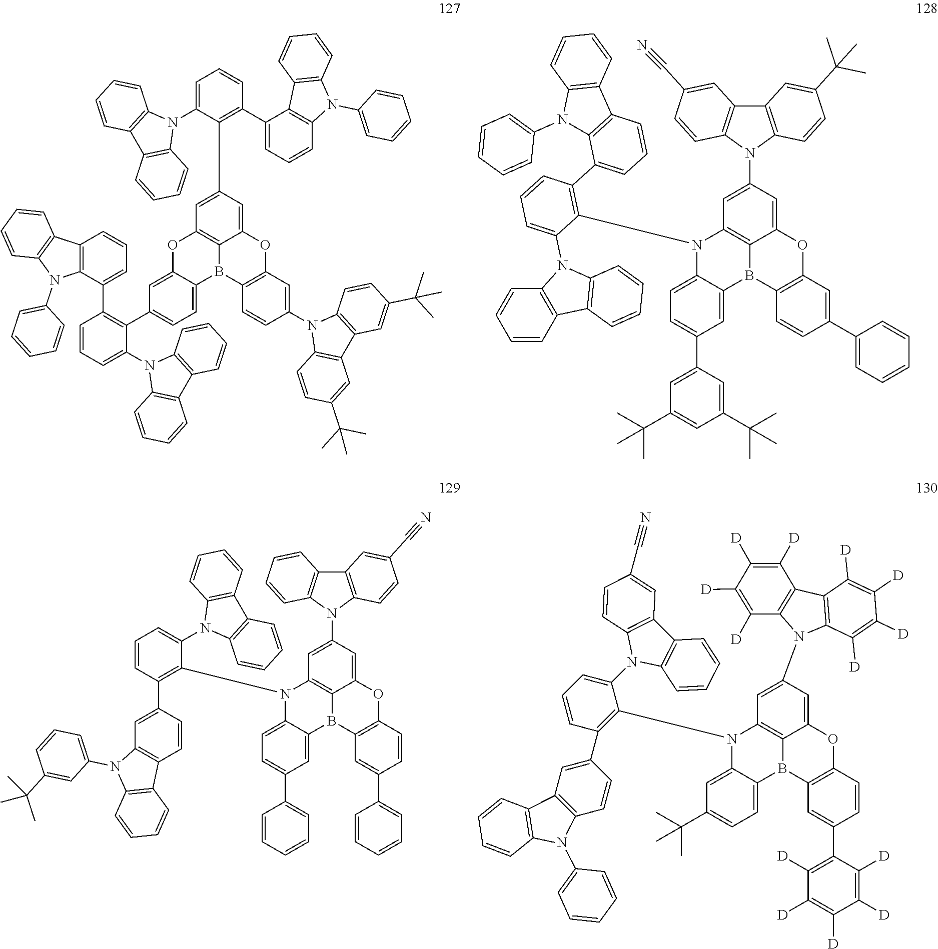

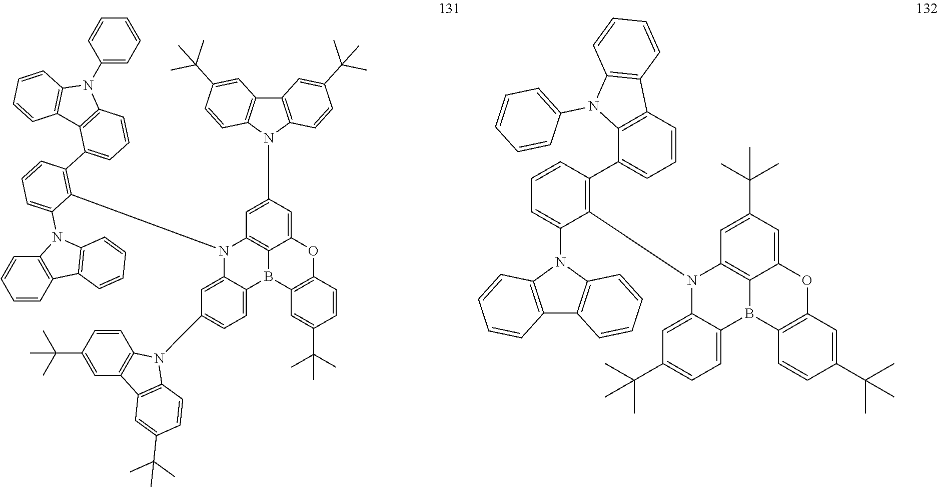 [SMILES: CC(C)(C)c1ccc2c(c1)B1c3ccc(-n4c5ccc(C(C)(C)C)cc5c5cc(C(C)(C)C)ccc54)cc3N(c3c(-c4cccc5c4c4ccccc4n5-c4ccccc4)cccc3-n3c4ccccc4c4ccccc43)c3cc(-n4c5ccc(C(C)(C)C)cc5c5cc(C(C)(C)C)ccc54)cc(c31)O2 ; CC(C)(C)c1ccc2c(c1)Oc1cc(C(C)(C)C)cc3c1B2c1ccc(C(C)(C)C)cc1N3c1c(-c2cccc3c4ccccc4n(-c4ccccc4)c23)cccc1-n1c2ccccc2c2ccccc21]

The polycyclic compound includes a core moiety of a fused ring that includes a boron atom as a ring-forming atom, and including at least two substituents having a dibenzoheterole skeleton that are bonded at an ortho-position to the core moiety via a benzene derivative as a linking moiety, and thus may control the distortion between bonds in the molecule, thereby exhibiting high stability. The polycyclic compound has an increase in delayed luminescence due to the effect of the at least two substituents having a dibenzoheterole skeleton introduced, thereby exhibiting improved luminous efficiency characteristics. The polycyclic compound may be used as a material for a light emitting element, thereby improving luminous efficiency and service life characteristics of the light emitting element.

An emission layer EML of the light emitting element may include the polycyclic compound. An emission layer EML may include the polycyclic compound as a dopant material. The polycyclic compound may be a thermally activated delayed fluorescence material. The polycyclic compound may be used as a thermally activated delayed fluorescence (TADF) dopant. For example, in an embodiment, in the light emitting element ED, the emission layer EML may include, as a thermally activated delayed fluorescence dopant, at least one polycyclic compound selected from Compound Group 1 as described herein. However, a use of the polycyclic compound is not limited thereto.

The polycyclic compound may be a luminescent material that emits light having a central wavelength in a range of about 430 nm to about 490 nm. For example, the polycyclic compound may emit blue light. For example, the polycyclic compound represented by Formula 1 may be a blue thermally activated delayed fluorescence (TADF) dopant. However, embodiments are not limited thereto.

For example, an absolute value of a triplet energy level (T1) of an exciplex formed by a hole transporting host and an electron transporting host may be in a range of about 2.4 eV to about 3.0 eV. A triplet energy level of the exciplex may be a value that is less than an energy gap of each host material. The exciplex may have a triplet energy level that is less than or equal to about 3.0 eV that is an energy gap between the hole transporting host and the electron transporting host.

In an embodiment, the emission layer EML may include the first compound represented by Formula 1, and at least one of a second compound represented by Formula HT-1 or a third compound represented by Formula ET-1. In another embodiment, the emission layer EML may further include a fourth compound represented by Formula M-b.

In an embodiment, the emission layer EML may include a second compound represented by Formula HT-1. For example, the second compound may be used as a hole transport host material of the emission layer EML.

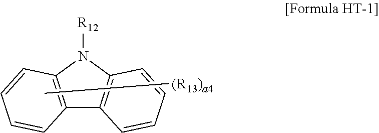

In Formula HT-1, a4 may be an integer from 0 to 8. When a4 is 2 or more, multiple R₁₃ group may be the same as each other or at least one thereof may be different from the others. In Formula HT-1, R₁₂ and R₁₃ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms. For example, R₁₂ may be a substituted phenyl group, an unsubstituted dibenzofuran group, or a substituted fluorenyl group. For example, R₁₃ may be a substituted or unsubstituted carbazole group.

The second compound may be any compound selected from Compound Group 2. Compound Group 2 may include a compound represented by Formula HT-1. Compound Group 2 may also include compounds other than a compound represented by Formula HT-1. The light emitting element ED may include any compound selected from Compound Group 2. In Compound Group 2, D is a deuterium atom.

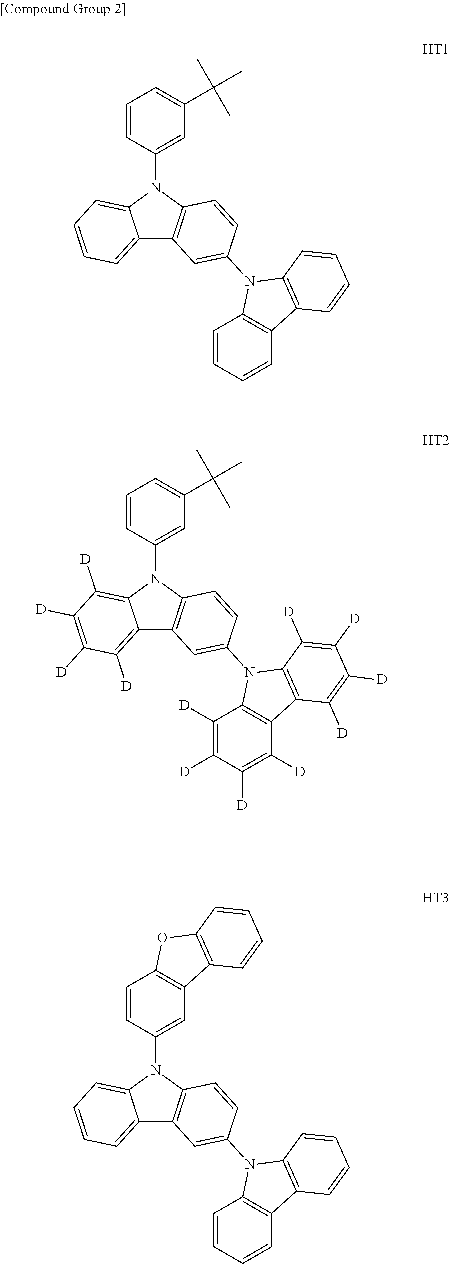 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

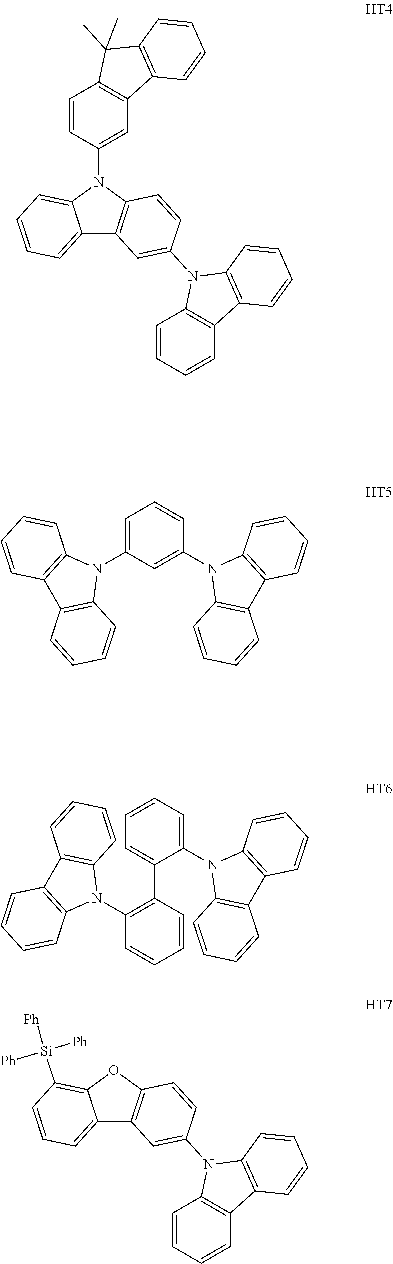 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

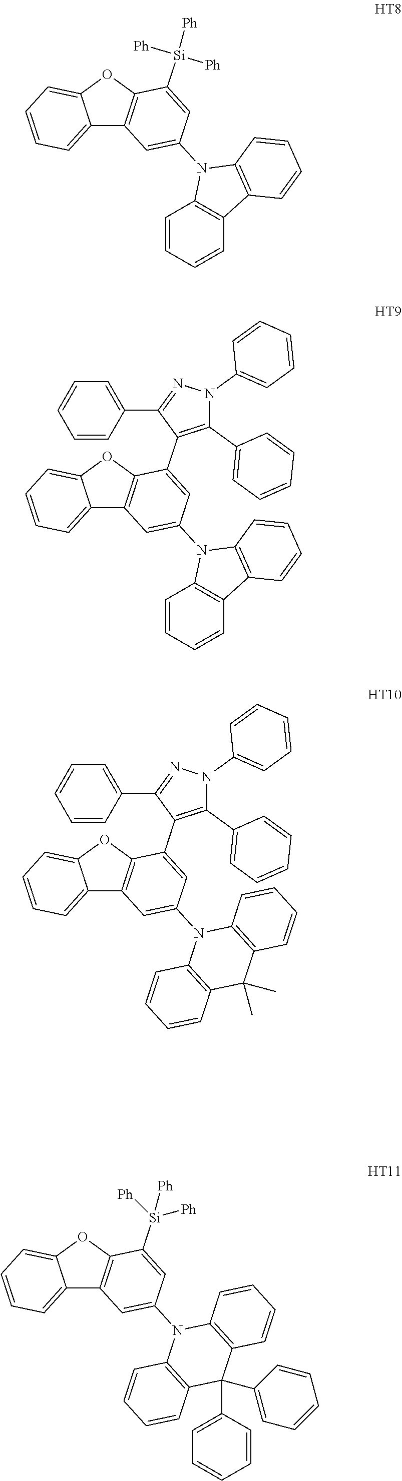 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

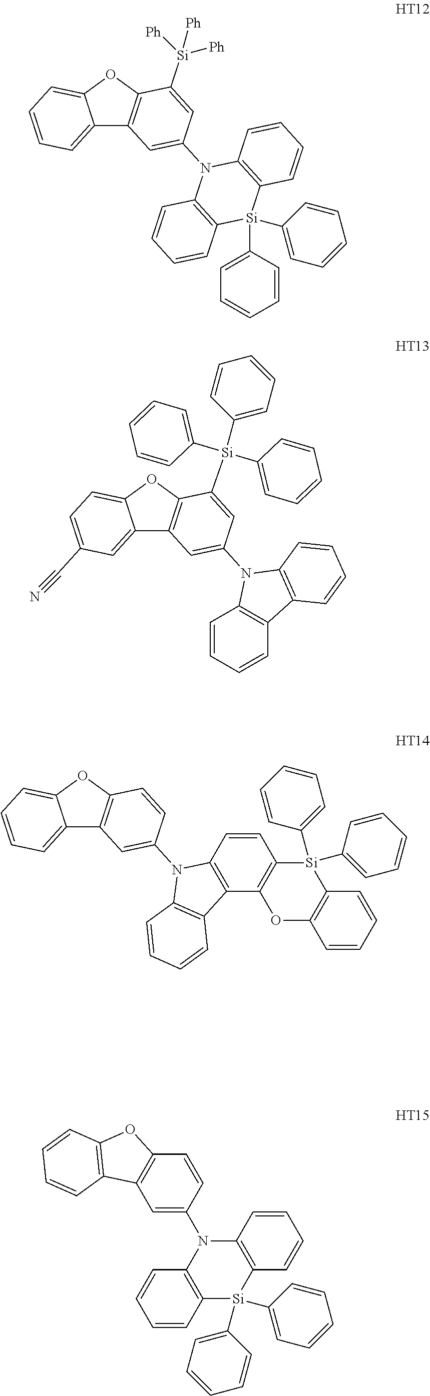

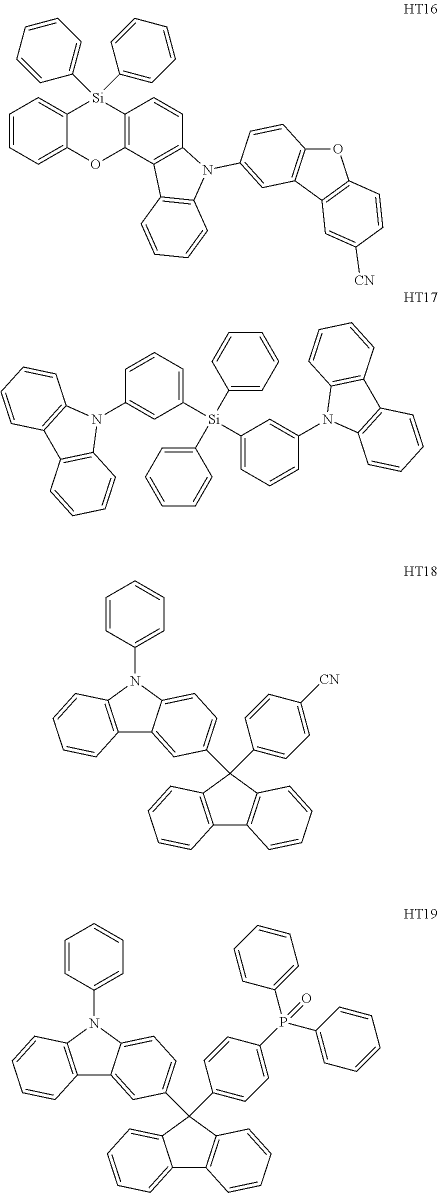

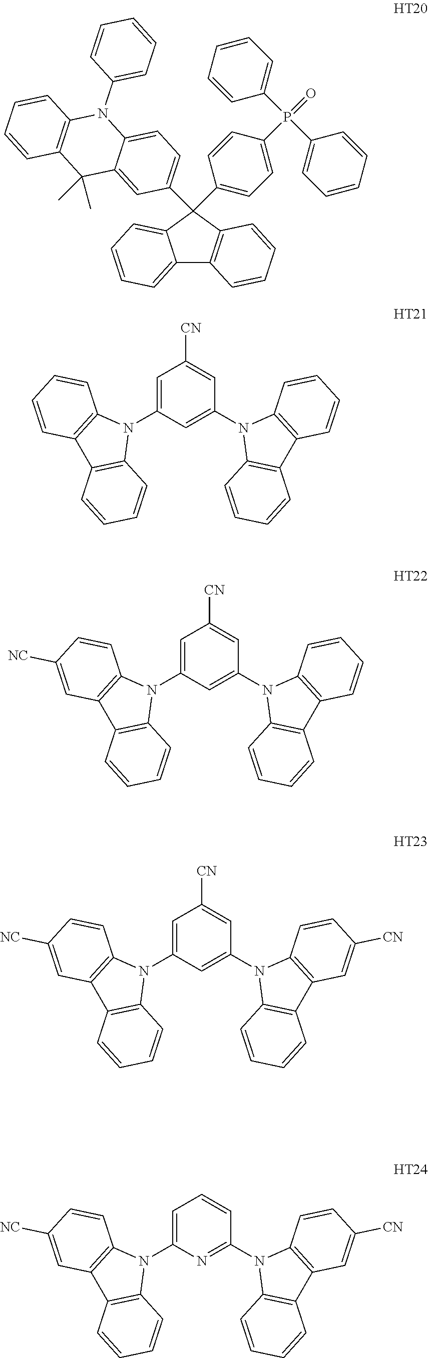 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

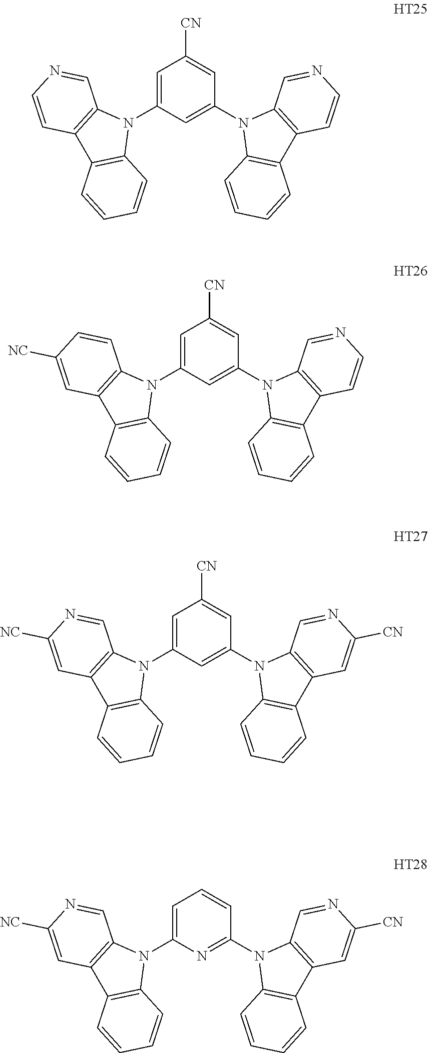 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

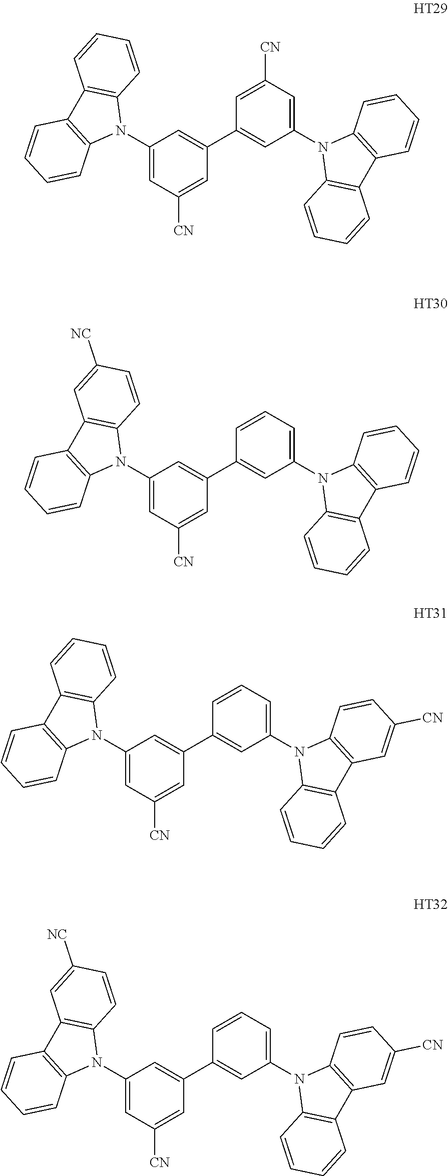 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

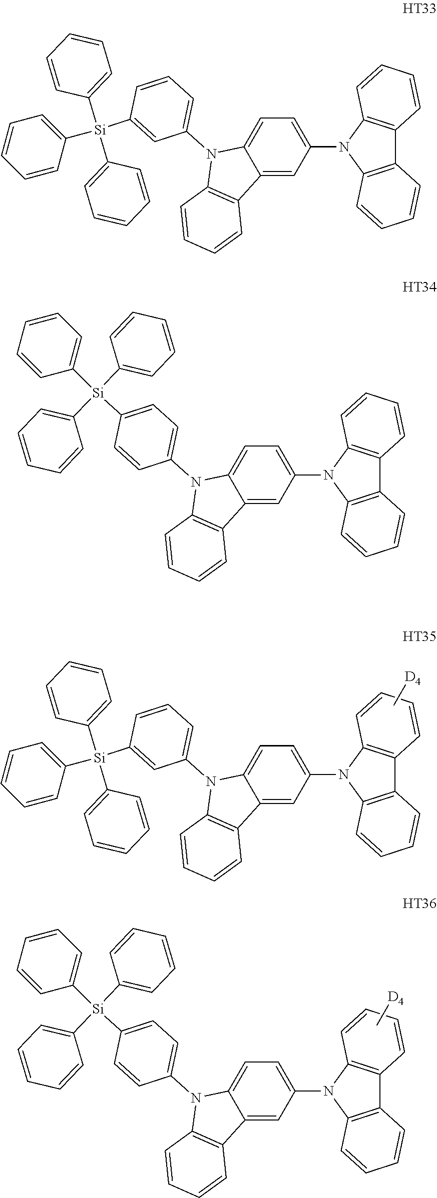

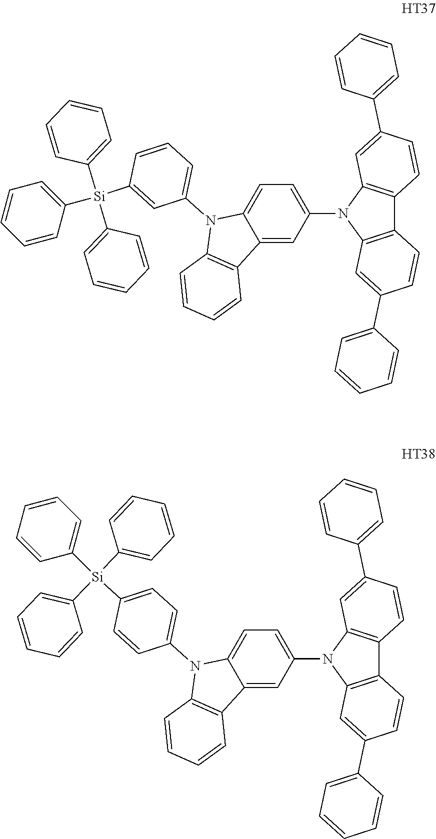 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

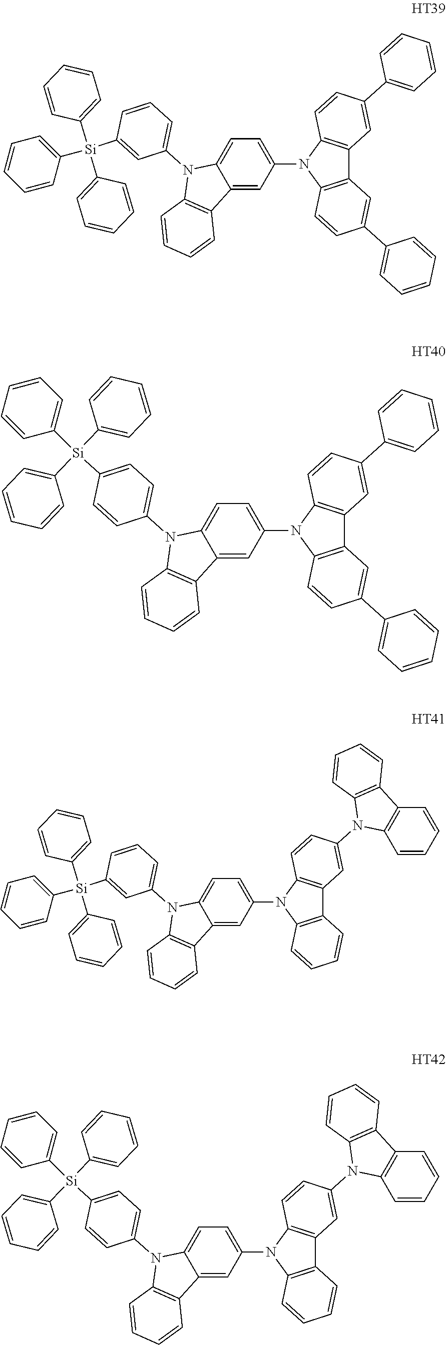 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

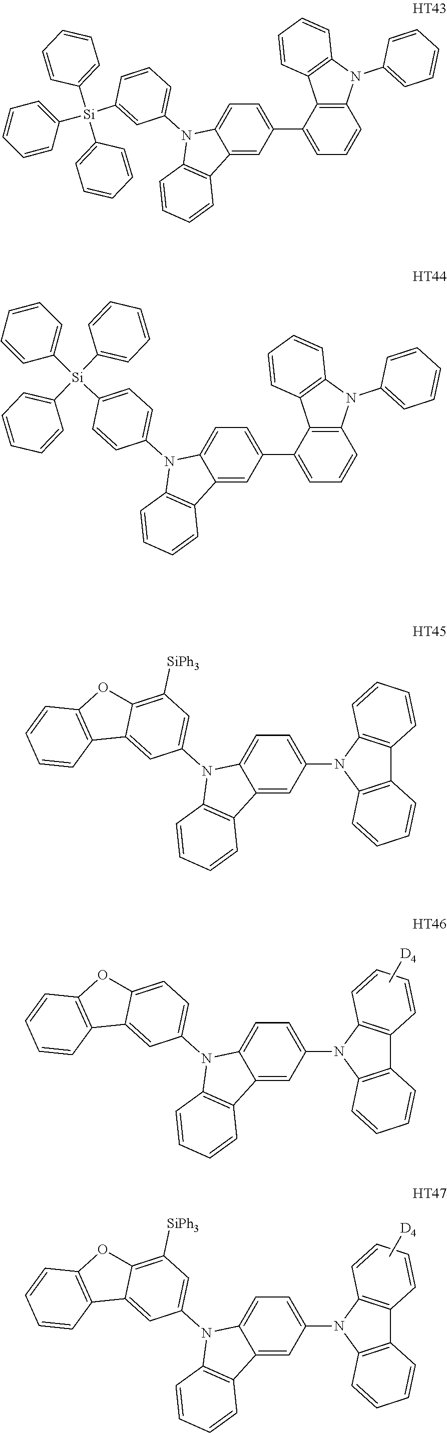

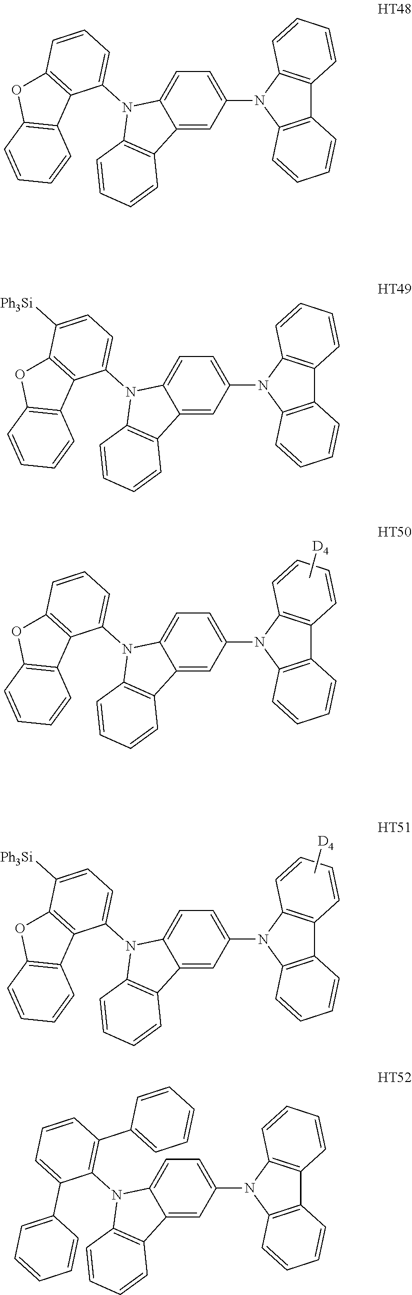

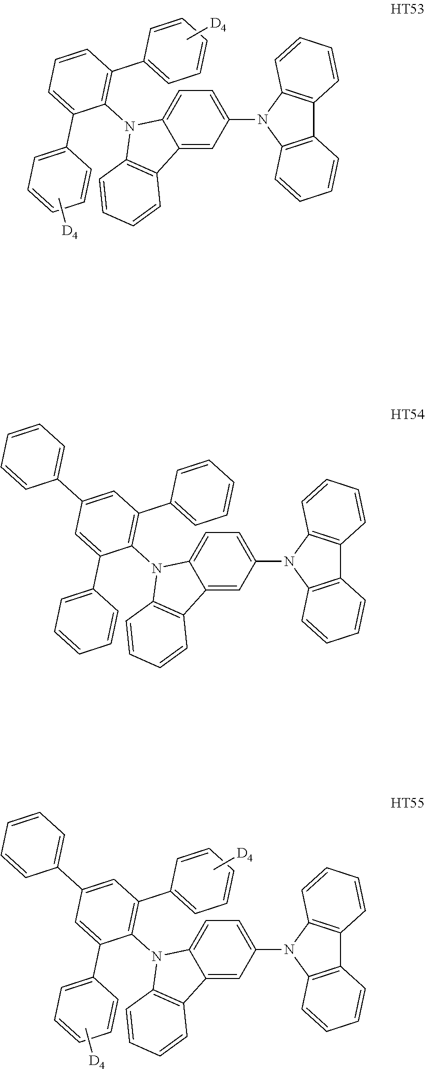

In an embodiment, the emission layer EML may include a third compound represented by Formula ET-1. For example, the third compound may be used as an electron transport host material of the emission layer EML.

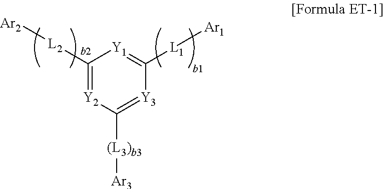

In Formula ET-1, at least one of Y₁ to Y₃ may each be N; the remainder of Y₁ to Y₃ may each independently be C(Rₐ); and Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may each independently be a substituted or unsubstituted phenyl group, or a substituted or unsubstituted carbazole group.

The third compound may be any compound selected from Compound Group 3. The light emitting element ED may include any compound selected from Compound Group 3. In Compound Group 3, D is a deuterium atom.

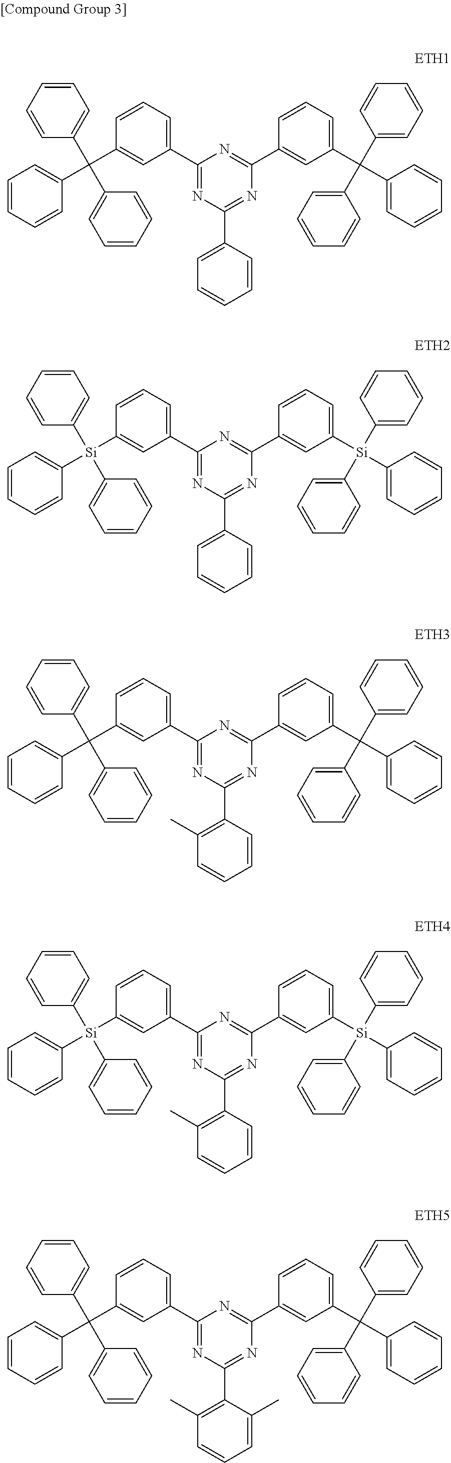

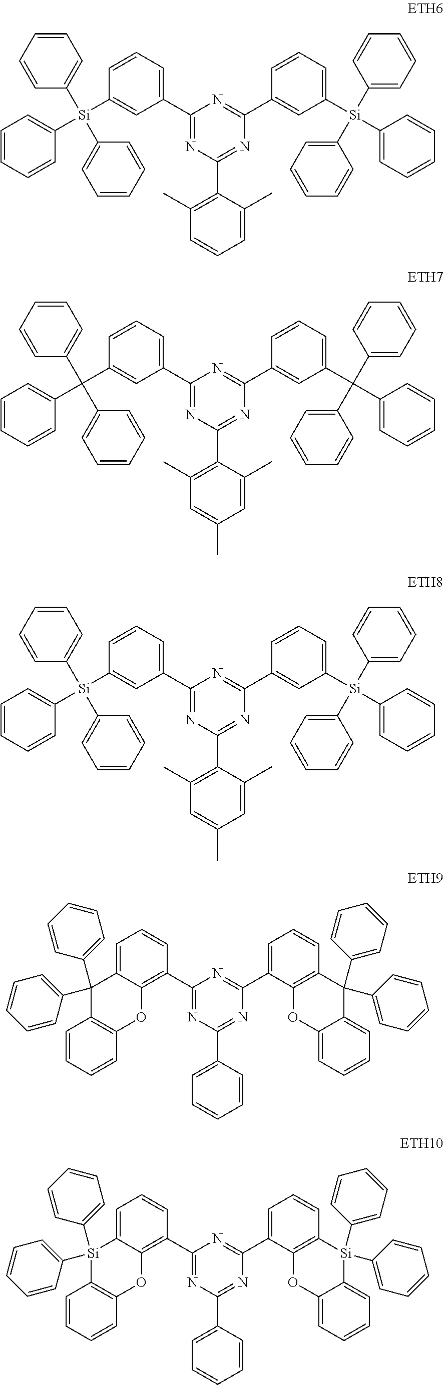

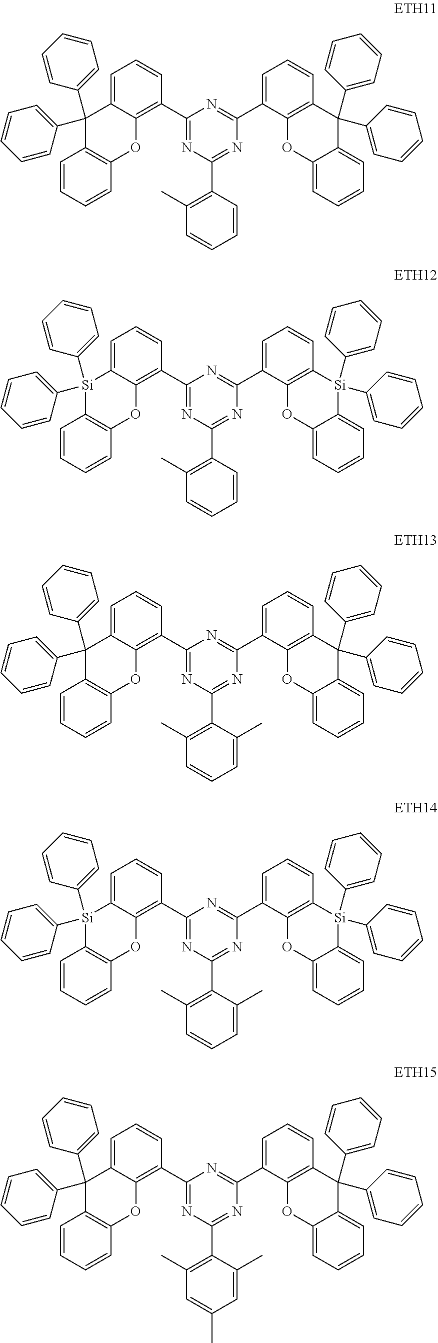

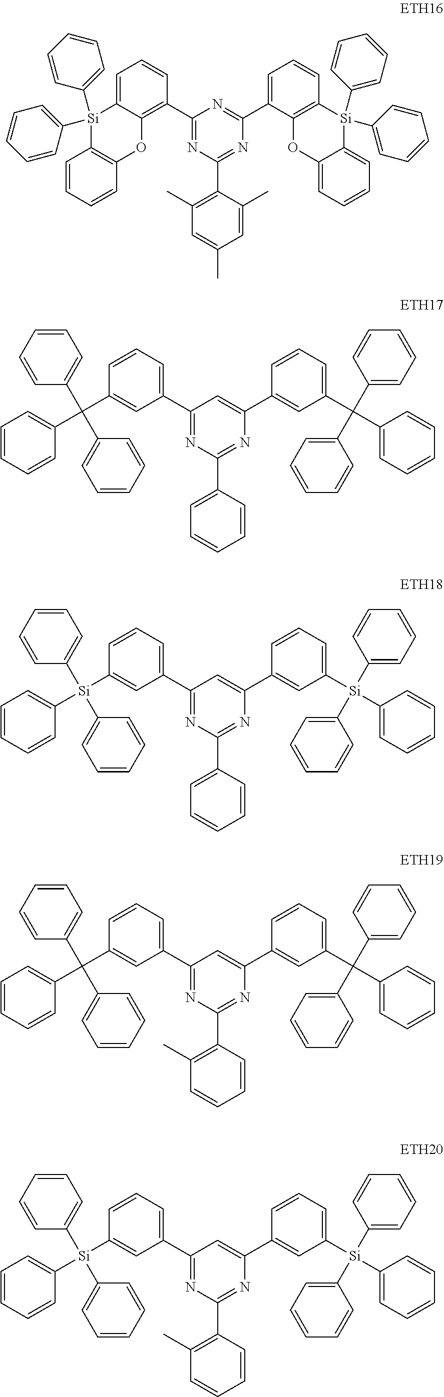

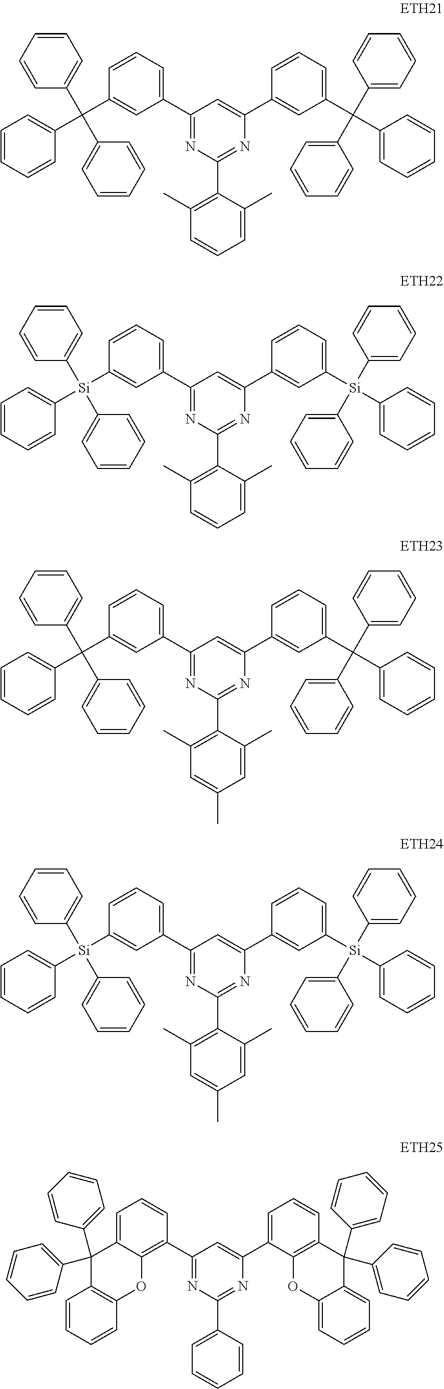

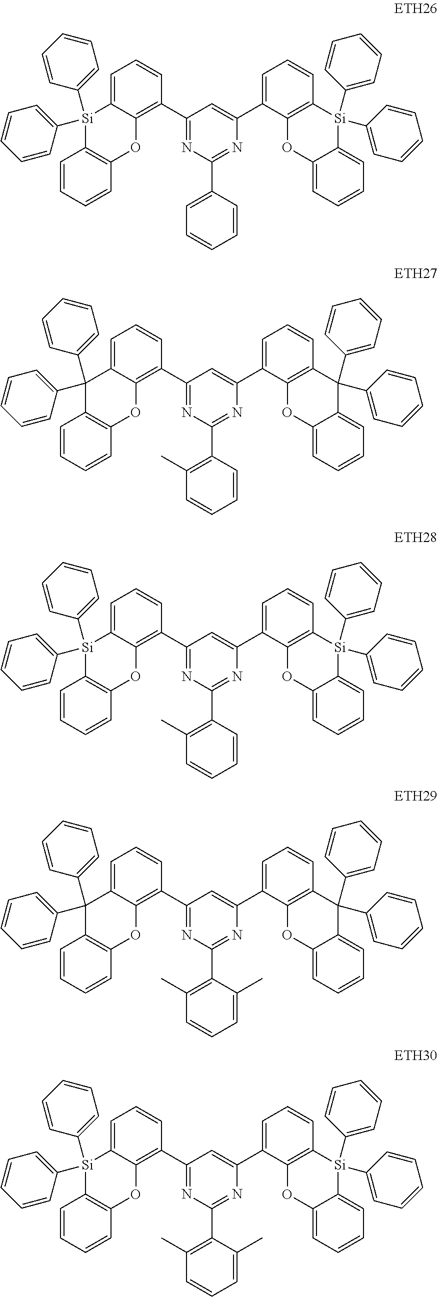

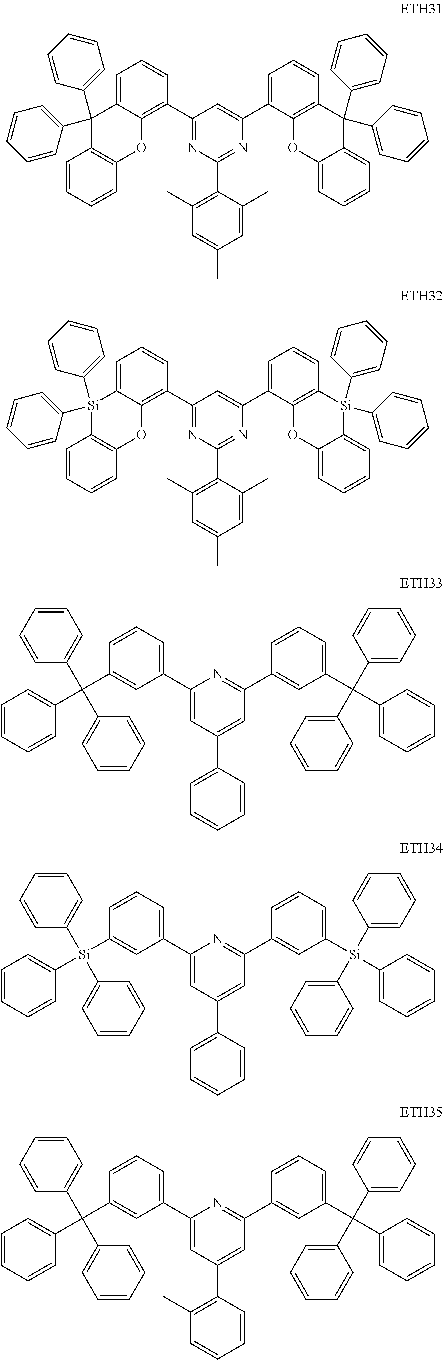

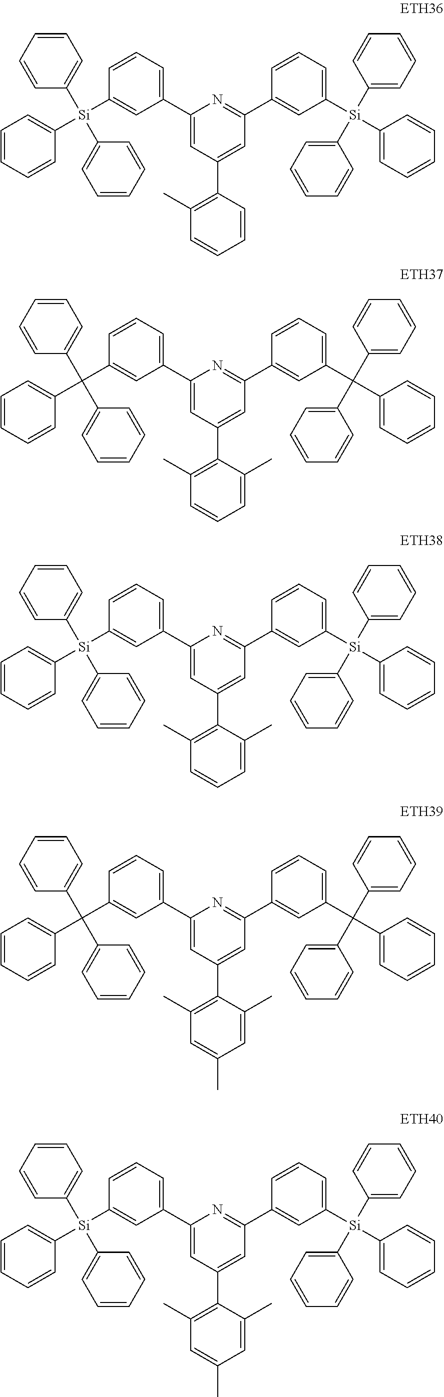

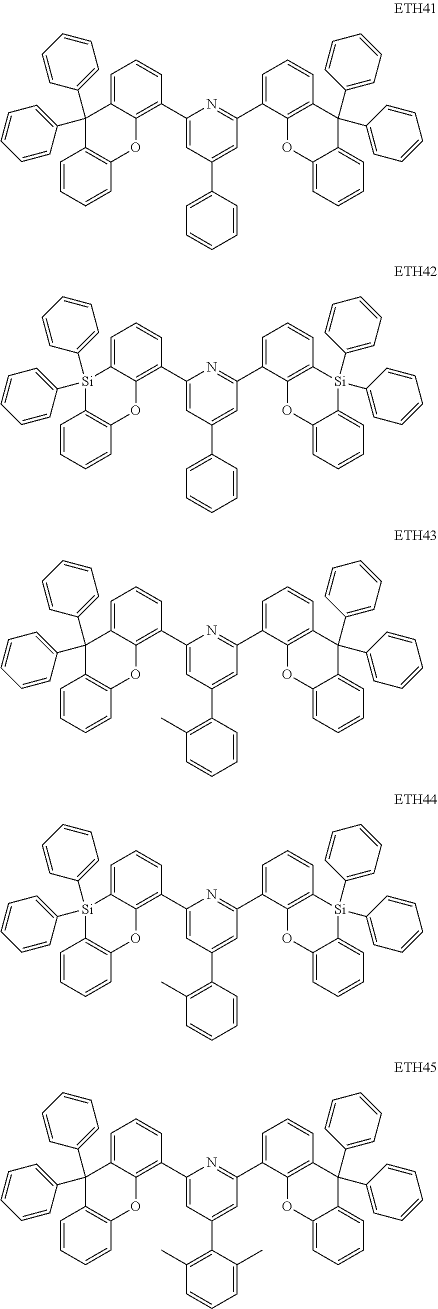

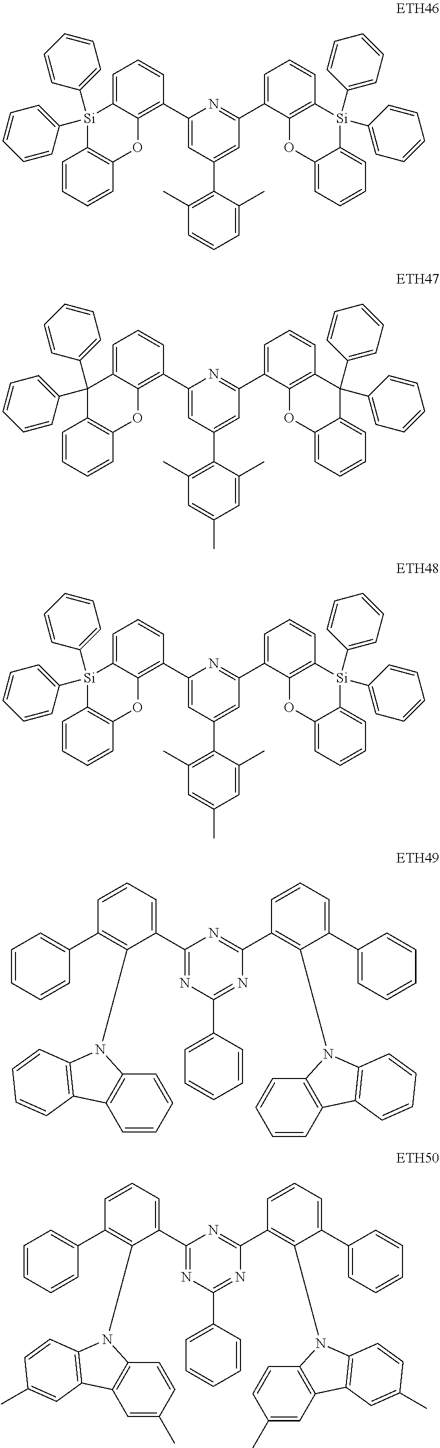

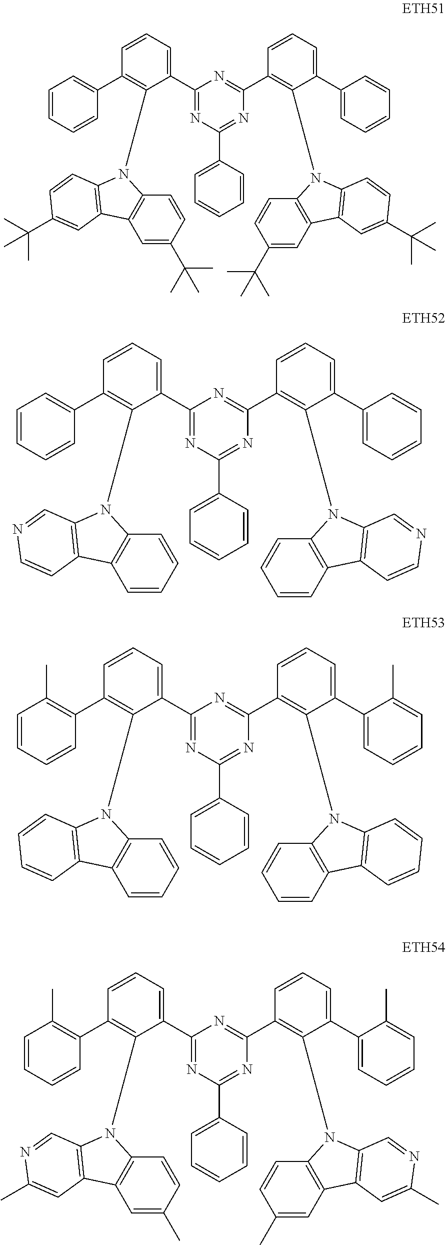

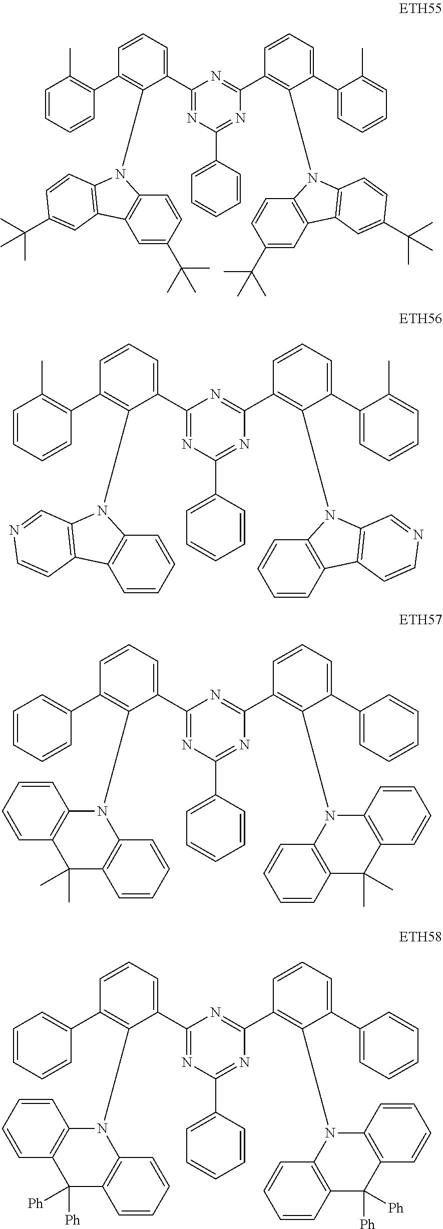

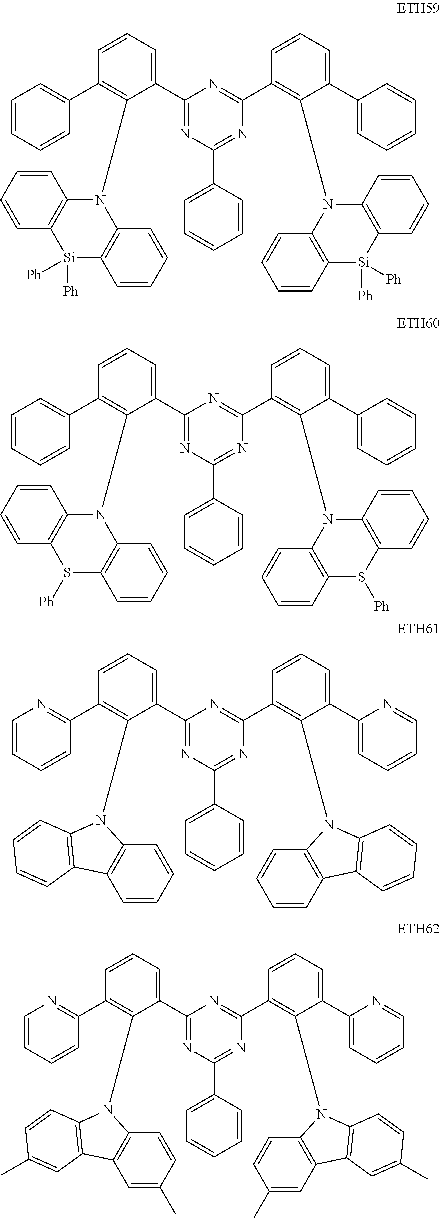

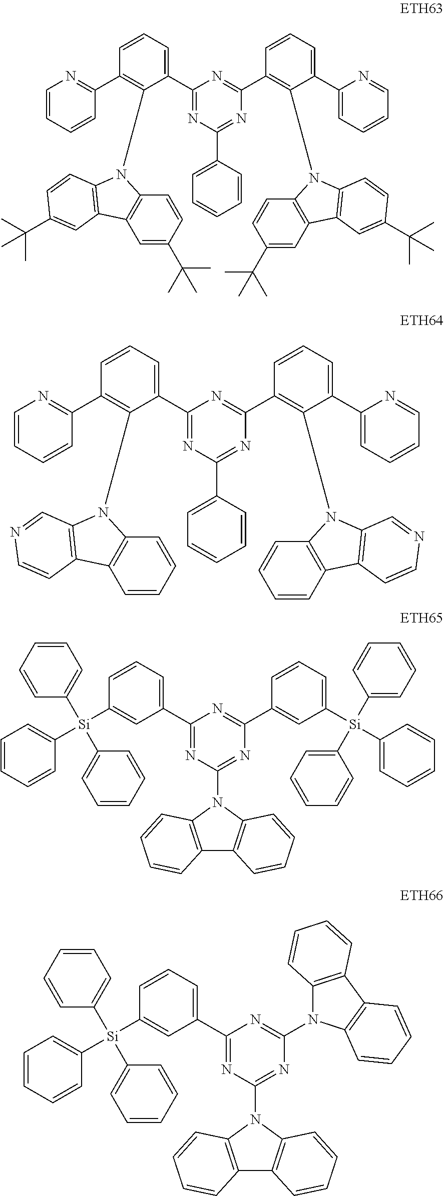 [SMILES: CC(C)(C)c1ccc2c(c1)c1cc(C(C)(C)C)ccc1n2-c1c(-c2ccccn2)cccc1-c1nc(-c2ccccc2)nc(-c2cccc(-c3ccccn3)c2-n2c3ccc(C(C)(C)C)cc3c3cc(C(C)(C)C)ccc32)n1 ; c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

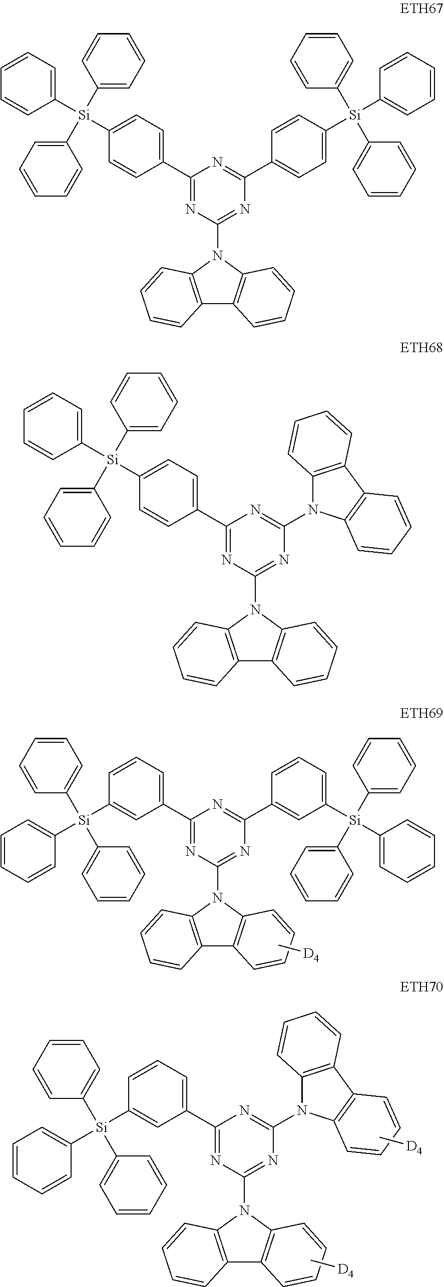

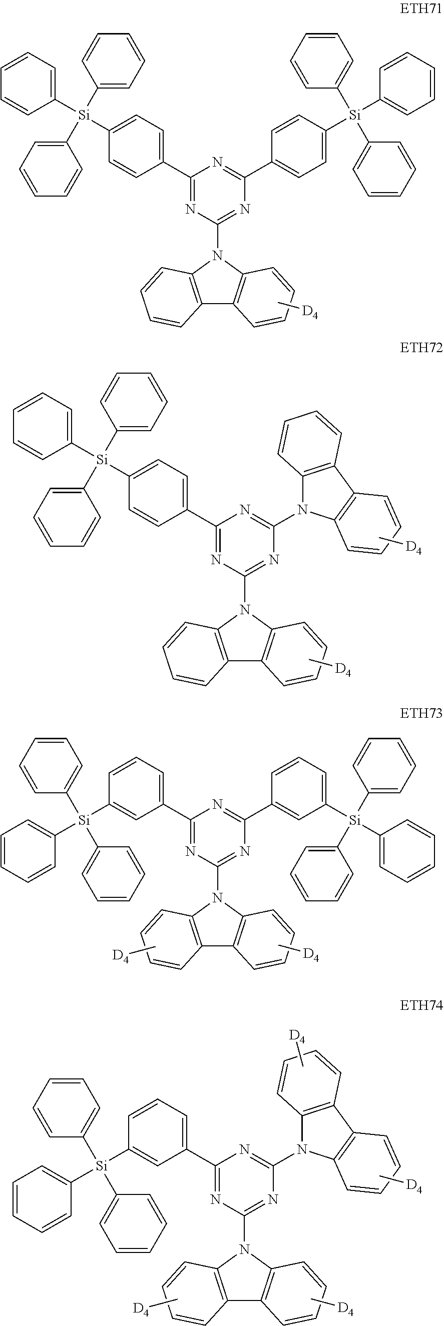

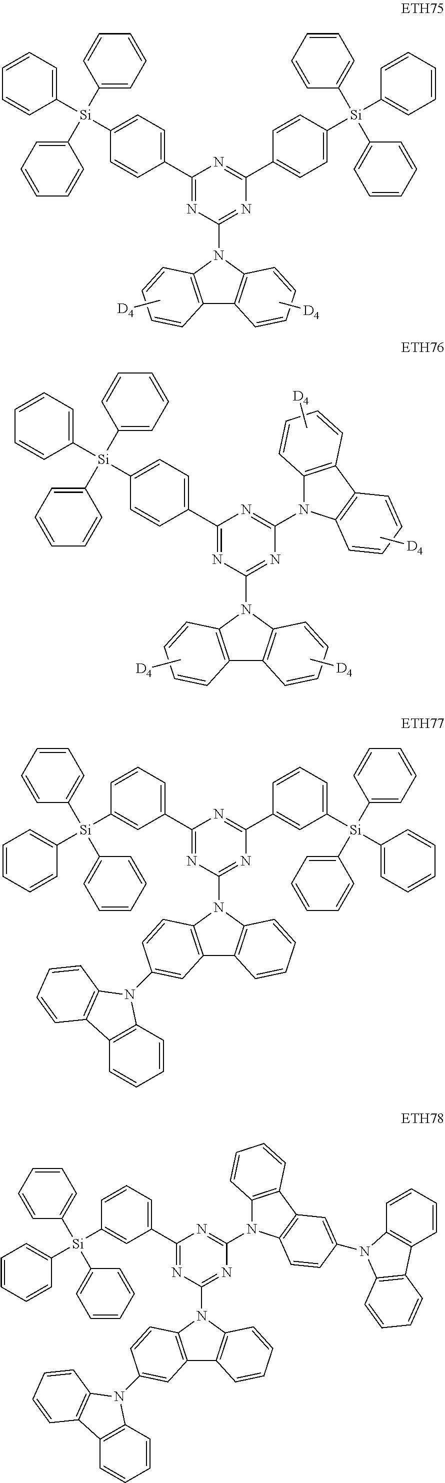

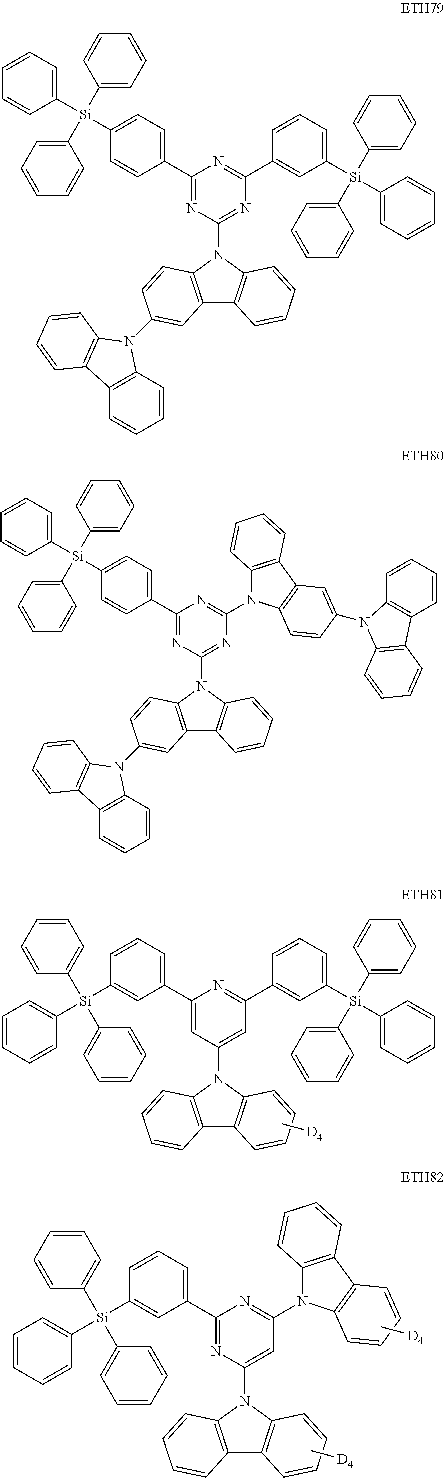

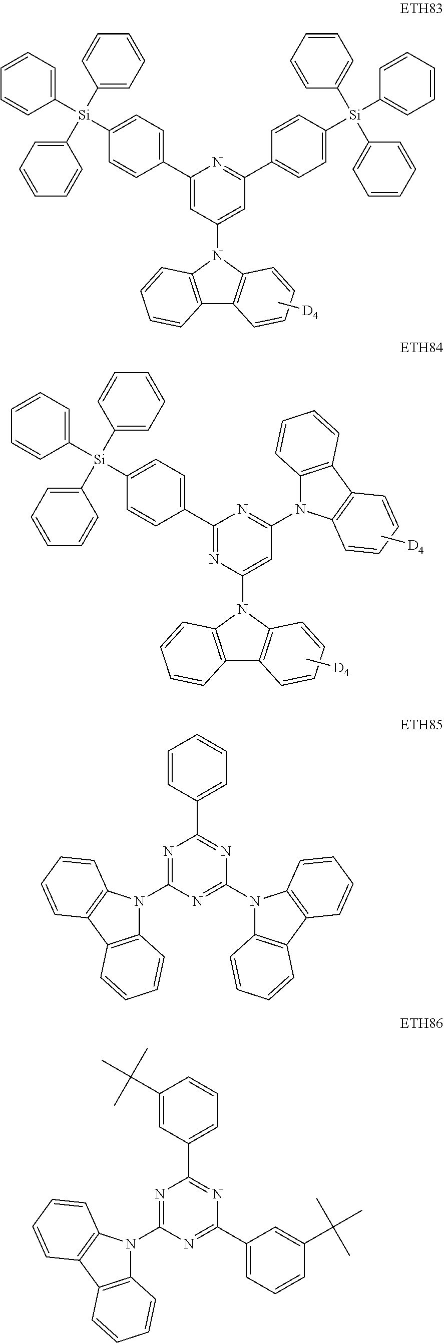

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

An absolute value of a triplet energy level (T1) of the exciplex formed by the hole transporting host and the electron transporting host may be in a range of about 2.4 eV to about 3.0 eV. The triplet energy level of the exciplex may be a value that is less than an energy gap of each host material. The exciplex may have a triplet energy level equal to or less than about 3.0 eV that is an energy gap between the hole transporting host and the electron transporting host.

In an embodiment, the emission layer EML may include a fourth compound represented by Formula M-b. For example, the fourth compound may be used as a phosphorescent sensitizer in the emission layer EML. Energy may be transferred from the fourth compound to the first compound, thereby emitting light.

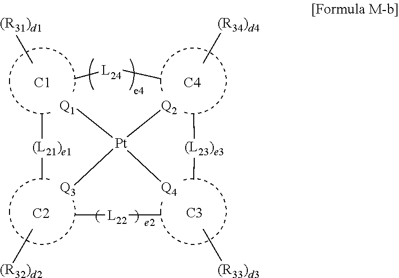

In Formula M-b, Q to Q may each independently be C or N; and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms.

In Formula M-b, e1 to e4 may each independently be 0 or 1; and L₂₁ to L₂₄ may each independently be a direct linkage,

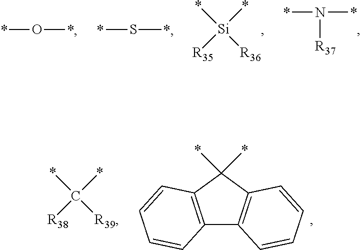

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In Formula M-b, d1 to d4 may each independently be an integer from 0 to 4. When d1 is 2 or more, multiple R₃₁ groups may be the same as each other or at least one thereof may be different from the others. When d2 is 2 or more, multiple R₃₂ groups may be the same as each other or at least one thereof may be different from the others. When d3 is an integer of 2 or more, multiple R₃₃ groups may be the same as each other or at least one thereof may be different from the others. When d4 is 2 or more, multiple R₃₄ groups may be the same as each other or at least one thereof may be different from the others.

In Formula M-b, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

The fourth compound may be any compound selected from Compound Group 4. The light emitting element ED may include any compound selected from Compound Group 4:

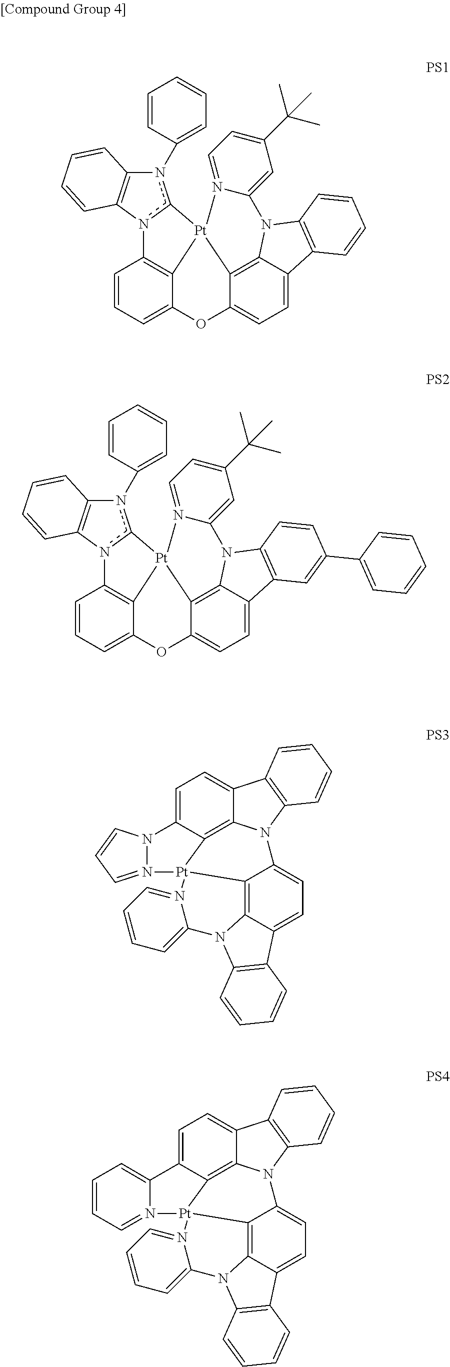

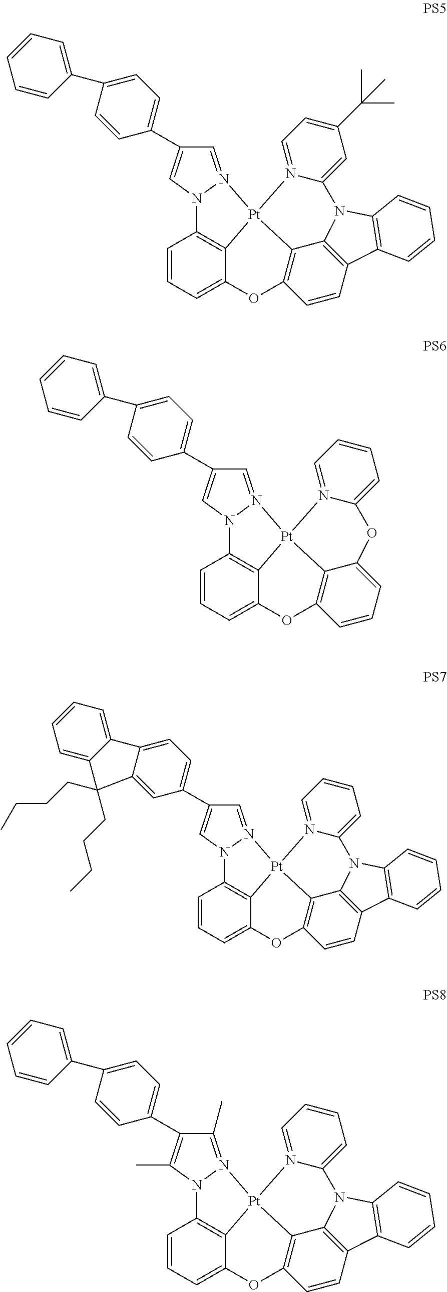

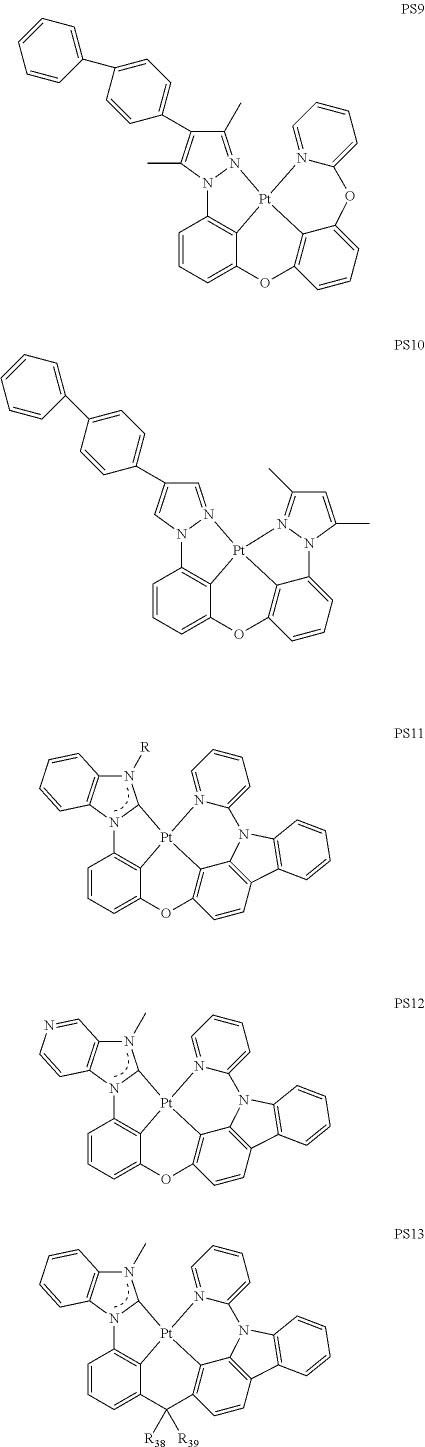

In Compound Group 4, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the emission layer EML may include: the first compound; and at least one of the second compound and the third compound; and may further include the fourth compound. For example, in an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. The fourth compound may serve as a phosphorescent sensitizer. The fourth compound may emit phosphorescence or may transfer energy to the first compound as an auxiliary dopant. However, embodiments are not limited thereto.

The emission layer EML may further include a material of the related art for the emission layer in addition to the first to fourth compounds presented above. In the light emitting element ED, the emission layer EML may further include an anthracene derivative, a pyrene derivative, a fluoranthene derivative, a chrysene derivative, a dihydrobenzanthracene derivative, a triphenylene derivative, or the like. For example, the emission layer EML may further include an anthracene derivative or a pyrene derivative.

In the light emitting element ED according to embodiments illustrated in FIGS. 3 to 6, the emission layer EML may include a compound represented by Formula E-1. The compound represented by Formula E-1 may be used as a fluorescent host material.

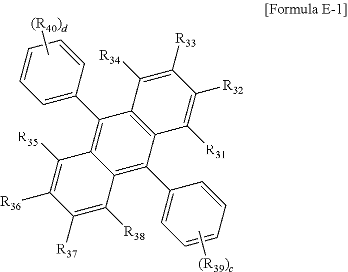

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

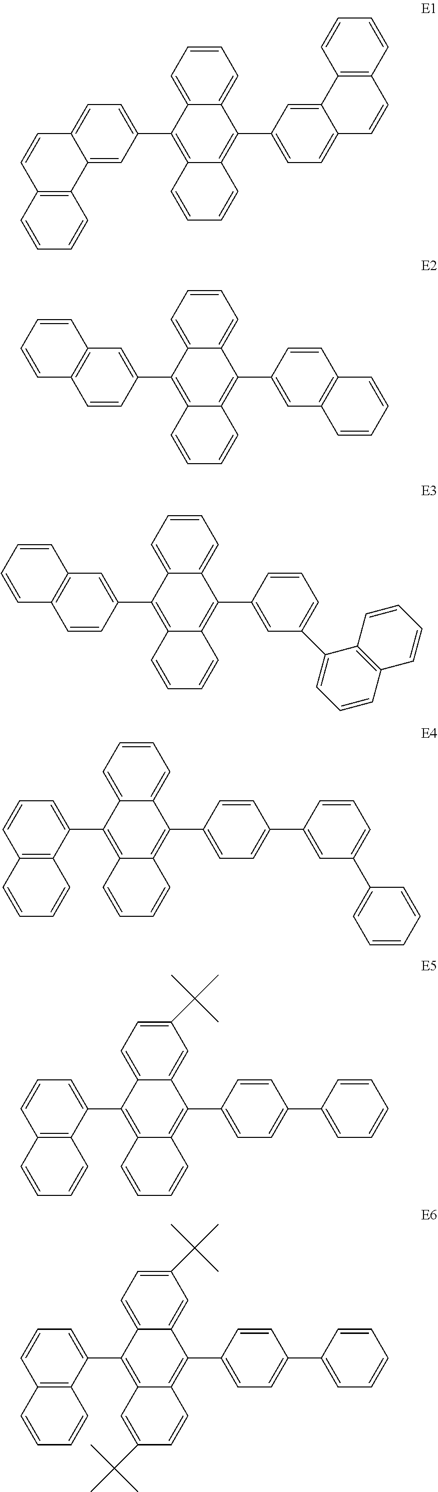

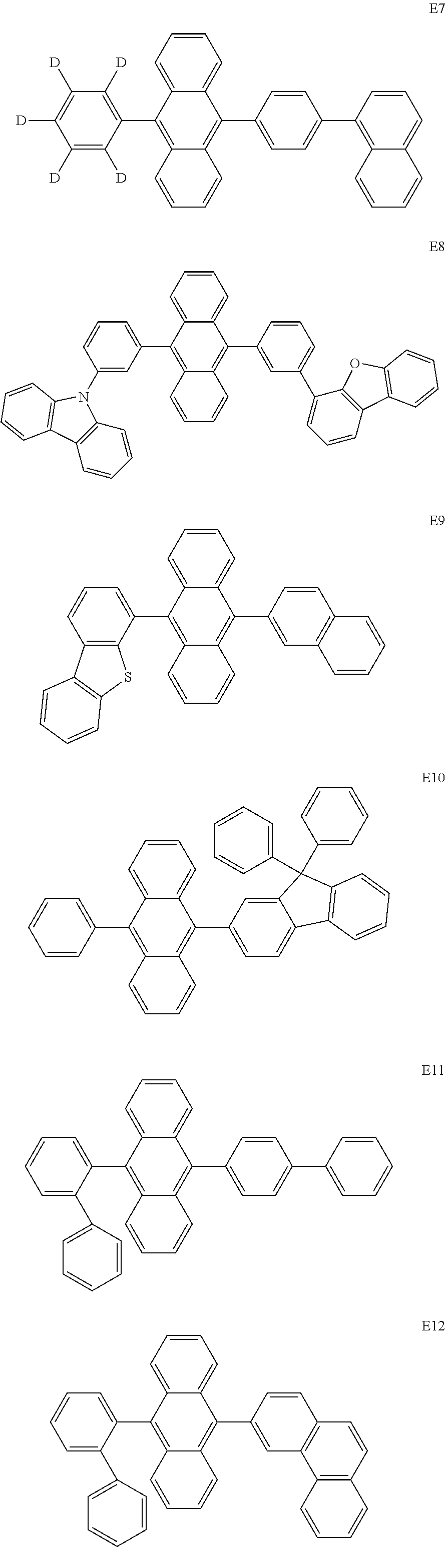

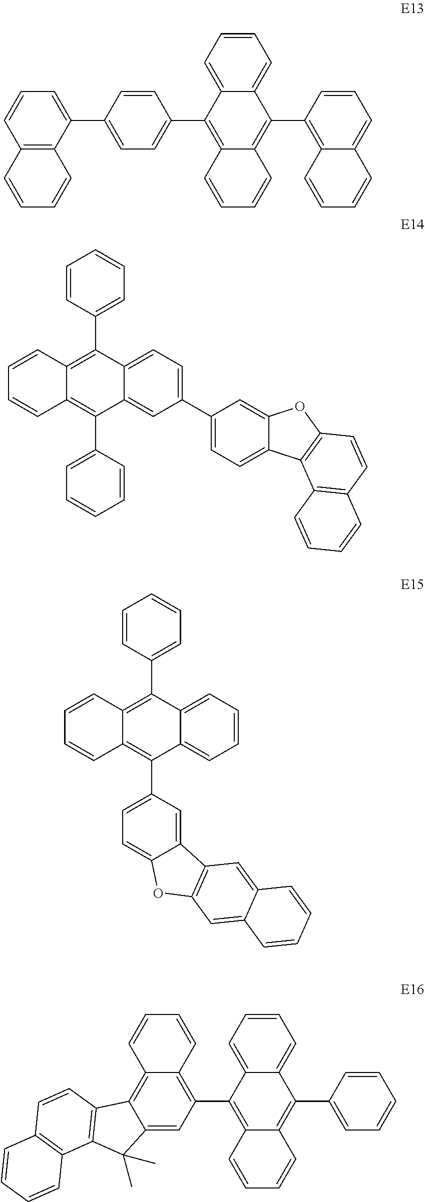

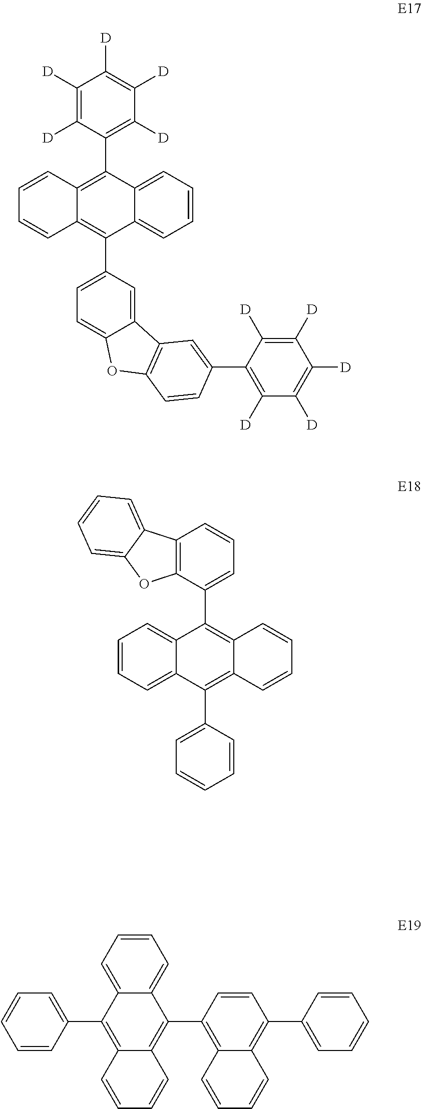

In an embodiment, the emission layer EML may include a compound represented by Formula E-2a or Formula E-2b. The compound represented by Formula E-2a or Formula E-2b may be used as a phosphorescent host material.

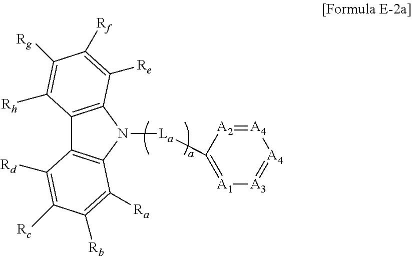

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or more, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

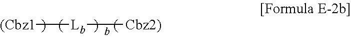

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

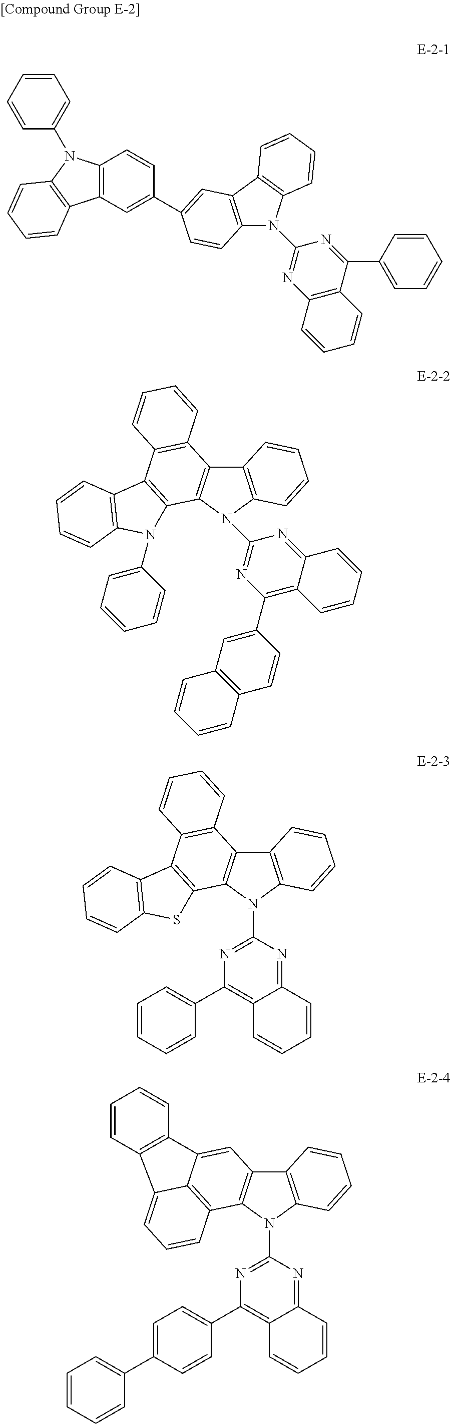

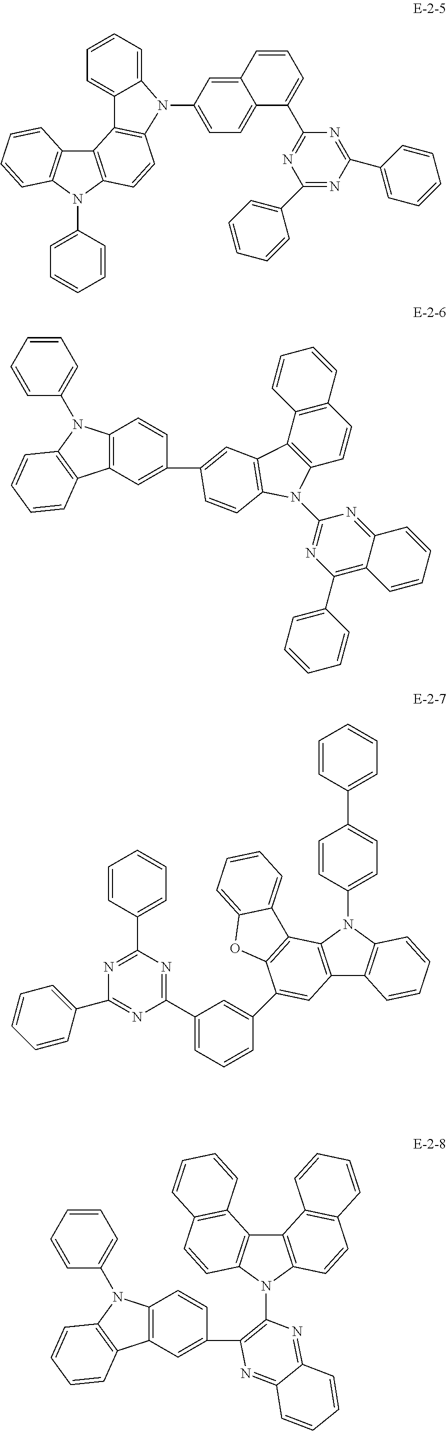 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3cc(-c4nc5ccccc5nc4-n4c5ccc6ccccc6c5c5c6ccccc6ccc54)ccc32)cc1]

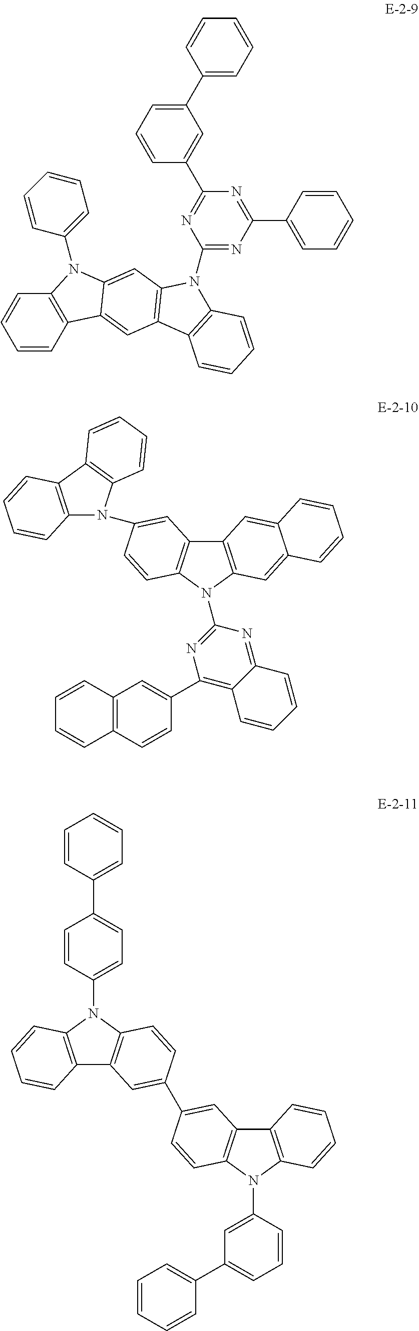 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

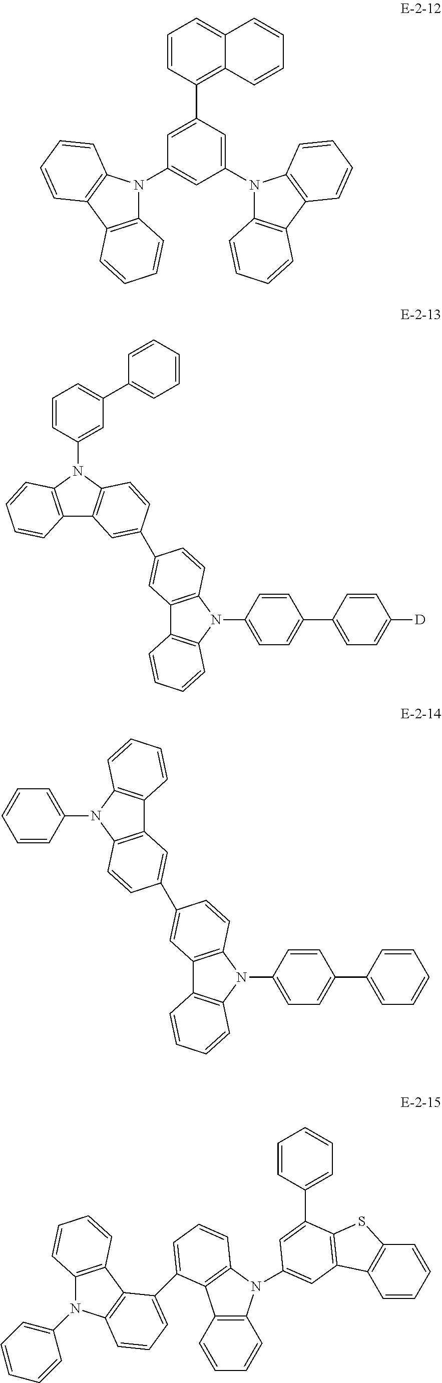 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

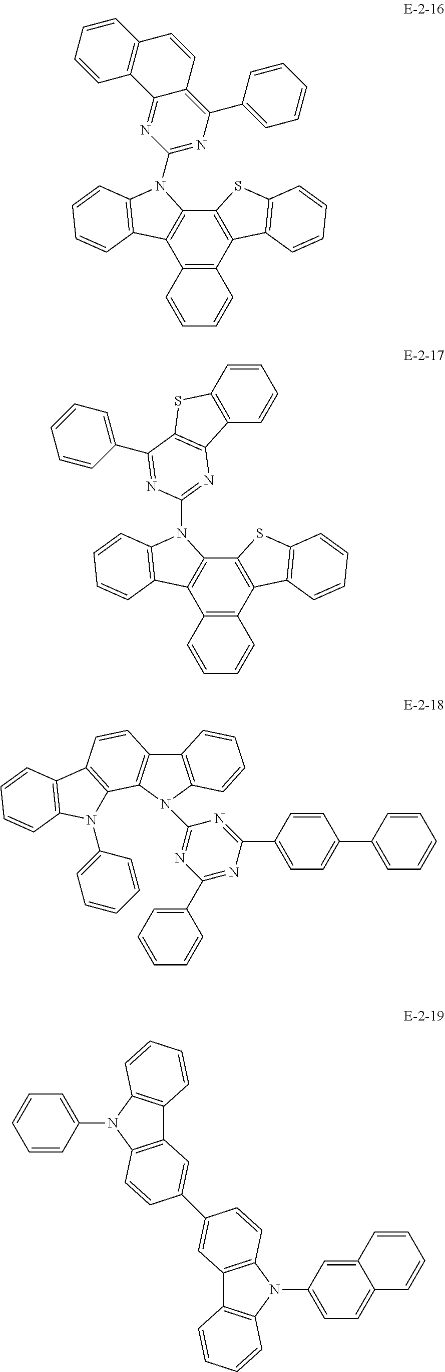

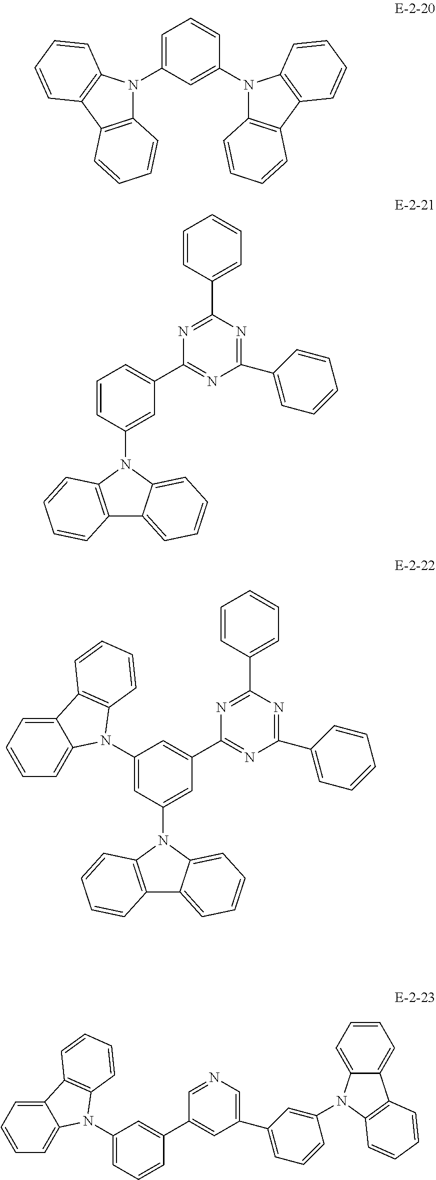

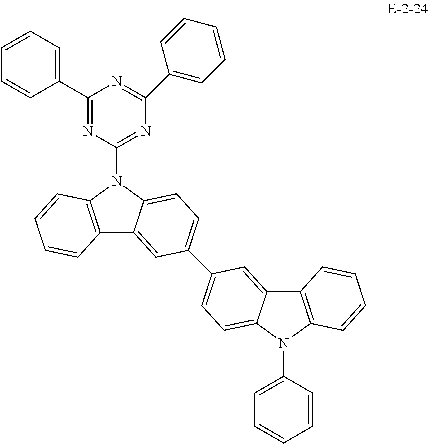 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include a compound represented by Formula M-a. In an embodiment, the compound represented by Formula M-a may be used as a phosphorescent dopant material. In another embodiment, the compound represented by Formula M-a may be used as an auxiliary dopant material.

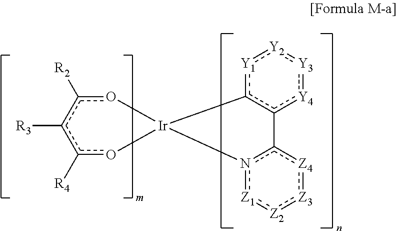

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

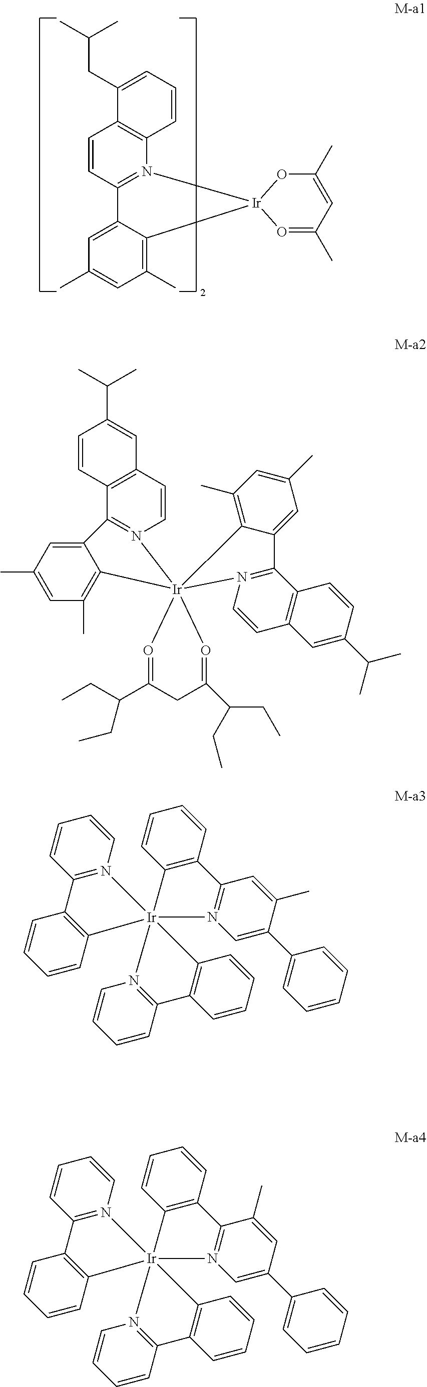

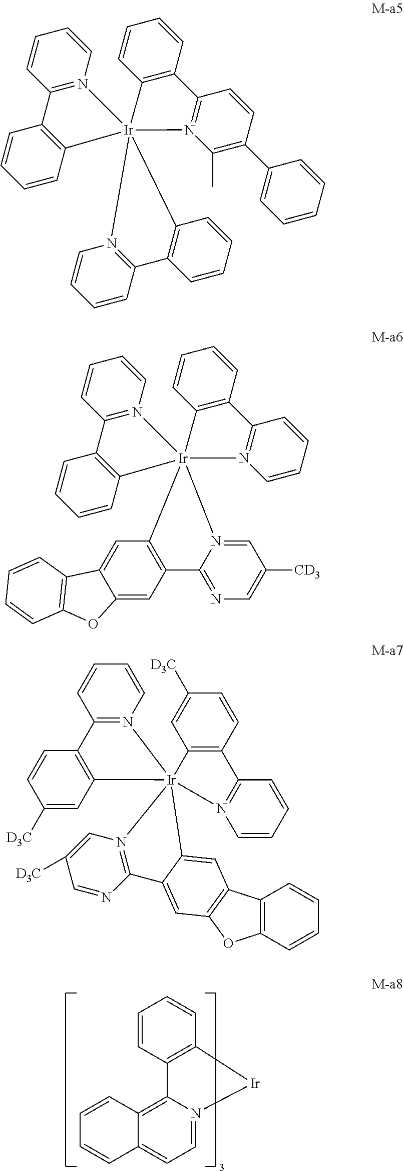

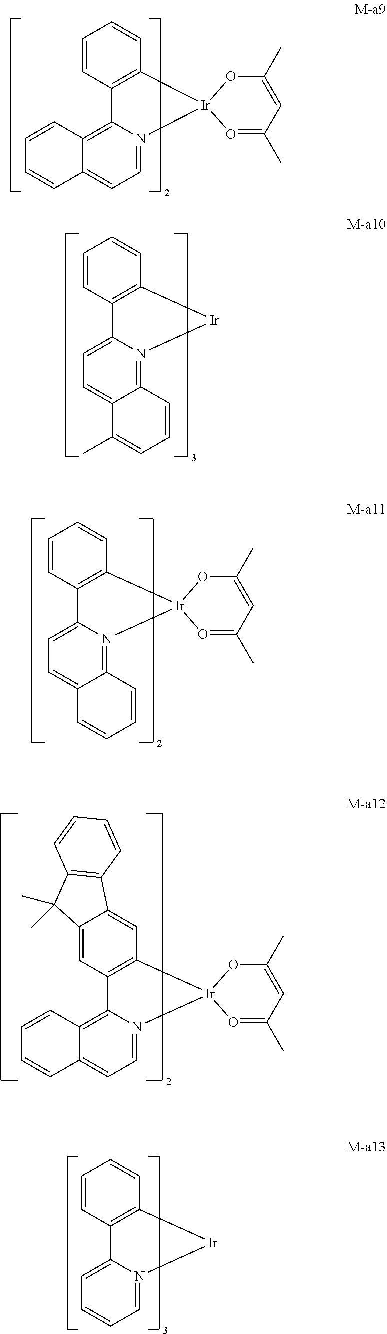

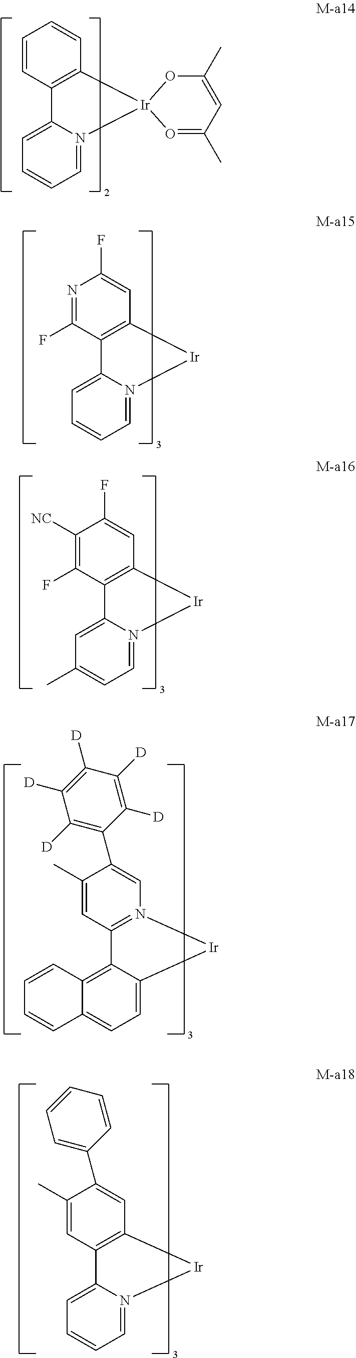

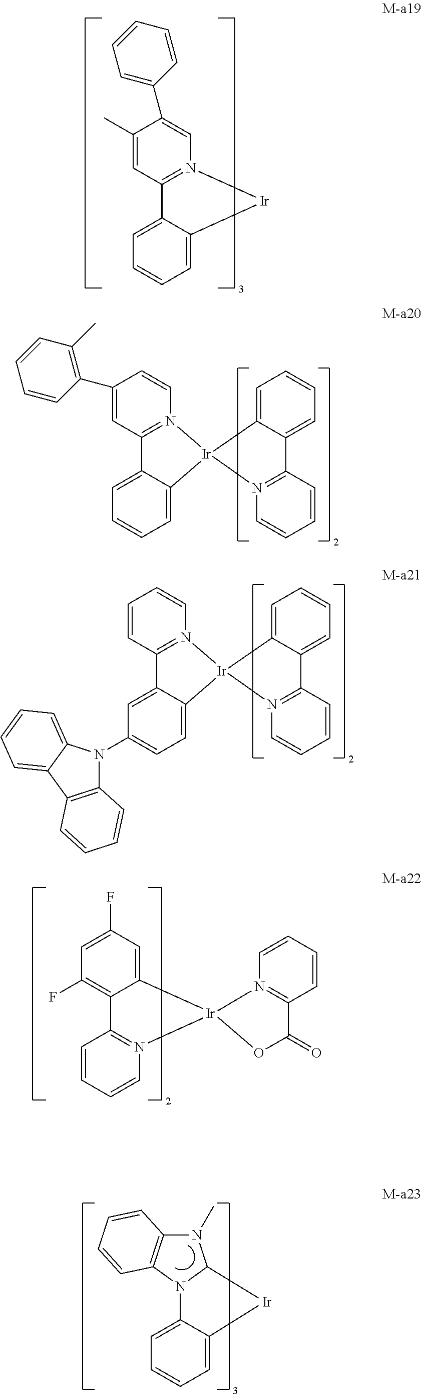

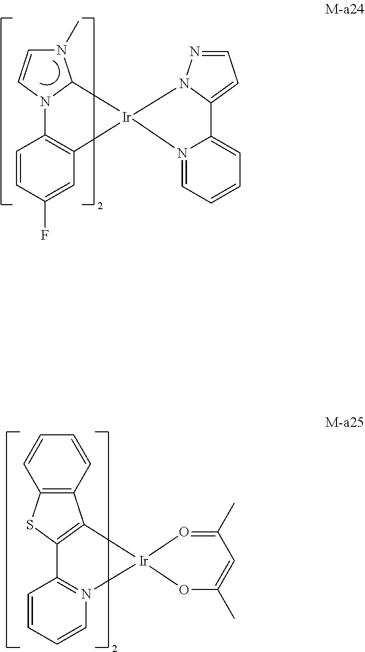

Compound M-a1 and Compound M-a2 may each be used as a red dopant material, and Compound M-a3 to Compound M-a7 may each be used as a green dopant material.

The emission layer EML may further include a compound represented by any one of Formula F-a to Formula F-c. The compound represented by one of Formula F-a to Formula F-c may be used as a fluorescence dopant material.

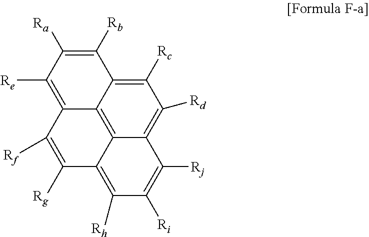

In Formula F-a, two of Rₐ to Rⱼ may each independently be substituted with a group represented by ·—NAr₁Ar₂. The remainder of Rₐ to Rⱼ which are not substituted with ·—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by ·—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

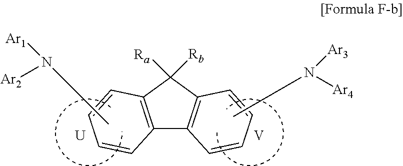

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When U and V are each O, a fused ring having a fluorene core of Formula F-b may be a cyclic compound having three rings. When U and V are each 1, a fused ring having a fluorene core of Formula F-b may be a cyclic compound having five rings.

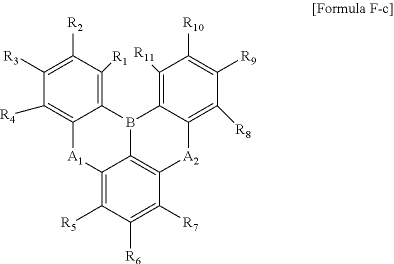

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to substituents of an adjacent ring to form a condensed ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

In an embodiment, when a light emitting element ED includes multiple emission layers EML, at least one emission layer EML may include a phosphorescence dopant material of the related art. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinato (FIrpic), bis(2,4-difluorophenylpyridinato)-tetrakis(1-pyrazolyl)borate iridium(III) (FIr6), or platinum octaethyl porphyrin (PtOEP) may be used as a phosphorescent dopant. However, embodiments are not limited thereto.

In an embodiment, at least one emission layer EML may include a quantum dot. The quantum dot may be a Group II-VI compound, a Group III-VI compound, a Group I-III-VI compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and any mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any mixture thereof, a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and any mixture thereof, or any combination thereof.

The Group III-VI compound may include: a binary compound such as In₂S₃ or In₂Se₃; a ternary compound such as InGaS₃ or InGaSe₃; or any combination thereof.

The Group 1-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and any mixture thereof, a quaternary compound such as AgInGaS₂ or CuInGaS₂; or any combination thereof.

The Group III-V compound may include: a binary compound selected from the group consisting of GaN, GaP, GaAs, GaSb, AlN, AlP, AlAs, AlSb, InN, InP, InAs, InSb, and any mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and any mixture thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any mixture thereof, or any combination thereof. In an embodiment, the Group III-V compound may further include a Group II metal. For example, InZnP, etc., may be selected as a Group III-II-V compound.

The Group IV-VI compound may include: a binary compound selected from the group consisting of SnS, SnSe, SnTe, PbS, PbSe, PbTe, and any mixture thereof, a ternary compound selected from the group consisting of SnSeS, SnSeTe, SnSTe, PbSeS, PbSeTe, PbSTe, SnPbS, SnPbSe, SnPbTe, and any mixture thereof, a quaternary compound selected from the group consisting of SnPbSSe, SnPbSeTe, SnPbSTe, and any mixture thereof, or any combination thereof. The Group IV element may be Si, Ge, or any mixture thereof. The Group IV compound may include a binary compound selected from the group consisting of SiC, SiGe, and any mixture thereof.

A binary compound, a ternary compound, or a quaternary compound may be present in a particle at a uniform concentration distribution, or may be present in a particle at a partially different concentration distribution. In an embodiment, a quantum dot may have a core/shell structure in which one quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or may serve as a charging layer to impart electrophoresis properties to the quantum dot. The shell may be a single layer or a multilayer.

Examples of the shell of the quantum dot may include a metal oxide, a non-metal oxide, a semiconductor compound, or any combination thereof.

Examples of metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, and NiO; a ternary compound such as MgAl₂O₄, CoFe₂O₄, NiFe₂O₄, and CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in the above ranges. Light emitted through a quantum dot may be emitted in all directions, so that a wide viewing angle may be improved.

The form of a quantum dot may be any form that is used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoplate, etc.

The quantum dot may control the color of emitted light according to a particle size thereof. Accordingly, the quantum dot may have various light emission colors such as blue, red, and green.

In the light emitting element ED according to an embodiment illustrated in each of FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure including different materials, or may have a structure in which an electron transport layer ETL/electron injection layer EIL, a hole blocking layer HBL/electron transport layer ETL/electron injection layer EIL, an electron transport layer ETL/buffer layer (not shown)/electron injection layer EIL are stacked in its respective stated order from an emission layer EML, but embodiments are not limited thereto. The electron transport region ETR may have a thickness, for example, in a range of about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2:

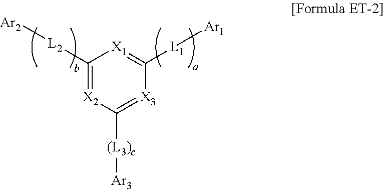

In Formula ET-2, at least one of X₁ to X₃ may each be N; and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or any mixture thereof.

In an embodiment, the electron transport region ETR may include at least one compound selected from Compound ET1 to Compound ET36:

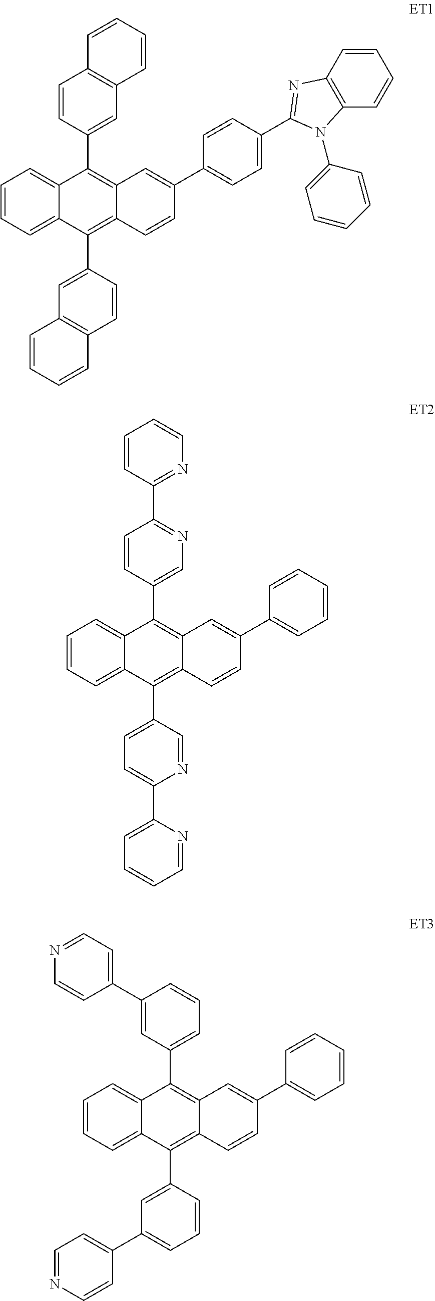 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

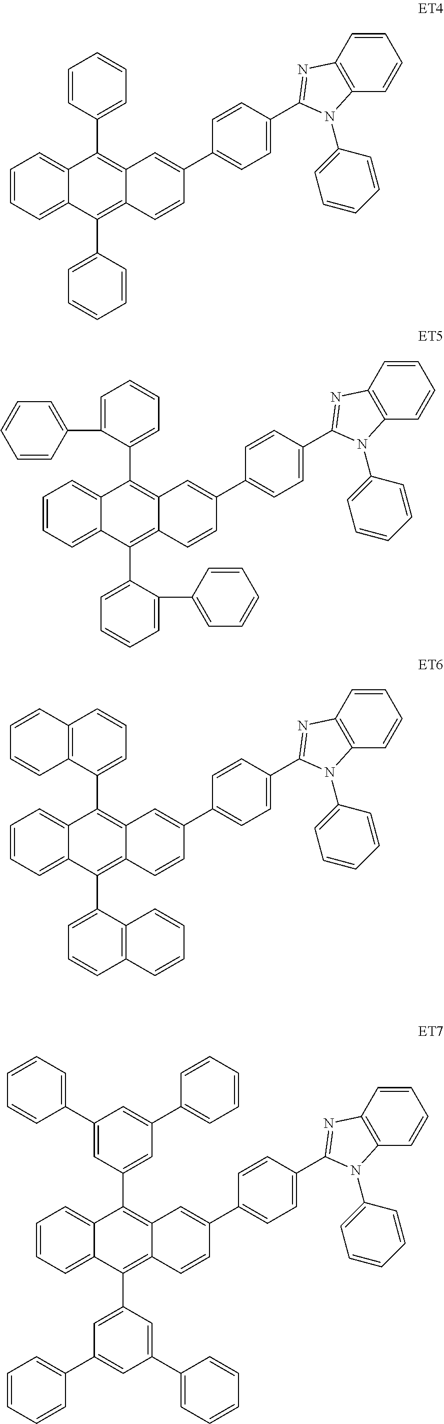 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

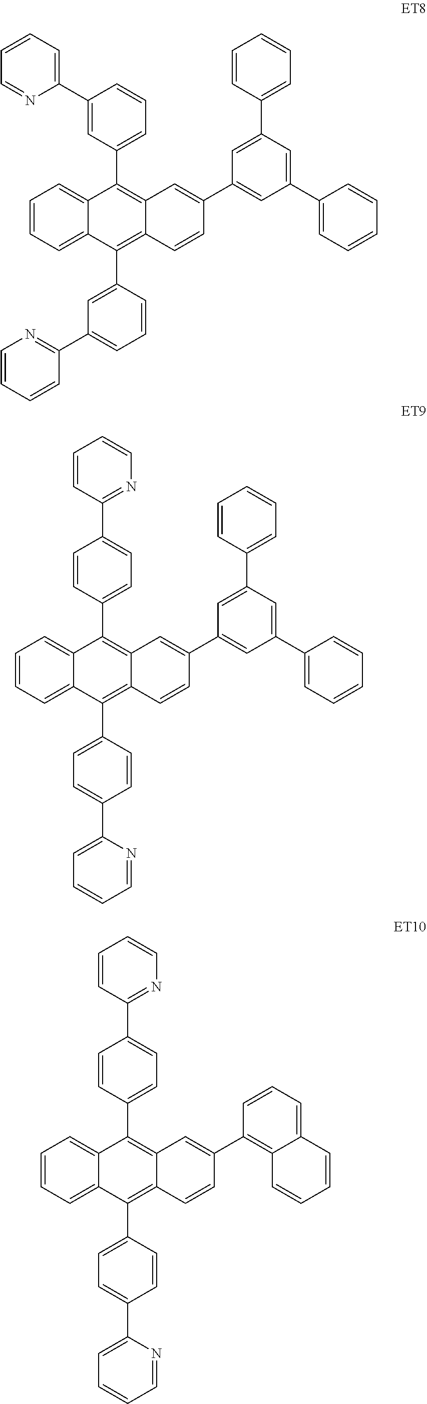

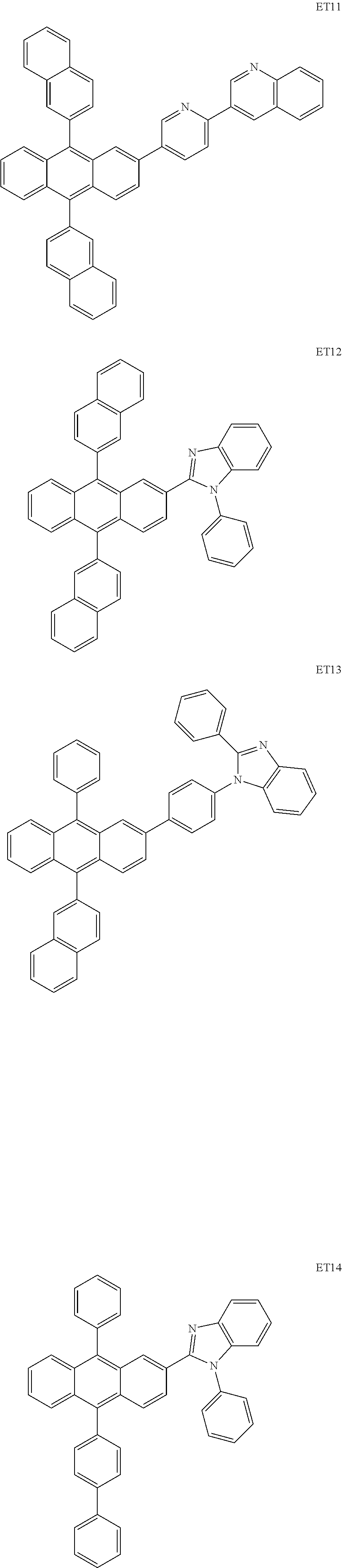 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1]

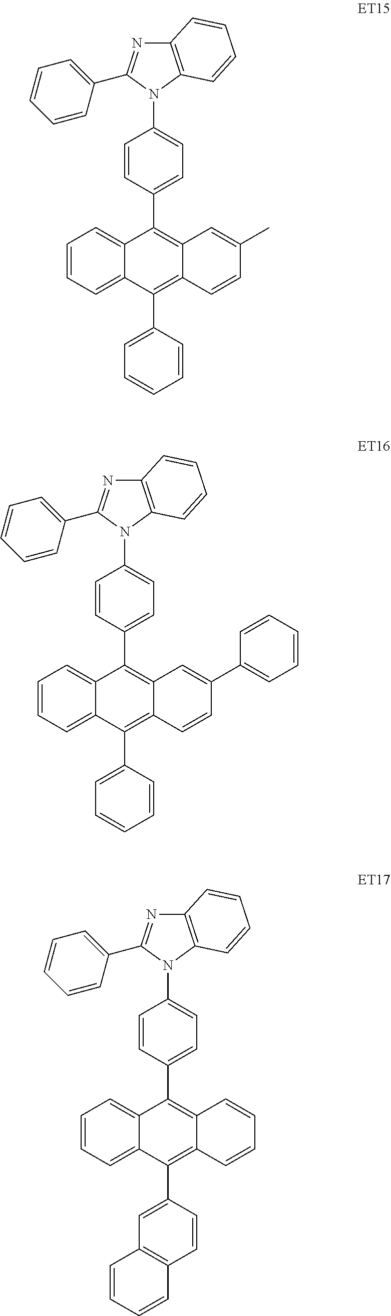 [SMILES: Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1]

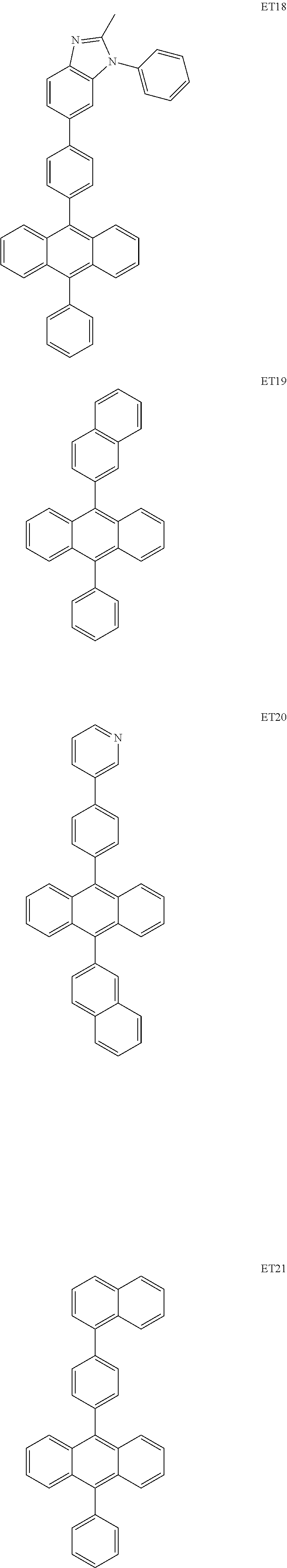

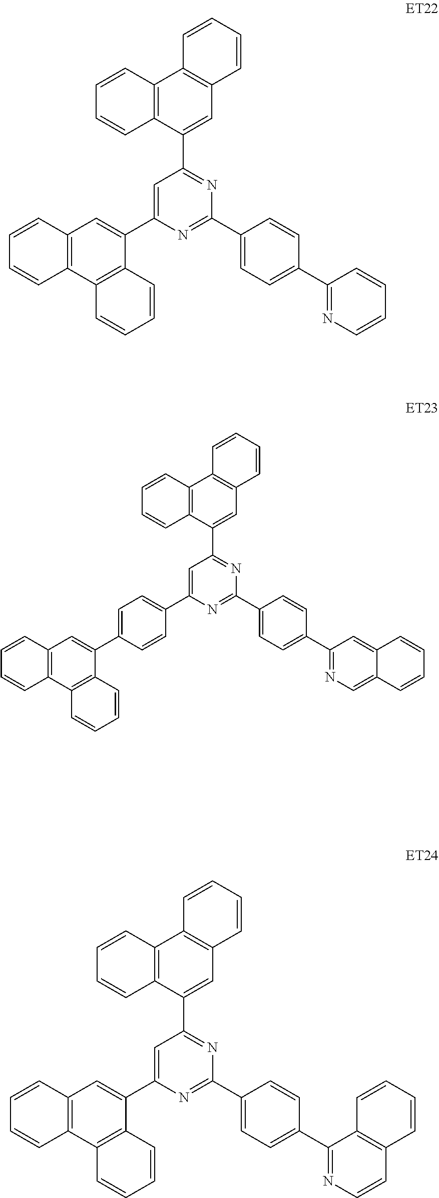 [SMILES: c1ccc(-c2ccc(-c3nc(-c4cc5ccccc5c5ccccc45)cc(-c4cc5ccccc5c5ccccc45)n3)cc2)nc1 ; c1ccc2cc(-c3ccc(-c4nc(-c5ccc(-c6cc7ccccc7c7ccccc67)cc5)cc(-c5cc6ccccc6c6ccccc56)n4)cc3)ncc2c1 ; c1ccc2c(-c3ccc(-c4nc(-c5cc6ccccc6c6ccccc56)cc(-c5cc6ccccc6c6ccccc56)n4)cc3)nccc2c1]

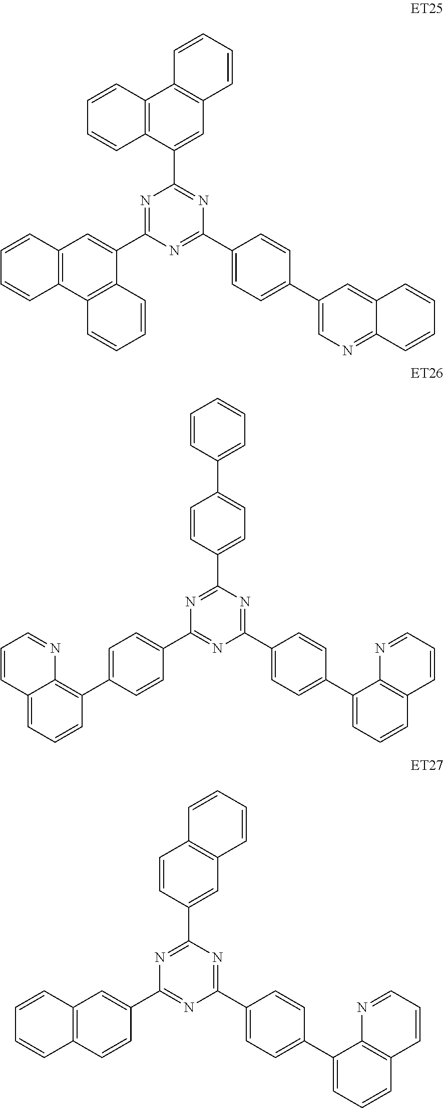 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

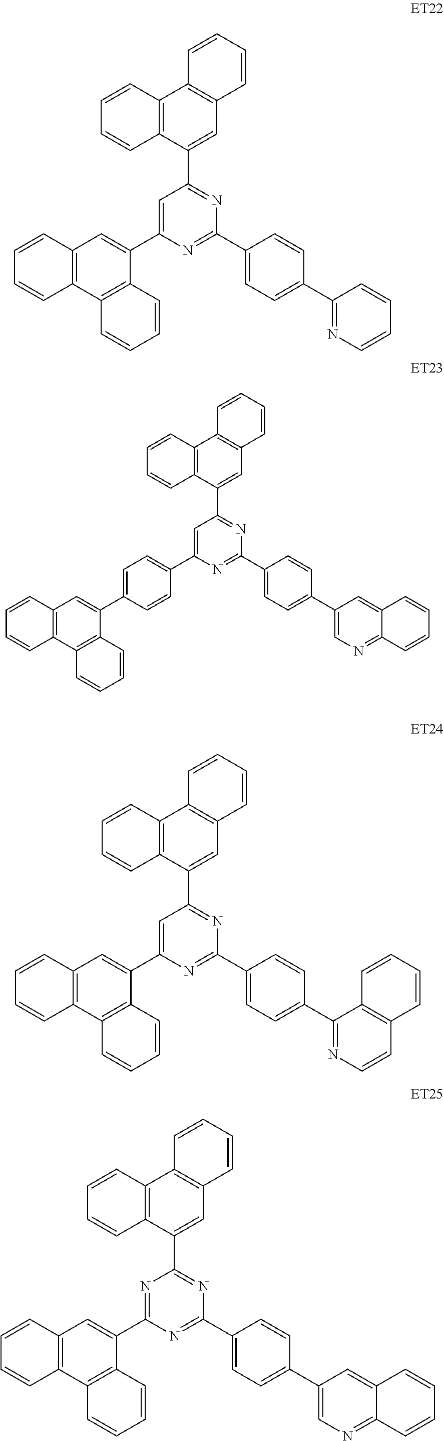 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

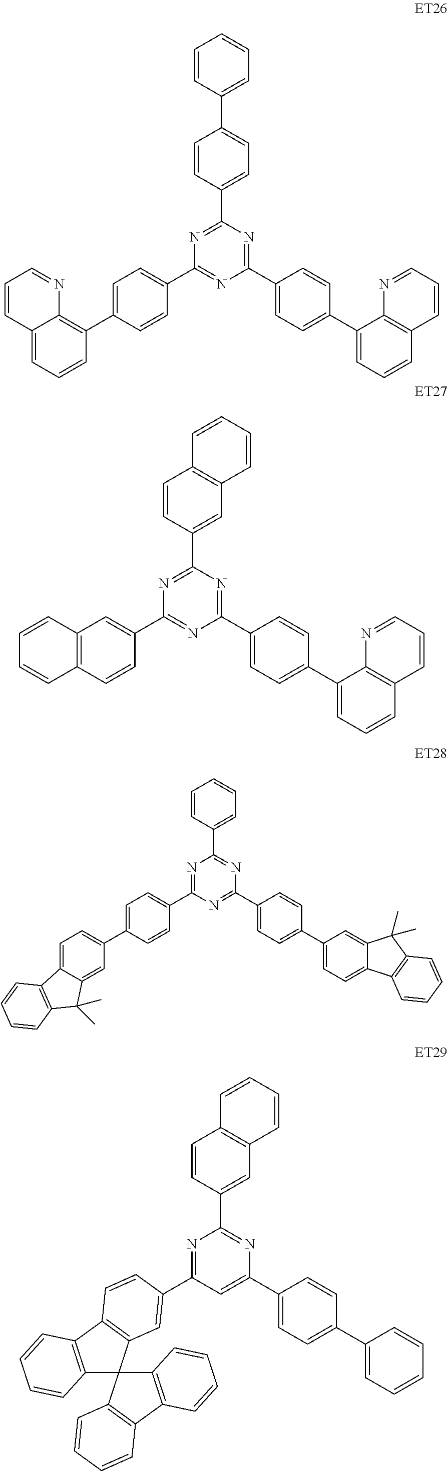 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

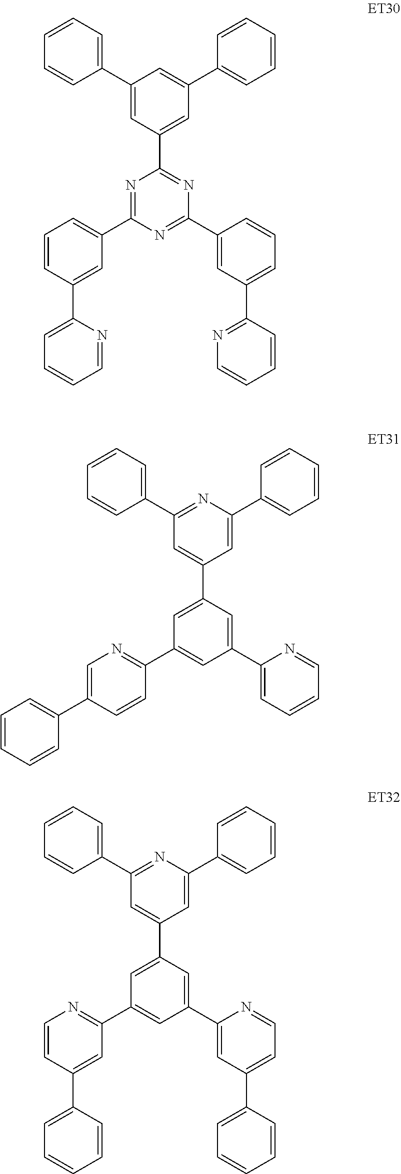 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

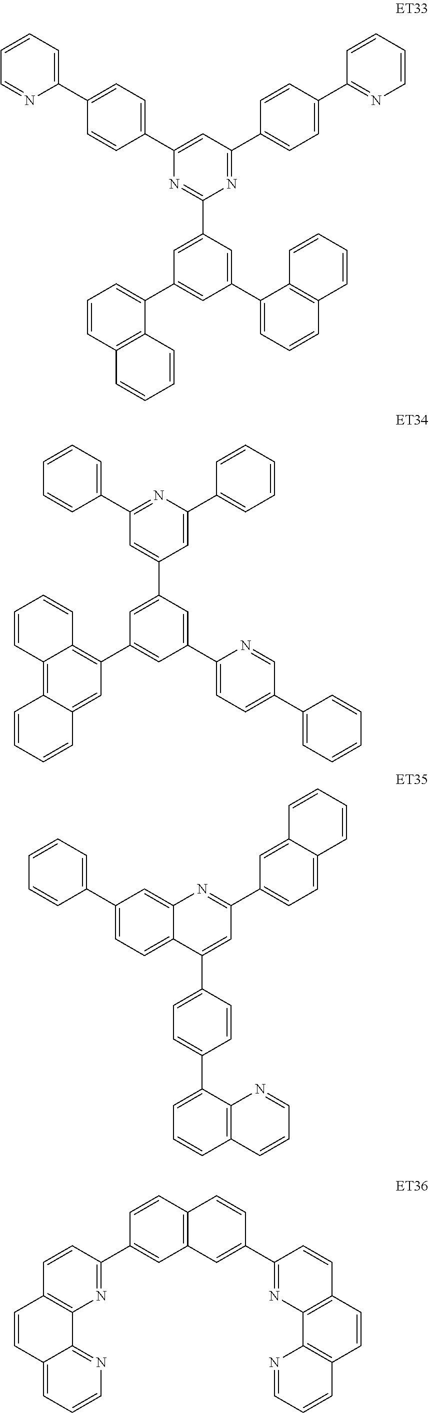

The electron transport regions ETR may include: a metal halide such as LiF, NaCl, CsF, RbCl, RbI, CuI, or KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may be formed of a metal oxide such as Li₂O or BaO, or 8-hydroxyl-lithium quinolate (Lig), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the electron transport region ETR in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, a compound thereof, or a mixture thereof (e.g., AgMg, AgYb, or MgYb). In another embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or an epoxy resin, or an acrylate such as methacrylate. However, embodiments are not limited thereto. In an embodiment, the capping layer CPL may include at least one of Compounds P1 to P5:

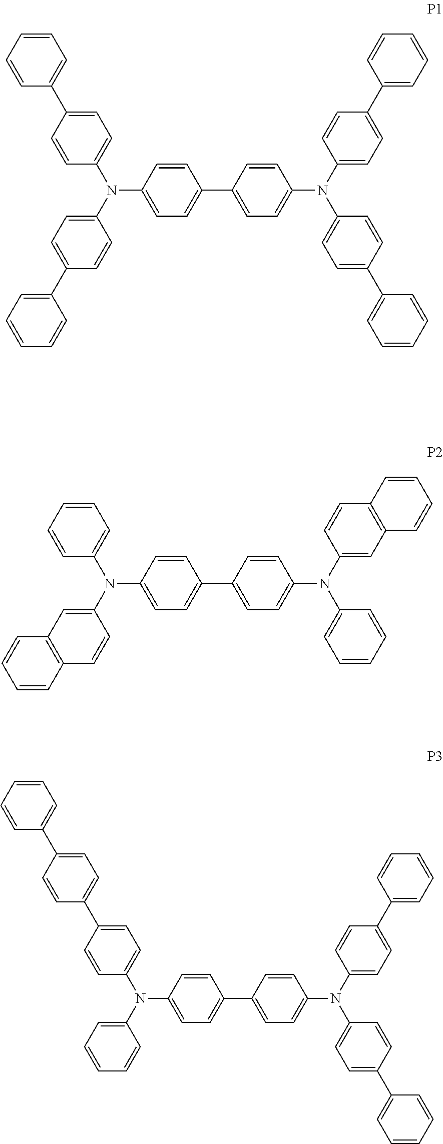 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

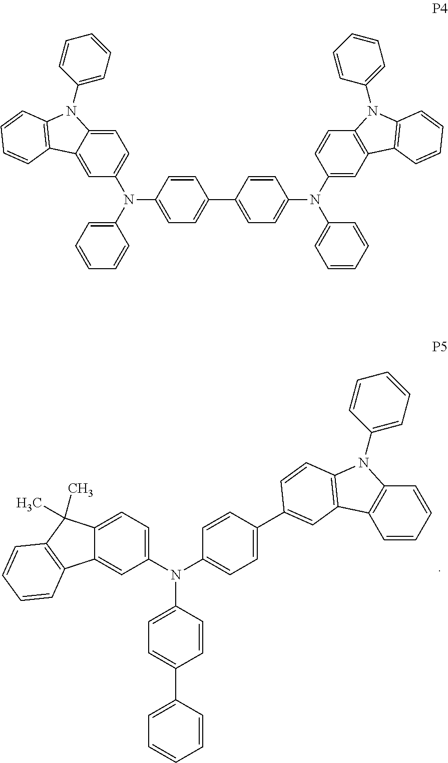 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, a refractive index of the capping layer CPL may be equal to or greater than about 1.6 with respect to light in a wavelength range of about 550 nm to about 660 nm.

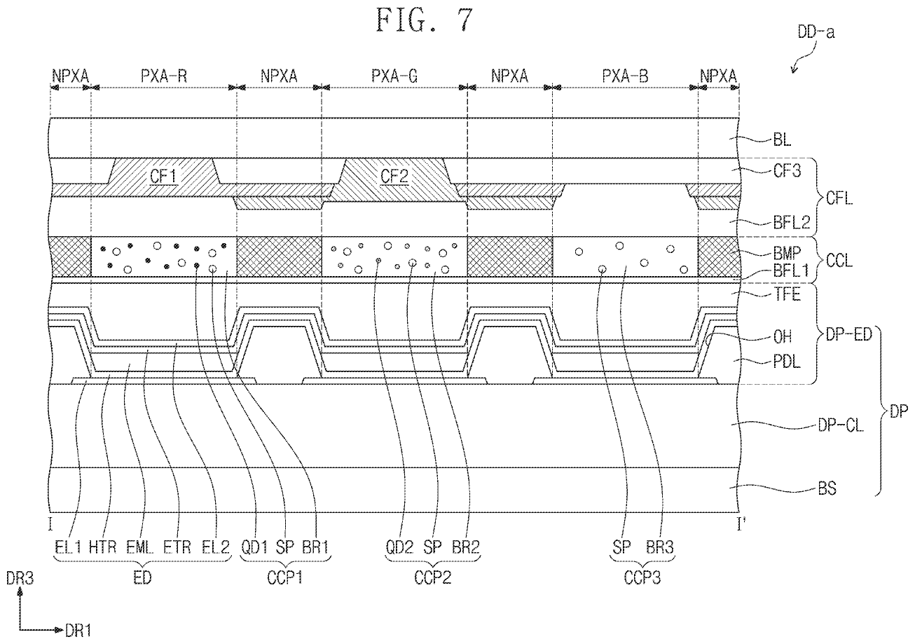

FIG. 7 to FIG. 10 are each a schematic cross-sectional view of a display device according to embodiments. In the explanation on the display devices according to embodiments with reference to FIGS. 7 to 10, the features which have been described above with respect to FIGS. 1 to 6 will not be explained again, and the differing features will be described.

Referring to FIG. 7, a display device DD-a according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element according to one of FIGS. 3 to 6 as described herein.

In the display device DD-a, the emission layer EML of the light emitting element ED may include the polycyclic compound as described herein.

Referring to FIG. 7, the emission layer EML may be disposed in an opening OH defined in a pixel defining film PDL. For example, the emission layer EML, which is separated by the pixel defining film PDL and provided corresponding to each of the light emitting regions PXA-R, PXA-G, and PXA-B, may each emit light in a same wavelength range.

In the display device DD-a, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3 which are spaced apart from each other, but embodiments are not limited thereto. In FIG. 7, it is shown that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 which transmits the first color light.

In an embodiment, the first light control part CCP1 may provide red light, which may be the second color light, and the second light control part CCP2 may provide green light, which may be the third color light. The third light control part CCP3 may provide blue light by transmitting a blue light which may be the first color light provided from the light emitting element ED. For example, the first quantum dot QD1 may be a red quantum dot, and the second quantum dot QD2 may be a green quantum dot. The quantum dots QD1 and QD2 may each be a quantum dot same as described herein.

The light control layer CCL may further include a scatterer SP. The first light control part CCP1 may include the first quantum dot QD1 and a scatterer SP, the second light control part CCP2 may include the second quantum dot QD2 and a scatterer SP, and the third light control part CCP3 may not include any quantum dot but may include a scatterer SP.

The scatterer SP may be inorganic particles. For example, the scatterer SP may include at least one of TiO₂, ZnO, Al₂O₃, SiO₂, or hollow silica. The scatterer SP may include any one a TiO₂, ZnO, Al₂O₃, SiO₂, and hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and filters CF1, CF2, and CF3, which will be explained below.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin film which secures a transmittance, etc. The barrier layers BFL1 and BFL2 may each independently further include an organic film. The barrier layers BFL1 and BFL2 may each independently be formed of a single layer or of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter. The first to third filters CF1, CF2, and CF3 may be disposed to respectively correspond to the red light emitting region PXA-R, the green light emitting region PXA-G, and the blue light emitting region PXA-B.

Although not shown in the drawings, the color filter layer CFL may include a light shielding part (not shown). The color filter layer CFL may include a light shielding part (not shown) that is disposed to overlap the boundaries between neighboring filters CF1, CF2, and CF3. The light shielding part (not shown) may be a black matrix. The light shielding part (not shown) may include an organic light shielding material or an inorganic light shielding material that includes a black pigment or a black dye. The light shielding part (not shown) may separate boundaries between adjacent filters CF1, CF2, and CF3. In an embodiment, the light shielding part (not shown) may be formed of a blue filter.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

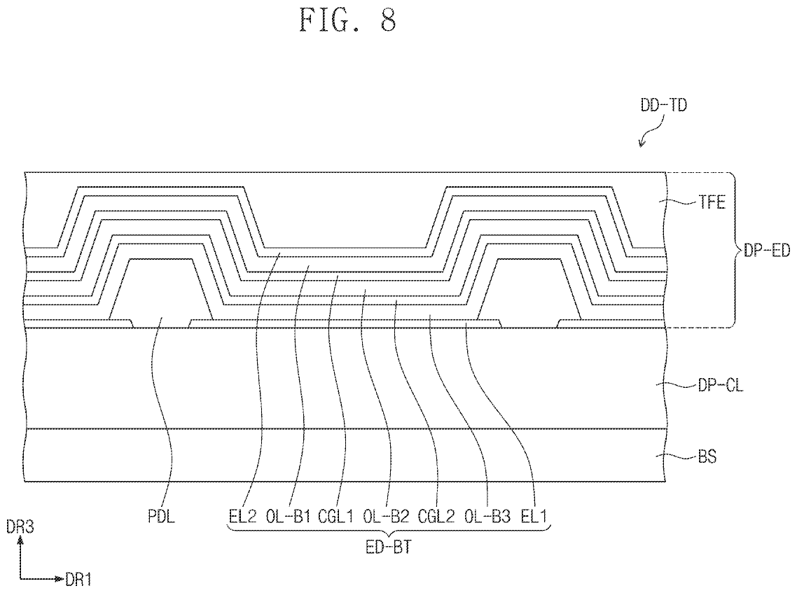

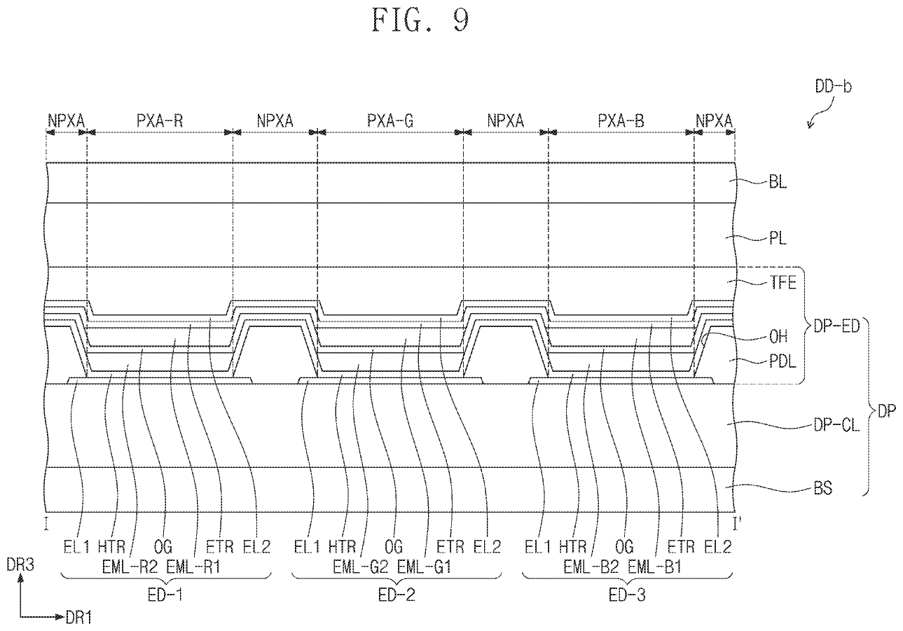

FIG. 8 is a schematic cross-sectional view illustrating a portion of a display device DD-a according to an embodiment. FIG. 8 illustrates a schematic cross-sectional view of a portion corresponding to the display panel DP of FIG. 7. In the display device DD-TD according to an embodiment, the light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. At least one of the light emitting structures OL-B1, OL-B2, and OL-B3 may include the polycyclic compound as described herein. The light emitting structures OL-B1, OL-B2, and OL-B3 may each include an emission layer EML (FIG. 7) and a hole transport region HTR (FIG. 7) and an electron transport region ETR (FIG. 7) disposed with the emission layer EML (FIG. 7) therebetween.

For example, the light emitting element ED-BT included in the display device DD-TD may be a light emitting element having a tandem structure and including multiple emission layers EML.

In an embodiment illustrated in FIG. 8, light emitted from each of the light emitting structures OL-B1, OL-B2, and OL-B3 may all be blue light. However, embodiments are not limited thereto, and the light respectively emitted from the light emitting structures OL-B1, OL-B2, and OL-B3 may have wavelength ranges that are different from each other. For example, the light emitting element ED-BT, which includes the light emitting structures OL-B1, OL-B2, and OL-B3 that emit light having different wavelength ranges from each other, may emit white light.

Charge generation layers CGL1 and CGL2 may be disposed between neighboring light emitting structures OL-B1, OL-B2, and OL-B3. Charge generation layers CGL1 and CGL2 may each independently include a p-type charge generation layer and/or an n-type charge generation layer.

In an embodiment, at least one of the light emitting structures OL-B1, OL-B2, and OL-B3 included in the display device DD-TD may include the polycyclic compound as described herein. For example, at least one of the emission layers included in the light emitting element ED-BT may include the polycyclic compound.

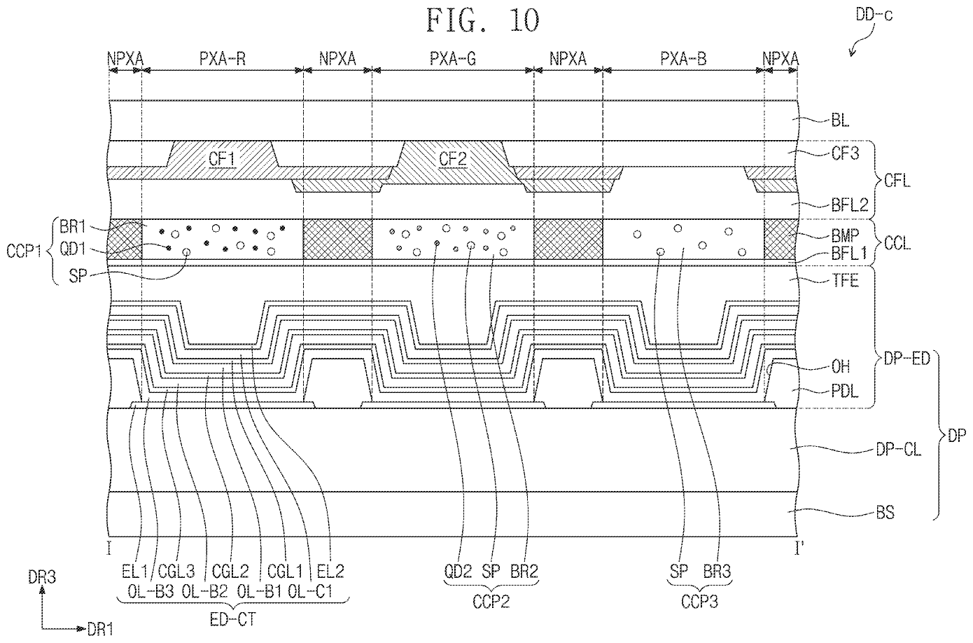

Referring to FIG. 9, a display device DD-b according to an embodiment may include light emitting elements ED-1, ED-2, and ED-3, which may each include two emission layers that are stacked. In comparison to the display device DD illustrated in FIG. 2, the embodiment illustrated in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which are stacked in that order. The emission auxiliary part OG may be provided as a common layer for all of the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, are stacked in that order.

The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display device DD-b.

At least one emission layer included in the display device DD-b illustrated in FIG. 9 may include the polycyclic compound as described herein. For example, in an embodiment, at least one of the first blue emission layer EML-B1 or the second blue emission layer EML-B2 may include the polycyclic compound.

In contrast to FIGS. 8 and 9, FIG. 10 illustrates a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 which are disposed between adjacent light emitting structures OL-B1, OL-B2, OL-B3, and OL-C1 may each independently include a p-type charge generation layer and/or an n-type charge generation layer.

In the display device DD-c, at least one of the light emitting structures OL-B1, OL-B2, OL-B3, and OL-C1 may include the polycyclic compound as described herein. For example, in an embodiment, at least one of the first to third light emitting structures OL-B1, OL-B2, and OL-B3 may include the polycyclic compound as described herein.

The light emitting element ED according to an embodiment may include the polycyclic compound in at least one functional layer disposed between the first electrode EL1 and the second electrode EL2, thereby exhibiting excellent luminous efficiency and improved service life characteristics. For example, the polycyclic compound according to an embodiment may be included in the emission layer EML of the light emitting element ED, and the light emitting element ED may exhibit high efficiency and long service life characteristics.

The polycyclic compound may include a substituent that includes a carbazole derivative, dibenzothiophene derivative, or a dibenzofuran derivative, which is a bulky hetero substituent, and a core moiety of a fused ring containing a boron atom, and thus may have high stability. The polycyclic compound includes the core moiety of a fused ring containing a boron atom, and a nitrogen-containing heterocyclic group, thereby implementing both short range charge transfer and long range charge transfer phenomena, and thus may be used as a thermally activated delayed fluorescence dopant material, thereby increasing luminous efficiency.

Hereinafter, a polycyclic compound according to an embodiment and a light emitting element according to an embodiment will be described in detail with reference to the Examples and the Comparative Examples. The Examples described below are only provided as illustrations to assist in understanding the disclosure, and the scope thereof is not limited thereto.

### EXAMPLES

### 1. Synthesis of Polycyclic Compound

A synthesis method of a polycyclic compound according to an embodiment will be described in detail by illustrating a synthesis method for Compounds 8, 33, 49, 95, 111, and 121. The synthesis methods of the polycyclic compounds are provided as examples, but synthesis methods according to embodiments are not limited to the Examples below.

(1) Synthesis of Compound 8

Polycyclic Compound 8 according to an example may be synthesized by, for example, the steps shown in Reaction Scheme 1:

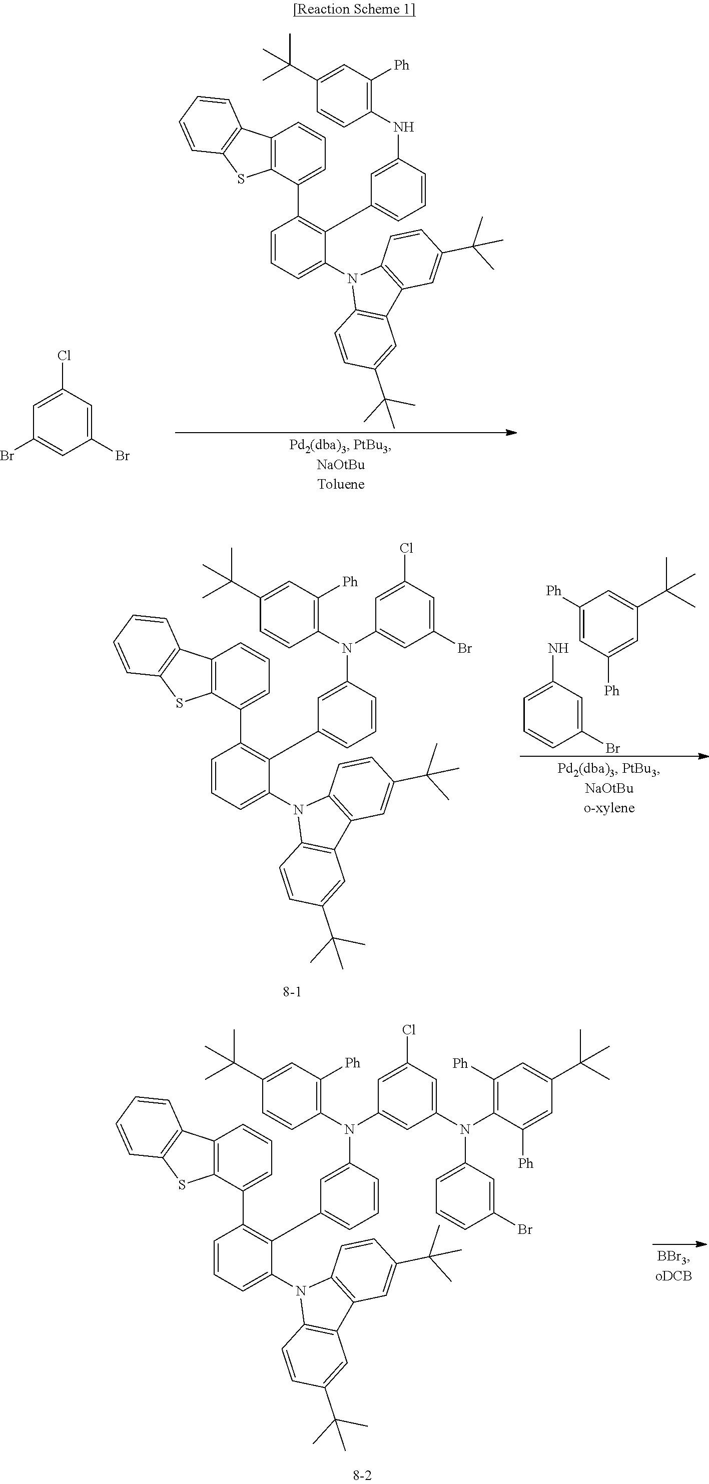

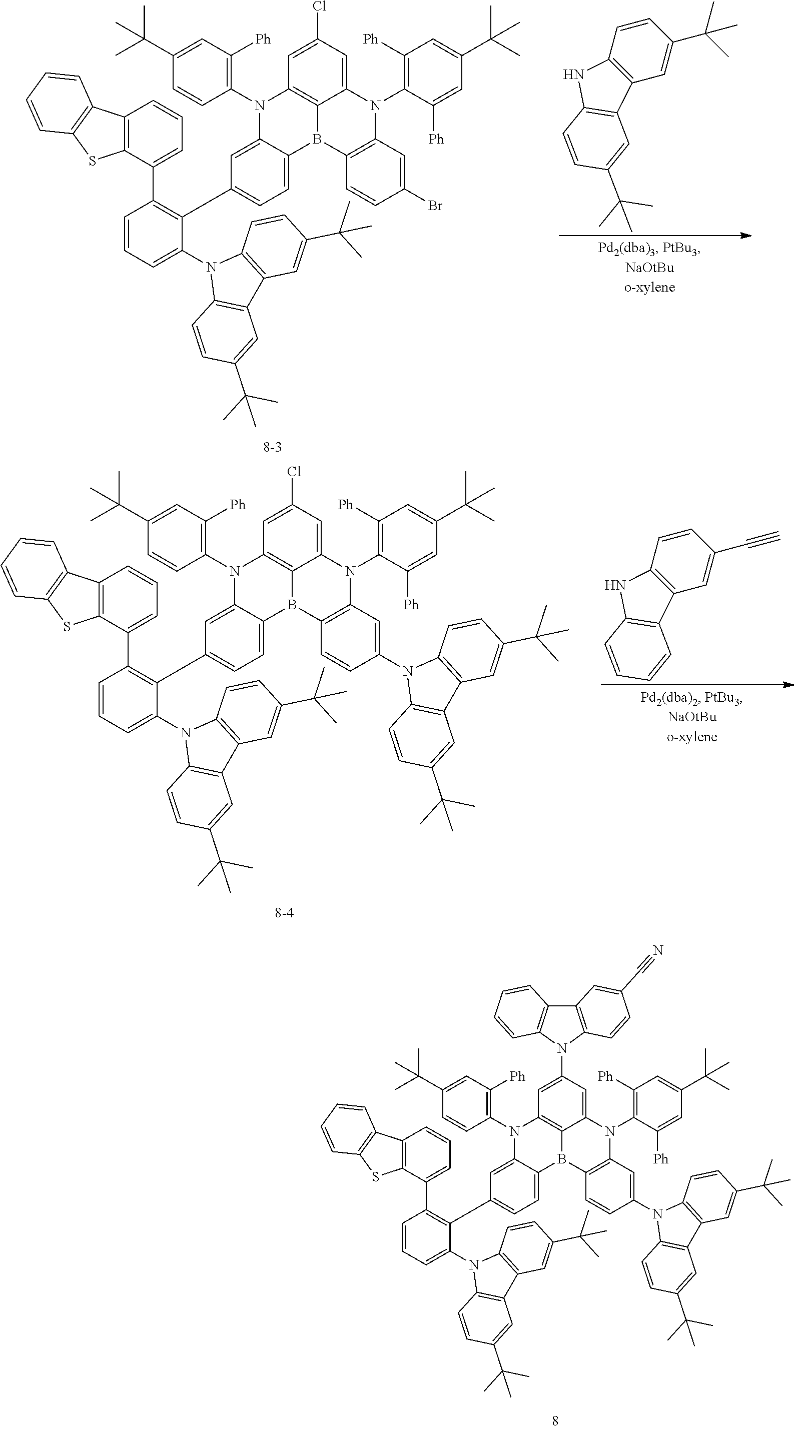

<Synthesis of Intermediate 8-1>

1,3-dibromo-5-chlorobenzene (2 eq), 5-(tert-butyl)-N-(2′-(3,6-di-tert-butyl-9H-carbazol-9-yl)-6′-(dibenzo[b,d]thiophen-4-yl)-[1,1′-biphenyl]-3-yl)-[1,1′-biphenyl]-2-amine (1 eq), tris(dibenzylideneacetone)dipalladium(0) (Pd₂(dba)₃) (0.05 eq), tri-tert-butylphosphine (PtBu₃) (0.10 eq), and sodium tert-butoxide (NaOtBu) (1.5 eq) were dissolved in toluene, and the resultant mixture was stirred in a nitrogen atmosphere at about 90° C. for about 24 hours.

After cooling, the resultant mixture was dried under reduced pressure and the toluene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 8-1. (yield: 64%)

<Synthesis of Intermediate 8-2>

Intermediate 8-1 (1 eq), N-(3-bromophenyl)-5′-(tert-butyl)-[1,1′:3′,1″-terphenyl]-2′-amine (1 eq), tris(dibenzylideneacetone)dipalladium(0) (0.05 eq), tri-tert-butylphosphine (0.10 eq), and sodium tert-butoxide (3 eq) were dissolved in o-xylene, and the resultant mixture was stirred in a nitrogen atmosphere at about 100° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 8-2. (yield: 67%)

<Synthesis of Intermediate 8-3>

Intermediate 8-2 (1 eq) was dissolved in ortho dichlorobenzene (oDCB), and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 20 hours. After the mixture was cooled to about 0° C., triethylamine was slowly dropped to the flask until heating stopped to terminate the reaction, and hexane was added to the flask, thereby extracting solids. The extracted solids were obtained by filtration. The obtained solids were purified with silica filtration, and purified again through recrystallization in methylenechloride/hexane (MC/Hex) to obtain Intermediate 8-3. Intermediate 8-3 was purified by column chromatography (dichloromethane:n-hexane). (yield: 8%)

<Synthesis of Intermediate 8-4>

Intermediate 8-3 (1 eq), 3,6-di-tert-butyl-9H-carbazole (1 eq), tris(dibenzylideneacetone)dipalladium(0) (0.05 eq), tri-tert-butylphosphine (0.10 eq), and sodium tert-butoxide (3 eq) were dissolved in o-xylene, and the resultant mixture was stirred in a nitrogen atmosphere at about 120° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 8-4. (yield: 59%)

<Synthesis of Compound 8>

Intermediate 8-4 (1 eq), 9H-carbazole-3-carbonitrile (1.3 eq), Tris(dibenzylideneacetone)dipalladium(0) (0.05 eq), tri-tert-butylphosphine (0.10 eq), and sodium tert-butoxide (3 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized (dichloromethane:n-hexane) by column chromatography to obtain Compound 8 (yield: 53%, MS[M+H]⁺=1764). The resulting product was further purified by sublimation purification to obtain final purity.

(2) Synthesis of Compound 33

Polycyclic Compound 33 according to an example may be synthesized by, for example, the steps shown in Reaction Scheme 2:

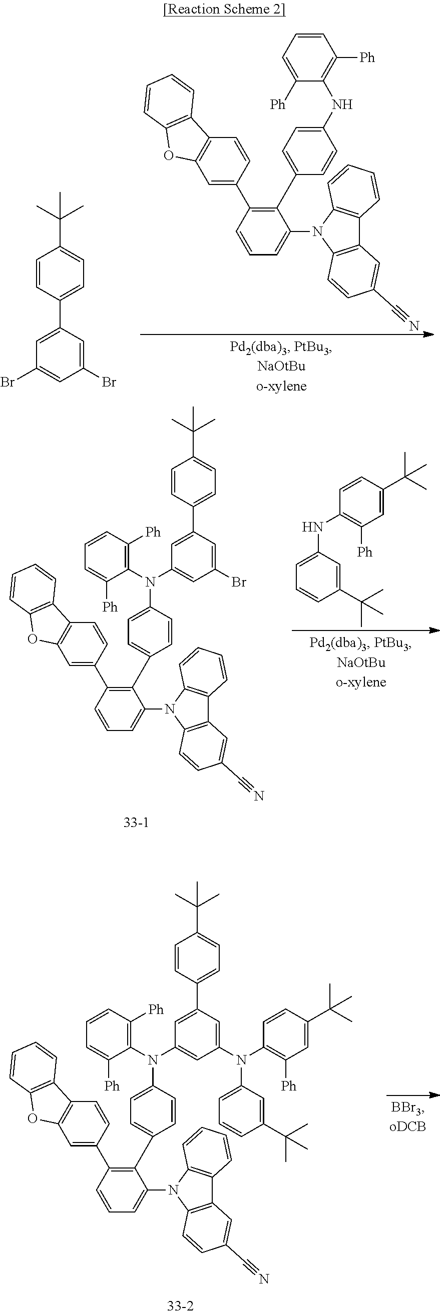 [SMILES: CC(C)(C)c1ccc(-c2cc(Br)cc(Br)c2)cc1 ; N#Cc1ccc2c(c1)c1ccccc1n2-c1cccc(-c2ccc3c(c2)oc2ccccc23)c1-c1ccc(Nc2c(-c3ccccc3)cccc2-c2ccccc2)cc1 ; CC(C)(C)c1ccc(-c2cc(Br)cc(N(c3ccc(-c4c(-c5ccc6c(c5)oc5ccccc56)cccc4-n4c5ccccc5c5cc(C#N)ccc54)cc3)c3c(-c4ccccc4)cccc3-c3ccccc3)c2)cc1 ; CC(C)(C)c1cccc(Nc2ccc(C(C)(C)C)cc2-c2ccccc2)c1 ; CC(C)(C)c1ccc(-c2cc(N(c3cccc(C(C)(C)C)c3)c3ccc(C(C)(C)C)cc3-c3ccccc3)cc(N(c3ccc(-c4c(-c5ccc6c(c5)oc5ccccc56)cccc4-n4c5ccccc5c5cc(C#N)ccc54)cc3)c3c(-c4ccccc4)cccc3-c3ccccc3)c2)cc1]

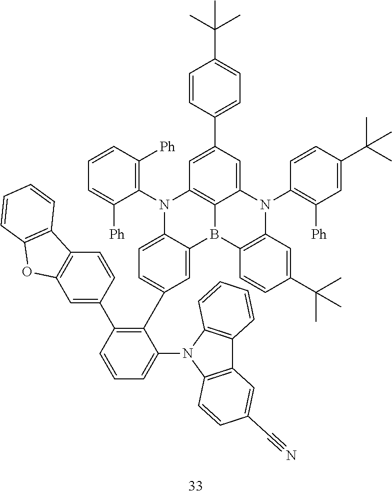 [SMILES: CC(C)(C)c1ccc(-c2cc3c4c(c2)N(c2c(-c5ccccc5)cccc2-c2ccccc2)c2ccc(-c5c(-c6ccc7c(c6)oc6ccccc67)cccc5-n5c6ccccc6c6cc(C#N)ccc65)cc2B4c2ccc(C(C)(C)C)cc2N3c2ccc(C(C)(C)C)cc2-c2ccccc2)cc1]

<Synthesis of Intermediate 33-1>

3,5-dibromo-4′-(tert-butyl)-1,1′-biphenyl (1 eq), 9-(4′-([1,1′:3′,1″-terphenyl]-2′-ylamino)-6-(dibenzo[b,d]furan-3-yl)-[1,1′-biphenyl]-2-yl)-9H-carbazole-3-carbonitrile (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 33-1. (yield: 57%)

<Synthesis of Intermediate 33-2>

Intermediate 33-1 (1 eq), 5-(tert-butyl)-N-(3-(tert-butyl)phenyl)-[1,1′-biphenyl]-2-amine (1.1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 33-2. (yield: 61%)

<Synthesis of Compound 33>

Intermediate 33-2 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and hexane was added to the flask, thereby extracting solids.

The extracted solids were obtained by filtration. The obtained solids were purified with a silica filter, and purified again through recrystallization in MC/Hex to obtain Compound 33. Compound 33 was purified by column chromatography (dichloromethane:n-hexane). (yield: 6%, MS[M+H]⁺=1325)

(3) Synthesis of Compound 49

Polycyclic Compound 49 according to an example may be synthesized by, for example, the steps shown in Reaction Scheme 3:

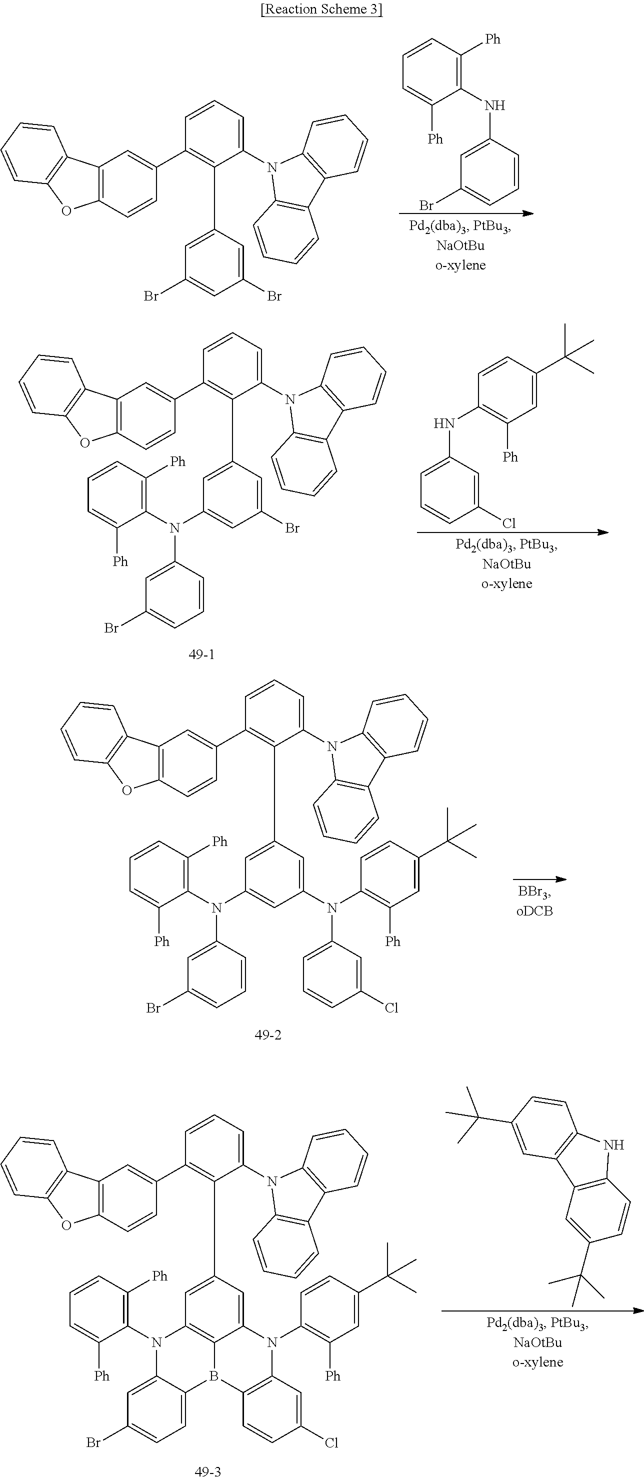

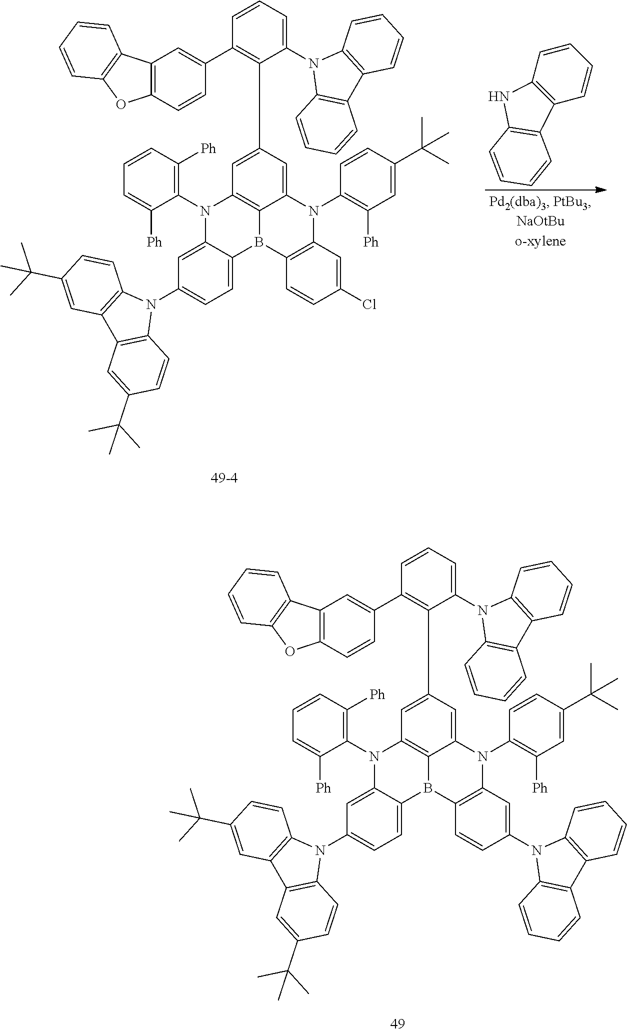

<Synthesis of Intermediate 49-1>

9-(3′,5′-dibromo-6-(dibenzo[b,d]furan-2-yl)-[1,1′-biphenyl]-2-yl)-9H-carbazole (1 eq), N-(3-bromophenyl)-[1,1′:3′,1″-terphenyl]-2′-amine (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 49-1. (yield: 56%)

<Synthesis of Intermediate 49-2>

Intermediate 49-1 (1 eq), 5-(tert-butyl)-N-(3-chlorophenyl)-[1,1′-biphenyl]-2-amine (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 100° C. for about 10 hours. After cooling, the resultant mixture was dried under reduced pressure, and the o-xylene was removed. The resulting product was washed three times with dichloromethane and water to obtain organic layers. The obtained organic layers were dried over MgSO₄, and dried under reduced pressure. The resulting product was purified and recrystallized by column chromatography (dichloromethane:n-hexane) to obtain Intermediate 49-2. (yield: 62%)

<Synthesis of Intermediate 49-3>

Intermediate 49-2 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and hexane was added to the flask, thereby extracting solids. The extracted solids were obtained by filtration. The obtained solids were purified with silica filtration, and purified again through recrystallization in MC/Hex to obtain Intermediate 49-3. Intermediate 49-3 was purified by column chromatography (dichloromethane:n-hexane). (yield: 8%)

<Synthesis of Intermediate 49-4>

Intermediate 49-3 (1 eq), 3,6-di-tert-butyl-9H-carbazole (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 100° C. for about 20 hours. After cooling, the resultant mixture was dried under reduced pressure, and the o-xylene was removed. The resulting product was washed three times with dichloromethane and water to obtain organic layers. The obtained organic layers were dried over MgSO₄, and dried under reduced pressure. The resulting product was purified and recrystallized by column chromatography (dichloromethane:n-hexane) to obtain Intermediate 49-4. (yield: 82%)

<Synthesis of Compound 49>

Intermediate 49-4 (1 eq), 9H-carbazole (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with dichloromethane and water to obtain organic layers. The obtained organic layers were dried over MgSO₄, and dried under reduced pressure. The resulting product was purified and recrystallized by column chromatography (dichloromethane:n-hexane) to obtain Compound 49. (yield: 69%, MS[M+H]⁺=1554)

(4) Synthesis of Compound 95

Polycyclic Compound 95 according to an example may be synthesized by, for example, the steps shown in Reaction Scheme 4:

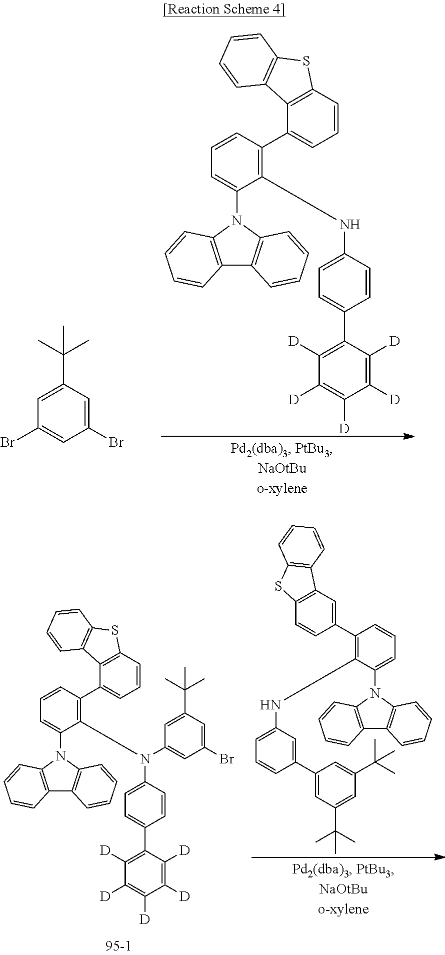

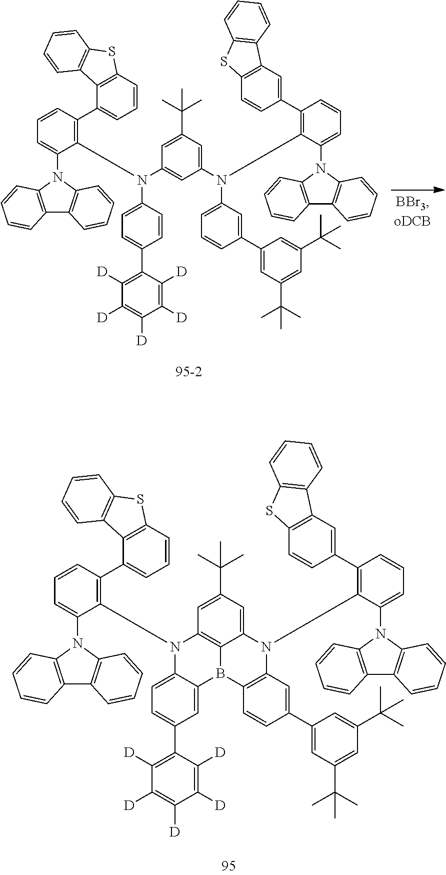 [SMILES: [2H]c1c([2H])c([2H])c(-c2ccc(N(c3cc(N(c4cccc(-c5cc(C(C)(C)C)cc(C(C)(C)C)c5)c4)c4c(-c5ccc6sc7ccccc7c6c5)cccc4-n4c5ccccc5c5ccccc54)cc(C(C)(C)C)c3)c3c(-c4cccc5sc6ccccc6c45)cccc3-n3c4ccccc4c4ccccc43)cc2)c([2H])c1[2H] ; [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3cccc4sc5ccccc5c34)cccc2-n2c3ccccc3c3ccccc32)c([2H])c1[2H]]

<Synthesis of Intermediate 95-1>

1,3-dibromo-5-(tert-butyl)benzene (1 eq), N-(2-(9H-carbazol-9-yl)-6-(dibenzo[b,d]thiophen-1-yl)phenyl)-[1,1′-biphenyl]-2′,3′,4′,5′,6′-d5-4-amine (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 95-1. (yield: 64%)

<Synthesis of Intermediate 95-2>

Intermediate 95-1 (1 eq), N-(2-(9H-carbazol-9-yl)-6-(dibenzo[b,d]thiophen-2-yl)phenyl)-3′,5′-di-tert-butyl-[1,1′-biphenyl]-3-amine (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 95-2. (yield: 57%)

<Synthesis of Compound 95>

Intermediate 95-2 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and hexane was added to the flask, thereby extracting solids. The extracted solids were obtained by filtration. The obtained solids were purified with a silica filter, and purified again through recrystallization in MC/Hex to obtain Compound 95. Compound 95 was purified by column chromatography (dichloromethane:n-hexane). (yield: 11%, MS[M+H]⁺=1440)

(5) Synthesis of Compound 111

Polycyclic Compound 111 according to an example may be synthesized by, for example, the steps shown in Reaction Scheme 5:

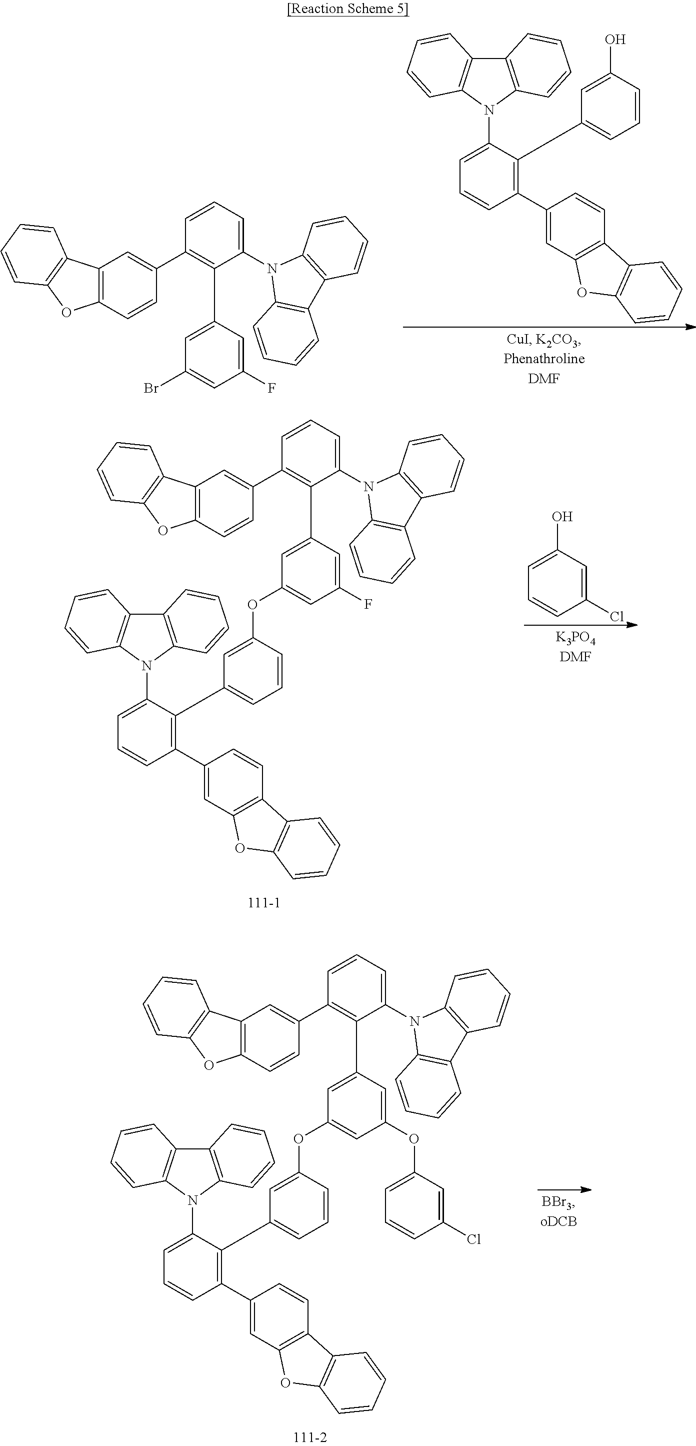 [SMILES: Fc1cc(Br)cc(-c2c(-c3ccc4oc5ccccc5c4c3)cccc2-n2c3ccccc3c3ccccc32)c1 ; Oc1cccc(-c2c(-c3ccc4c(c3)oc3ccccc34)cccc2-n2c3ccccc3c3ccccc32)c1 ; Fc1cc(Oc2cccc(-c3c(-c4ccc5c(c4)oc4ccccc45)cccc3-n3c4ccccc4c4ccccc43)c2)cc(-c2c(-c3ccc4oc5ccccc5c4c3)cccc2-n2c3ccccc3c3ccccc32)c1 ; Oc1cccc(Cl)c1 ; Clc1cccc(Oc2cc(Oc3cccc(-c4c(-c5ccc6c(c5)oc5ccccc56)cccc4-n4c5ccccc5c5ccccc54)c3)cc(-c3c(-c4ccc5oc6ccccc6c5c4)cccc3-n3c4ccccc4c4ccccc43)c2)c1]

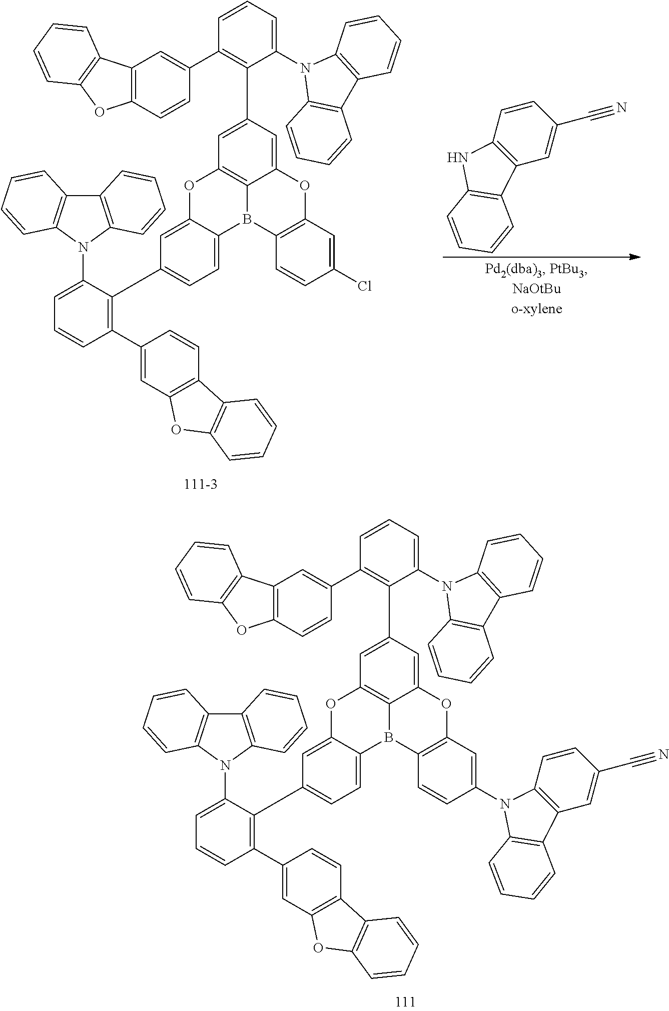 [SMILES: Clc1ccc2c(c1)Oc1cc(-c3c(-c4ccc5oc6ccccc6c5c4)cccc3-n3c4ccccc4c4ccccc43)cc3c1B2c1ccc(-c2c(-c4ccc5c(c4)oc4ccccc45)cccc2-n2c4ccccc4c4ccccc42)cc1O3 ; N#Cc1ccc2[nH]c3ccccc3c2c1 ; N#Cc1ccc2c(c1)c1ccccc1n2-c1ccc2c(c1)Oc1cc(-c3c(-c4ccc5oc6ccccc6c5c4)cccc3-n3c4ccccc4c4ccccc43)cc3c1B2c1ccc(-c2c(-c4ccc5c(c4)oc4ccccc45)cccc2-n2c4ccccc4c4ccccc42)cc1O3]

<Synthesis of Intermediate 111-1>

9-(3′-bromo-6-(dibenzo[b,d]furan-2-yl)-5′-fluoro-[1,1′-biphenyl]-2-yl)-9H-carbazole (1 eq), 3-(2′-9H-carbazol-9-yl-6′-(dibenzo[b,d]furan-3-yl)-phenyl) phenol (1 eq), copper iodide (1 eq), potassium carbonate (2 eq), and 1,10-phenanthroline (1 eq) were dissolved in N,N-dimethylformamide anhydrous, and the resultant mixture was stirred in a nitrogen atmosphere at about 160° C. for about 24 hours. After cooling, the resultant mixture was dried under reduced pressure, and the N,N-dimethylformamide was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 111-1. (yield: 62%)

<Synthesis of Intermediate 111-2>

Intermediate 111-1 (1 eq), 3-chlorophenol (1 eq), and potassium phosphate (3 eq) were dissolved in N,N-dimethylformamide anhydrous, and the resultant mixture was stirred in a nitrogen atmosphere at about 150° C. for about 24 hours. After cooling, the resultant mixture was dried under reduced pressure, and the N,N-dimethylformamide was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 111-2. (yield: 70%)

<Synthesis of Intermediate 111-3>

Intermediate 111-2 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and hexane was added to the flask, thereby extracting solids. The extracted solids were obtained by filtration. The obtained solids were purified with silica filtration, and purified again through recrystallization in MC/Hex to obtain Intermediate 111-3. Intermediate 111-3 was purified by column chromatography (dichloromethane:n-hexane). (yield: 7%)

<Synthesis of Compound 111>

Intermediate 111-3 (1 eq), 9H-carbazole-3-carbonitrile (1 eq), Tris(dibenzylideneacetone)dipalladium(0) (0.05 eq), tri-tert-butylphosphine (0.10 eq), and sodium tert-butoxide (2 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Compound 111. (yield: 72%, MS[M+H]⁺=1275)

(6) Synthesis of Compound 121

Polycyclic Compound 121 according to an example may be synthesized by, for example, the steps shown in Reaction Scheme 6:

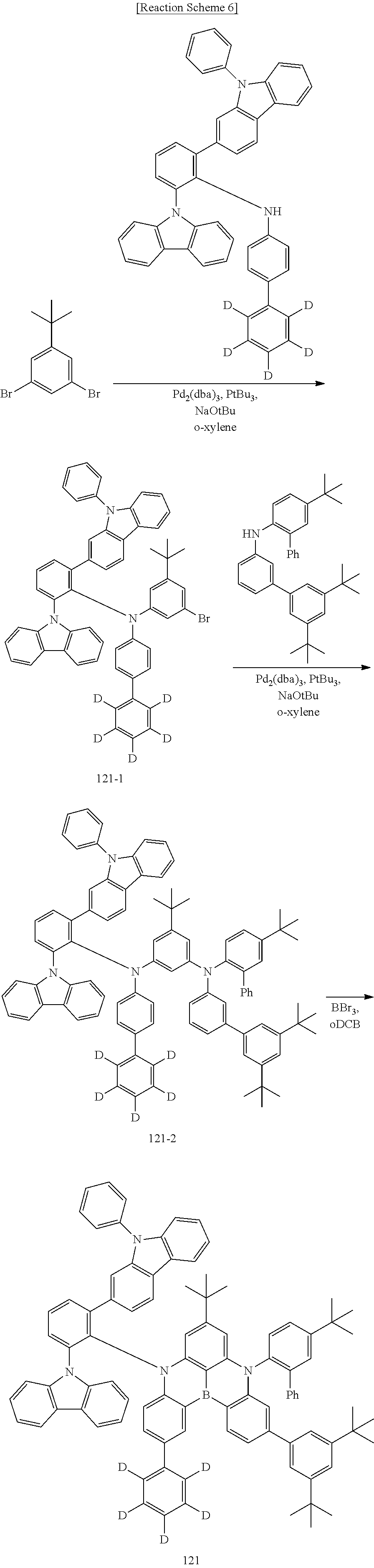

<Synthesis of Intermediate 121-1>

1,3-dibromo-5-(tert-butyl)benzene (1 eq), N-(2-(9H-carbazol-9-yl)-6-(9-phenyl-9H-carbazol-2-yl)phenyl)-[1,1′-biphenyl]-2′,3′,4′,5′,6′-d5-4-amine (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 121-1. (yield: 51%)

<Synthesis of Intermediate 121-2>

Intermediate 121-1 (1 eq), 5-(tert-butyl)-N-(3′,5′-di-tert-butyl-[1,1′-biphenyl]-3-yl)-[1,1′-biphenyl]-2-amine (1 eq), tris(dibenzylideneacetone)dipalladium(0) (0.05 eq), tri-tert-butylphosphine (0.10 eq), and sodium tert-butoxide (1.5 eq) were dissolved in o-xylene, and the resultant mixture was stirred in a nitrogen atmosphere at about 150° C. for about 24 hours. After cooling, the resultant mixture was dried under reduced pressure, and the o-xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 121-2. (yield: 69%)

<Synthesis of Compound 121>

Intermediate 121-2 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and hexane was added to the flask, thereby extracting solids. The extracted solids were obtained by filtration. The obtained solids were purified with a silica filter, and purified again through recrystallization in MC/Hex to obtain Compound 121. Compound 121 was purified by column chromatography (dichloromethane:n-hexane). (yield: 9%, MS[M+H]⁺=1284)

### 2. Example and Comparative Example Compounds

Example Compounds and Comparative Example Compounds used to manufacture light emitting elements of Examples and Comparative Examples are listed in Table 1:

TABLE 1

| | |
|---|---|
| Compound 8 | 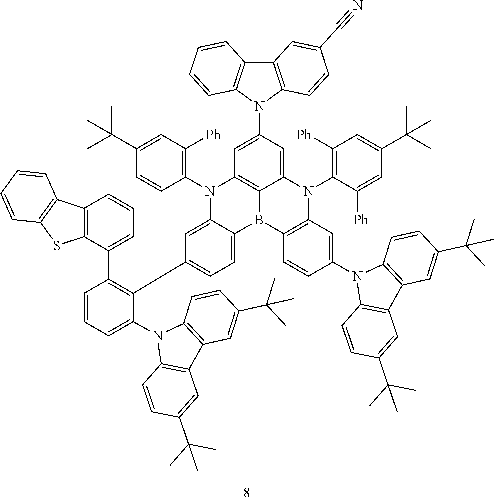 [SMILES: CC(C)(C)c1ccc(N2c3cc(-c4c(-c5cccc6c5sc5ccccc56)cccc4-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-n5c6ccccc6c6cc(C#N)ccc65)cc2c43)c(-c2ccccc2)c1] |
| Compound 33 | 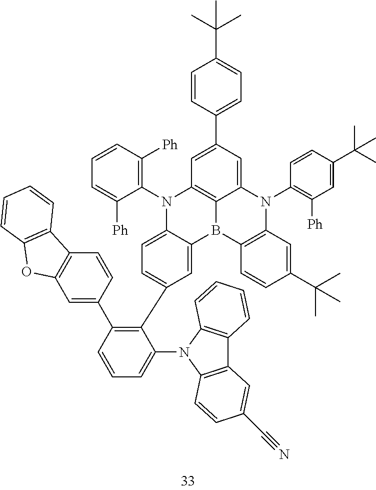 [SMILES: CC(C)(C)c1ccc(-c2cc3c4c(c2)N(c2c(-c5ccccc5)cccc2-c2ccccc2)c2ccc(-c5c(-c6ccc7c(c6)oc6ccccc67)cccc5-n5c6ccccc6c6cc(C#N)ccc65)cc2B4c2ccc(C(C)(C)C)cc2N3c2ccc(C(C)(C)C)cc2-c2ccccc2)cc1] |
| Compound 49 | 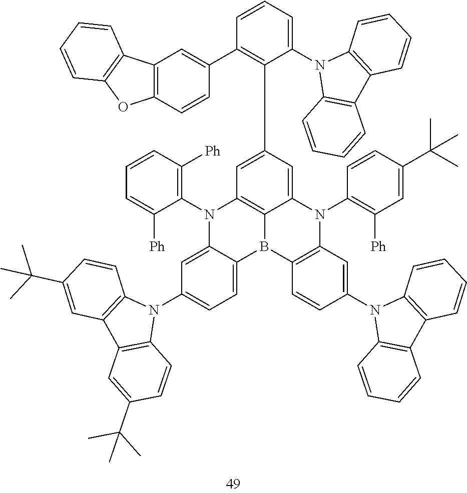 [SMILES: CC(C)(C)c1ccc(N2c3cc(-n4c5ccccc5c5ccccc54)ccc3B3c4ccc(-n5c6ccc(C(C)(C)C)cc6c6cc(C(C)(C)C)ccc65)cc4N(c4c(-c5ccccc5)cccc4-c4ccccc4)c4cc(-c5c(-c6ccc7oc8ccccc8c7c6)cccc5-n5c6ccccc6c6ccccc65)cc2c43)c(-c2ccccc2)c1] |
| Compound 95 | 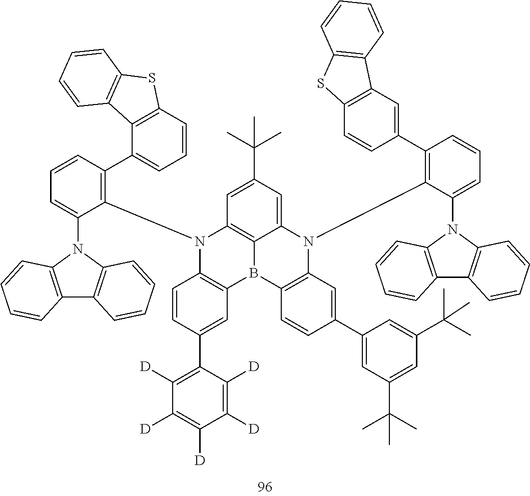 [SMILES: [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3cccc4sc5ccccc5c34)cccc2-n2c3ccccc3c3ccccc32)c([2H])c1[2H]] |
| Compound 111 | 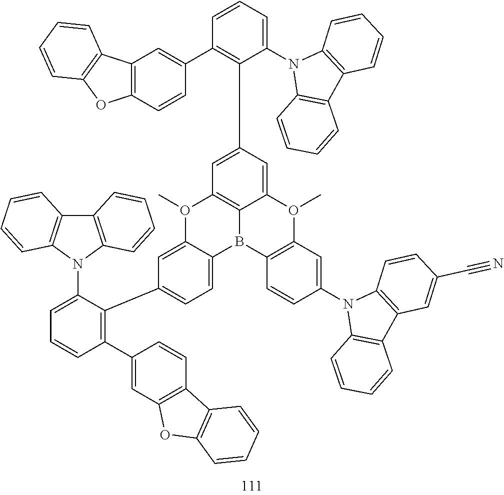 |
| Compound 121 | 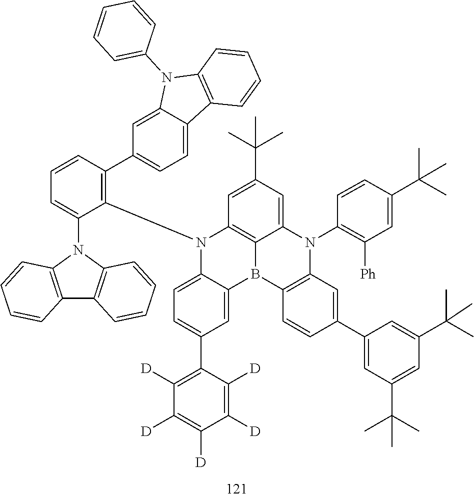 [SMILES: [2H]c1c([2H])c([2H])c(-c2ccc3c(c2)B2c4ccc(-c5cc(C(C)(C)C)cc(C(C)(C)C)c5)cc4N(c4ccc(C(C)(C)C)cc4-c4ccccc4)c4cc(C(C)(C)C)cc(c42)N3c2c(-c3ccc4c5ccccc5n(-c5ccccc5)c4c3)cccc2-n2c3ccccc3c3ccccc32)c([2H])c1[2H]] |
| Comparative Example Compound 1 | 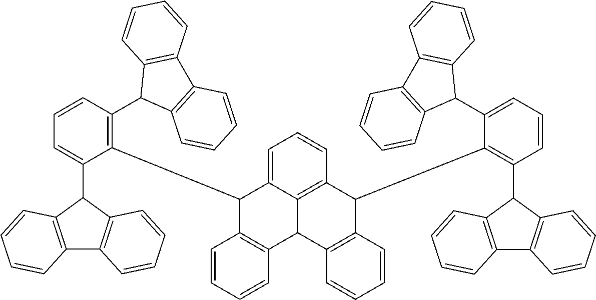 [SMILES: c1ccc2c(c1)-c1ccccc1C2c1cccc(C2c3ccccc3-c3ccccc32)c1C1c2ccccc2C2c3ccccc3C(c3c(C4c5ccccc5-c5ccccc54)cccc3C3c4ccccc4-c4ccccc43)c3cccc1c32] |
| Comparative Example Compound 2 | 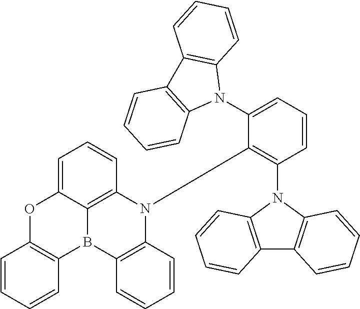 [SMILES: c1ccc2c(c1)Oc1cccc3c1B2c1ccccc1N3c1c(-n2c3ccccc3c3ccccc32)cccc1-n1c2ccccc2c2ccccc21] |
| Comparative Example Compound 3 | 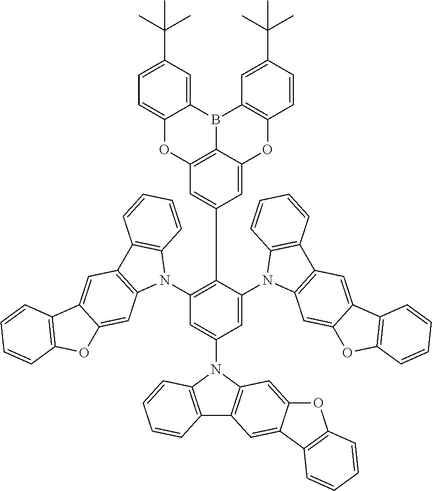 [SMILES: CC(C)(C)c1ccc2c(c1)B1c3cc(C(C)(C)C)ccc3Oc3cc(-c4c(-n5c6ccccc6c6cc7c(cc65)oc5ccccc57)cc(-n5c6ccccc6c6cc7c(cc65)oc5ccccc57)cc4-n4c5ccccc5c5cc6c(cc54)oc4ccccc46)cc(c31)O2] |
| Comparative Example Compound 4 | 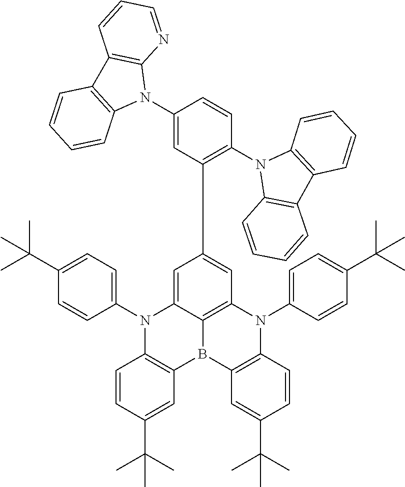 [SMILES: CC(C)(C)c1ccc(N2c3ccc(C(C)(C)C)cc3B3c4cc(C(C)(C)C)ccc4N(c4ccc(C(C)(C)C)cc4)c4cc(-c5cc(-n6c7ccccc7c7cccnc76)ccc5-n5c6ccccc6c6ccccc65)cc2c43)cc1] |

### 3. Manufacture and Evaluation of Light Emitting Element 1

(1) Manufacture of Light Emitting Element 1

Light emitting element 1 including the polycyclic compound according to an Example Compound or a Comparative Example Compound in the emission layer was manufactured as follows. Compounds 8, 33, 49, 95, 111, and 121 that are the polycyclic compounds of examples were used as a dopant material of the emission layer to manufacture the light emitting elements of Examples 1-1 to 1-6, respectively. Comparative Example Compound C1 to Comparative Example Compound C4 were used as a dopant material in the emission layer to manufacture the light emitting elements of Comparative Examples 1-1 to 1-4, respectively.

A glass substrate (made by Corning Co.), on which an ITO electrode of about 15 Ω/cm² (about 1,200 Å) is formed as a first electrode, was cut to a size of about 50 mm×50 mm×0.7 mm, cleansed by ultrasonic waves using isopropyl alcohol and pure water for about five minutes. The glass substrate was irradiated with ultraviolet rays for about 30 minutes and exposed to ozone and cleansed, and was installed on a vacuum deposition apparatus.

NPD was deposited in vacuum on the upper portion of the glass substrate to form a 300 Å-thick hole injection layer. A hole transport layer material was deposited in vacuum to form a 200 Å-thick hole transport layer. As the hole transport layer material, H-1-2, H-1-3, H-1-5, and H-1-6 were used as shown in Table 2. CzSi was deposited on the upper portion of the hole transport layer to form a 100 Å-thick emission-auxiliary layer.

On the upper portion of the emission-auxiliary layer, a host mixture, a phosphorescent sensitizer, and a dopant of Example Compound or Comparative Example Compound were co-deposited at a weight ratio of 85:14:1 to form a 200 Å-thick emission layer. The host mixture was provided by mixing a first host (HT1, HT2, HT3, and HT4) and a second host (EHT85, EHT66, and EHT86) at a weight ratio of 5:5 as shown in Table 2. PS1 or PS2 was used as the phosphorescent sensitizer as shown in Table 2.

TSPO1 was deposited on the upper portion of the emission layer to form a 200 Å-thick hole blocking layer, and TPBi was deposited on the upper portion of the hole blocking layer to form a 300 Å-thick electron transport layer. LiF was deposited on the upper portion of the electron transport layer to form a 10 Å-thick electron injection layer, and Al was deposited on the upper portion of the electron injection layer to form a 3,000 Å-thick second electrode. Compound P4 was deposited on the upper portion of the second electrode to form a 700 Å-thick capping layer, thereby manufacturing light emitting element 1.

The compounds used to manufacture light emitting element 1 are as follows:

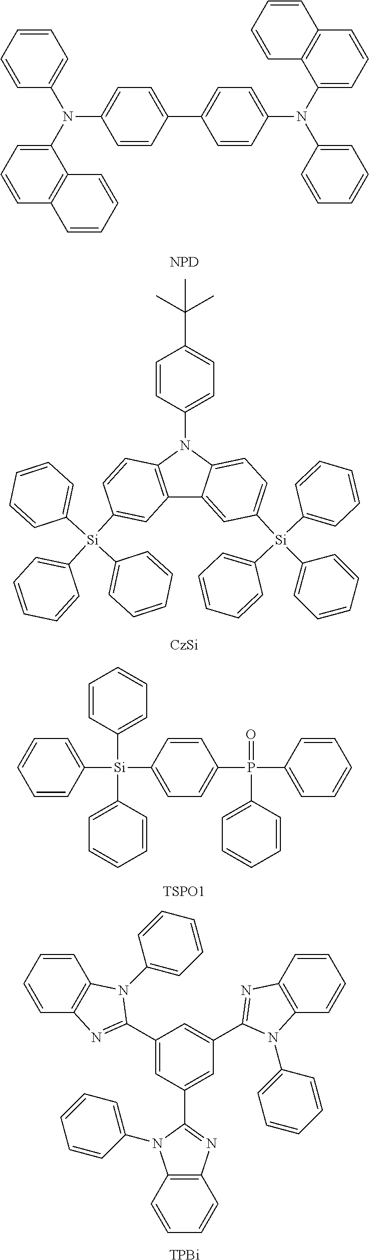

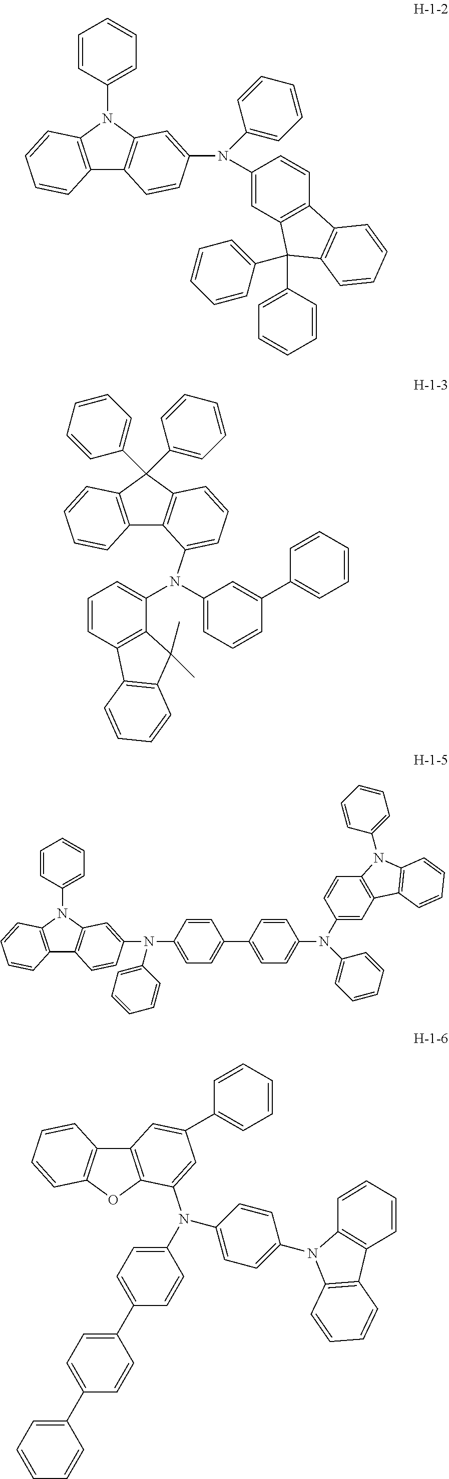 [SMILES: c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

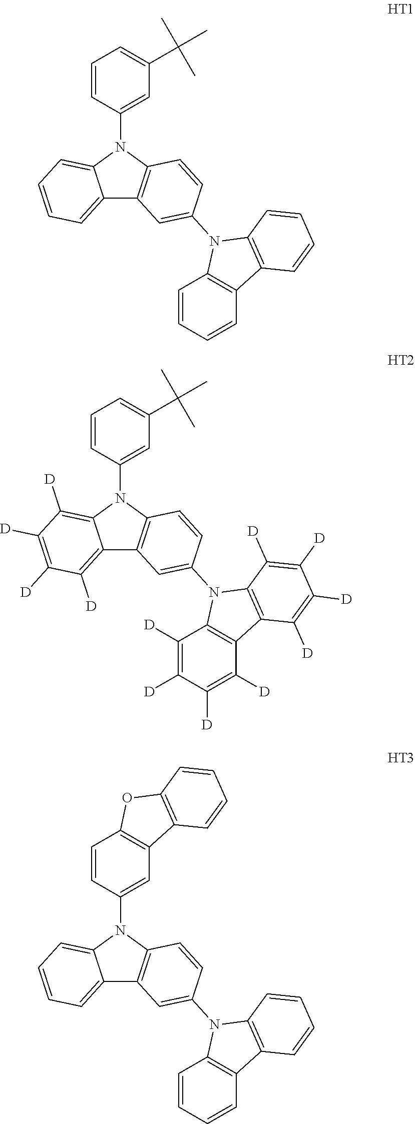

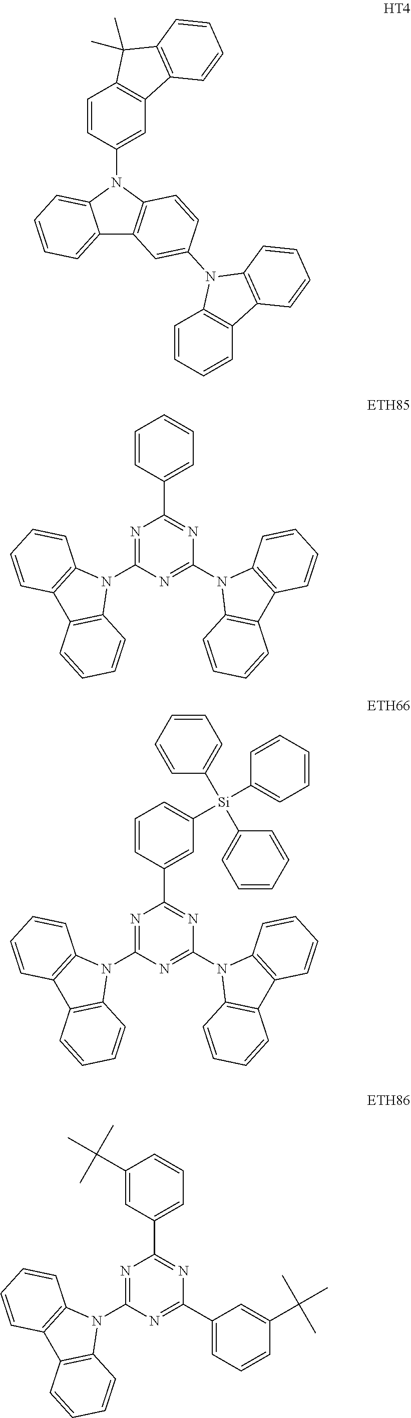

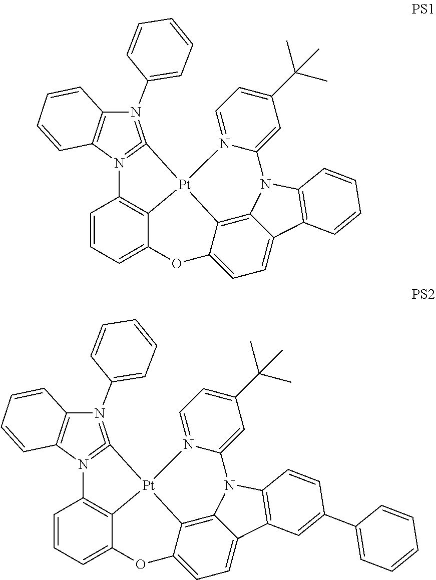

(2) Evaluation of Light Emitting Element 1

Driving voltages (V), luminous efficiencies (cd/A), maximum external quantum efficiencies (EQEₘₐₓ, %), service life (%), and emission colors of light emitting elements 1 according to Examples 1-1 to 1-6 and Comparative Examples 1-1 to 1-4 are listed in Table 2.

The driving voltages (V), luminous efficiencies (cd/A), maximum external quantum efficiencies (EQEₘₐₓ, %), and emission colors of light emitting elements 1 were measured at a brightness of 1,000 cd/m² by using Keithley MU 236 and a luminance meter PR650. For the element service life, the time taken to reach 95% brightness relative to an initial brightness was measured as a service life (T₉₅), and shown as a relative value assuming the service life in Comparative Example 1-1 as 100%.

TABLE 2

| | | | | | | | Maximum | Element | |
|---|---|---|---|---|---|---|---|---|---|
| | | | | | | | external | service life | |
| | Hole | | | | | | quantum | (%) | |
| | transport | | | | Driving | | efficiency | Ref. | |
| | layer | Host | | Dopant | voltage | Efficiency | EQEₘₐₓ,_ | Comparative | Emission |
| Division | material | (HT:ET = 5:5) | Sensitizer | compound | (V) | (cd/A) | (%) | Example 1 | color |
| Example 1-1 | H-1-2 | HT2/ | PS1 | Compound 8 | 4.2 | 26.8 | 25.6 | 260 | Blue |
| | | ETH66 | | | | | | | |
| Example 1-2 | H-1-3 | HT1/ | PS2 | Compound 33 | 4.3 | 25.7 | 24.8 | 245 | Blue |
| | | ETH86 | | | | | | | |
| Example 1-3 | H-1-5 | HT3/ | PS1 | Compound 49 | 4.2 | 25.5 | 24.2 | 255 | Blue |
| | | ETH66 | | | | | | | |
| Example 1-4 | H-1-6 | HT1/ | PS2 | Compound 95 | 4.4 | 24.6 | 23.4 | 230 | Blue |
| | | ETH86 | | | | | | | |
| Example 1-5 | H-1-2 | HT1/ | PS2 | Compound 111 | 4.4 | 24.3 | 23.6 | 195 | Blue |
| | | ETH86 | | | | | | | |
| Example 1-6 | H-1-3 | HT2/ | PS1 | Compound 121 | 4.5 | 25.6 | 24.9 | 225 | Blue |
| | | ETH66 | | | | | | | |
| Comparative | H-1-2 | HT4/ | PS1 | Comparative | 4.6 | 18.9 | 17.8 | 100 | Blue |
| Example 1-1 | | ETH86 | | Example | | | | | |
| | | | | Compound 1 | | | | | |
| Comparative | H-1-3 | HT2/ETH86 | PS2 | Comparative | 4.7 | 17.1 | 16.6 | 75 | Blue |
| Example 1-2 | | | | Example | | | | | |
| | | | | Compound 2 | | | | | |
| Comparative | H-1-6 | HT3/EHT85 | PS1 | Comparative | 4.7 | 18.3 | 17.2 | 135 | Blue |
| Example 1-3 | | | | Example | | | | | |
| | | | | Compound 3 | | | | | |
| Comparative | H-1-6 | HT3/ | PS1 | Comparative | 4.6 | 19.4 | 18.3 | 150 | Blue |
| Example 1-4 | | ETH85 | | Example | | | | | |
| | | | | Compound 4 | | | | | |

Referring to the results of Table 2, Examples 1-1 to 1-6 each exhibit characteristics of higher luminous efficiency, improved maximum external quantum efficiency, and long service life as compared with Comparative Examples 1-1 to 1-4. It may be understood that Examples 1-1 to 1-6 exhibit lower driving voltage characteristics as compared with Comparative Examples 1-1 to 1-4.

### 4. Manufacture and Evaluation of Light Emitting Element 2

(1) Manufacture of Light Emitting Element 2

The light emitting elements of Examples 2-1 to 2-6 were manufactured in the same manner as the light emitting elements of Examples 1-1 to 1-6, except that the phosphorescent sensitizer was not used when the emission layer was formed. The light emitting elements of Comparative Examples 2-1 to 2-4 were manufactured in the same manner as the light emitting elements of Comparative Examples 1-1 to 1-4, except that the phosphorescent sensitizer was not used when the emission layer was formed. For the light emitting elements of Examples 2-1 to 2-6 and Comparative Examples 2-1 to 2-4, when the emission layer was formed, a host mixture and a dopant were provided at a weight ratio of 99:1 and co-deposited to a thickness of about 200 Å.

(2) Evaluation of Light Emitting Element 2

Driving voltages (V), luminous efficiencies (cd/A), maximum external quantum efficiencies (EQEₘₐₓ, %), and emission colors of the light emitting elements according to Examples 2-1 to 2-6 and Comparative Examples 2-1 to 2-4 are listed in Table 3. The driving voltages (V), luminous efficiencies (cd/A), maximum external quantum efficiencies (EQEₘₐₓ, %), and emission colors of the light emitting elements were measured at a brightness of 1,000 cd/m² by using Keithley MU 236 and a luminance meter PR650.

TABLE 3

| | | | | | | Maximum | |
|---|---|---|---|---|---|---|---|
| | Hole | | | | | external | |
| | transport | Host | | | | quantum | |
| | layer | (HT:ET = | Dopant | Driving voltage | Efficiency | efficiency | Luminous |
| Division | material | 5:5) | compound | (V) | (cd/A) | (%) | color |
| Example 2-1 | H-1-2 | HT2/ET2 | Compound 8 | 6.0 | 8.7 | 7.9 | Blue |
| Example 2-2 | H-1-3 | HT1/ET3 | Compound 33 | 6.1 | 8.4 | 7.6 | Blue |
| Example 2-3 | H-1-5 | HT3/ET2 | Compound 49 | 6.0 | 8.3 | 7.5 | Blue |
| Example 2-4 | H-1-6 | HT1/ET3 | Compound 95 | 6.2 | 8.0 | 7.2 | Blue |
| Example 2-5 | H-1-2 | HT1/ET3 | Compound 111 | 6.2 | 7.9 | 7.1 | Blue |
| Example 2-6 | H-1-3 | HT2/ET2 | Compound 121 | 6.3 | 8.1 | 7.4 | Blue |
| Comparative | H-1-2 | HT4/ET3 | Comparative | 6.4 | 6.1 | 5.3 | Blue |
| Example 2-1 | | | Example | | | | |
| | | | Compound 1 | | | | |
| Comparative | H-1-3 | HT2/ET3 | Comparative | 6.5 | 5.5 | 4.7 | Blue |
| Example 2-2 | | | Example | | | | |
| | | | Compound 2 | | | | |
| Comparative | H-1-6 | HT3/ET1 | Comparative | 6.5 | 5.9 | 5.1 | Blue |
| Example 2-3 | | | Example | | | | |
| | | | Compound 3 | | | | |
| Comparative | H-1-6 | HT3/ET1 | Comparative | 6.4 | 6.3 | 5.5 | Blue |
| Example 2-4 | | | Example | | | | |
| | | | Compound 4 | | | | |

Referring to the results of Table 3, Examples 2-1 to 2-6 each exhibit lower driving voltage characteristics, and characteristics of higher luminous efficiency and improved maximum external quantum efficiency, as compared with Comparative Examples 2-1 to 2-4.

The polycyclic compound according to Examples has, as a core moiety, a planar pentacyclic fused ring containing a boron atom (B) as a ring-forming atom, and includes two substituents having a dibenzoheterole skeleton which are respectively substituted at an ortho-position to the core moiety, and when used as a material for the emission layer, may contribute to high efficiency and an increase in service life of the light emitting element. The polycyclic compound according to Examples includes the two substituents having a dibenzoheterole skeleton via a benzene derivative as a linking moiety, and thus distortion in the molecule is controlled, and therefore improved stability may be exhibited. Accordingly, the light emitting element including the polycyclic compound according to Examples may have improved luminous efficiency and service life characteristics.

Each of the two substituents having a dibenzoheterole skeleton is bonded to the benzene derivative linking moiety at an ortho-position to the core moiety and thus the polycyclic compound according to Examples may have activated multiple resonance in the compound molecule and high oscillator strength (f) and high absorbance. Accordingly, the polycyclic compound may have improved light extraction efficiency of the light emitting element, and may contribute more to delayed fluorescence, thereby increasing luminous efficiency.

The polycyclic compound has a structure including a core moiety of a fused ring containing a boron atom as a ring-forming atom and one or two bulky substituents in which two substituents having a dibenzoheterole skeleton are linked via a benzene derivative as a linking moiety, so that a steric structure due to the distortion between the bulky substituent and the core moiety improves the stability of the entire compound, and increased luminous efficiency characteristics due to the delayed fluorescence may be exhibited. The light emitting element including the polycyclic compound may exhibit long service life characteristics while maintaining excellent luminous efficiency.

The light emitting element may include the polycyclic compound of an embodiment, thereby exhibiting high efficiency and long service life characteristics.

The polycyclic compound may include a boron-containing core moiety and a substituent having a dibenzoheterole skeleton, thereby contributing to service life improvement and luminous efficiency increase of the light emitting element.

The polycyclic compound may include a boron-containing core moiety, and a substituent having a dibenzoheterole skeleton bonded at an ortho-position to the boron-containing core moiety, thereby contributing to service life improvement and luminous efficiency increase of the light emitting element.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein the emission layer comprises:
a first compound represented by Formula 1; and
at least one of a second compound represented by Formula HT-1 or a third compound represented by Formula ET-1: 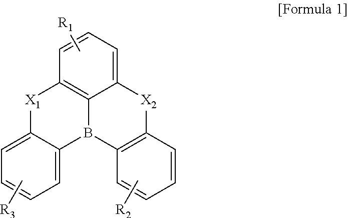
wherein in Formula 1,
X₁ and X₂ are each independently N(R₄) or O,
one or two of R₁ to R₄ are each independently a group represented by Formula 2, and
the remainder of R₁ to R₄ are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms, 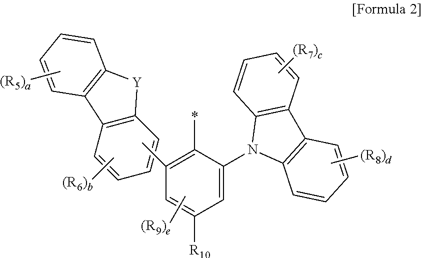
wherein in Formula 2,
Y is N(R₁₁), O, or S,
R₅ to R₈, R₁₀, and R₁₁ are each independently a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted aryl group having 6 to 60 ring-forming carbon atoms, or a substituted or unsubstituted heteroaryl group having 2 to 60 ring-forming carbon atoms,
R₉ is a hydrogen atom or a deuterium atom,
a, c, and d are each independently an integer from 0 to 4,
b is an integer from 0 to 3, and
e is an integer from 0 to 2, 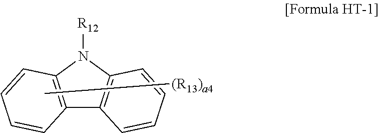
wherein in Formula HT-1,
a4 is an integer from 0 to 8, and
R₁₂ and R₁₃ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms, 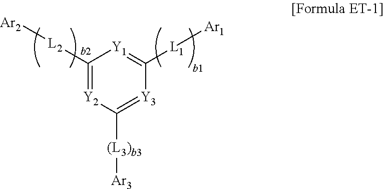
wherein in Formula ET-1,
at least one of Y₁ to Y₃ is each N, and
the remainder of Y₁ to Y₃ are each independently C(Rₐ),
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

2. The light emitting element of claim 1, wherein the emission layer further comprises a fourth compound represented by Formula M-b: 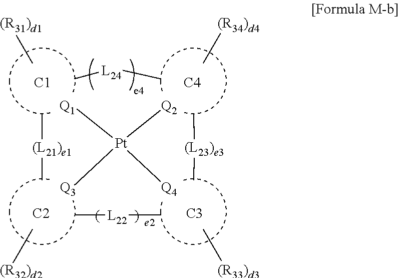
wherein in Formula M-b,
Q₁ to Q₄ are each independently C or N,
C1 to C4 are each independently a substituted or unsubstituted hydrocarbon ring group having 5 to 30 ring-forming carbon atoms, or a substituted or unsubstituted heterocyclic group having 2 to 30 ring-forming carbon atoms,
e1 to e4 are each independently 0 or 1,
L₂₁ to L₂₄ are each independently a direct linkage, 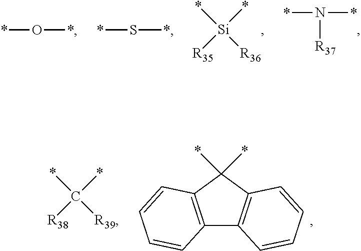
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer from 0 to 4,
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

3. The light emitting element of claim 1, wherein
one or two of R₁ to R₄ are each independently a group represented by Formula 2, and
the remainder of R₁ to R₄ are each independently a hydrogen atom, a deuterium atom, a t-butyl group, a substituted or unsubstituted phenyl group, a substituted or unsubstituted biphenyl group, a substituted or unsubstituted terphenyl group, or a substituted or unsubstituted carbazole group.

4. The light emitting element of claim 1, wherein at least one of R₁ to R₄ is each independently a deuterium atom, or each independently includes a substituent that includes a deuterium atom.

5. The light emitting element of claim 1, wherein the first compound is represented by one of Formula 1-1 to Formula 1-3: 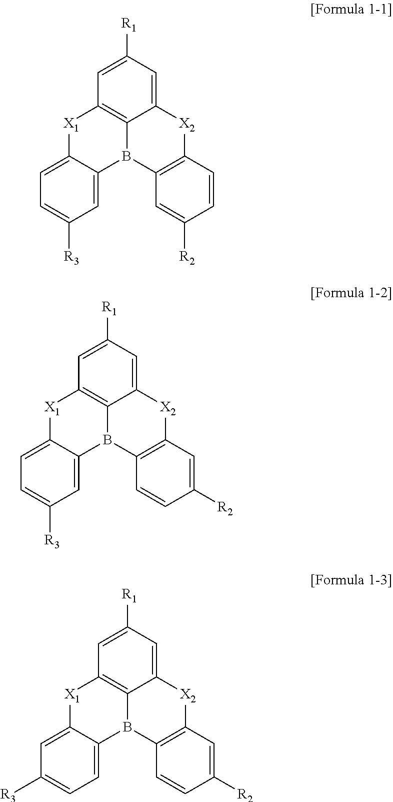
wherein in Formula 1-1 to Formula 1-3,
R₁ to R₃, X₁, and X₂ are each the same as defined in Formula 1.

6. The light emitting element of claim 5, wherein Formula 1-1 is represented by one of Formula 1-1-1 to Formula 1-1-4: 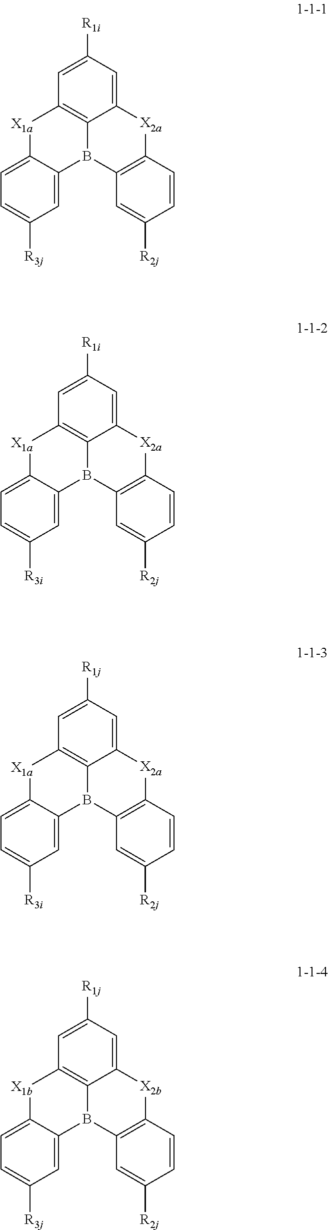
wherein in Formula 1-1-1 to Formula 1-1-4,
X₁ₐ and X₂ₐ are each independently N(R₄ⱼ) or O,
X_{1b} and X_{2b} are each independently N(R₄ᵢ) or O,
R₁ᵢ, R₃ᵢ, and R₄ᵢ are each independently a group represented by Formula 2, and
R₁ⱼ, R₂ⱼ, R₃ⱼ, and R₄ⱼ are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

7. The light emitting element of claim 5, wherein Formula 1-2 is represented by one of Formula 1-2-1 to Formula 1-2-3: 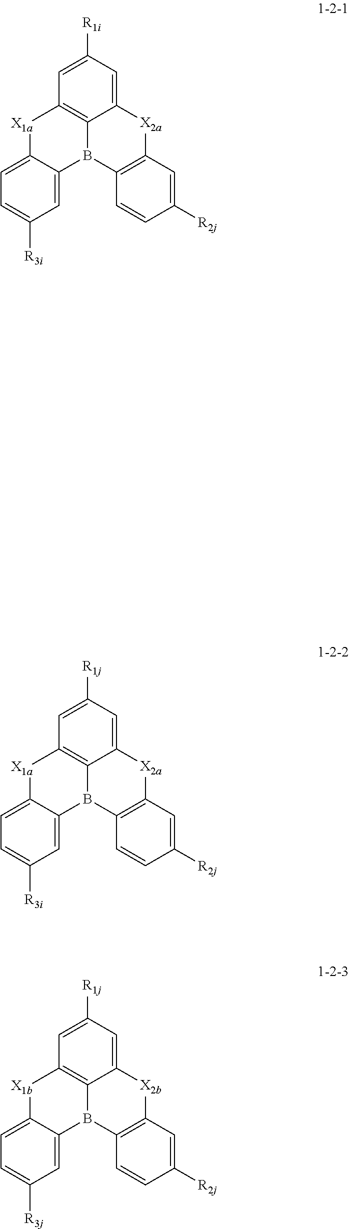
wherein in Formula 1-2-1 to Formula 1-2-3,
X₁ₐ and X₂ₐ are each independently N(R₄ⱼ) or O,
X_{1b} and X_{2b} are each independently N(R₄ᵢ) or O,
R₁ᵢ, R₃ᵢ, and R₄ᵢ are each independently a group represented by Formula 2, and
R₁ⱼ, R₂ⱼ, R₃ⱼ, and R₄ⱼ are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

8. The light emitting element of claim 5, wherein Formula 1-3 is represented by one of Formula 1-3-1 to Formula 1-3-4: 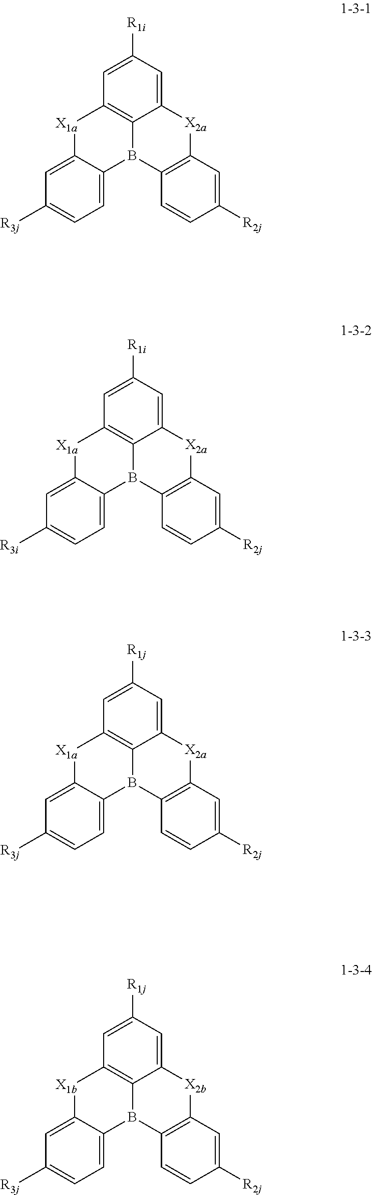
wherein in Formula 1-3-1 to Formula 1-3-4,
X₁ₐ and X₂ₐ are each independently N(R₄ⱼ) or O,
X_{1b} and X_{2b} are each independently N(R₄ᵢ) or O,
R_{1I}, R₃ᵢ, and R₄ᵢ are each independently a group represented by Formula 2, and
R₁ⱼ, R₂ⱼ, R₃ⱼ, and R₄ⱼ are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

9. The light emitting element of claim 1, wherein Formula 1 is represented by one of Formula 3-A to Formula 3-D: 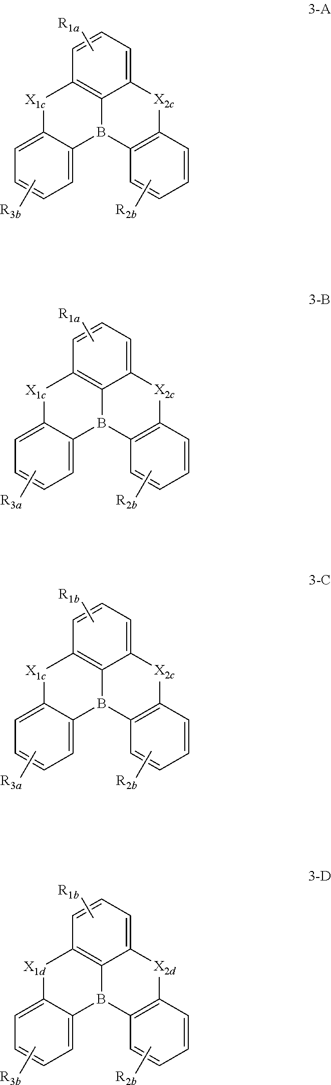
wherein in Formula 3-A to Formula 3-D,
X_{1c} and X_{2c} are each independently N(R_{4b}) or O,
X₁ₐ and X_{2d} are each independently N(R₄ₐ) or O,
R₁ₐ, R₃ₐ, and R₄ₐ are each independently a group represented by Formula 2, and
R_{1b}, R_{2b}, R_{3b}, and R_{4b} are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

10. The light emitting element of claim 1, wherein Formula 2 is represented by one of Formula 2-1 to Formula 2-4: 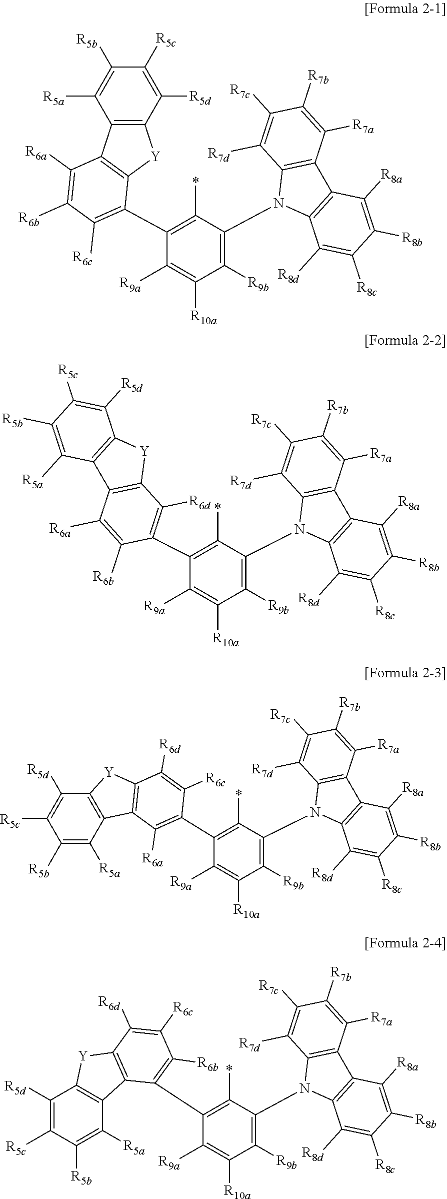
wherein in Formula 2-1 to Formula 2-4,
Y is O or S,
R₅ₐ to R_{5d}, R₆ₐ to R_{6d}, R₇ₐ to R_{7d}, R₈ₐ to R_{8d}, and R₁₀ₐ are each independently a hydrogen atom, a deuterium atom, a cyano group, or a substituted or unsubstituted alkyl group having 1 to 10 carbon atoms, and
R₉ₐ and R_{9b} are each independently a hydrogen atom or a deuterium atom.

11. The light emitting element of claim 1, wherein the emission layer comprises the first compound, the second compound, and the third compound.

12. The light emitting element of claim 2, wherein the emission layer comprises the first compound, the second compound, the third compound, and the fourth compound.

13. The light emitting element of claim 1, wherein the emission layer emits thermally activated delayed fluorescence.

14. The light emitting element of claim 1, wherein the emission layer emits light having a central wavelength in a range of about 430 nm to about 490 nm.

15. The light emitting element of claim 1, wherein the first compound is selected from Compound Group 1: 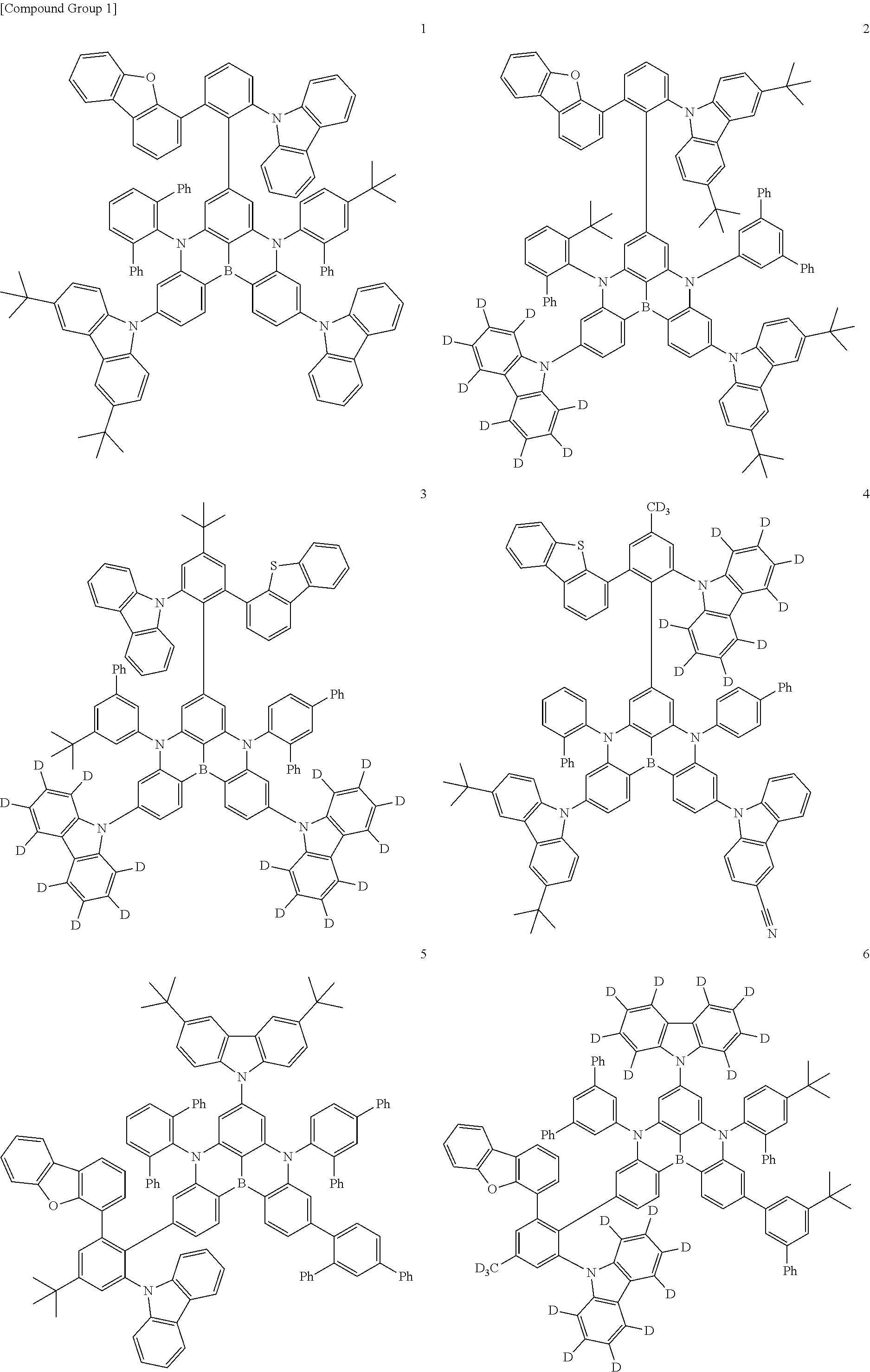 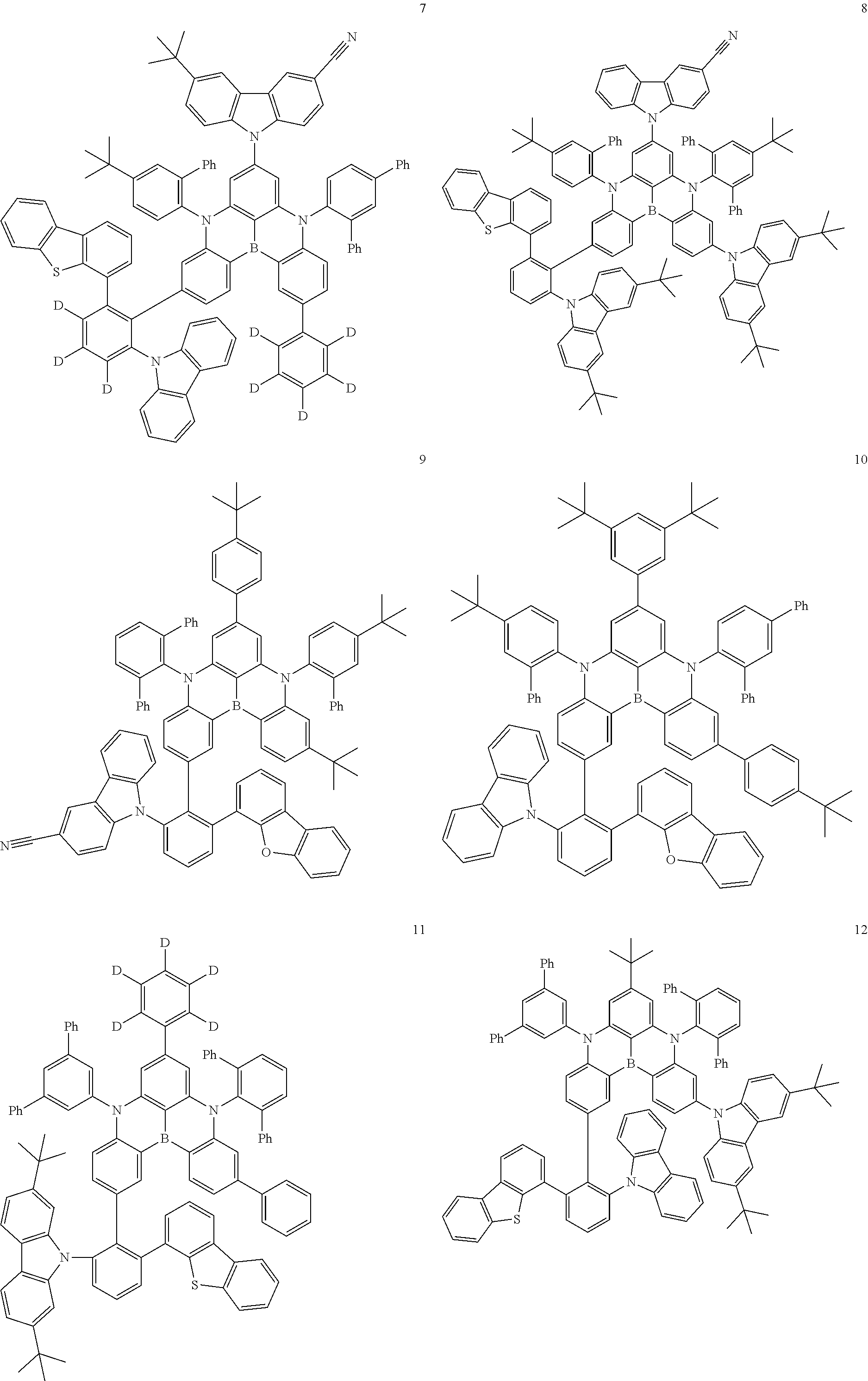 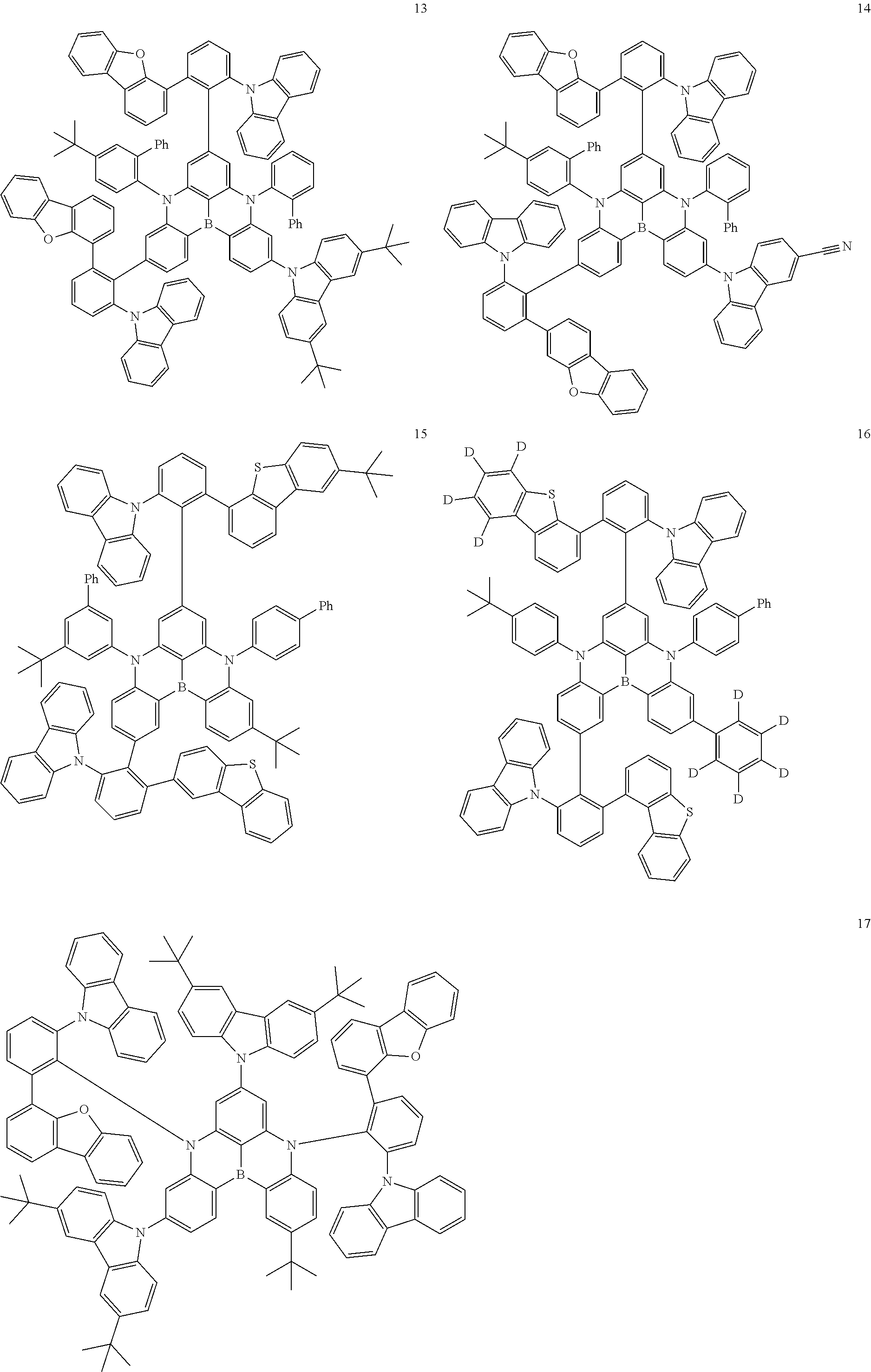 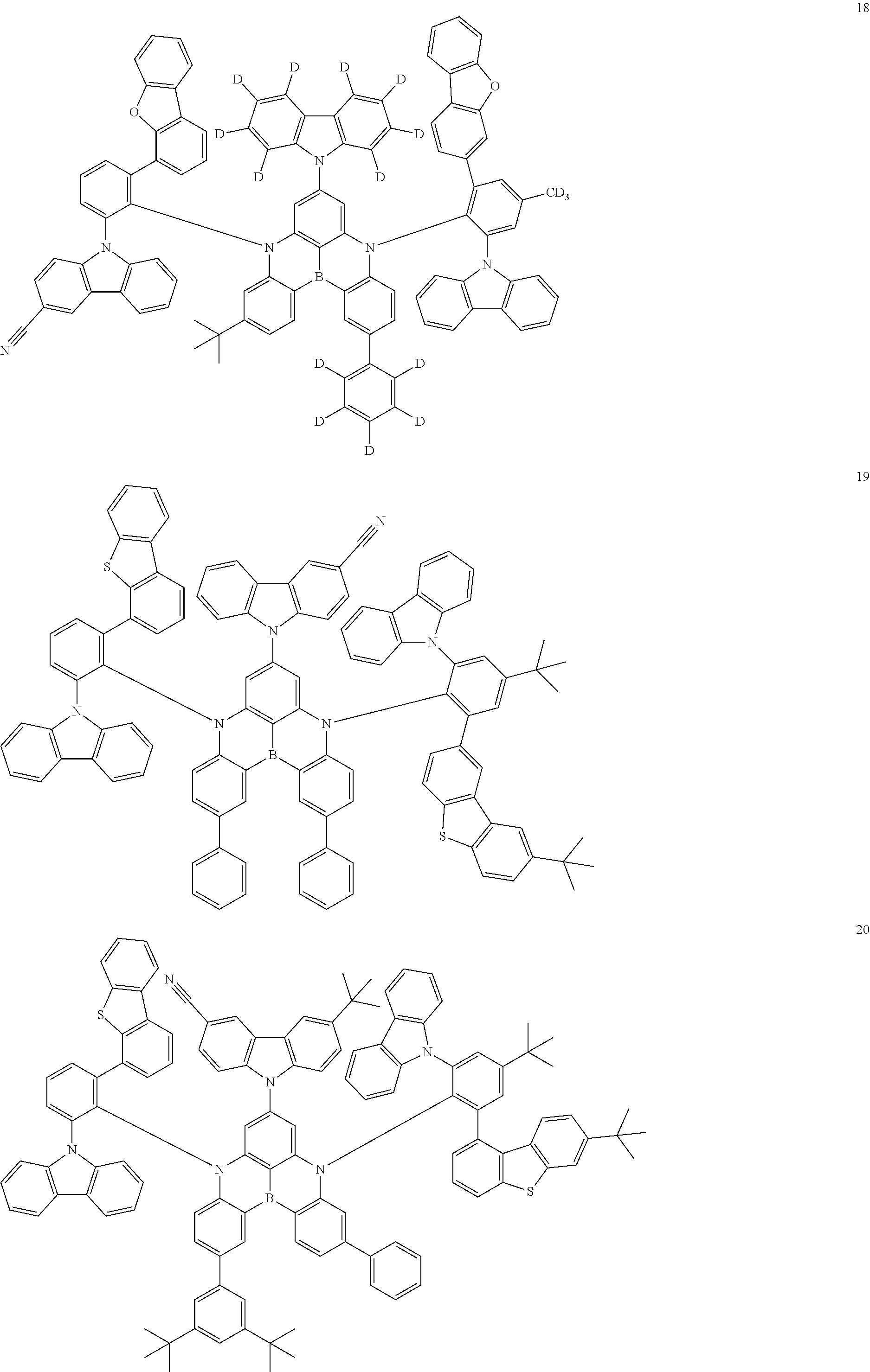 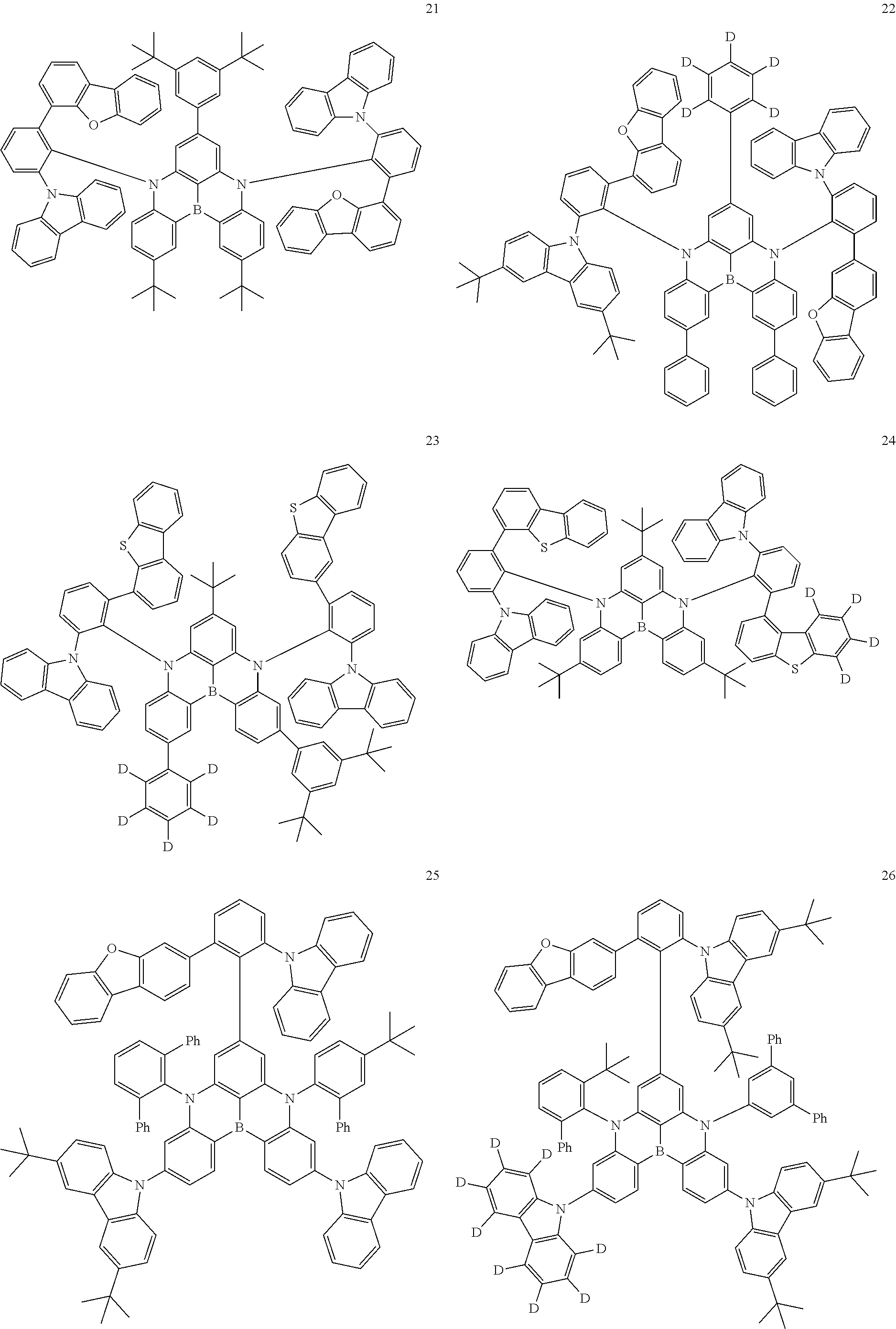 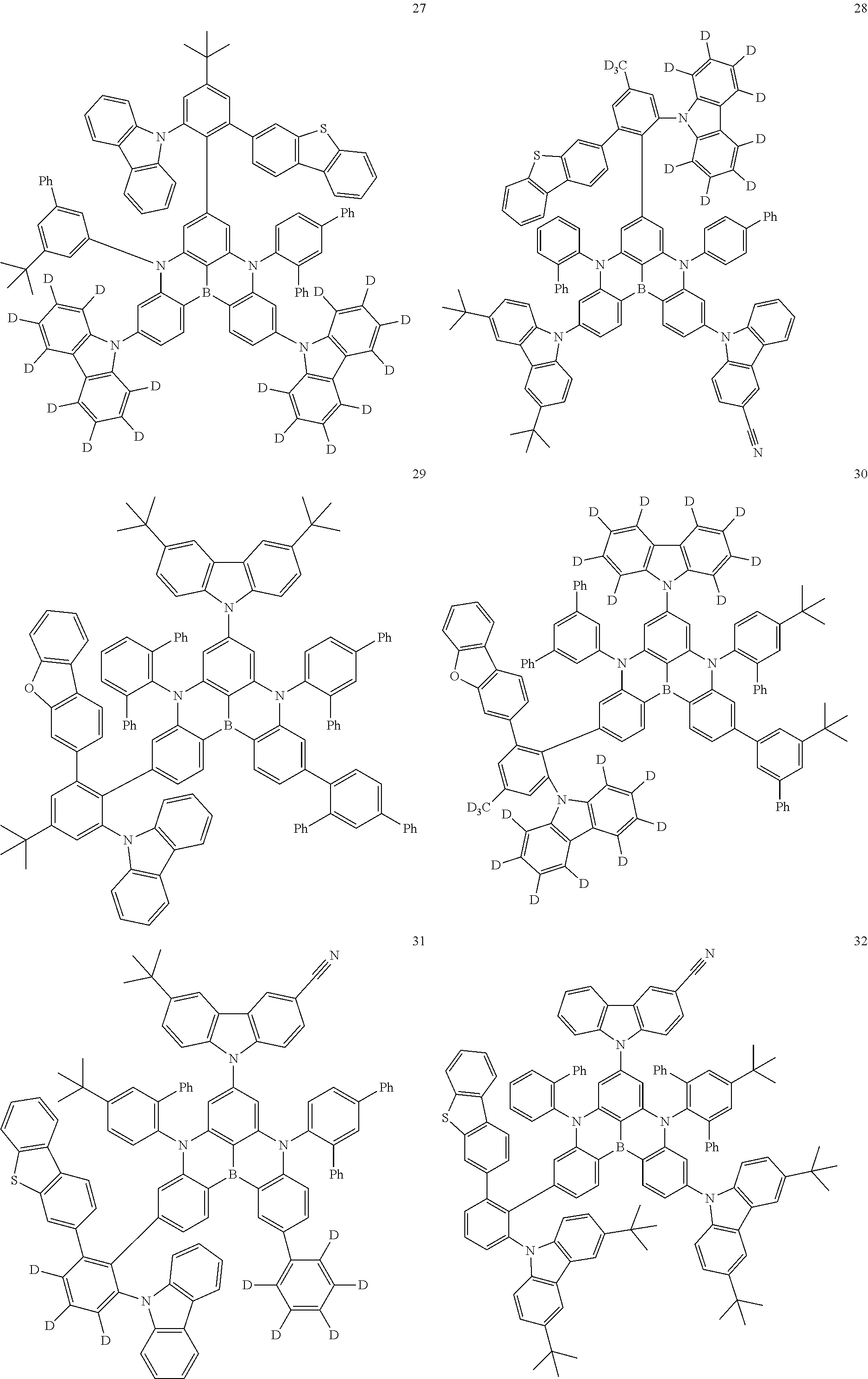 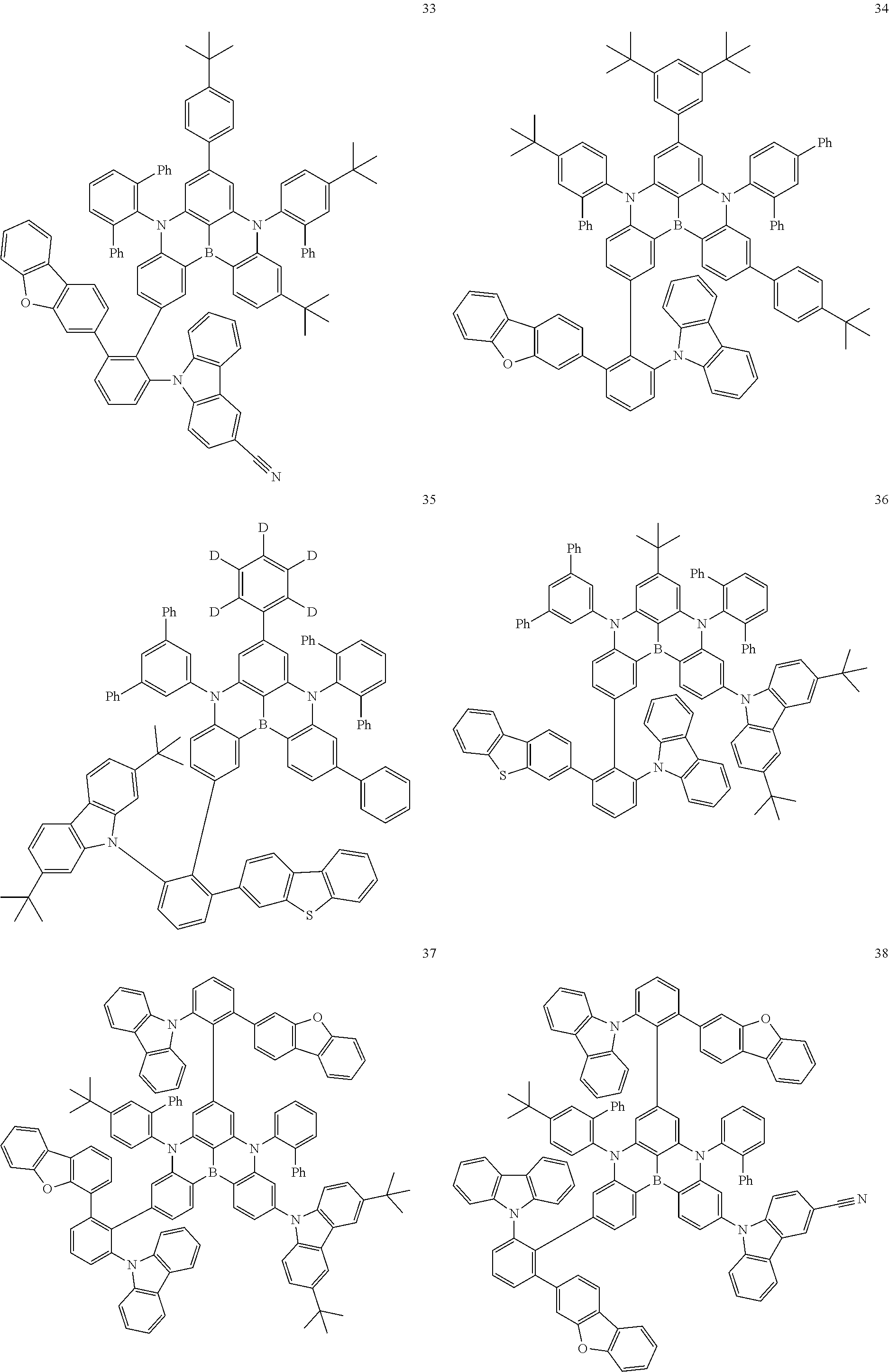 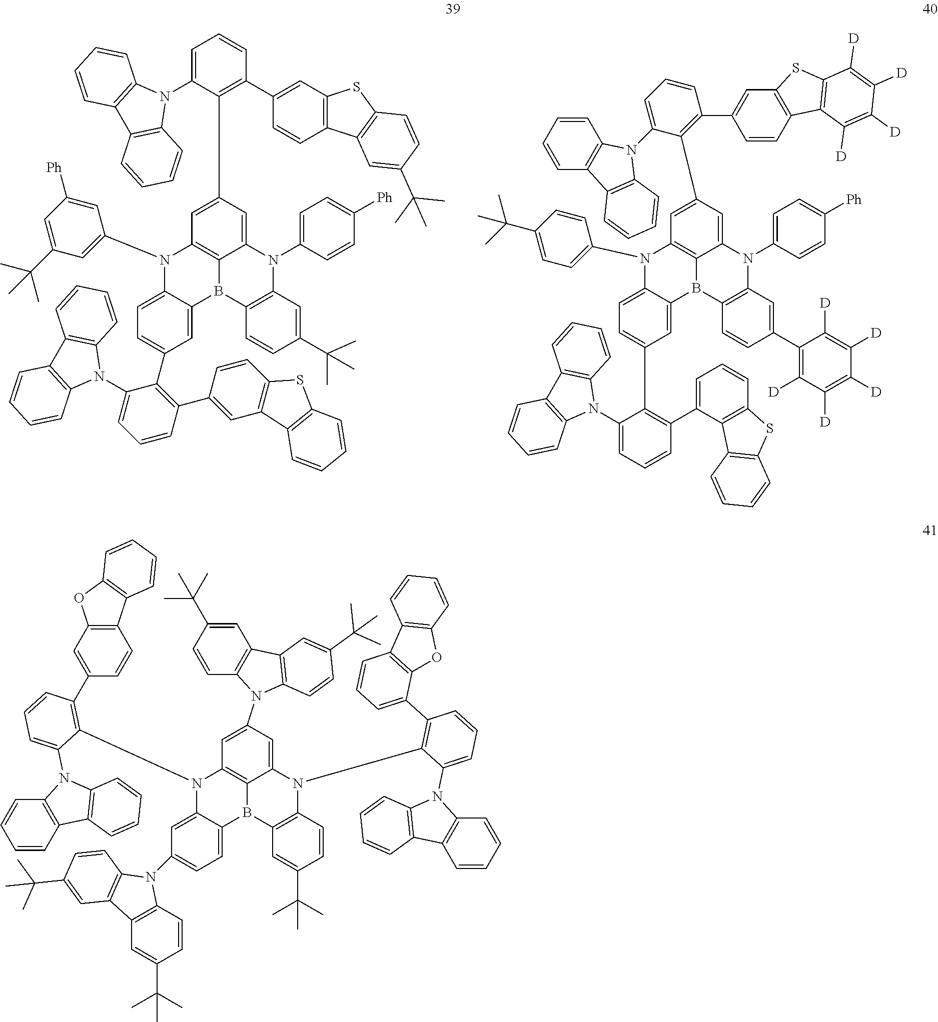 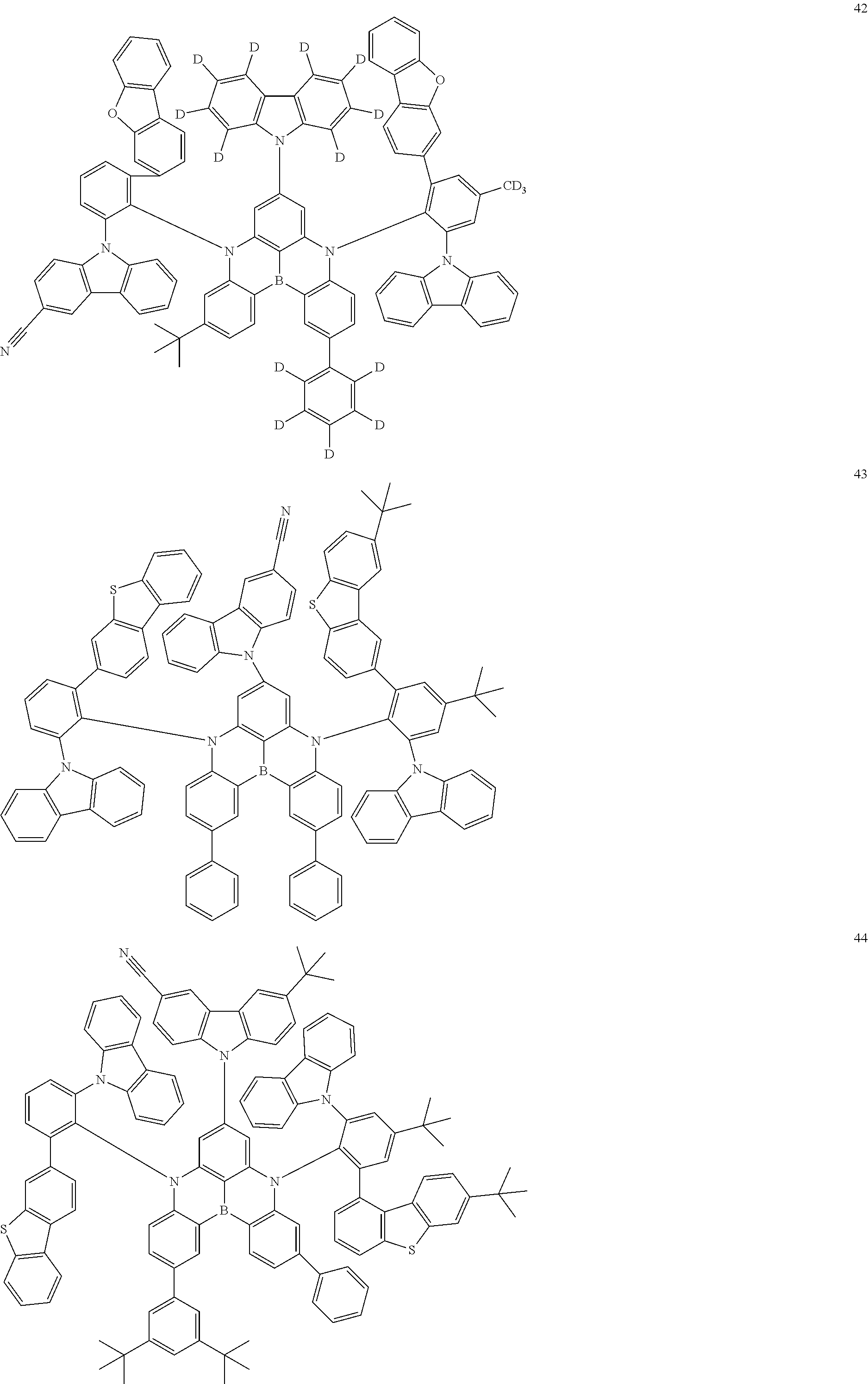 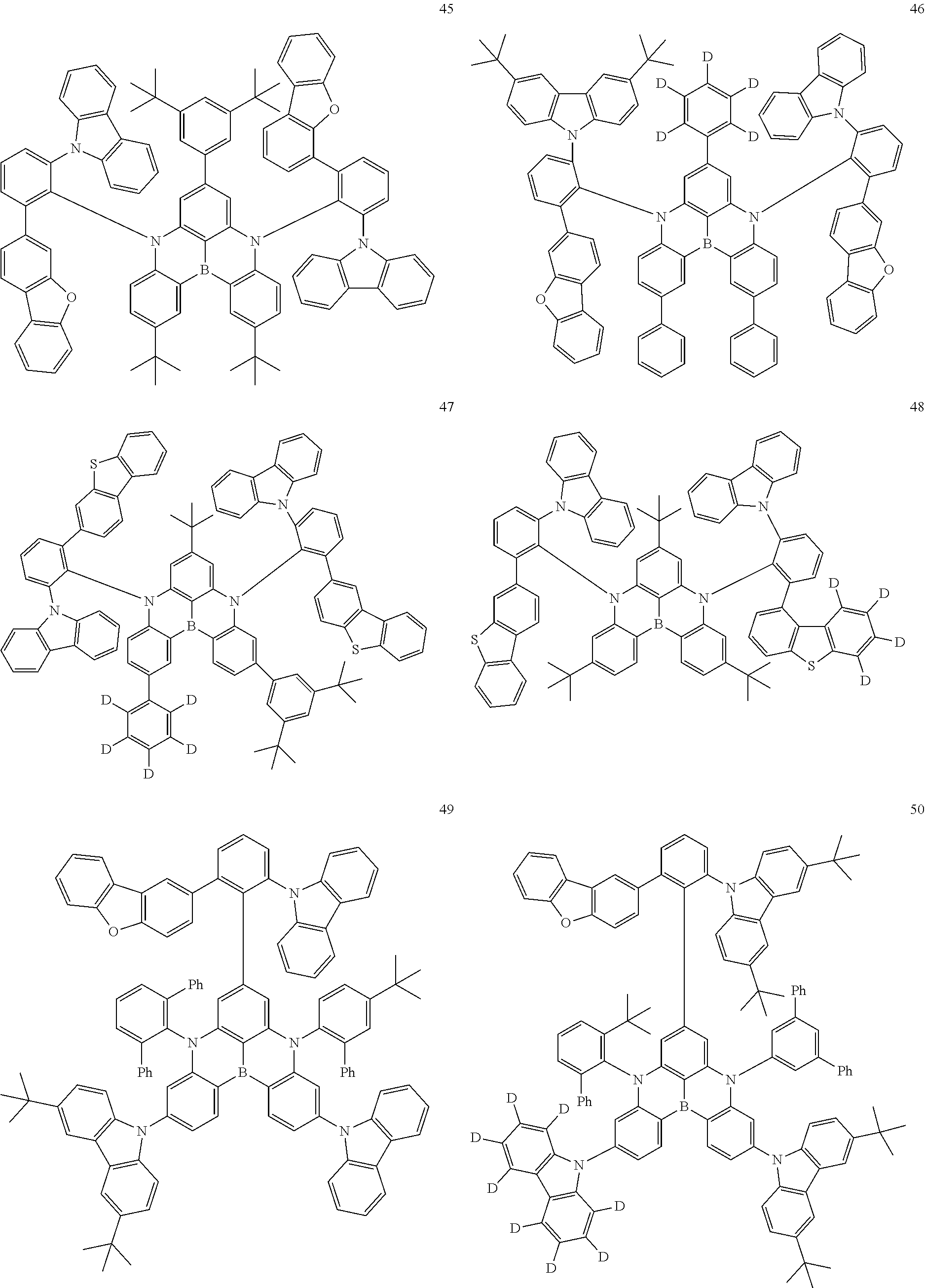 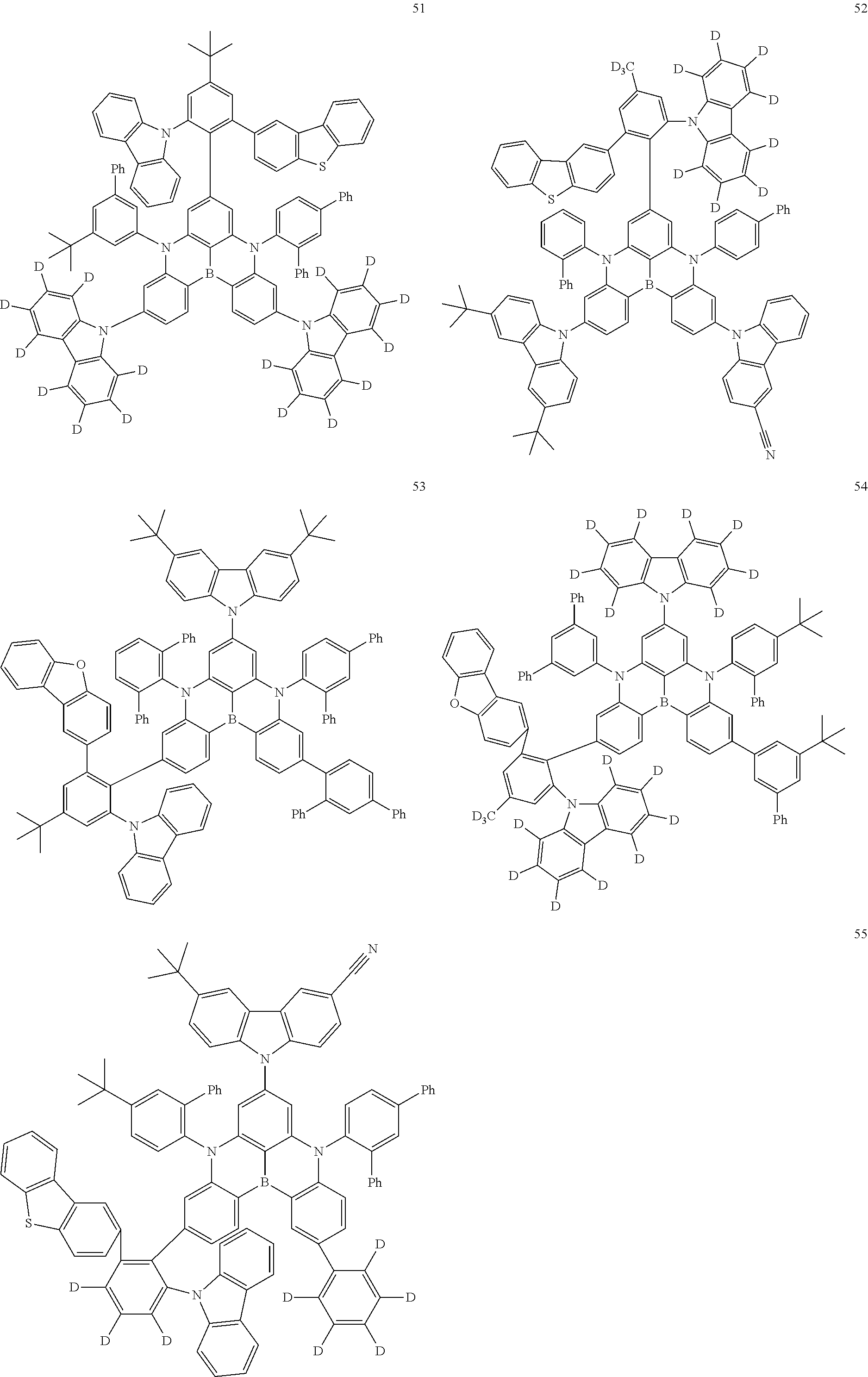 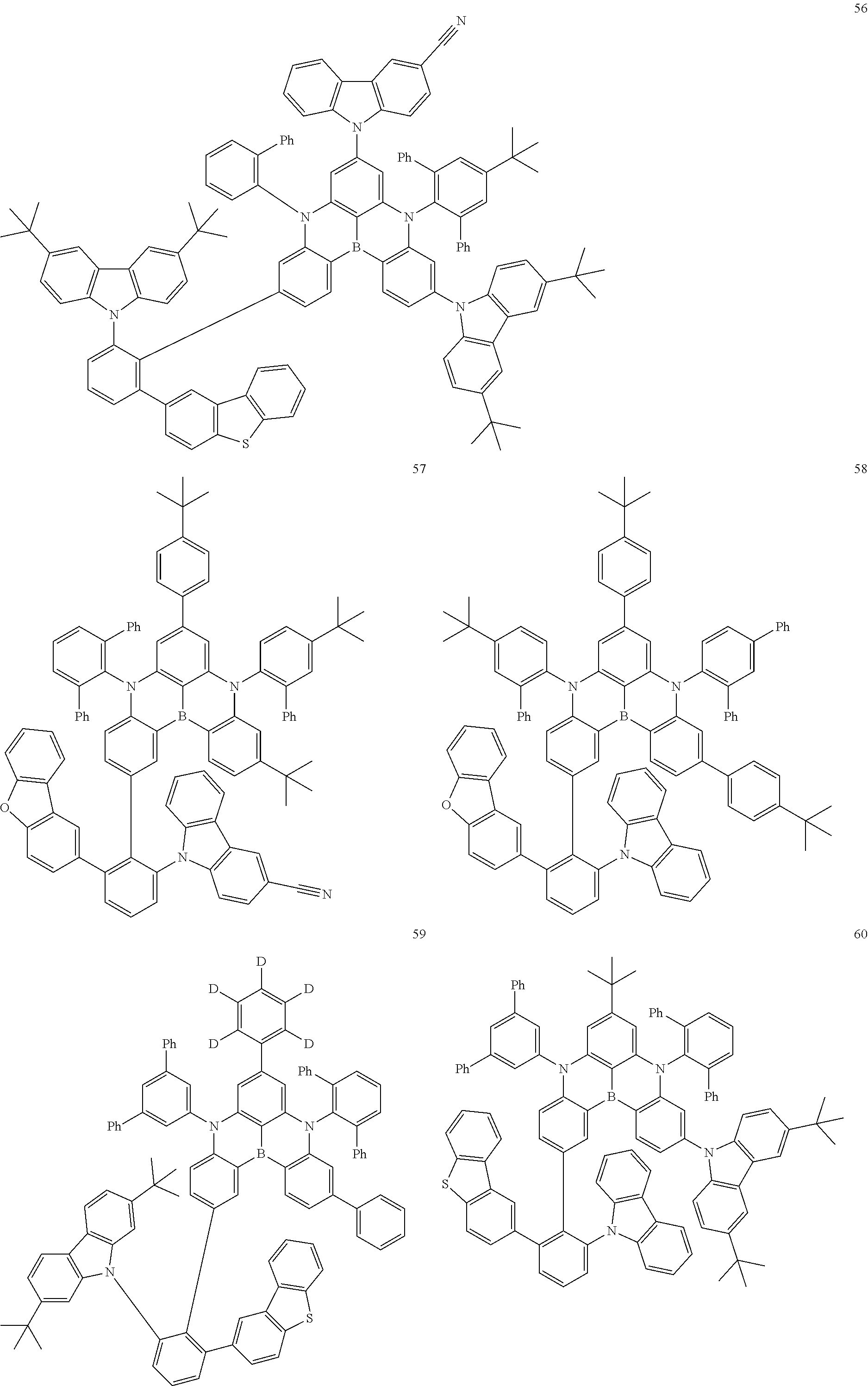 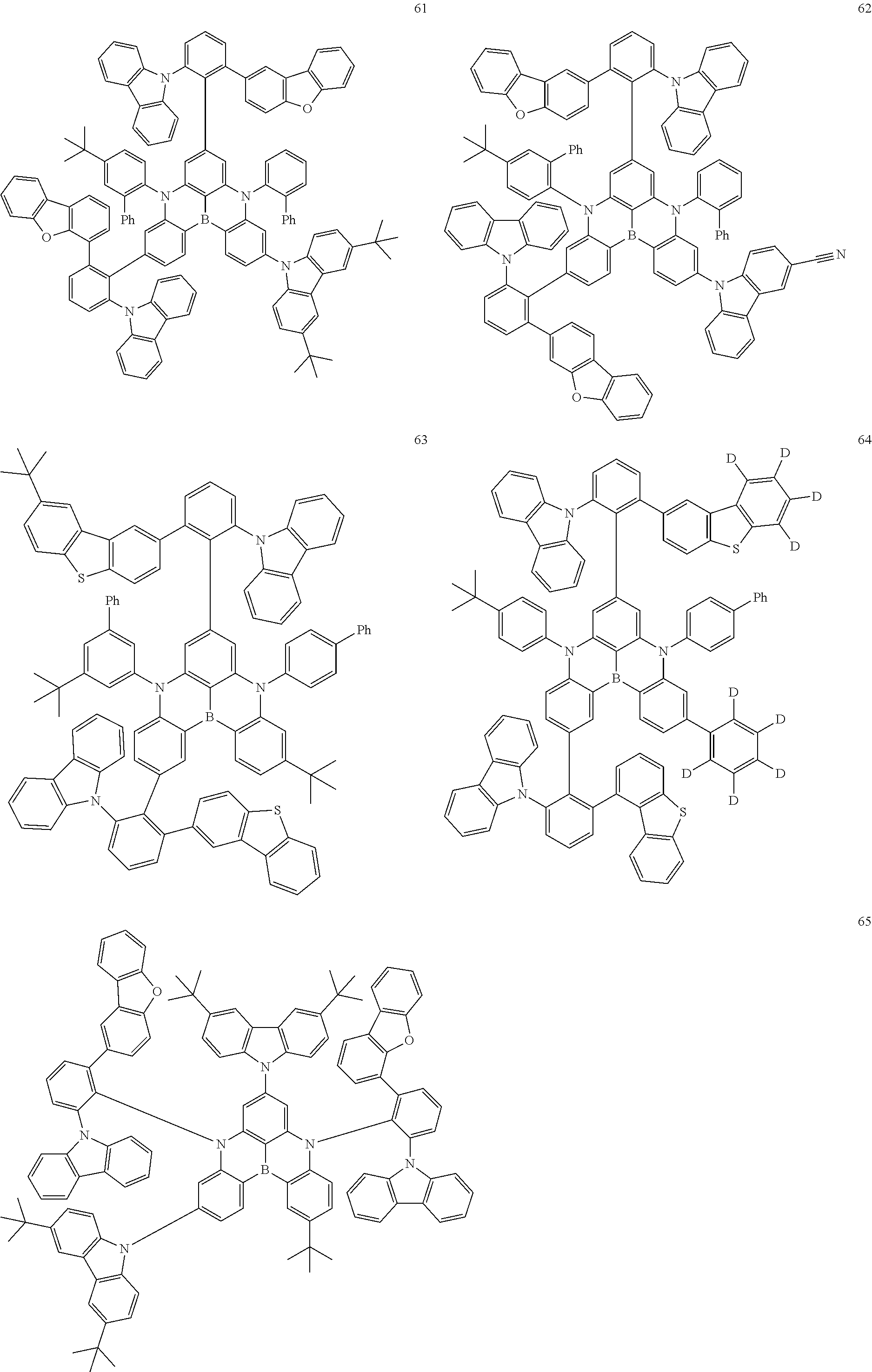 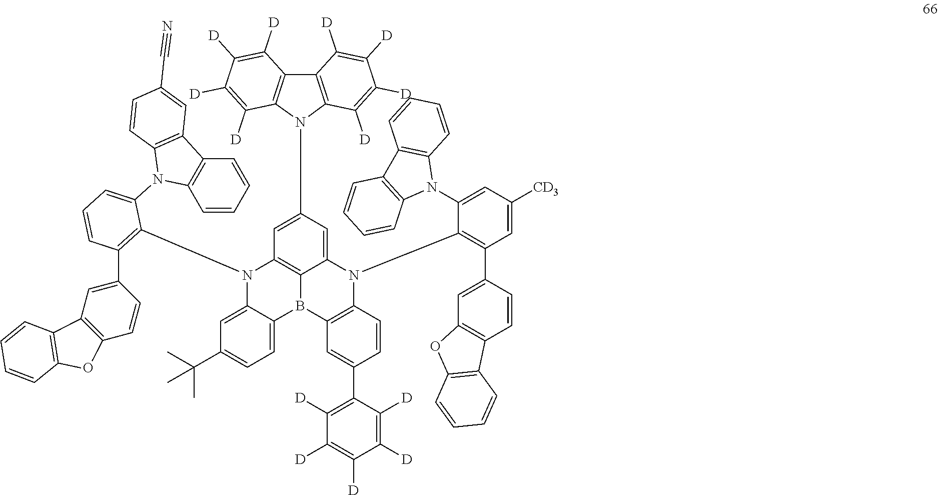 [SMILES: [2H]c1c([2H])c([2H])c(-c2ccc3c(c2)B2c4ccc(C(C)(C)C)cc4N(c4c(-c5ccc6oc7ccccc7c6c5)cccc4-n4c5ccccc5c5cc(C#N)ccc54)c4cc(-n5c6c([2H])c([2H])c([2H])c([2H])c6c6c([2H])c([2H])c([2H])c([2H])c65)cc(c42)N3c2c(-c3ccc4c(c3)oc3ccccc34)cc(C([2H])([2H])[2H])cc2-n2c3ccccc3c3ccccc32)c([2H])c1[2H]] 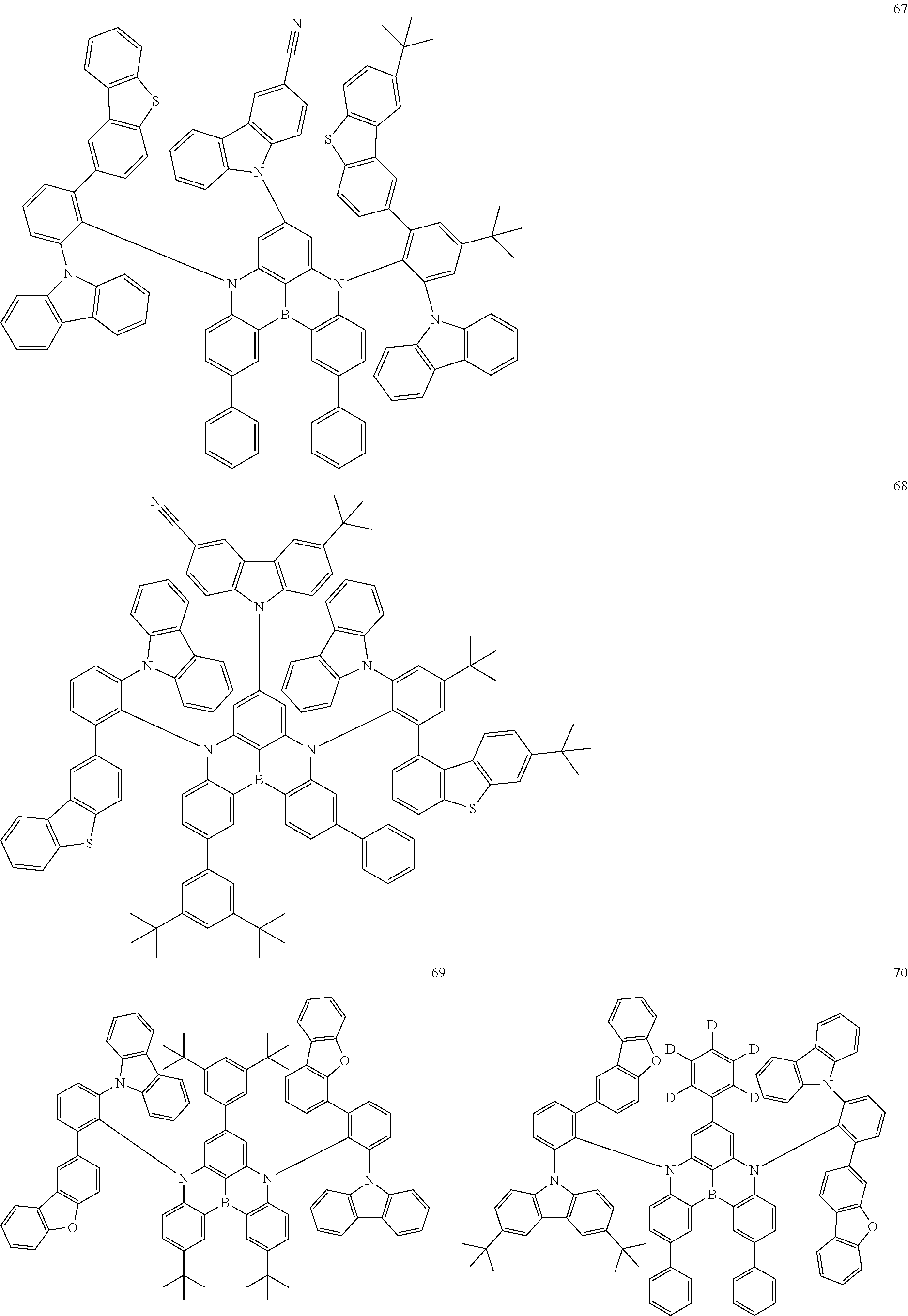 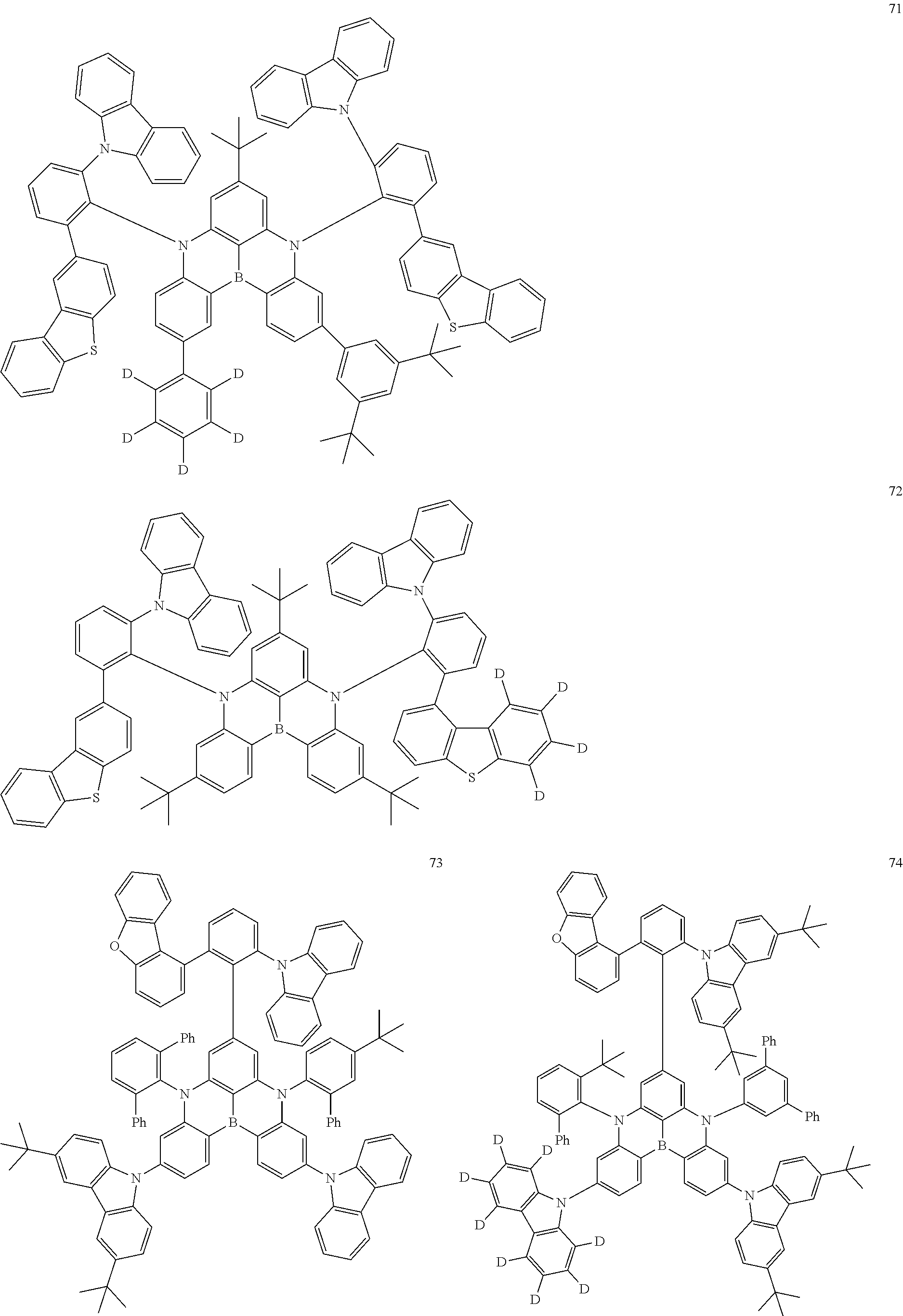 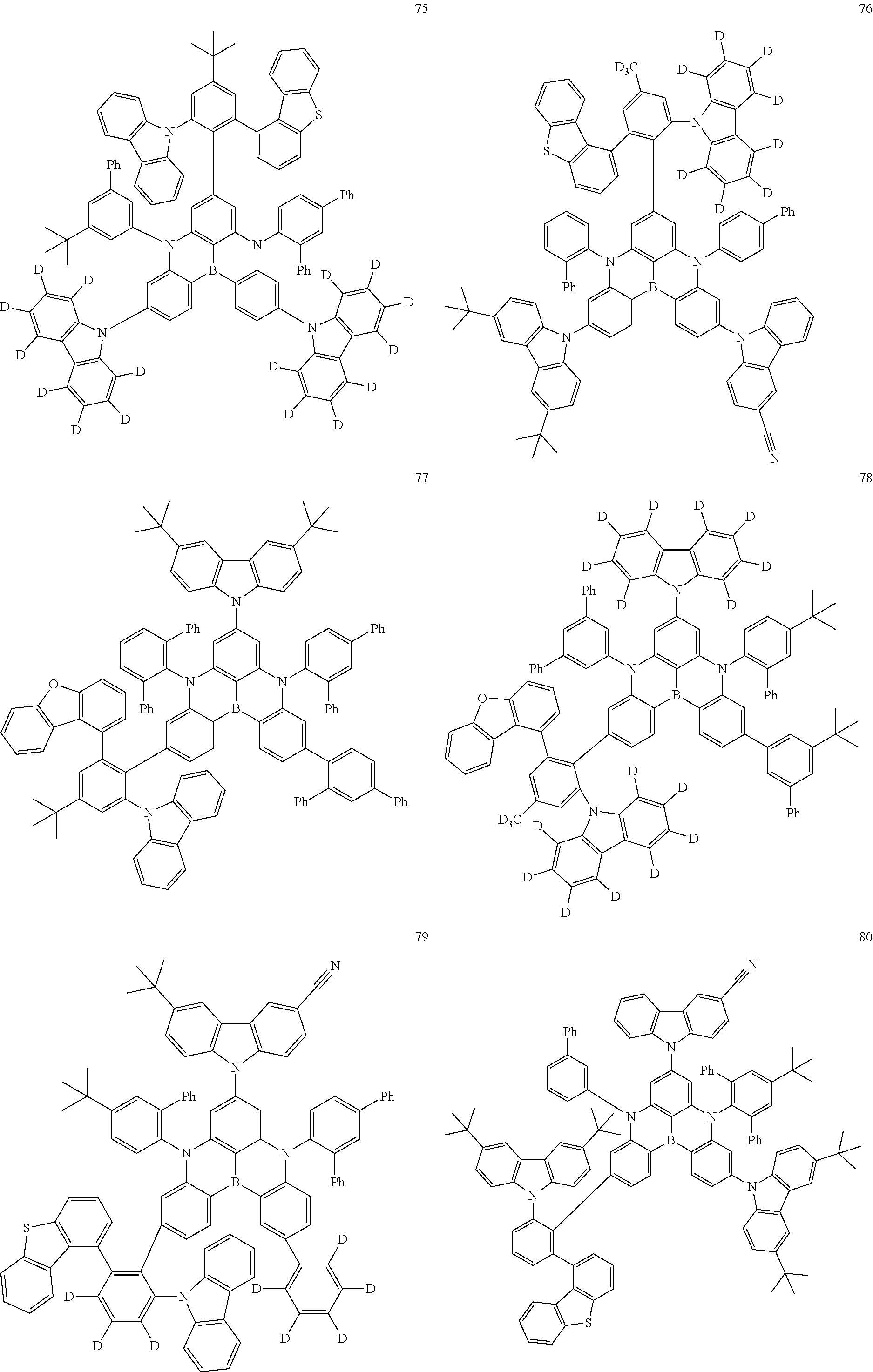 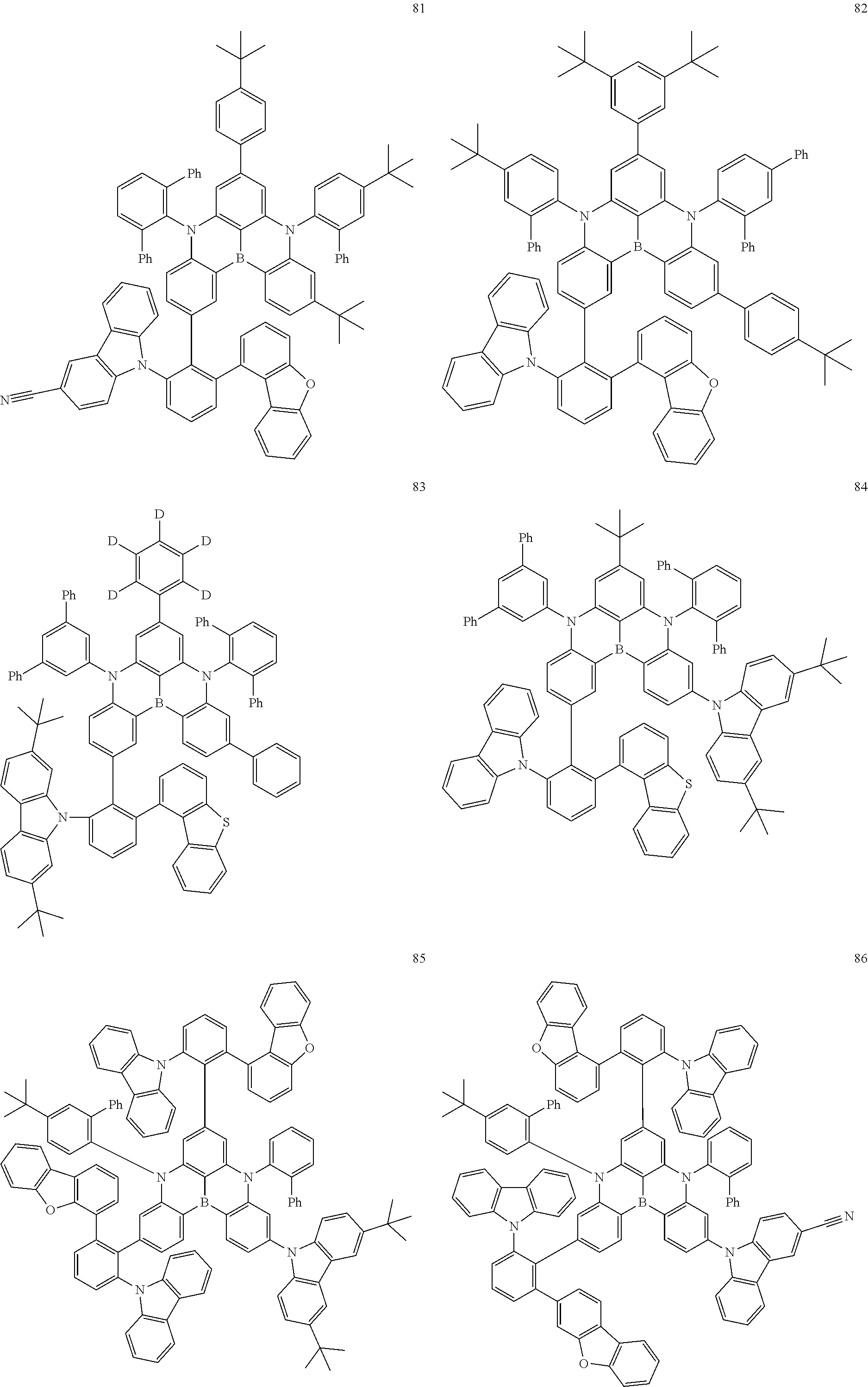 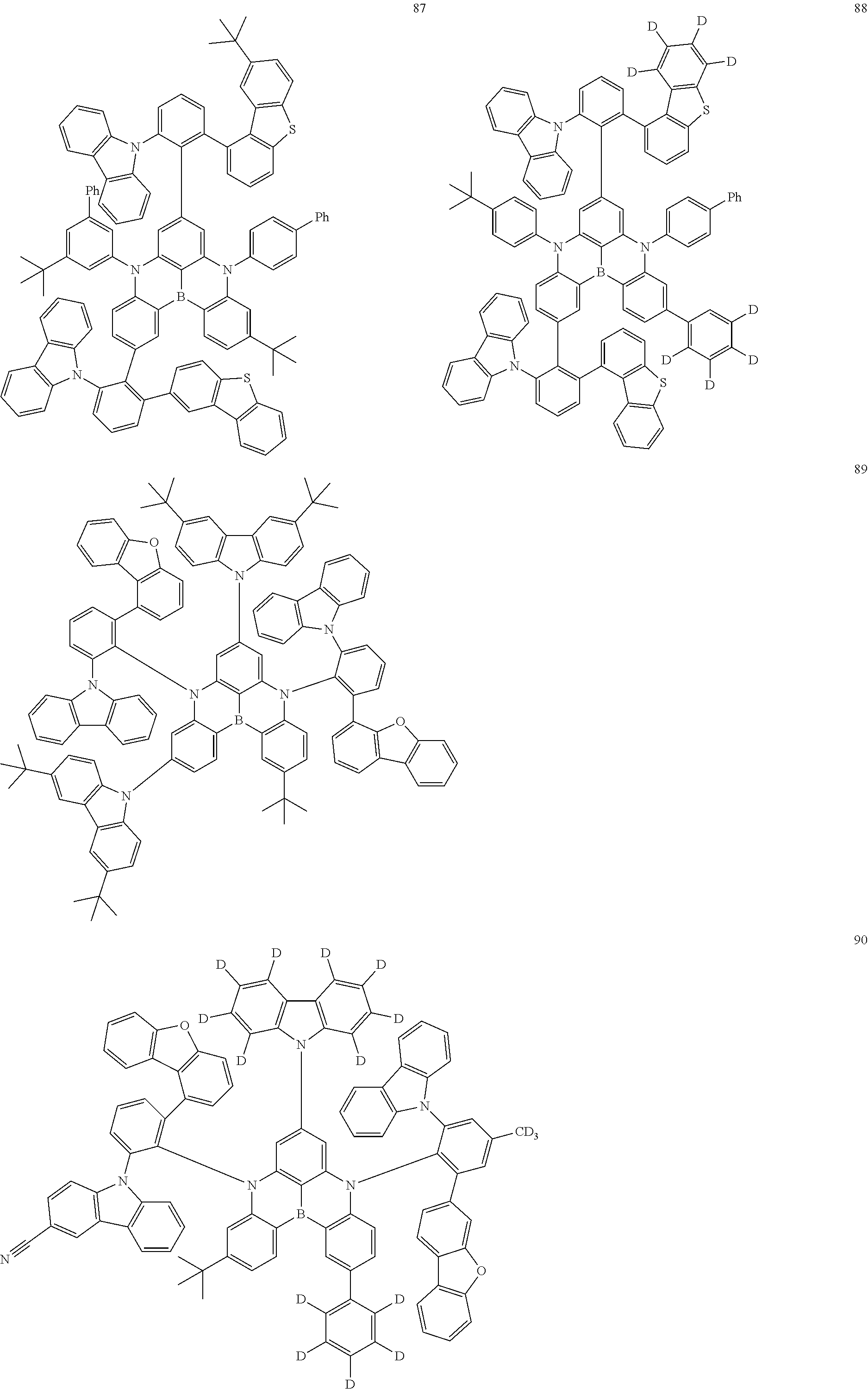 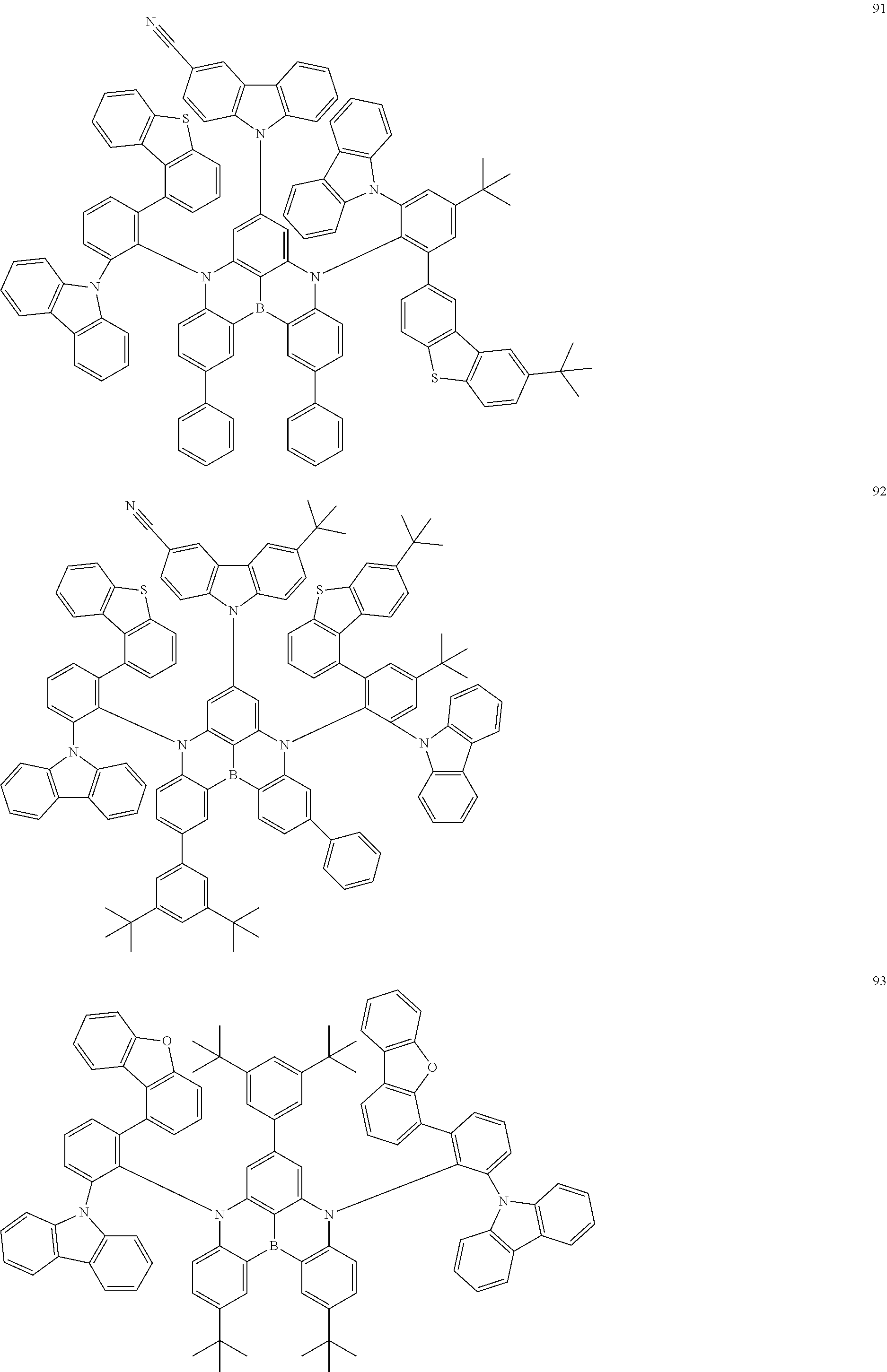 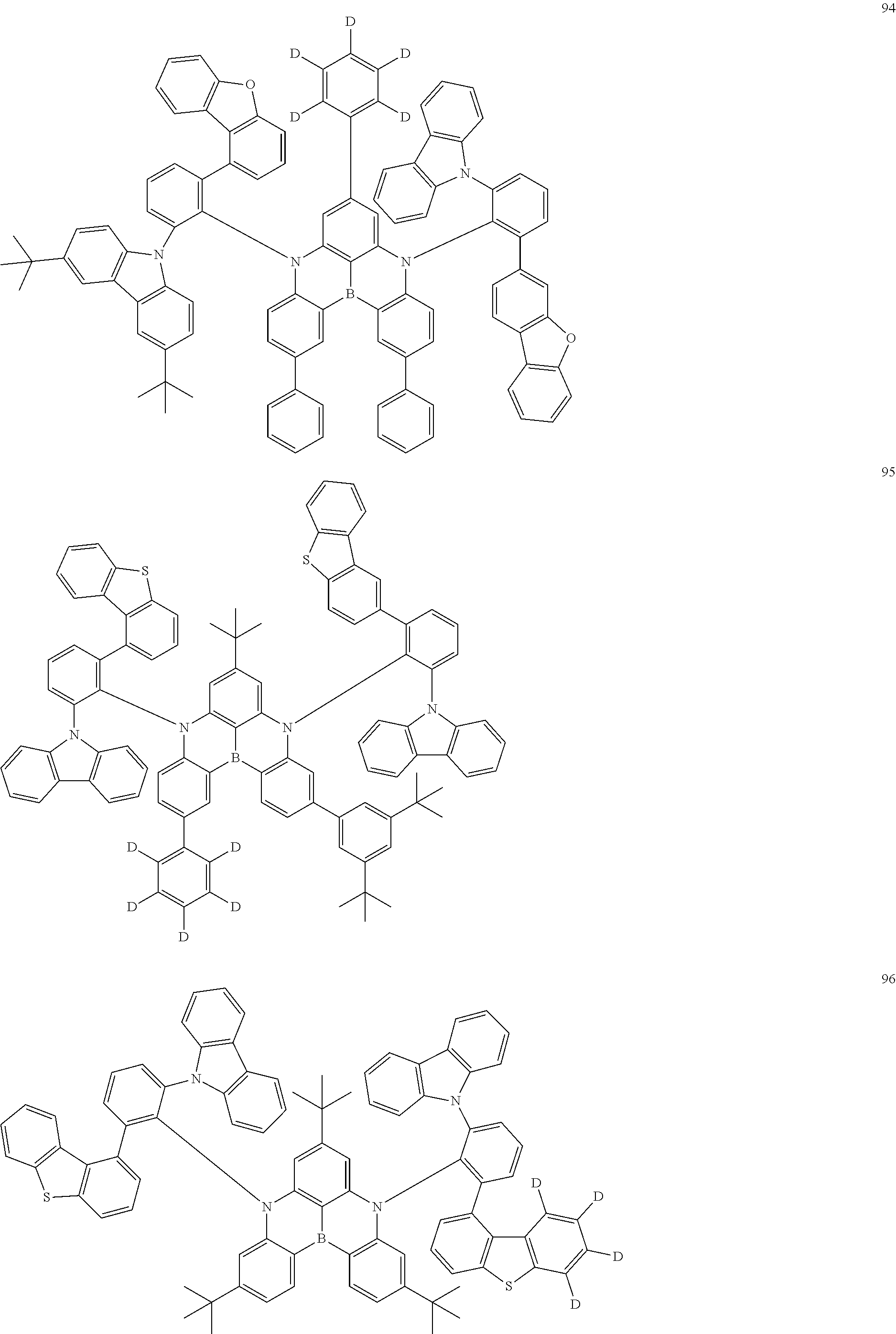 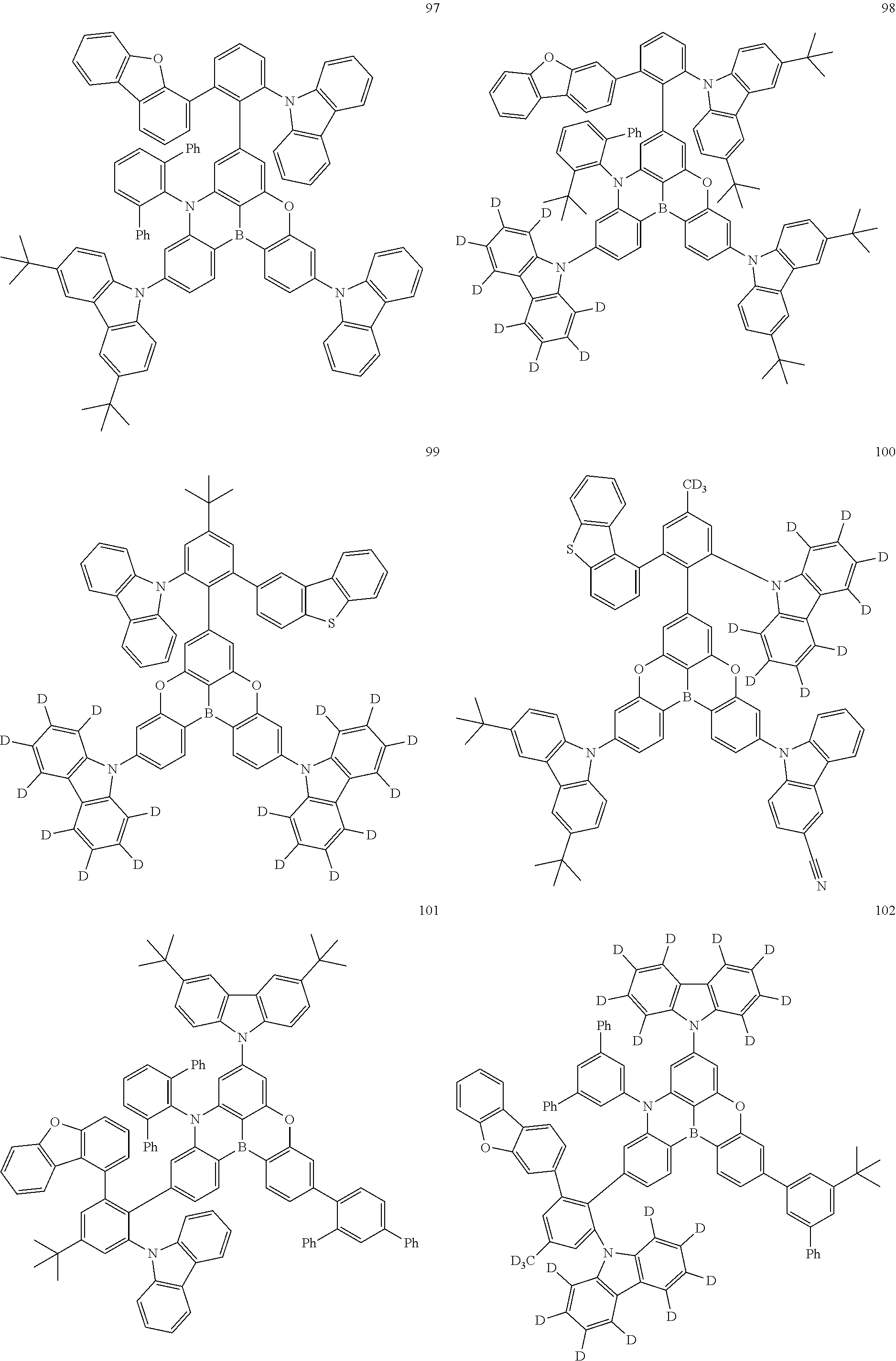 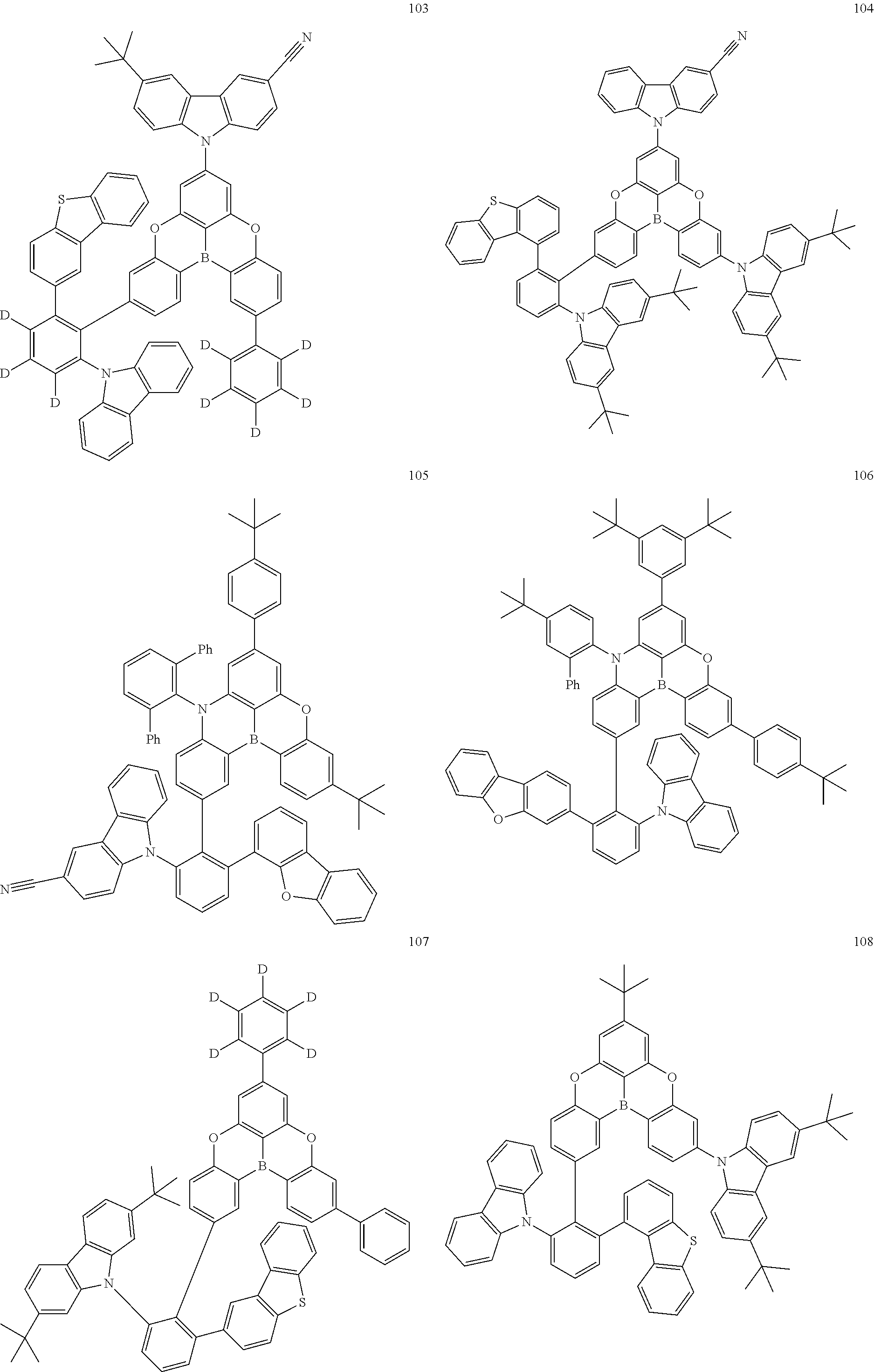 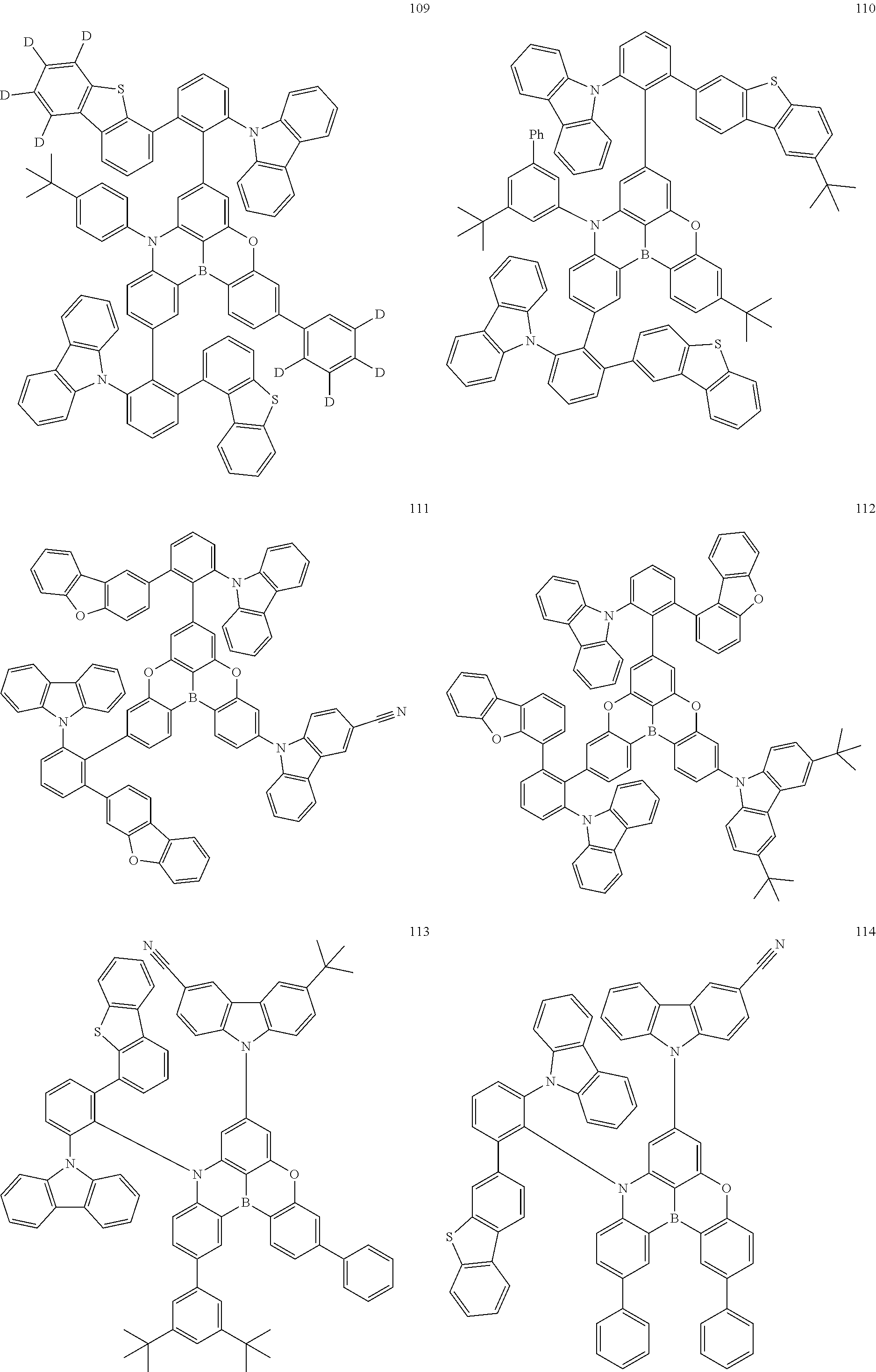 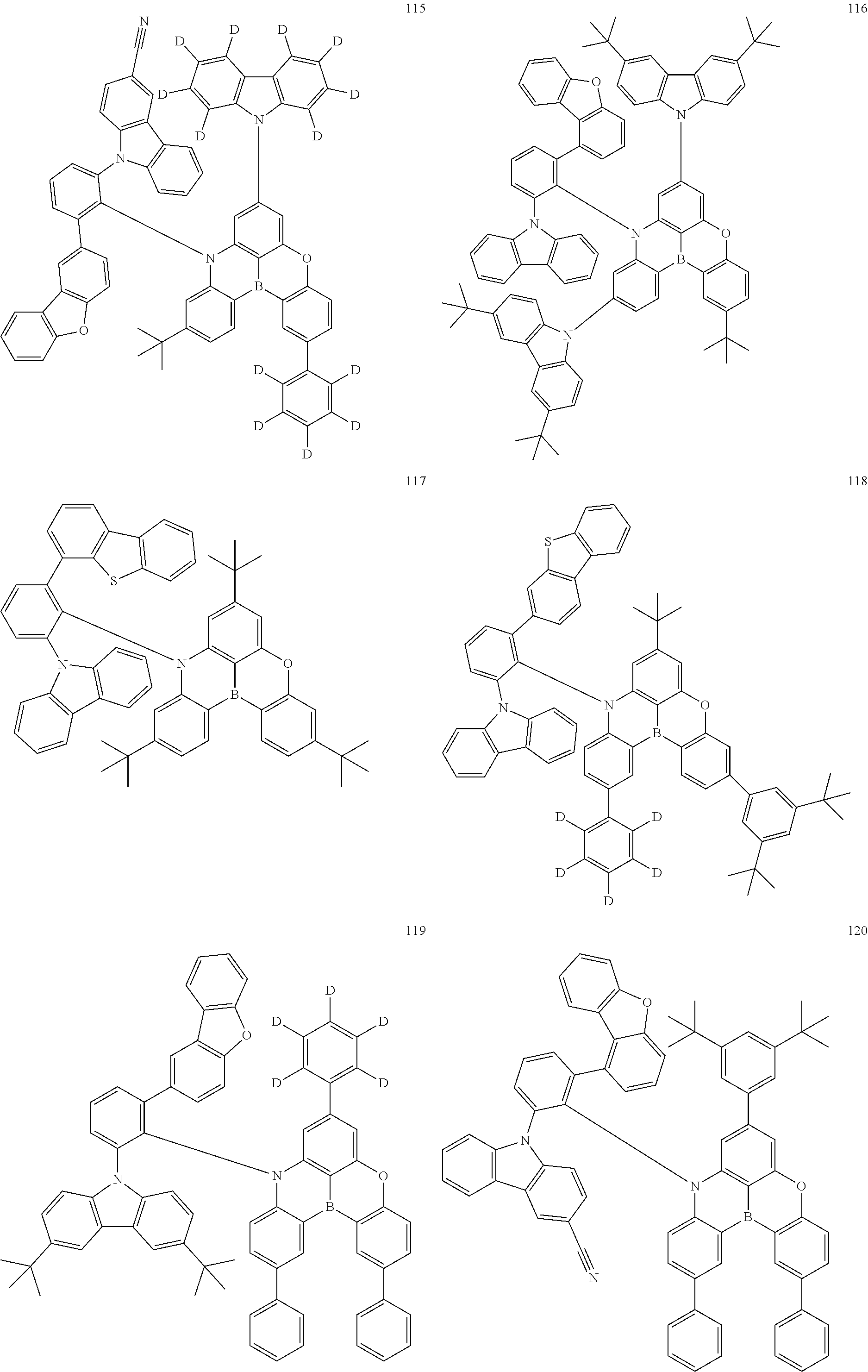 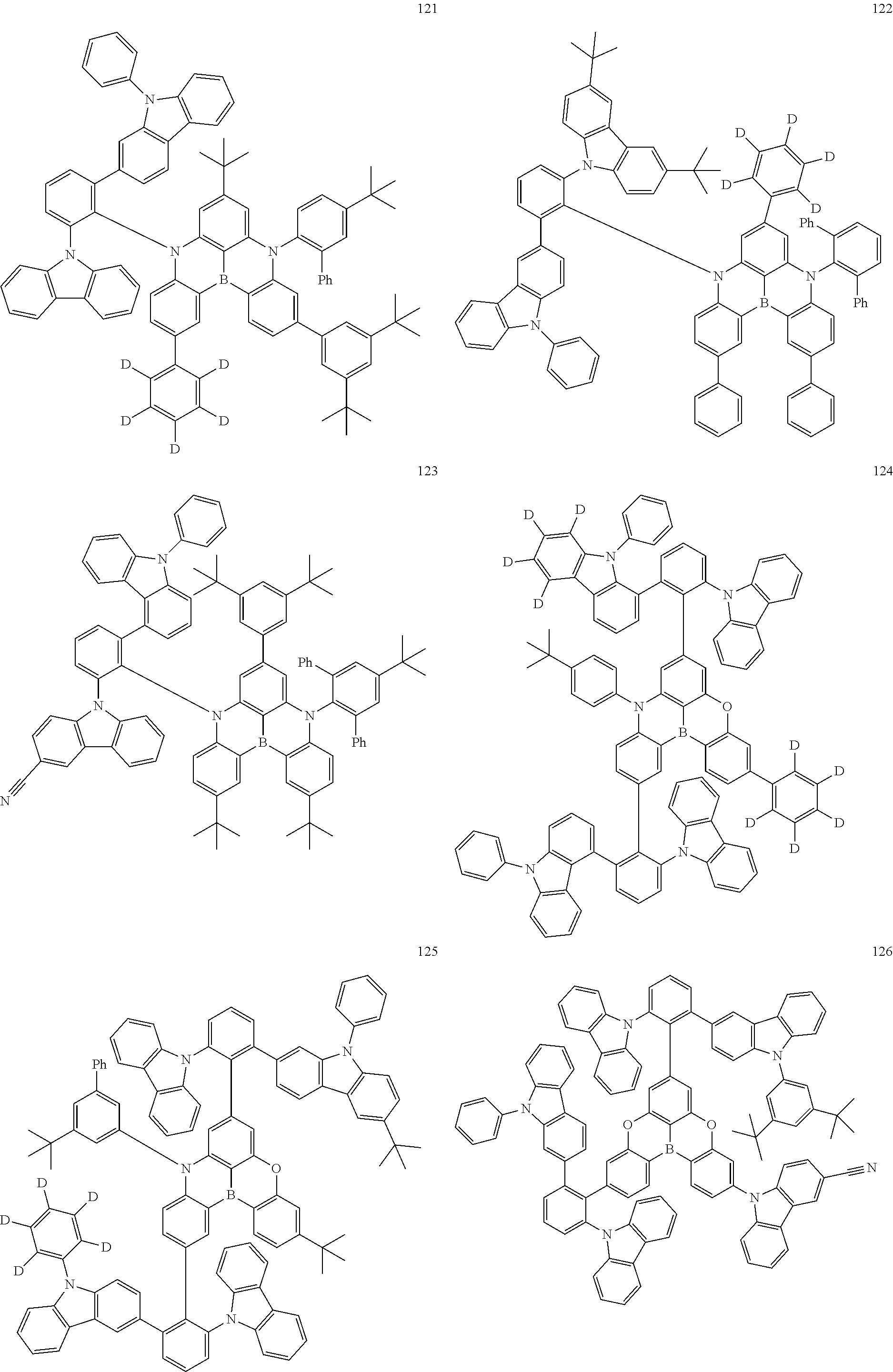 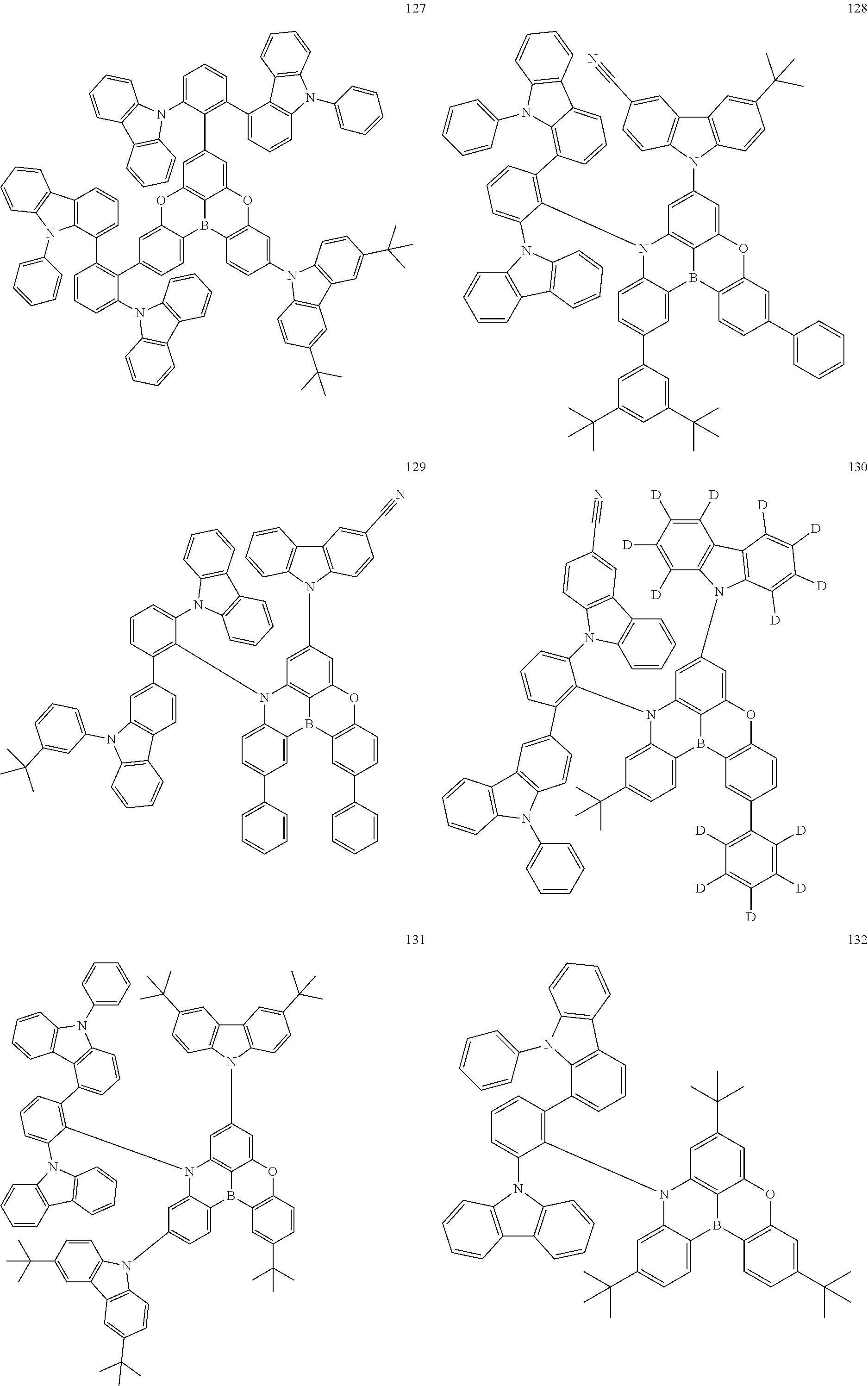
wherein in Compound Group 1,
Ph is a phenyl group, and
D is a deuterium atom.

16. A polycyclic compound represented by Formula 1: 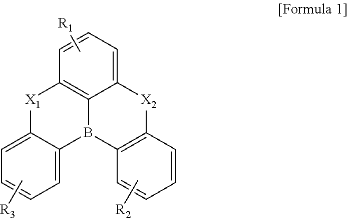
wherein in Formula 1,
X₁ and X₂ are each independently N(R₄) or O,
one or two of R₁ to R₄ are each independently a group represented by Formula 2, and
the remainder of R₁ to R₄ are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms, 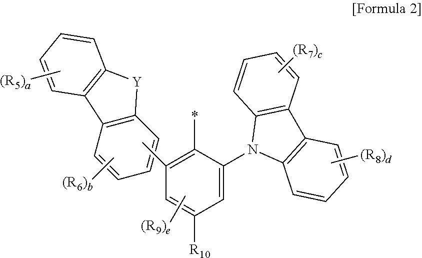
wherein in Formula 2,
Y is N(R₁₁), O, or S,
R₅ to R₈, R₁₀, and R₁₁ are each independently a hydrogen atom, a deuterium atom, a halogen atom, a cyano group, a substituted or unsubstituted amine group, a substituted or unsubstituted silyl group, a substituted or unsubstituted alkyl group having 1 to 10 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted aryl group having 6 to 60 ring-forming carbon atoms, or a substituted or unsubstituted heteroaryl group having 2 to 60 ring-forming carbon atoms,
R₉ is a hydrogen atom or a deuterium atom,
a, c, and d are each independently an integer from 0 to 4,
b is an integer from 0 to 3, and
e is an integer from 0 to 2.

17. The polycyclic compound of claim 16, wherein Formula 1 is represented by one of Formula 1-1 to Formula 1-3: 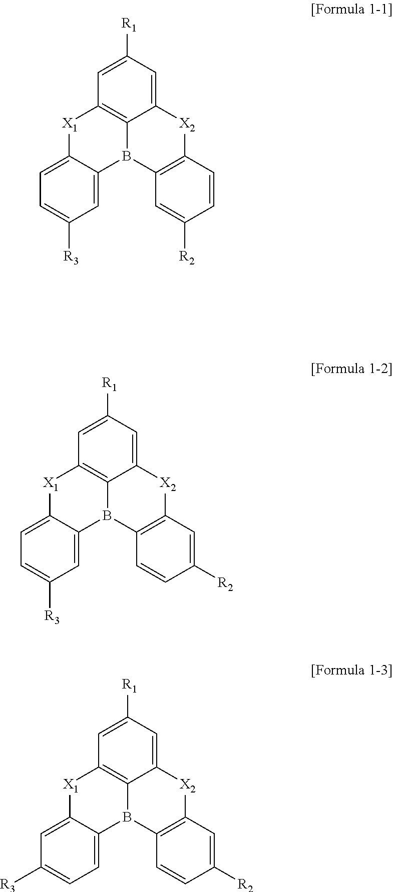
wherein in Formula 1-1 to Formula 1-3,
R₁ to R₃, X₁, and X₂ are each the same as defined in Formula 1 above.

18. The polycyclic compound of claim 17, wherein Formula 1-1 is represented by one of Formula 1-1-1 to Formula 1-1-4: 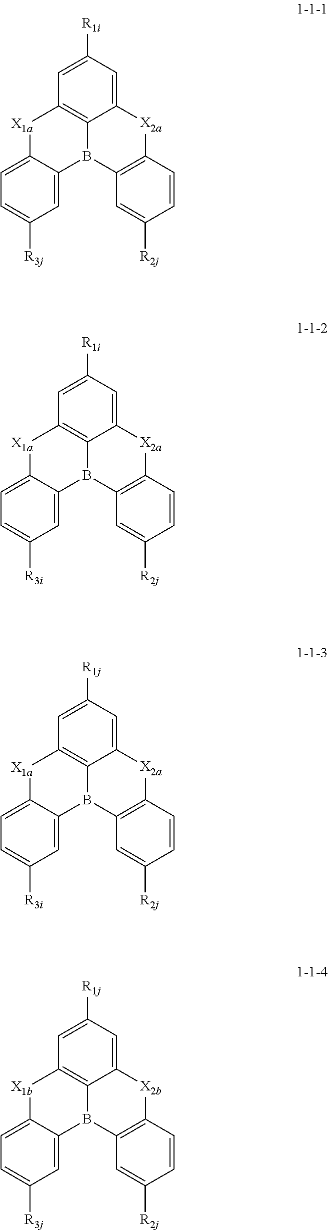
wherein in Formula 1-1-1 to Formula 1-1-4,
X₁ₐ and X₂ₐ are each independently N(R₄ⱼ) or O,
X_{1b} and X_{2b} are each independently N(R₄ᵢ) or O,
R₁ᵢ, R₃ᵢ, and R₄ᵢ are each independently a group represented by Formula 2, and
R₁ⱼ, R₂ⱼ, R₃ⱼ, and R₄ⱼ are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

19. The polycyclic compound of claim 17, wherein Formula 1-2 is represented by one of Formula 1-2-1 to Formula 1-2-3: 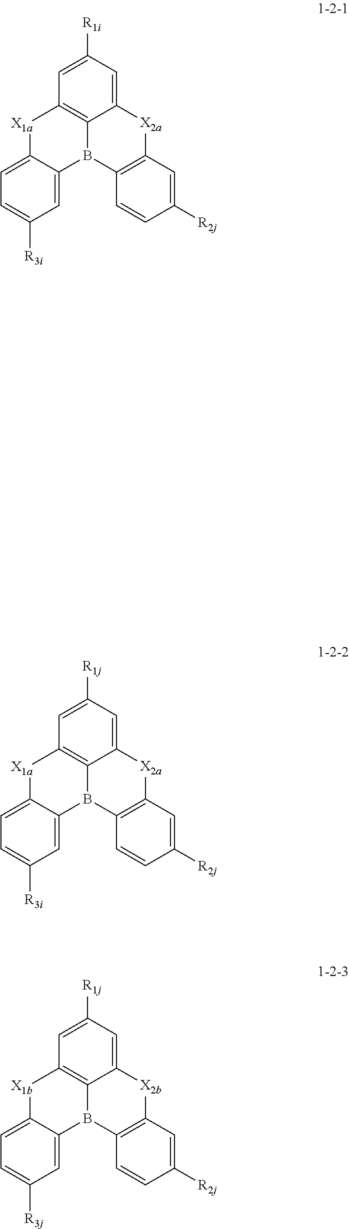
wherein in Formula 1-2-1 to Formula 1-2-3,
X₁ₐ and X₂ₐ are each independently N(R₄ⱼ) or O,
X_{1b} and X_{2b} are each independently N(R₄ᵢ) or O,
R₁ᵢ, R₃ᵢ, and R₄ᵢ are each independently a group represented by Formula 2, and
R₁ⱼ, R₂ⱼ, R₃ⱼ, and R₄ⱼ are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

20. The polycyclic compound of claim 17, wherein Formula 1-3 is represented by one of Formula 1-3-1 to Formula 1-3-4: 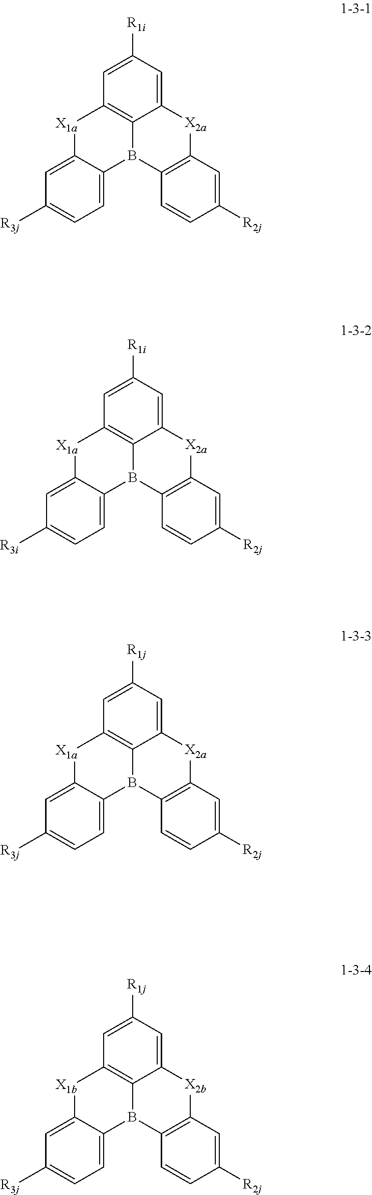
wherein in Formula 1-3-1 to Formula 1-3-4,
X₁ₐ and X₂ₐ are each independently N(R₄ⱼ) or O,
X_{1b} and X_{2b} are each independently N(R₄ᵢ) or O,
R₁ᵢ, R₃ᵢ, and R₄ᵢ are each independently a group represented by Formula 2, and
R₁ⱼ, R₂ⱼ, R₃ⱼ, and R₄ⱼ are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

21. The polycyclic compound of claim 16, wherein Formula 1 is represented by one of Formula 3-A to Formula 3-D: 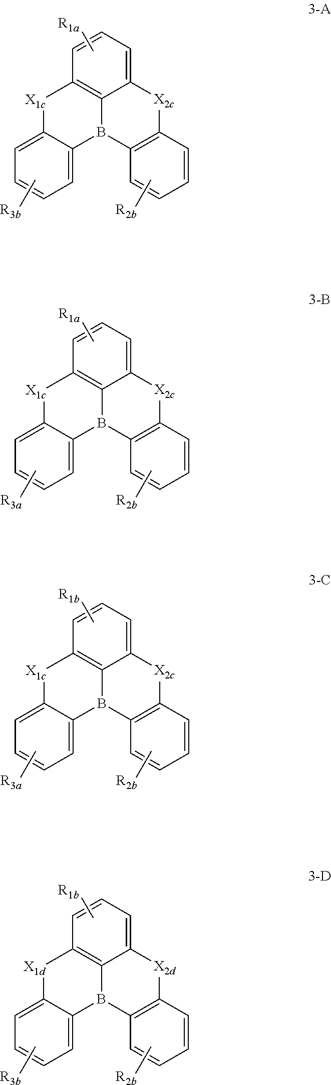
wherein in Formula 3-A to Formula 3-D,
X_{1c} and X_{2c} are each independently N(R_{4b}) or O,
X₁ₐ and X_{2d} are each independently N(R₄ₐ) or O,
R₁ₐ, R₃ₐ, and R₄ₐ are each independently a group represented by Formula 2, and
R_{1b}, R_{2b}, R_{3b}, and R_{4b} are each independently a hydrogen atom, a deuterium atom, a substituted or unsubstituted alkyl group having 1 to 20 carbon atoms, a substituted or unsubstituted aryl group having 6 to 20 ring-forming carbon atoms, or a substituted or unsubstituted heteroaryl group having 2 to 20 ring-forming carbon atoms.

22. The polycyclic compound of claim 16, wherein Formula 2 is represented by one of Formula 2-1 to Formula 2-4: 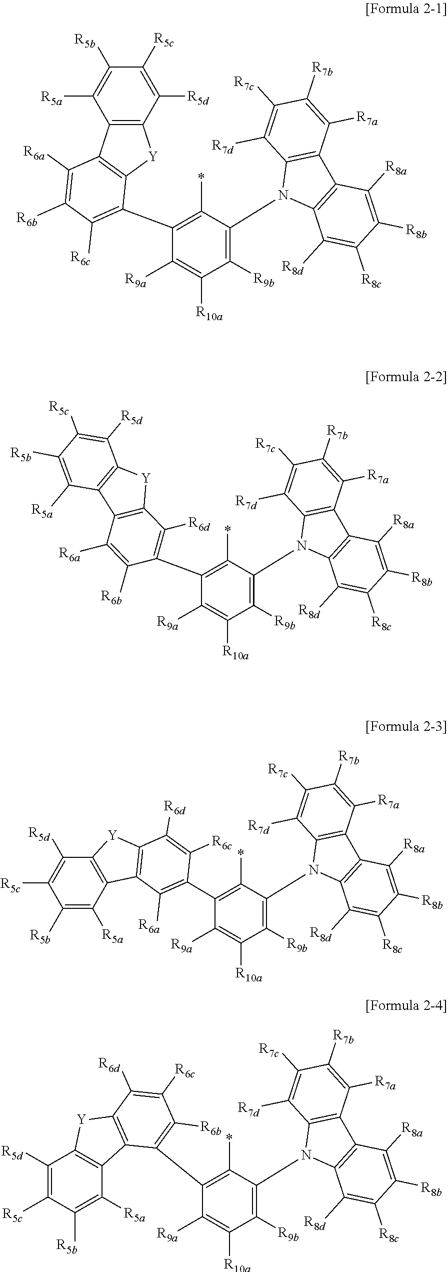
wherein in Formula 2-1 to Formula 2-4,
Y is O or S,
R₅ₐ to R_{5d}, R₆ₐ to R_{6d}, R₇ₐ to R_{7d}, R₈ₐ to R_{8d}, and R₁₀ₐ are each independently a hydrogen atom, a deuterium atom, a cyano group, or a substituted or unsubstituted alkyl group having 1 to 10 carbon atoms, and
R₉ₐ and R_{9b} are each independently a hydrogen atom or a deuterium atom.

23. The polycyclic compound of claim 16, wherein the polycyclic compound represented by Formula 1 is selected from Compound Group 1: 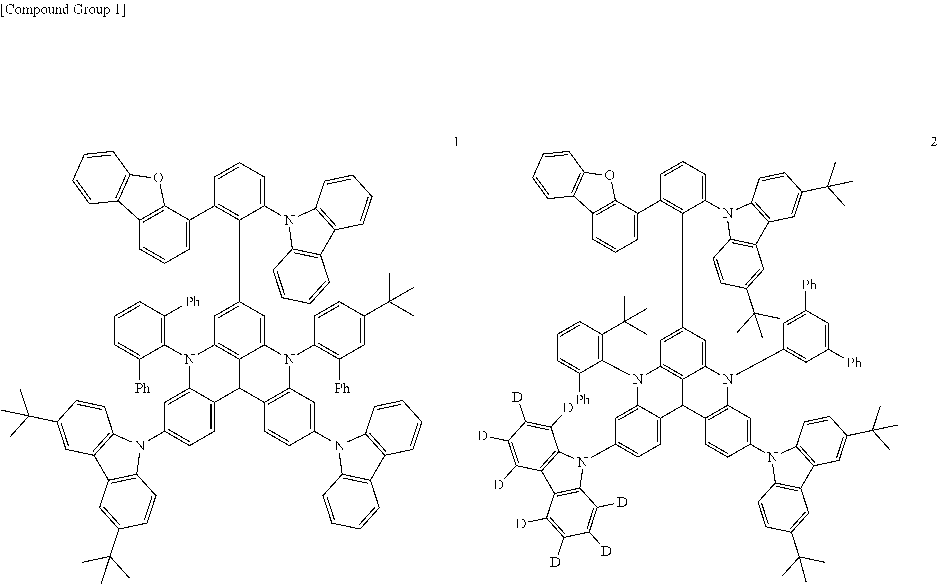 [SMILES: CC(C)(C)c1ccc(N2c3cc(-n4c5ccccc5c5ccccc54)ccc3C3c4ccc(-n5c6ccc(C(C)(C)C)cc6c6cc(C(C)(C)C)ccc65)cc4N(c4c(-c5ccccc5)cccc4-c4ccccc4)c4cc(-c5c(-c6cccc7c6oc6ccccc67)cccc5-n5c6ccccc6c6ccccc65)cc2c43)c(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cccc1C(C)(C)C)c1cc(-c3c(-c4cccc5c4oc4ccccc45)cccc3-n3c4ccc(C(C)(C)C)cc4c4cc(C(C)(C)C)ccc43)cc3c1C2c1ccc(-n2c4ccc(C(C)(C)C)cc4c4cc(C(C)(C)C)ccc42)cc1N3c1cc(-c2ccccc2)cc(-c2ccccc2)c1] 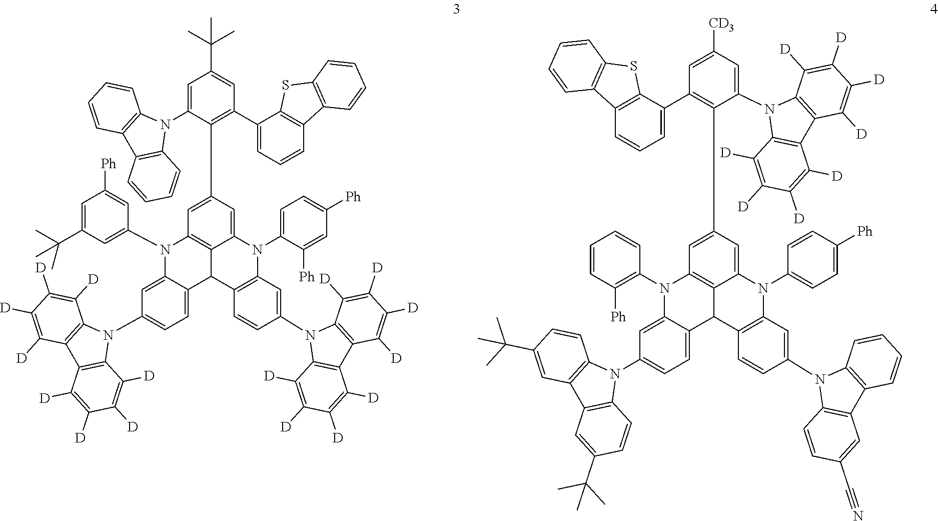 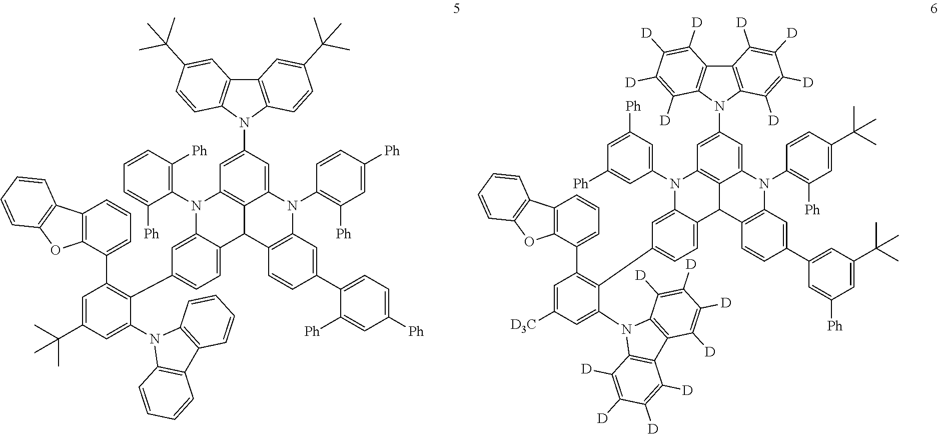 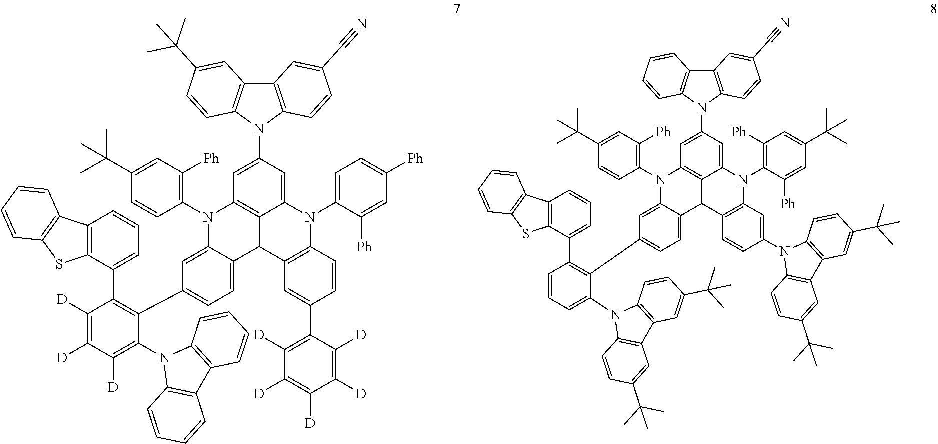 [SMILES: [2H]c1c([2H])c([2H])c(-c2ccc3c(c2)C2c4ccc(-c5c(-c6cccc7c6sc6ccccc67)c([2H])c([2H])c([2H])c5-n5c6ccccc6c6ccccc65)cc4N(c4ccc(C(C)(C)C)cc4-c4ccccc4)c4cc(-n5c6ccc(C#N)cc6c6cc(C(C)(C)C)ccc65)cc(c42)N3c2ccc(-c3ccccc3)cc2-c2ccccc2)c([2H])c1[2H] ; CC(C)(C)c1ccc(N2c3cc(-c4c(-c5cccc6c5sc5ccccc56)cccc4-n4c5ccc(C(C)(C)C)cc5c5cc(C(C)(C)C)ccc54)ccc3C3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-n5c6ccccc6c6cc(C#N)ccc65)cc2c43)c(-c2ccccc2)c1] 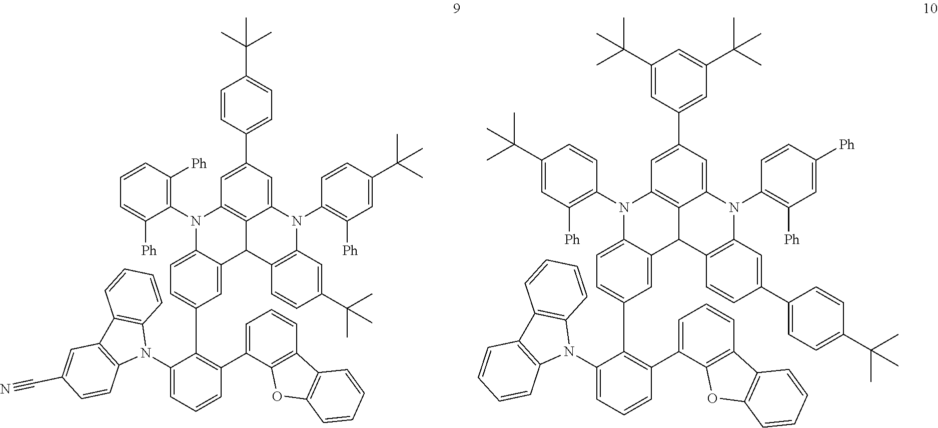 [SMILES: CC(C)(C)c1ccc(-c2cc3c4c(c2)N(c2c(-c5ccccc5)cccc2-c2ccccc2)c2ccc(-c5c(-c6cccc7c6oc6ccccc67)cccc5-n5c6ccccc6c6cc(C#N)ccc65)cc2C4c2ccc(C(C)(C)C)cc2N3c2ccc(C(C)(C)C)cc2-c2ccccc2)cc1 ; CC(C)(C)c1ccc(-c2ccc3c(c2)N(c2ccc(-c4ccccc4)cc2-c2ccccc2)c2cc(-c4cc(C(C)(C)C)cc(C(C)(C)C)c4)cc4c2C3c2cc(-c3c(-c5cccc6c5oc5ccccc56)cccc3-n3c5ccccc5c5ccccc53)ccc2N4c2ccc(C(C)(C)C)cc2-c2ccccc2)cc1] 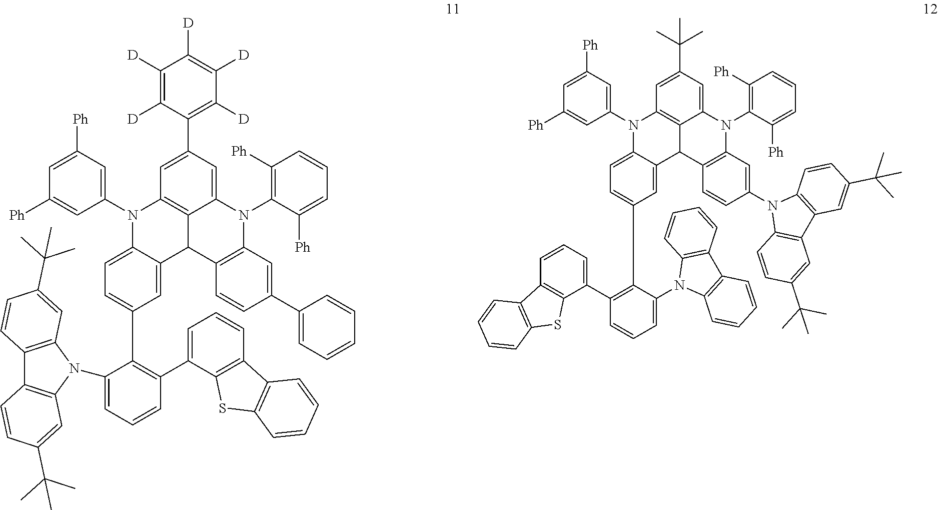 [SMILES: [2H]c1c([2H])c([2H])c(-c2cc3c4c(c2)N(c2c(-c5ccccc5)cccc2-c2ccccc2)c2cc(-c5ccccc5)ccc2C4c2cc(-c4c(-c5cccc6c5sc5ccccc56)cccc4-n4c5cc(C(C)(C)C)ccc5c5ccc(C(C)(C)C)cc54)ccc2N3c2cc(-c3ccccc3)cc(-c3ccccc3)c2)c([2H])c1[2H] ; CC(C)(C)c1cc2c3c(c1)N(c1c(-c4ccccc4)cccc1-c1ccccc1)c1cc(-n4c5ccc(C(C)(C)C)cc5c5cc(C(C)(C)C)ccc54)ccc1C3c1cc(-c3c(-c4cccc5c4sc4ccccc45)cccc3-n3c4ccccc4c4ccccc43)ccc1N2c1cc(-c2ccccc2)cc(-c2ccccc2)c1] 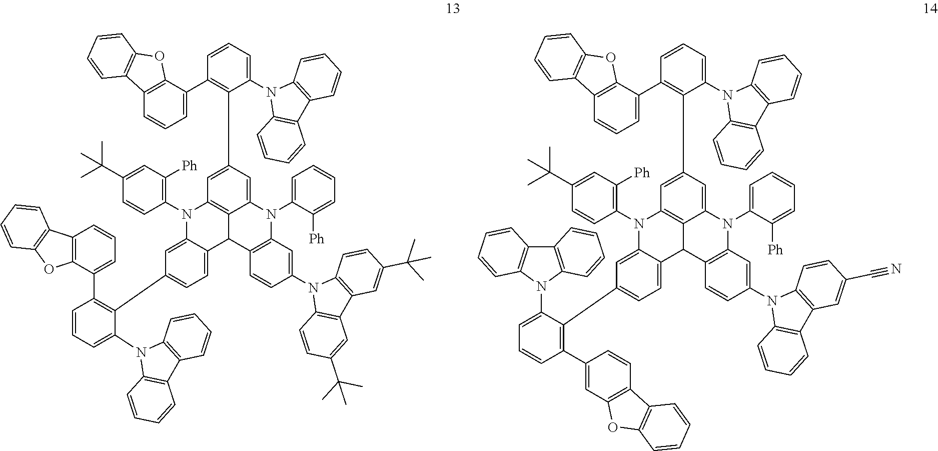 [SMILES: CC(C)(C)c1ccc(N2c3cc(-c4c(-c5cccc6c5oc5ccccc56)cccc4-n4c5ccccc5c5ccccc54)ccc3C3c4ccc(-n5c6ccc(C(C)(C)C)cc6c6cc(C(C)(C)C)ccc65)cc4N(c4ccccc4-c4ccccc4)c4cc(-c5c(-c6cccc7c6oc6ccccc67)cccc5-n5c6ccccc6c6ccccc65)cc2c43)c(-c2ccccc2)c1 ; CC(C)(C)c1ccc(N2c3cc(-c4c(-c5ccc6c(c5)oc5ccccc56)cccc4-n4c5ccccc5c5ccccc54)ccc3C3c4ccc(-n5c6ccccc6c6cc(C#N)ccc65)cc4N(c4ccccc4-c4ccccc4)c4cc(-c5c(-c6cccc7c6oc6ccccc67)cccc5-n5c6ccccc6c6ccccc65)cc2c43)c(-c2ccccc2)c1] 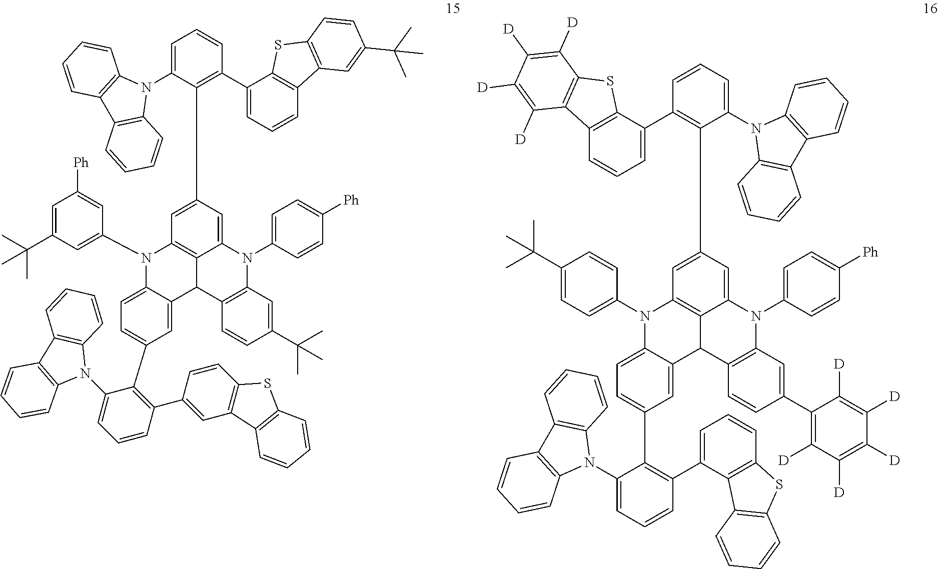 [SMILES: CC(C)(C)c1cc(-c2ccccc2)cc(N2c3ccc(-c4c(-c5ccc6sc7ccccc7c6c5)cccc4-n4c5ccccc5c5ccccc54)cc3C3c4ccc(C(C)(C)C)cc4N(c4ccc(-c5ccccc5)cc4)c4cc(-c5c(-c6cccc7c6sc6ccc(C(C)(C)C)cc67)cccc5-n5c6ccccc6c6ccccc65)cc2c43)c1 ; [2H]c1c([2H])c([2H])c(-c2ccc3c(c2)N(c2ccc(-c4ccccc4)cc2)c2cc(-c4c(-c5cccc6c5sc5c([2H])c([2H])c([2H])c([2H])c56)cccc4-n4c5ccccc5c5ccccc54)cc4c2C3c2cc(-c3c(-c5cccc6sc7ccccc7c56)cccc3-n3c5ccccc5c5ccccc53)ccc2N4c2ccc(C(C)(C)C)cc2)c([2H])c1[2H]] 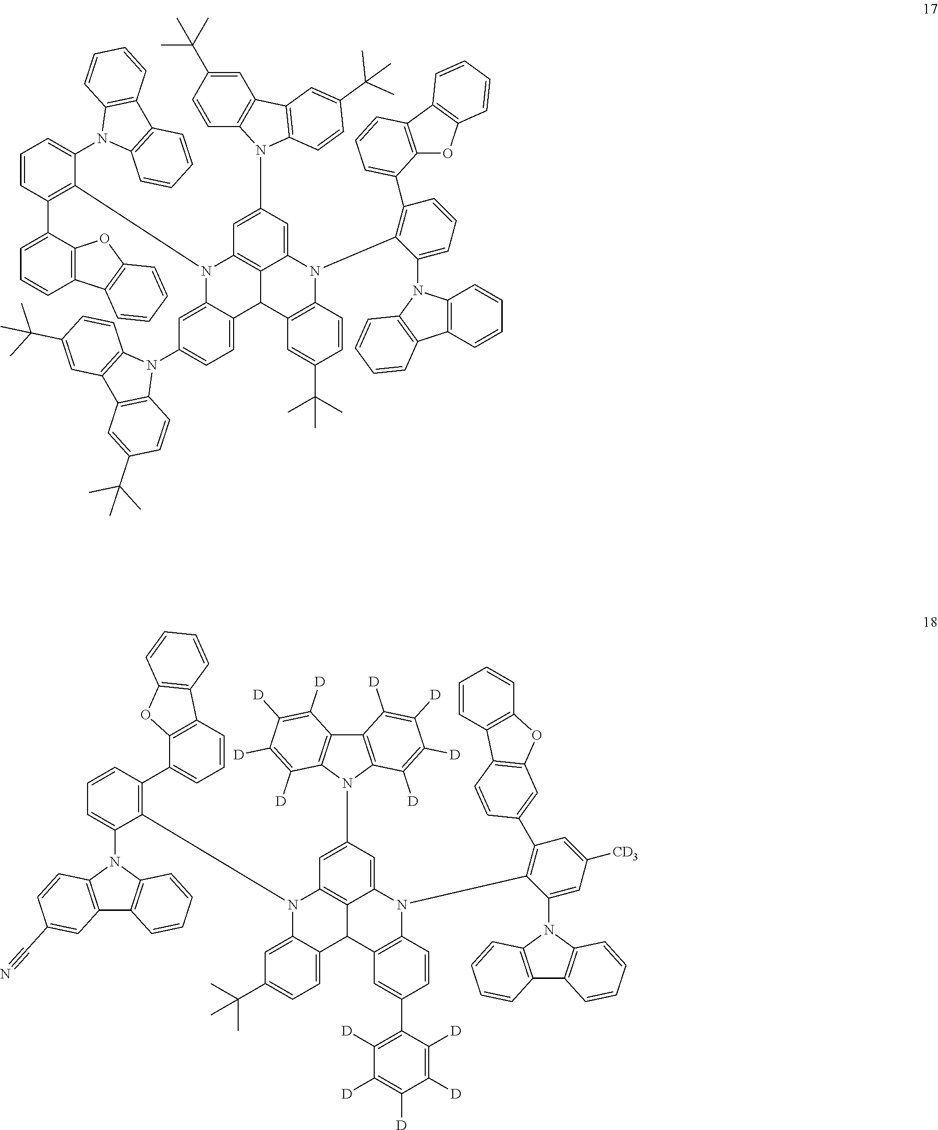 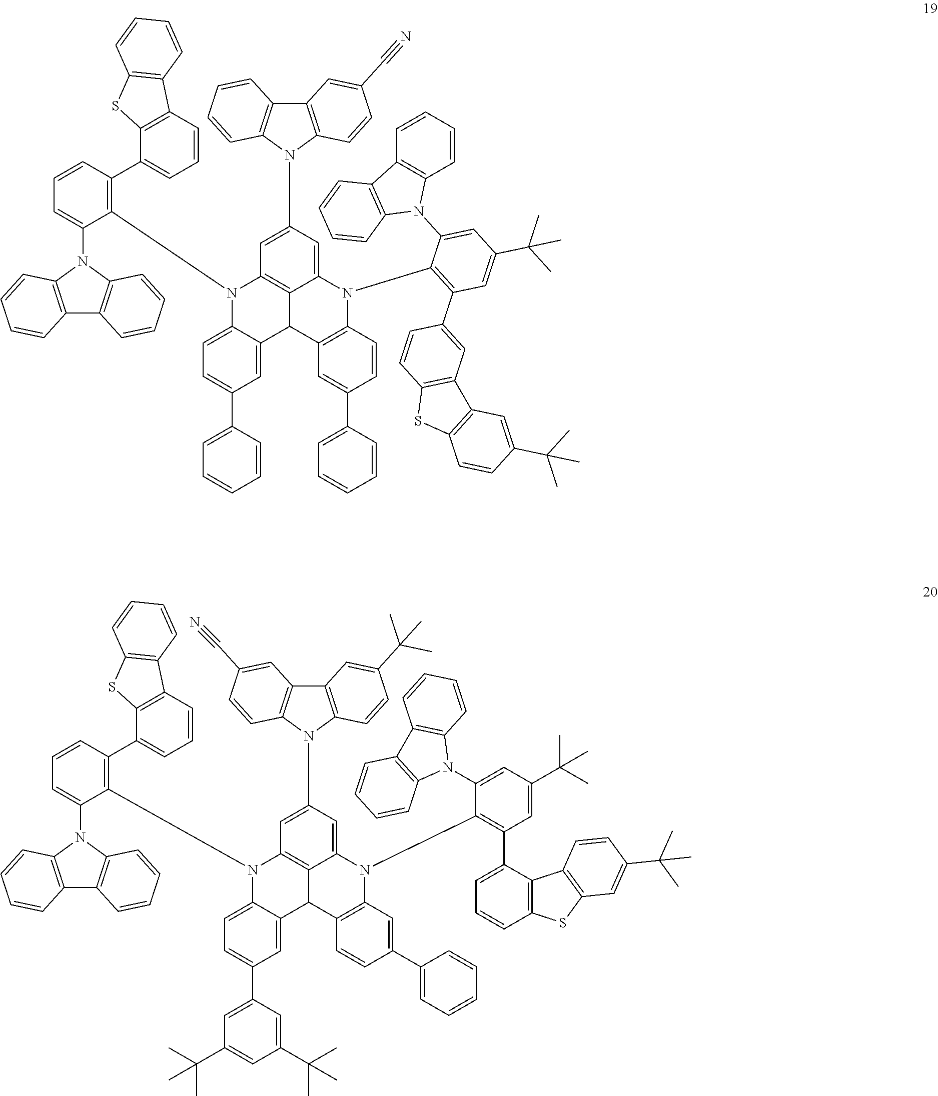 [SMILES: CC(C)(C)c1cc(-c2ccc3sc4ccc(C(C)(C)C)cc4c3c2)c(N2c3ccc(-c4ccccc4)cc3C3c4cc(-c5ccccc5)ccc4N(c4c(-c5cccc6c5sc5ccccc56)cccc4-n4c5ccccc5c5ccccc54)c4cc(-n5c6ccccc6c6cc(C#N)ccc65)cc2c43)c(-n2c3ccccc3c3ccccc32)c1 ; CC(C)(C)c1cc(-c2ccc3c(c2)C2c4ccc(-c5ccccc5)cc4N(c4c(-c5cccc6sc7cc(C(C)(C)C)ccc7c56)cc(C(C)(C)C)cc4-n4c5ccccc5c5ccccc54)c4cc(-n5c6ccc(C#N)cc6c6cc(C(C)(C)C)ccc65)cc(c42)N3c2c(-c3cccc4c3sc3ccccc34)cccc2-n2c3ccccc3c3ccccc32)cc(C(C)(C)C)c1] 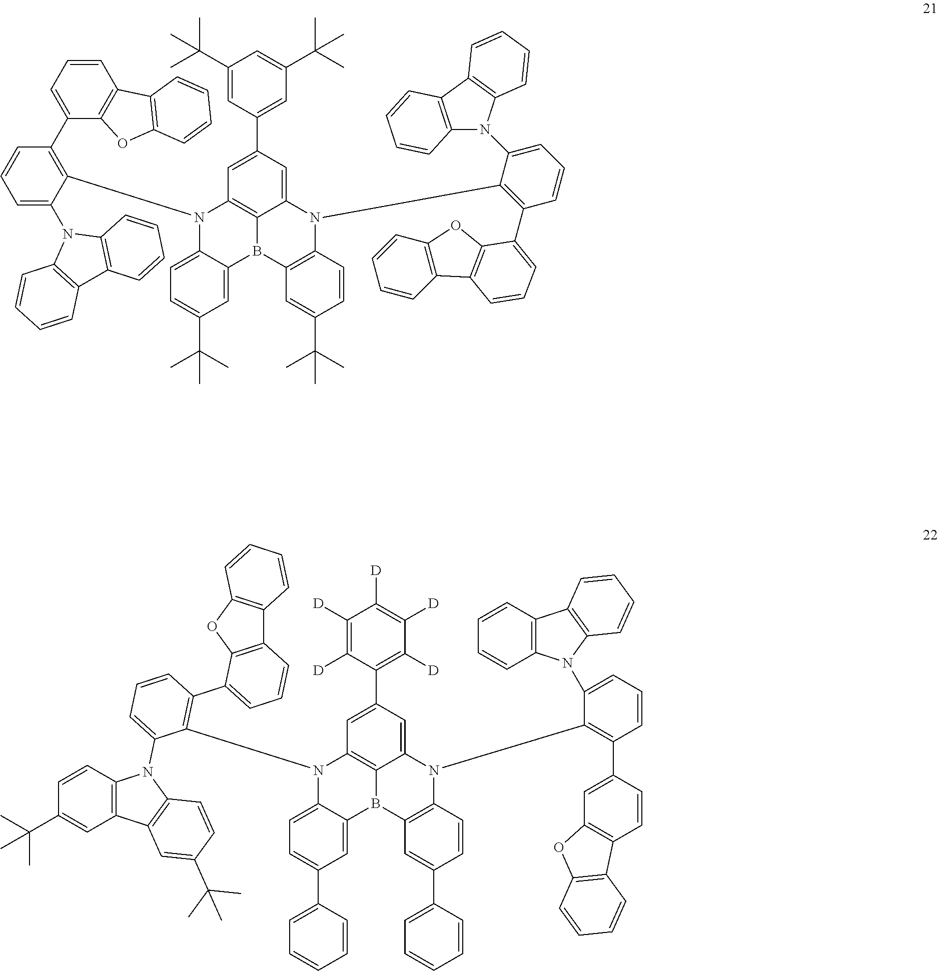 [SMILES: CC(C)(C)c1cc(-c2cc3c4c(c2)N(c2c(-c5cccc6c5oc5ccccc56)cccc2-n2c5ccccc5c5ccccc52)c2ccc(C(C)(C)C)cc2B4c2cc(C(C)(C)C)ccc2N3c2c(-c3cccc4c3oc3ccccc34)cccc2-n2c3ccccc3c3ccccc32)cc(C(C)(C)C)c1 ; [2H]c1c([2H])c([2H])c(-c2cc3c4c(c2)N(c2c(-c5cccc6c5oc5ccccc56)cccc2-n2c5ccc(C(C)(C)C)cc5c5cc(C(C)(C)C)ccc52)c2ccc(-c5ccccc5)cc2B4c2cc(-c4ccccc4)ccc2N3c2c(-c3ccc4c(c3)oc3ccccc34)cccc2-n2c3ccccc3c3ccccc32)c([2H])c1[2H]] 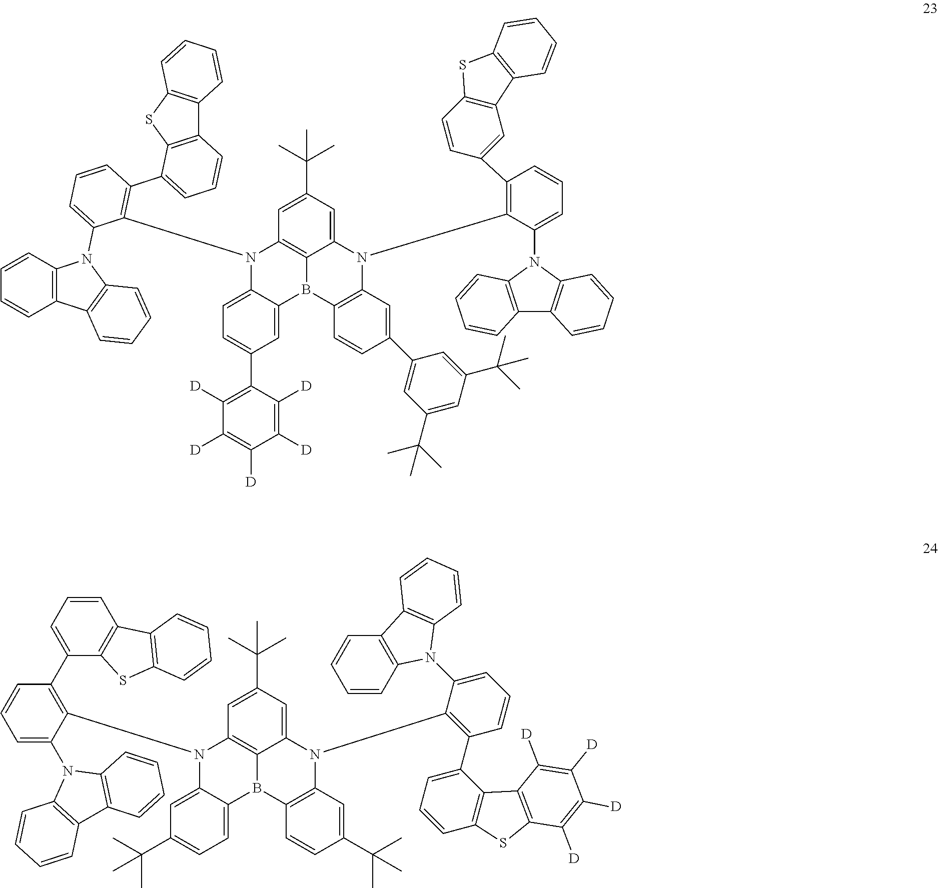 [SMILES: [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3cccc4c3sc3ccccc34)cccc2-n2c3ccccc3c3ccccc32)c([2H])c1[2H] ; [2H]c1c([2H])c([2H])c2c(sc3cccc(-c4cccc(-n5c6ccccc6c6ccccc65)c4N4c5cc(C(C)(C)C)ccc5B5c6ccc(C(C)(C)C)cc6N(c6c(-c7cccc8c7sc7ccccc78)cccc6-n6c7ccccc7c7ccccc76)c6cc(C(C)(C)C)cc4c65)c32)c1[2H]] 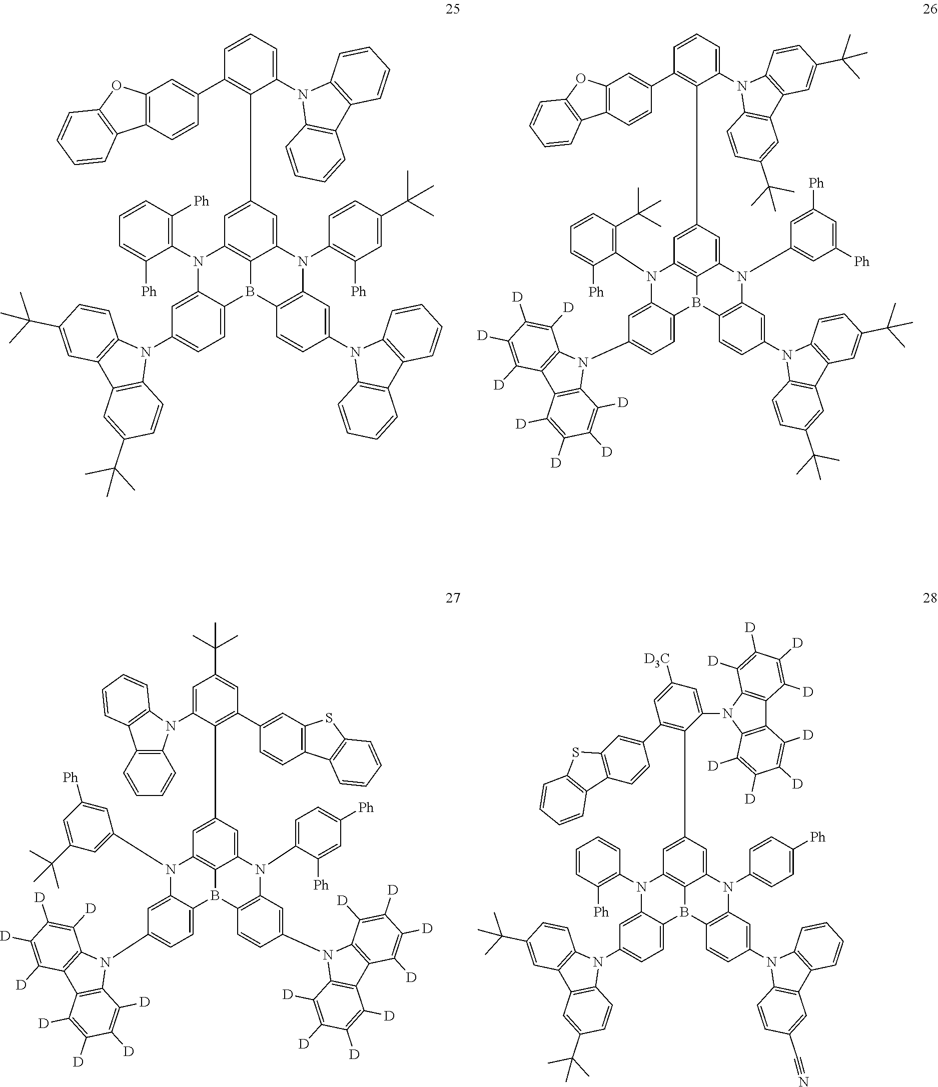 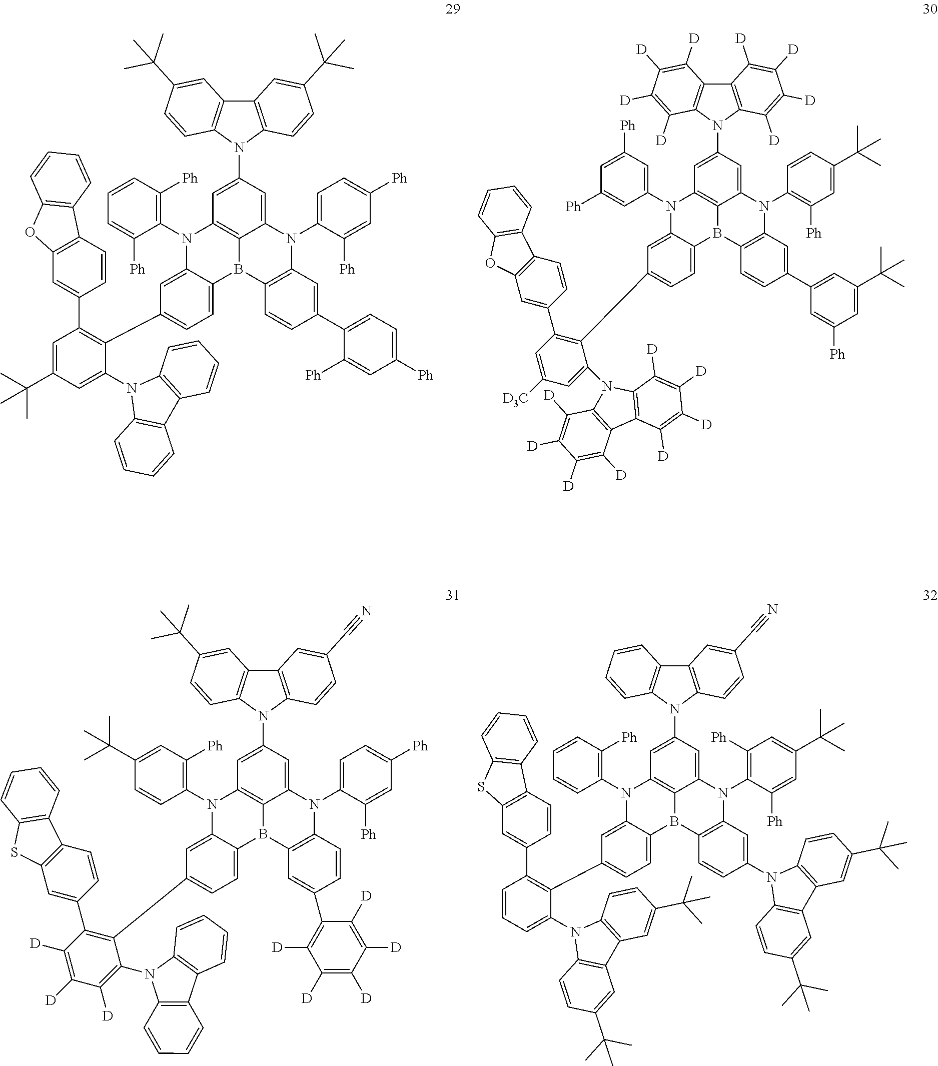 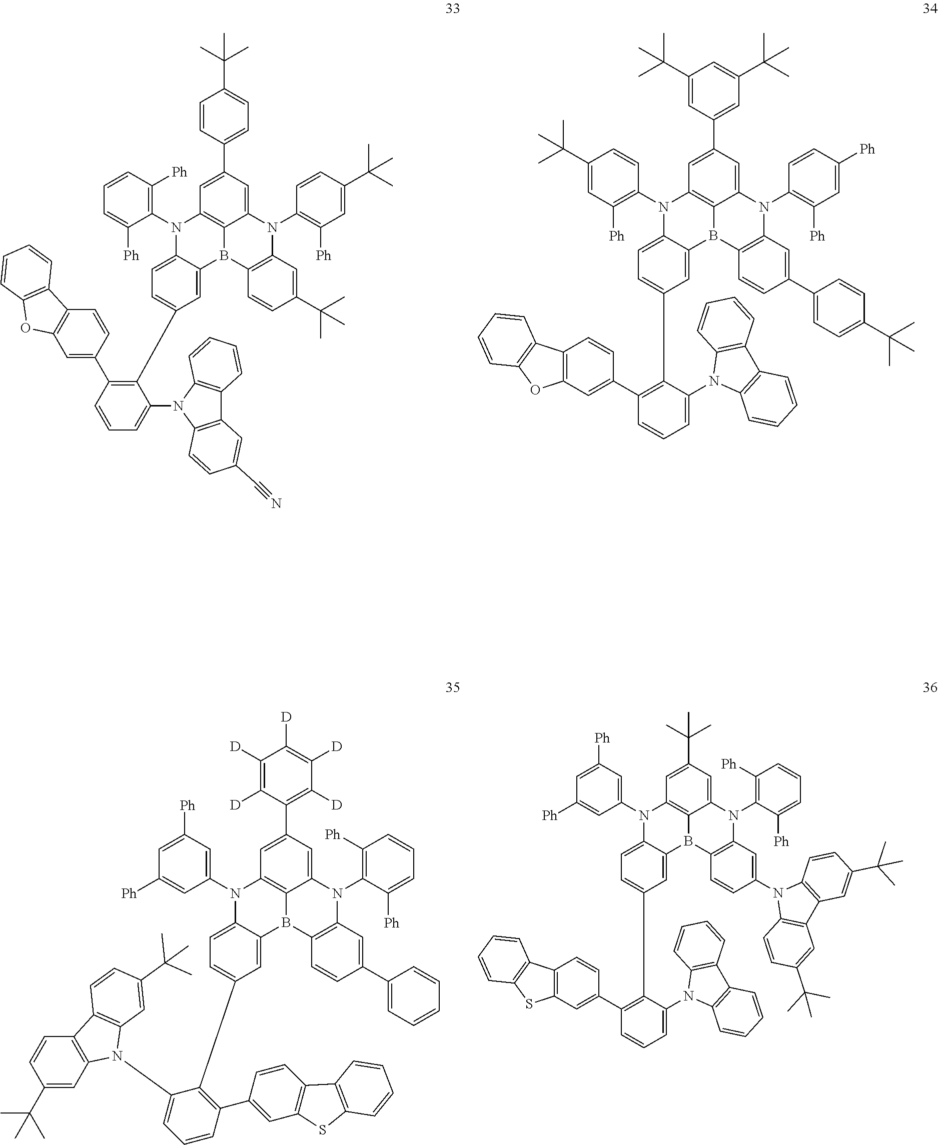 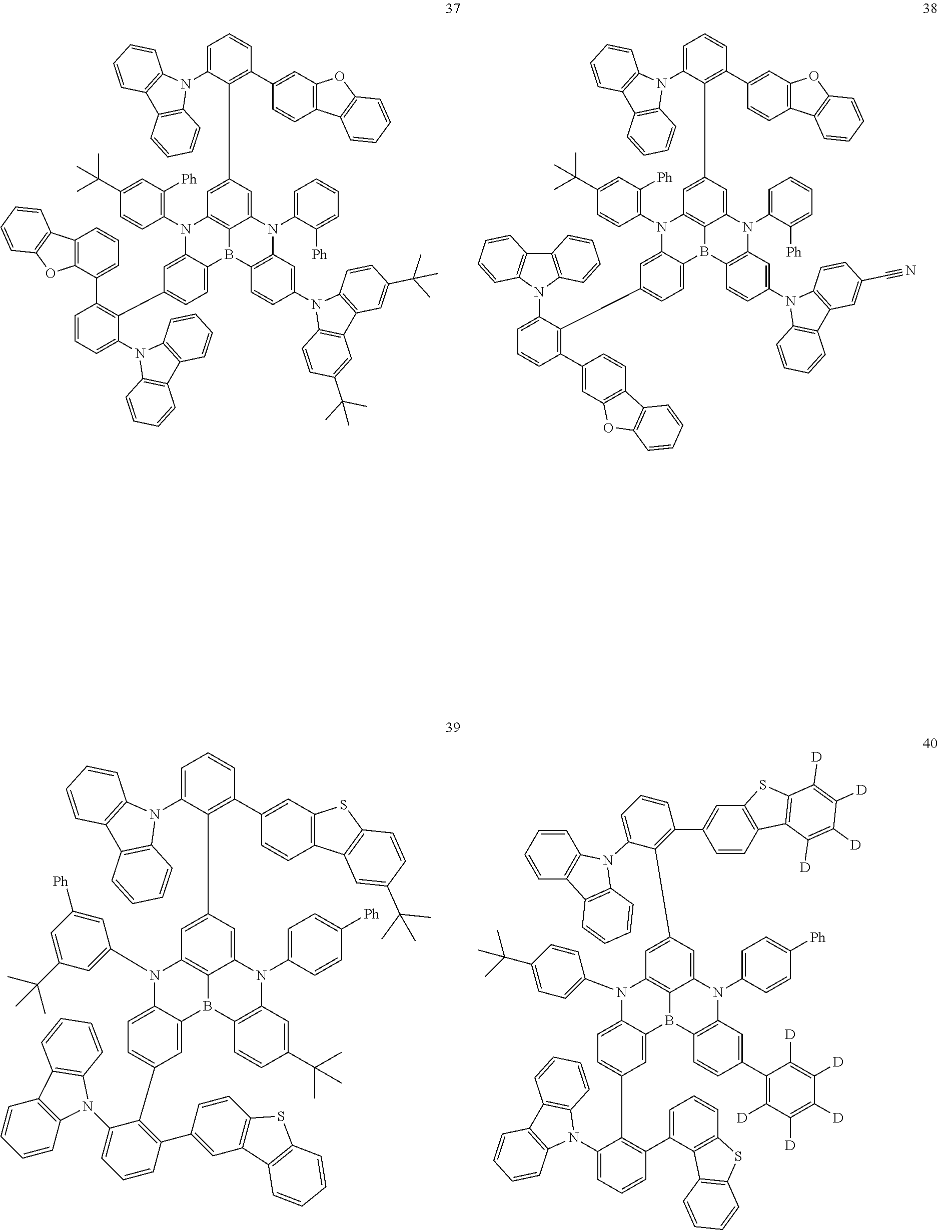 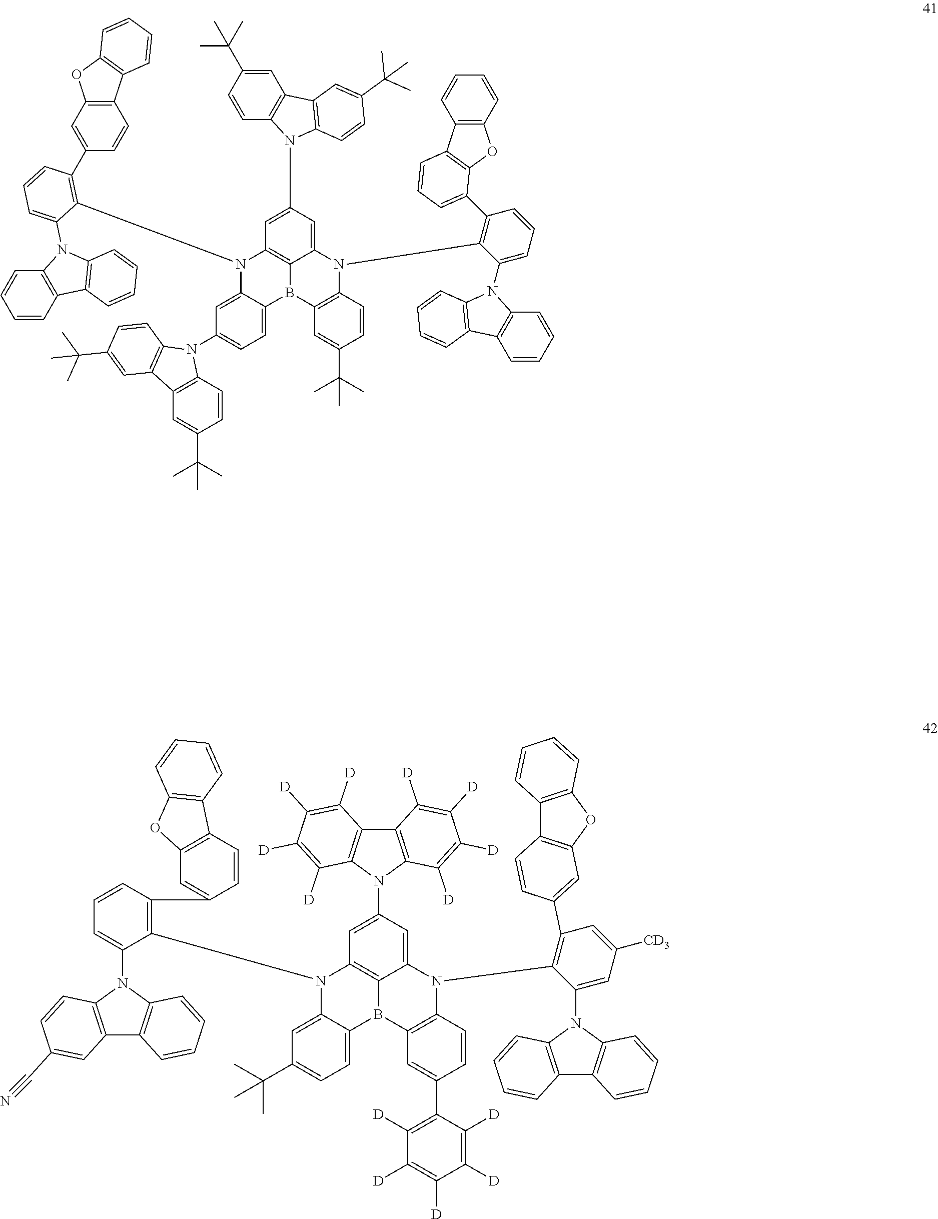 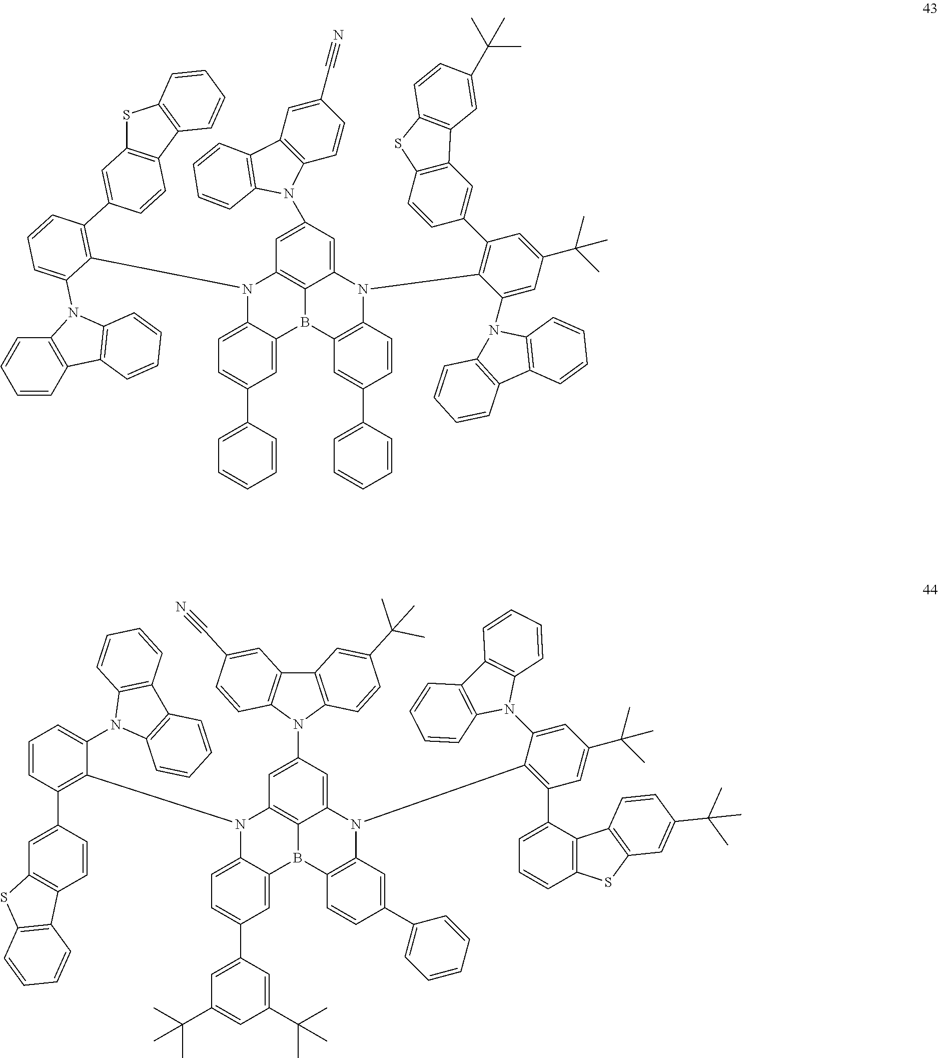 [SMILES: CC(C)(C)c1cc(-c2ccc3sc4ccc(C(C)(C)C)cc4c3c2)c(N2c3ccc(-c4ccccc4)cc3B3c4cc(-c5ccccc5)ccc4N(c4c(-c5ccc6c(c5)sc5ccccc56)cccc4-n4c5ccccc5c5ccccc54)c4cc(-n5c6ccccc6c6cc(C#N)ccc65)cc2c43)c(-n2c3ccccc3c3ccccc32)c1 ; CC(C)(C)c1cc(-c2ccc3c(c2)B2c4ccc(-c5ccccc5)cc4N(c4c(-c5cccc6sc7cc(C(C)(C)C)ccc7c56)cc(C(C)(C)C)cc4-n4c5ccccc5c5ccccc54)c4cc(-n5c6ccc(C#N)cc6c6cc(C(C)(C)C)ccc65)cc(c42)N3c2c(-c3ccc4c(c3)sc3ccccc34)cccc2-n2c3ccccc3c3ccccc32)cc(C(C)(C)C)c1] 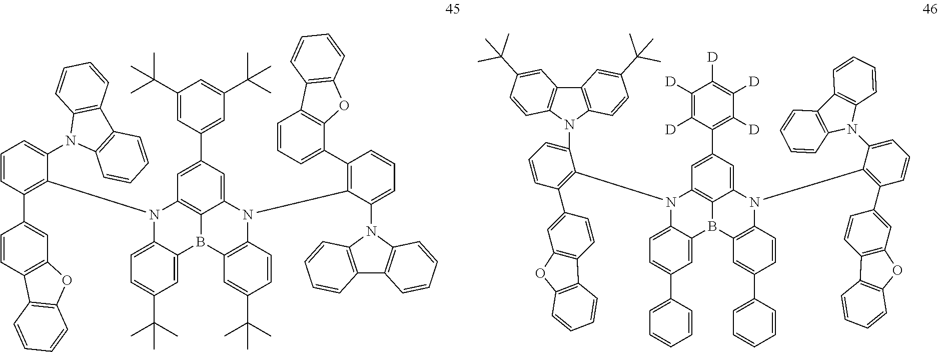 [SMILES: CC(C)(C)c1cc(-c2cc3c4c(c2)N(c2c(-c5cccc6c5oc5ccccc56)cccc2-n2c5ccccc5c5ccccc52)c2ccc(C(C)(C)C)cc2B4c2cc(C(C)(C)C)ccc2N3c2c(-c3ccc4c(c3)oc3ccccc34)cccc2-n2c3ccccc3c3ccccc32)cc(C(C)(C)C)c1 ; [2H]c1c([2H])c([2H])c(-c2cc3c4c(c2)N(c2c(-c5ccc6c(c5)oc5ccccc56)cccc2-n2c5ccc(C(C)(C)C)cc5c5cc(C(C)(C)C)ccc52)c2ccc(-c5ccccc5)cc2B4c2cc(-c4ccccc4)ccc2N3c2c(-c3ccc4c(c3)oc3ccccc34)cccc2-n2c3ccccc3c3ccccc32)c([2H])c1[2H]] 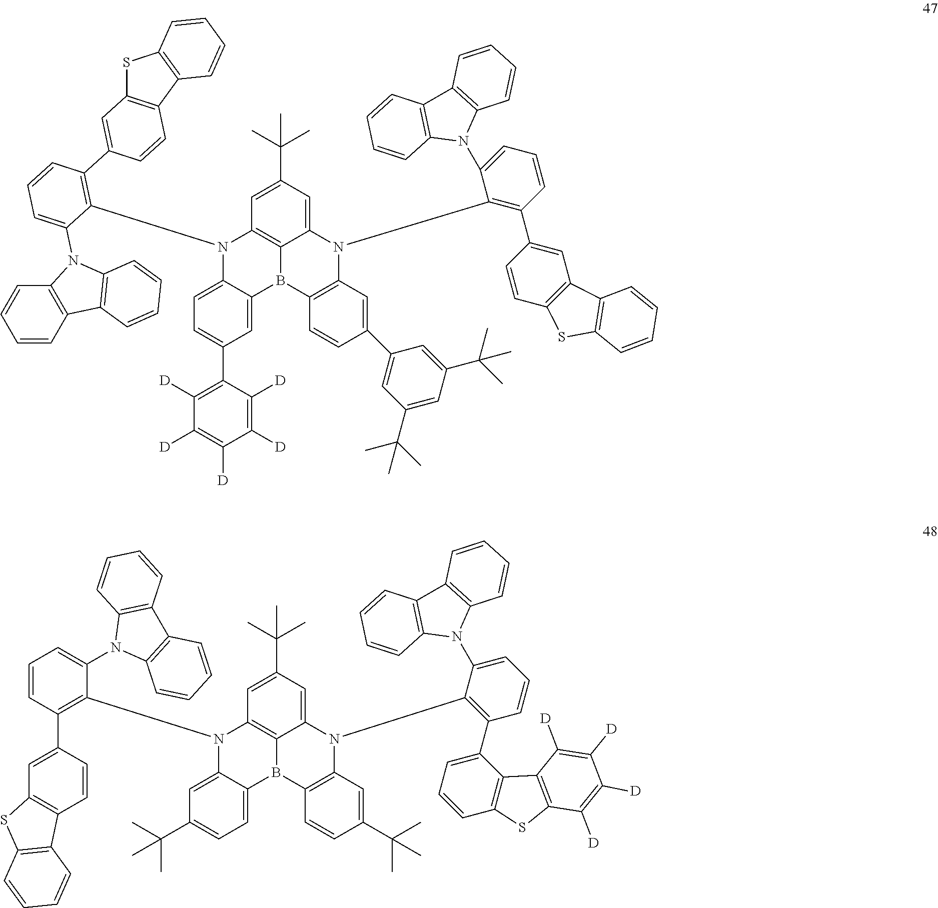 [SMILES: [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3ccc4c(c3)sc3ccccc34)cccc2-n2c3ccccc3c3ccccc32)c([2H])c1[2H] ; [2H]c1c([2H])c([2H])c2c(sc3cccc(-c4cccc(-n5c6ccccc6c6ccccc65)c4N4c5cc(C(C)(C)C)ccc5B5c6ccc(C(C)(C)C)cc6N(c6c(-c7ccc8c(c7)sc7ccccc78)cccc6-n6c7ccccc7c7ccccc76)c6cc(C(C)(C)C)cc4c65)c32)c1[2H]] 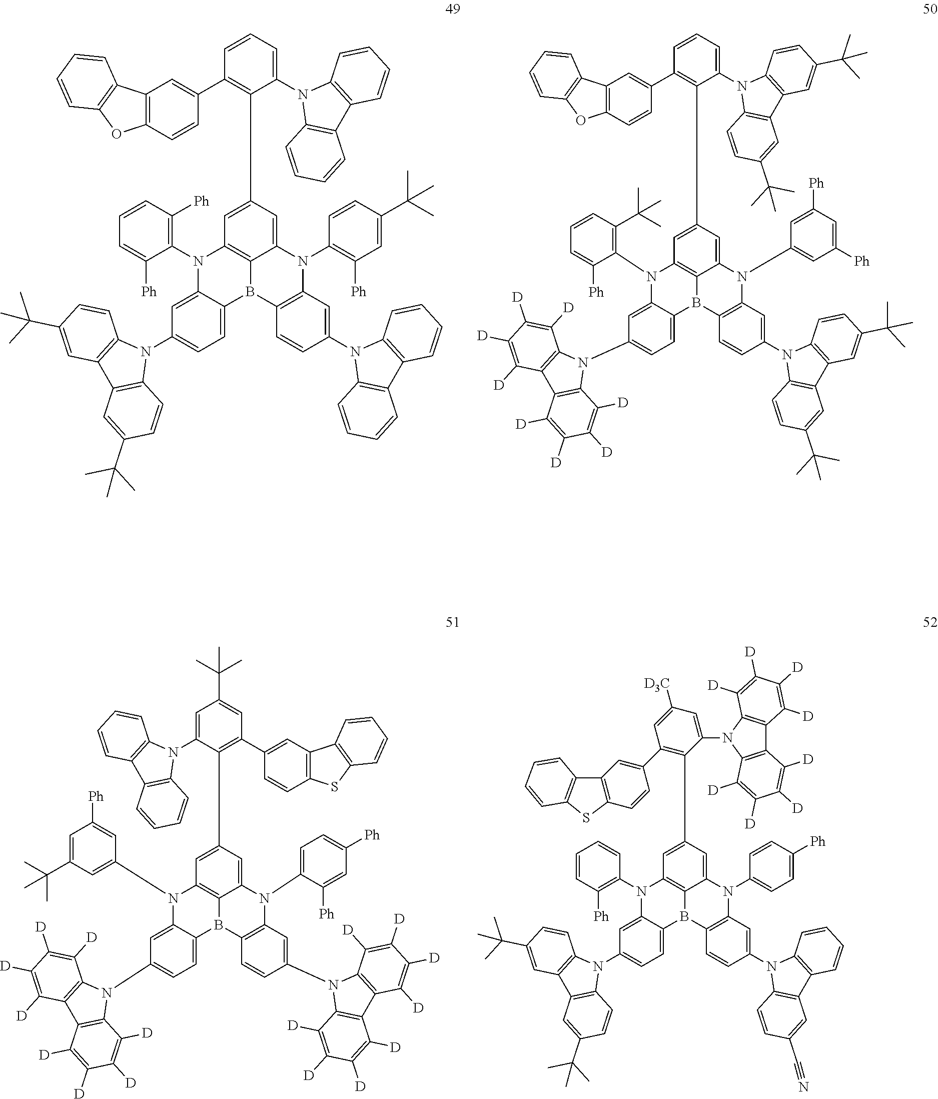 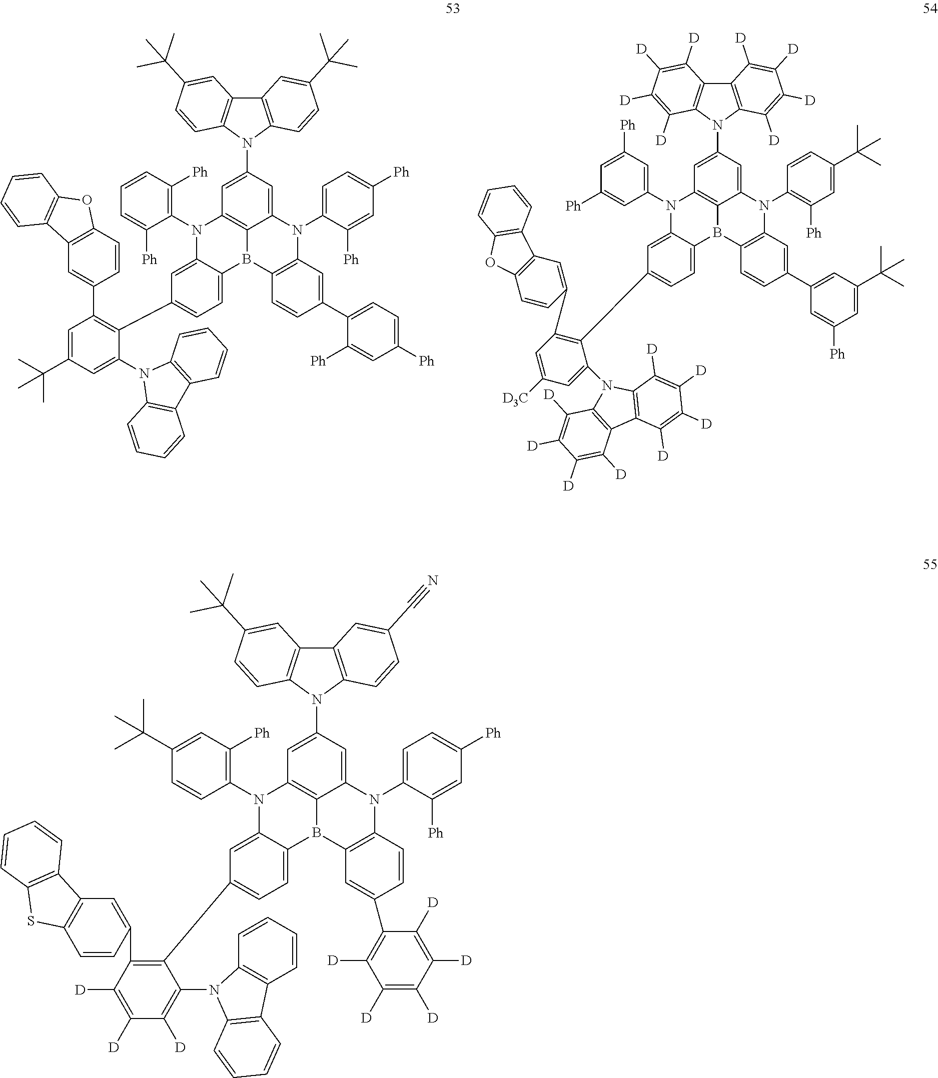 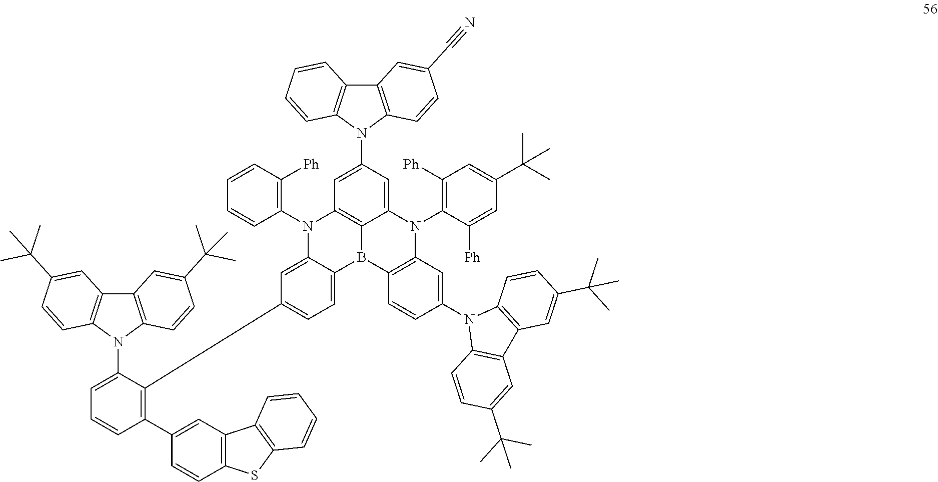 [SMILES: CC(C)(C)c1cc(-c2ccccc2)c(N2c3cc(-n4c5ccc(C(C)(C)C)cc5c5cc(C(C)(C)C)ccc54)ccc3B3c4ccc(-c5c(-c6ccc7sc8ccccc8c7c6)cccc5-n5c6ccc(C(C)(C)C)cc6c6cc(C(C)(C)C)ccc65)cc4N(c4ccccc4-c4ccccc4)c4cc(-n5c6ccccc6c6cc(C#N)ccc65)cc2c43)c(-c2ccccc2)c1] 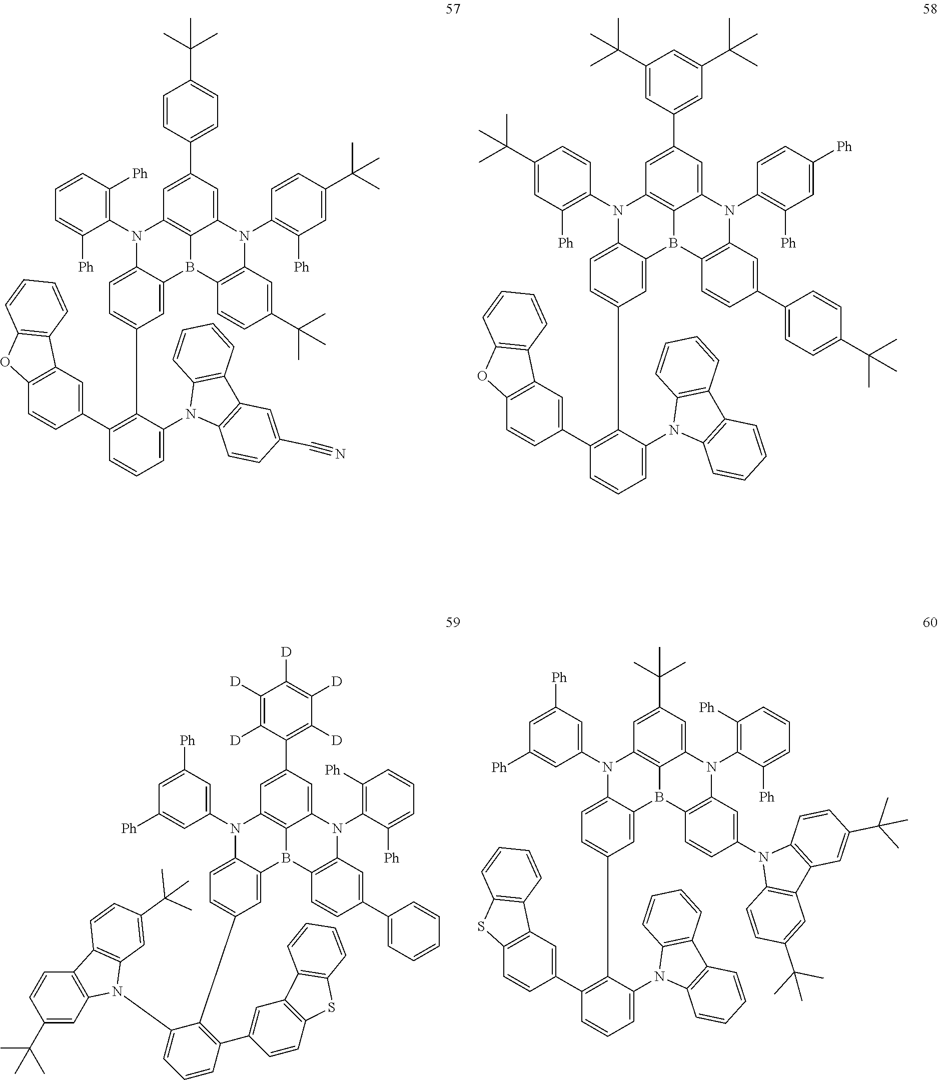 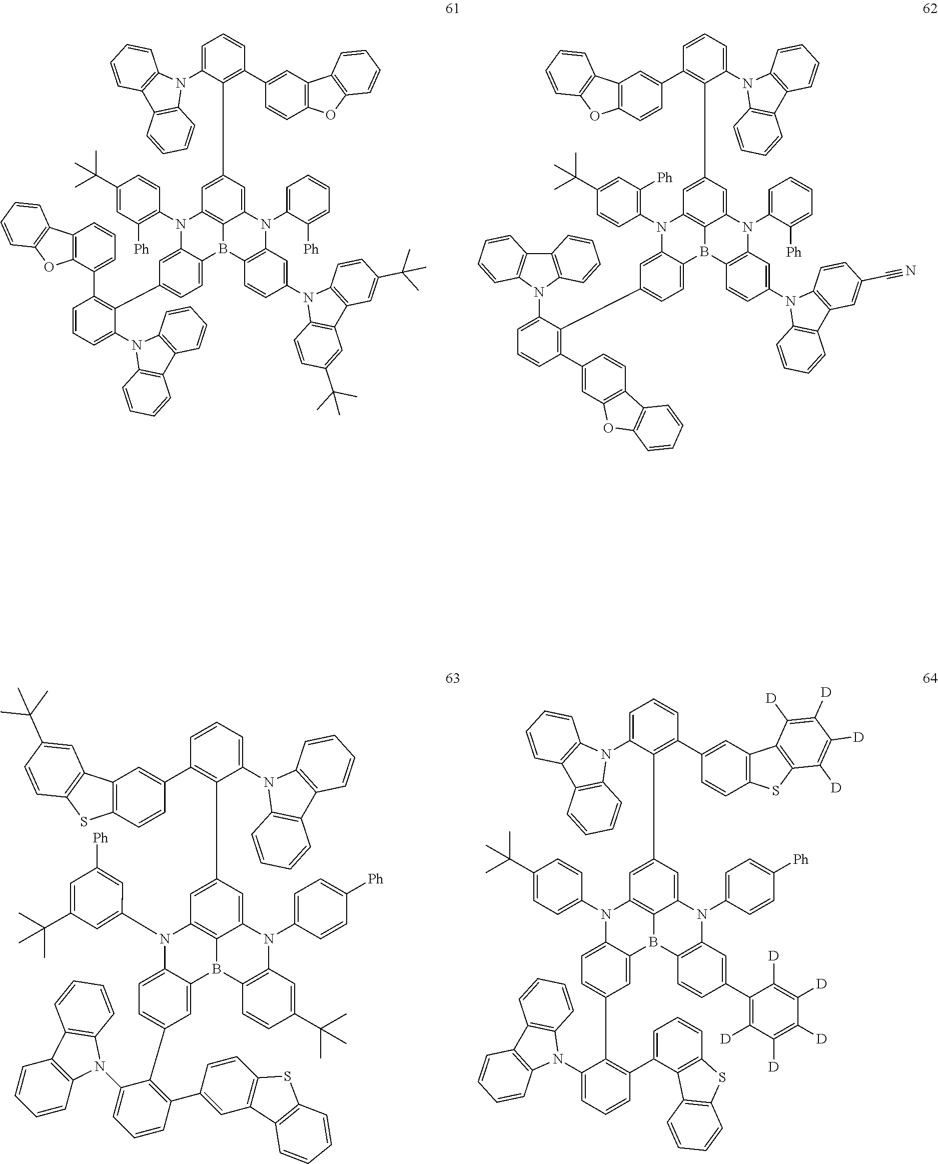 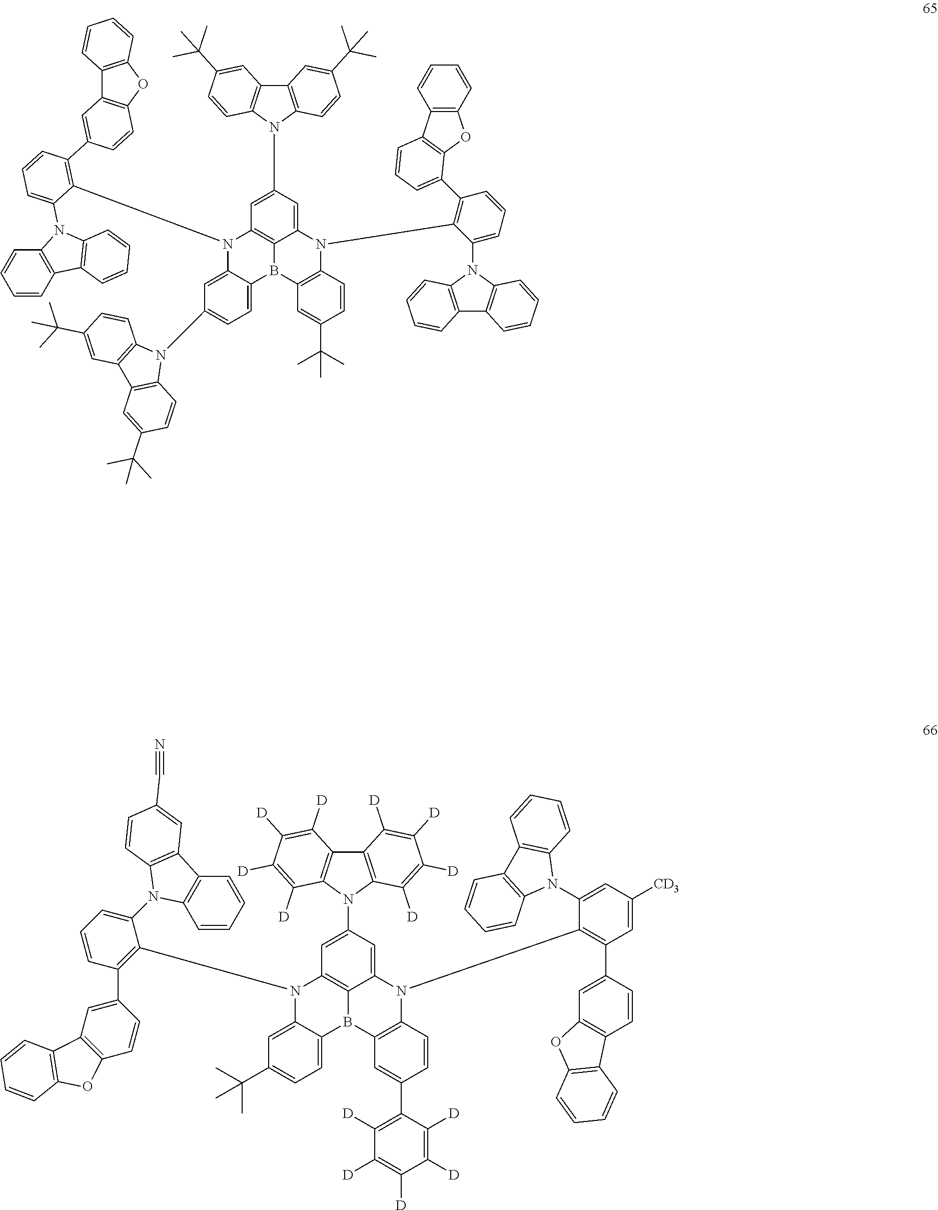 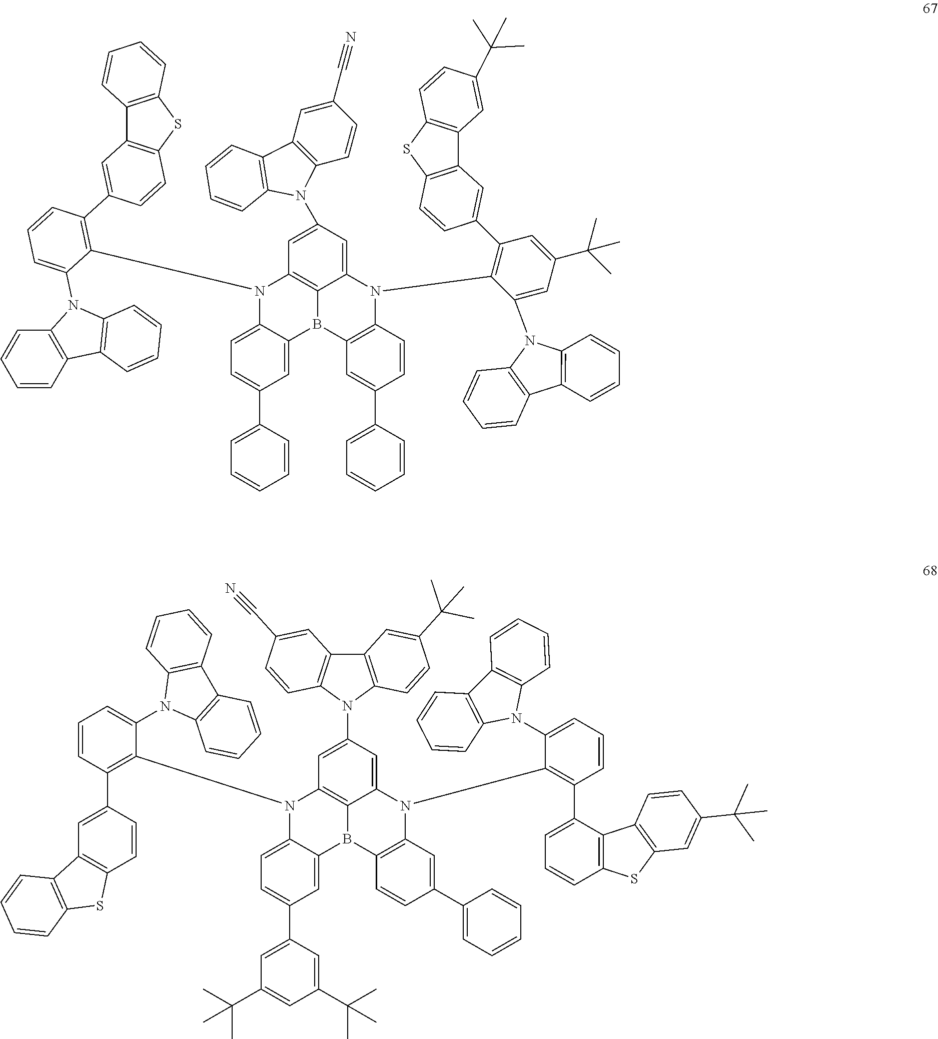 [SMILES: CC(C)(C)c1cc(-c2ccc3sc4ccc(C(C)(C)C)cc4c3c2)c(N2c3ccc(-c4ccccc4)cc3B3c4cc(-c5ccccc5)ccc4N(c4c(-c5ccc6sc7ccccc7c6c5)cccc4-n4c5ccccc5c5ccccc54)c4cc(-n5c6ccccc6c6cc(C#N)ccc65)cc2c43)c(-n2c3ccccc3c3ccccc32)c1 ; CC(C)(C)c1cc(-c2ccc3c(c2)B2c4ccc(-c5ccccc5)cc4N(c4c(-c5cccc6sc7cc(C(C)(C)C)ccc7c56)cccc4-n4c5ccccc5c5ccccc54)c4cc(-n5c6ccc(C#N)cc6c6cc(C(C)(C)C)ccc65)cc(c42)N3c2c(-c3ccc4sc5ccccc5c4c3)cccc2-n2c3ccccc3c3ccccc32)cc(C(C)(C)C)c1] 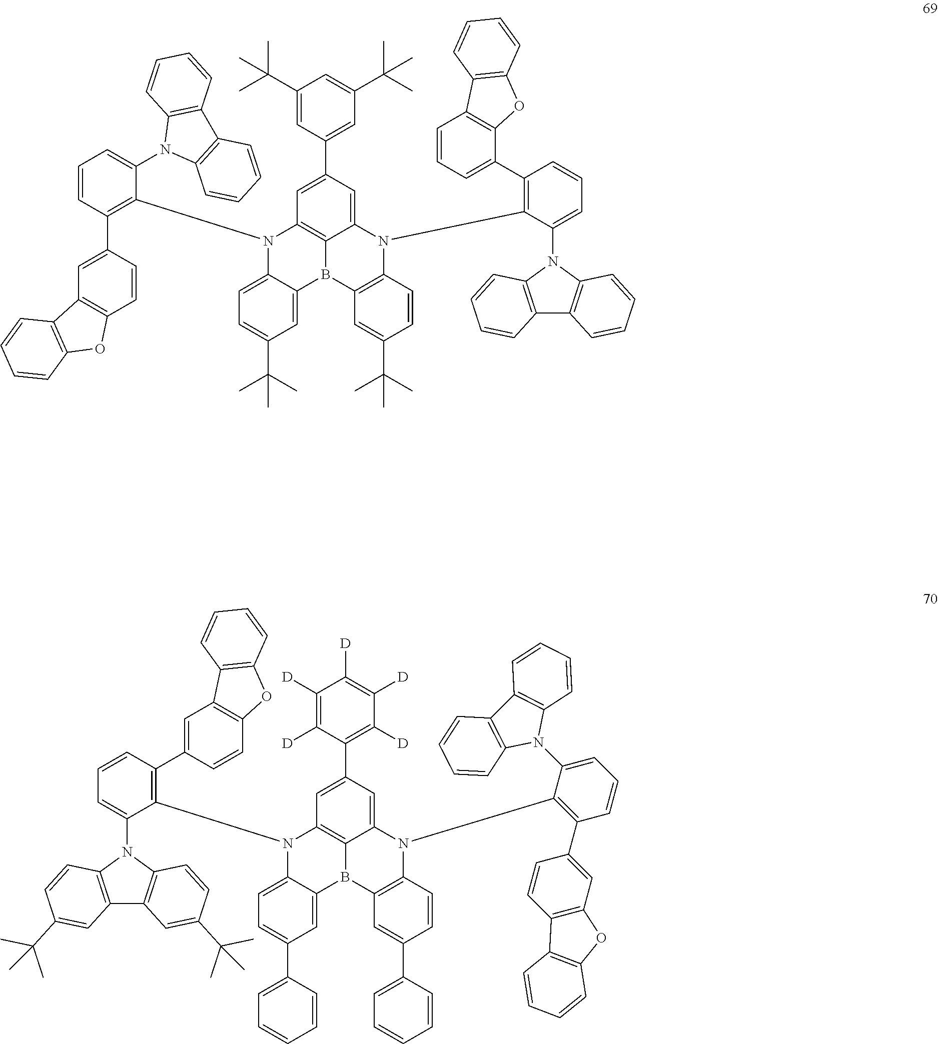 [SMILES: CC(C)(C)c1cc(-c2cc3c4c(c2)N(c2c(-c5cccc6c5oc5ccccc56)cccc2-n2c5ccccc5c5ccccc52)c2ccc(C(C)(C)C)cc2B4c2cc(C(C)(C)C)ccc2N3c2c(-c3ccc4oc5ccccc5c4c3)cccc2-n2c3ccccc3c3ccccc32)cc(C(C)(C)C)c1 ; [2H]c1c([2H])c([2H])c(-c2cc3c4c(c2)N(c2c(-c5ccc6oc7ccccc7c6c5)cccc2-n2c5ccc(C(C)(C)C)cc5c5cc(C(C)(C)C)ccc52)c2ccc(-c5ccccc5)cc2B4c2cc(-c4ccccc4)ccc2N3c2c(-c3ccc4c(c3)oc3ccccc34)cccc2-n2c3ccccc3c3ccccc32)c([2H])c1[2H]] 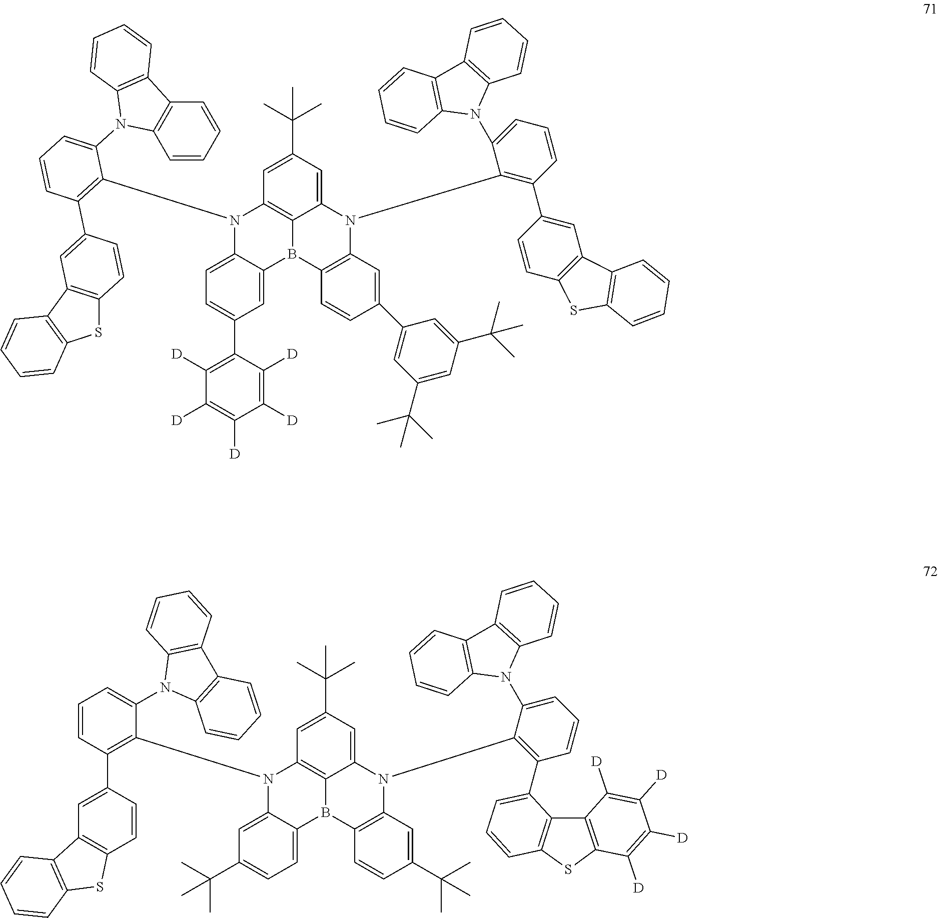 [SMILES: [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3ccc4sc5ccccc5c4c3)cccc2-n2c3ccccc3c3ccccc32)c([2H])c1[2H] ; [2H]c1c([2H])c([2H])c2c(sc3cccc(-c4cccc(-n5c6ccccc6c6ccccc65)c4N4c5cc(C(C)(C)C)ccc5B5c6ccc(C(C)(C)C)cc6N(c6c(-c7ccc8sc9ccccc9c8c7)cccc6-n6c7ccccc7c7ccccc76)c6cc(C(C)(C)C)cc4c65)c32)c1[2H]] 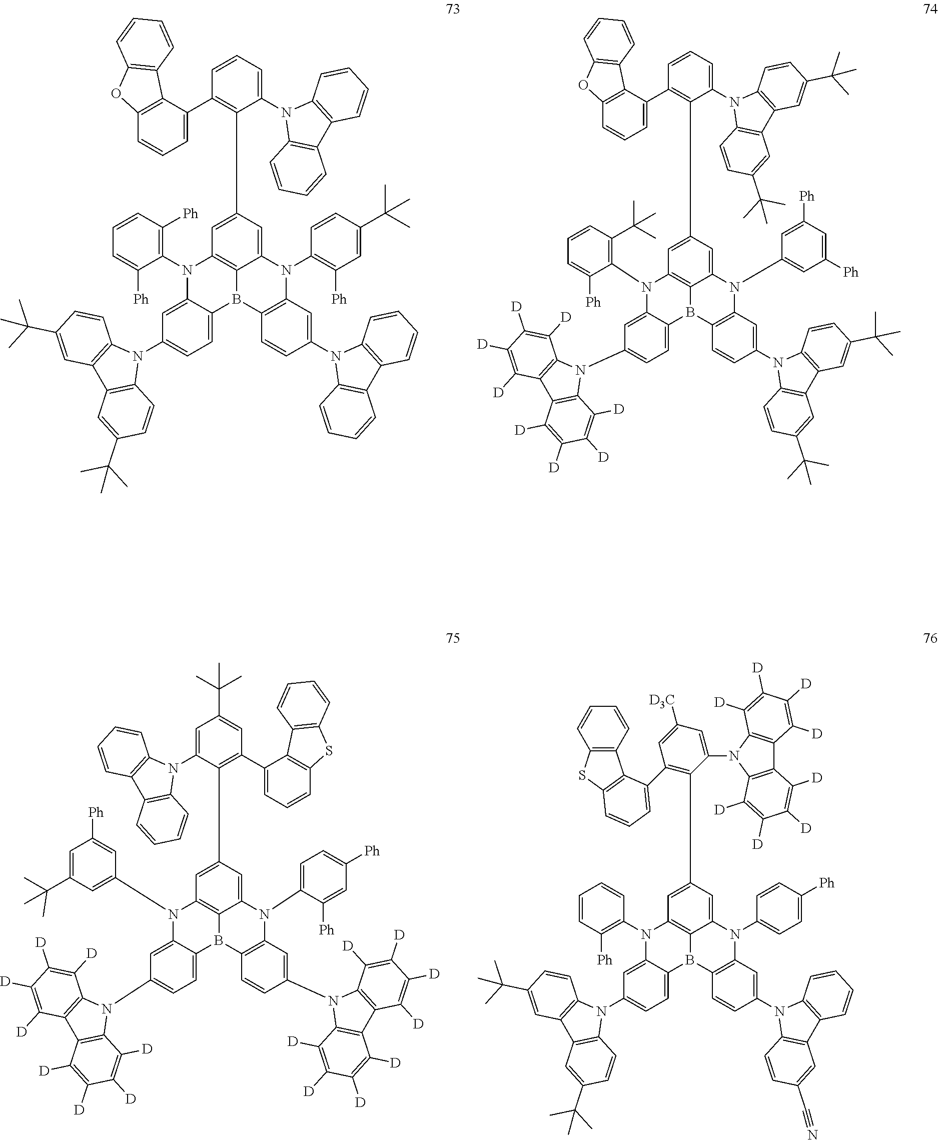 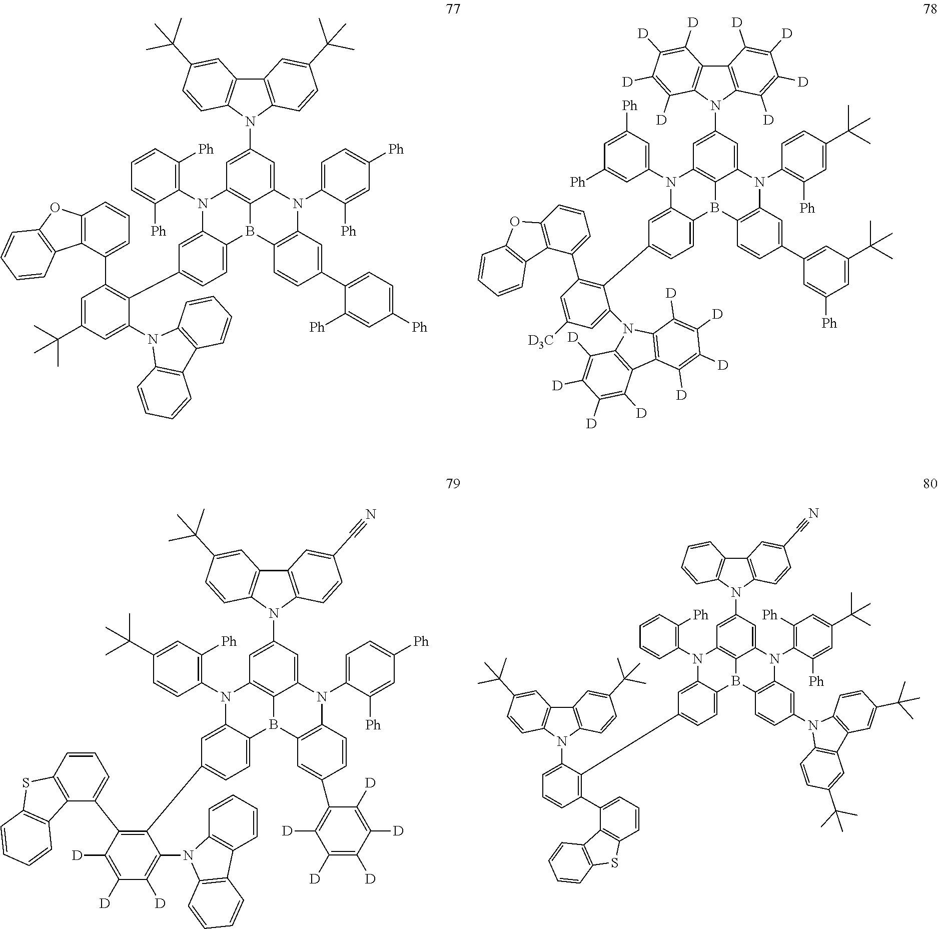 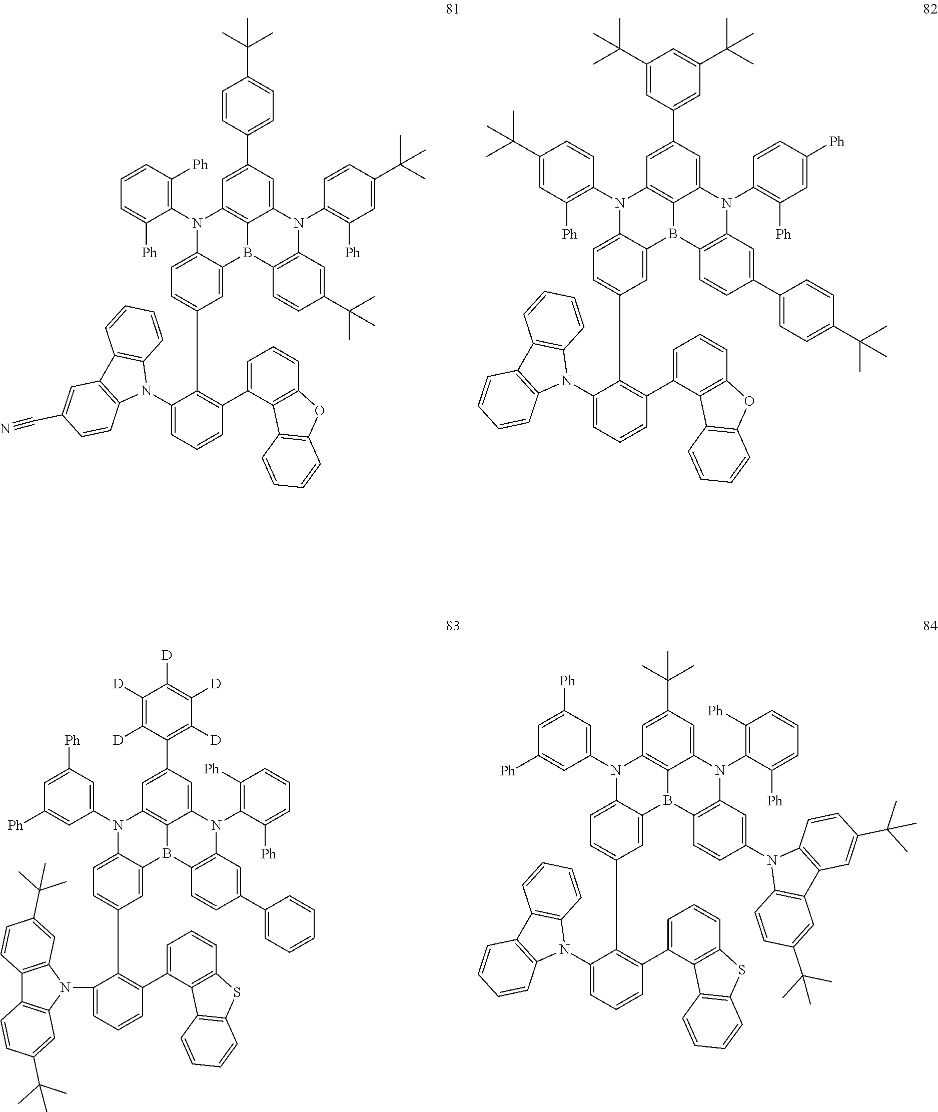 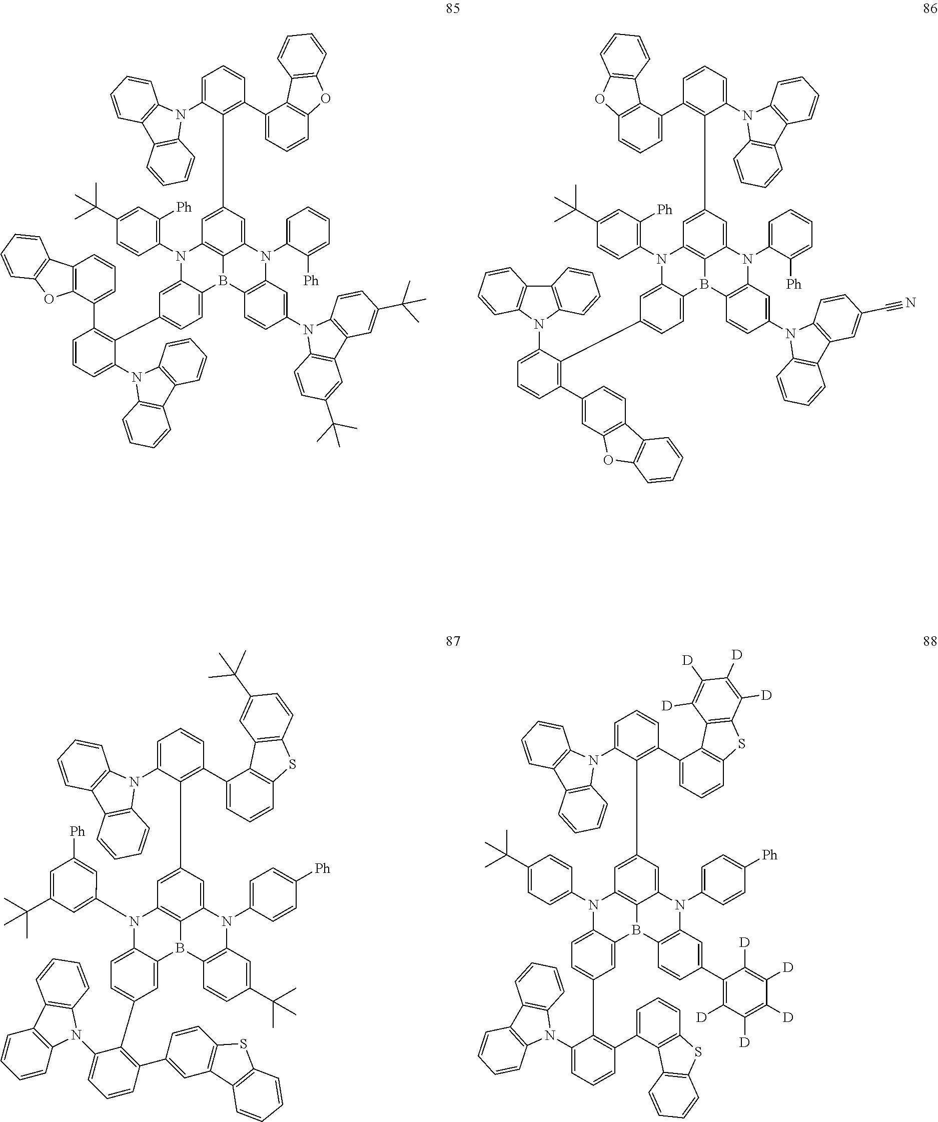 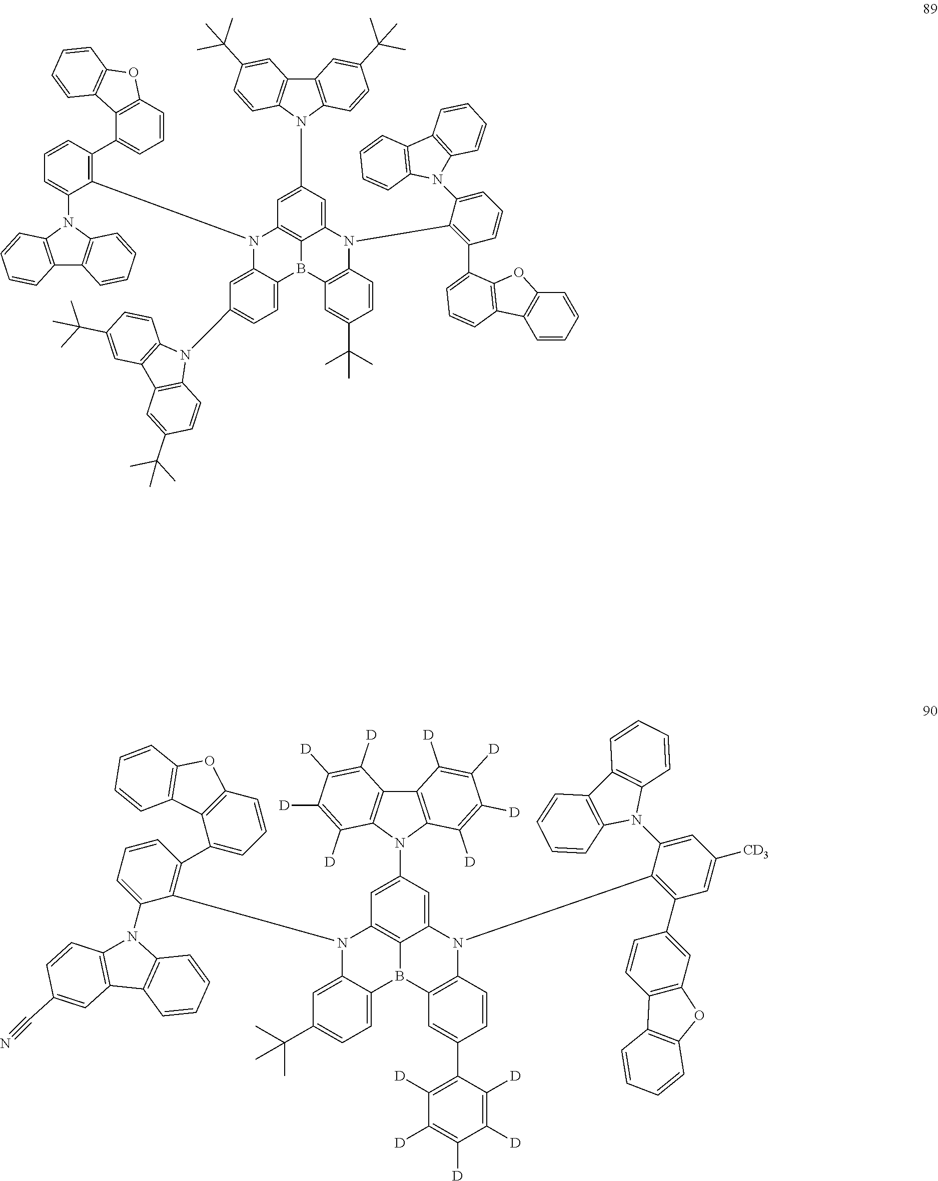 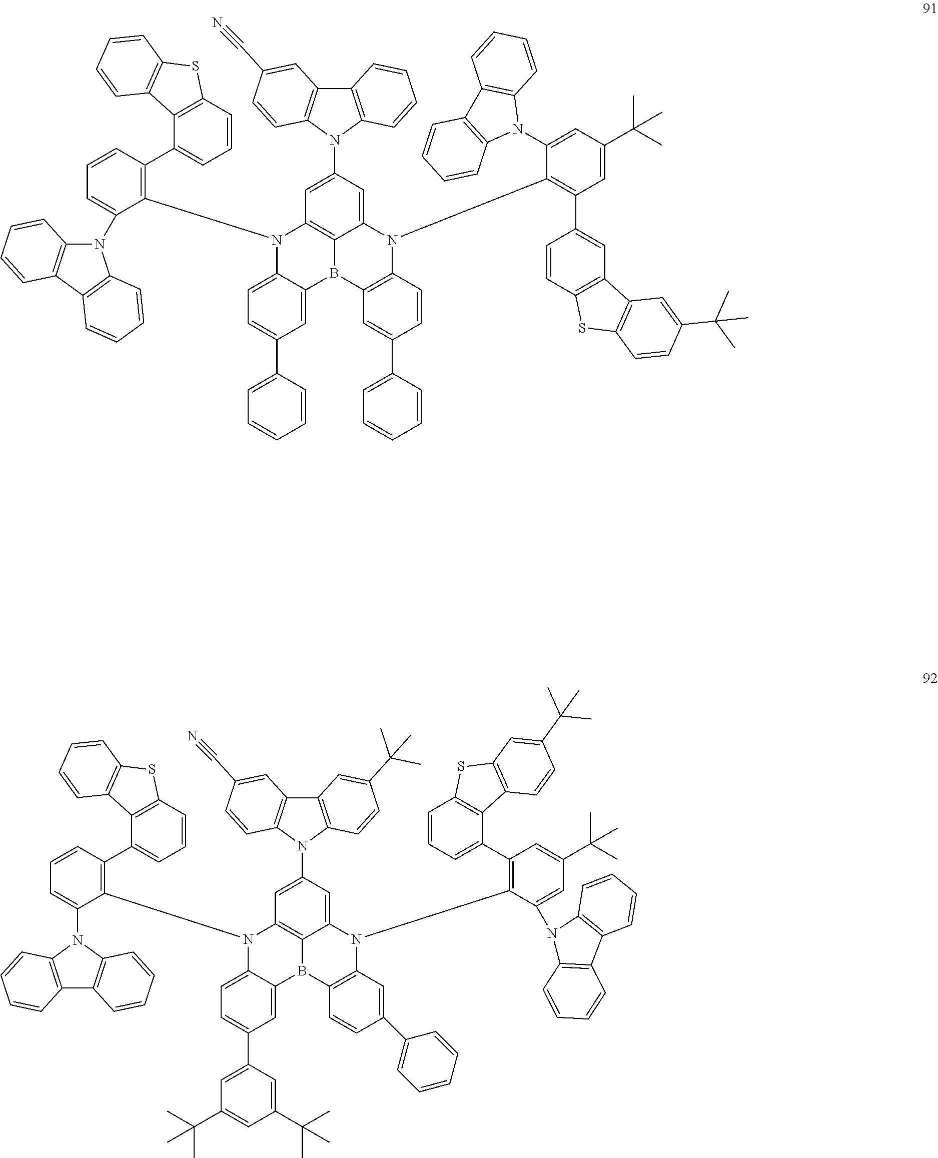 [SMILES: CC(C)(C)c1cc(-c2ccc3sc4ccc(C(C)(C)C)cc4c3c2)c(N2c3ccc(-c4ccccc4)cc3B3c4cc(-c5ccccc5)ccc4N(c4c(-c5cccc6sc7ccccc7c56)cccc4-n4c5ccccc5c5ccccc54)c4cc(-n5c6ccccc6c6cc(C#N)ccc65)cc2c43)c(-n2c3ccccc3c3ccccc32)c1 ; CC(C)(C)c1cc(-c2ccc3c(c2)B2c4ccc(-c5ccccc5)cc4N(c4c(-c5cccc6sc7cc(C(C)(C)C)ccc7c56)cc(C(C)(C)C)cc4-n4c5ccccc5c5ccccc54)c4cc(-n5c6ccc(C#N)cc6c6cc(C(C)(C)C)ccc65)cc(c42)N3c2c(-c3cccc4sc5ccccc5c34)cccc2-n2c3ccccc3c3ccccc32)cc(C(C)(C)C)c1] 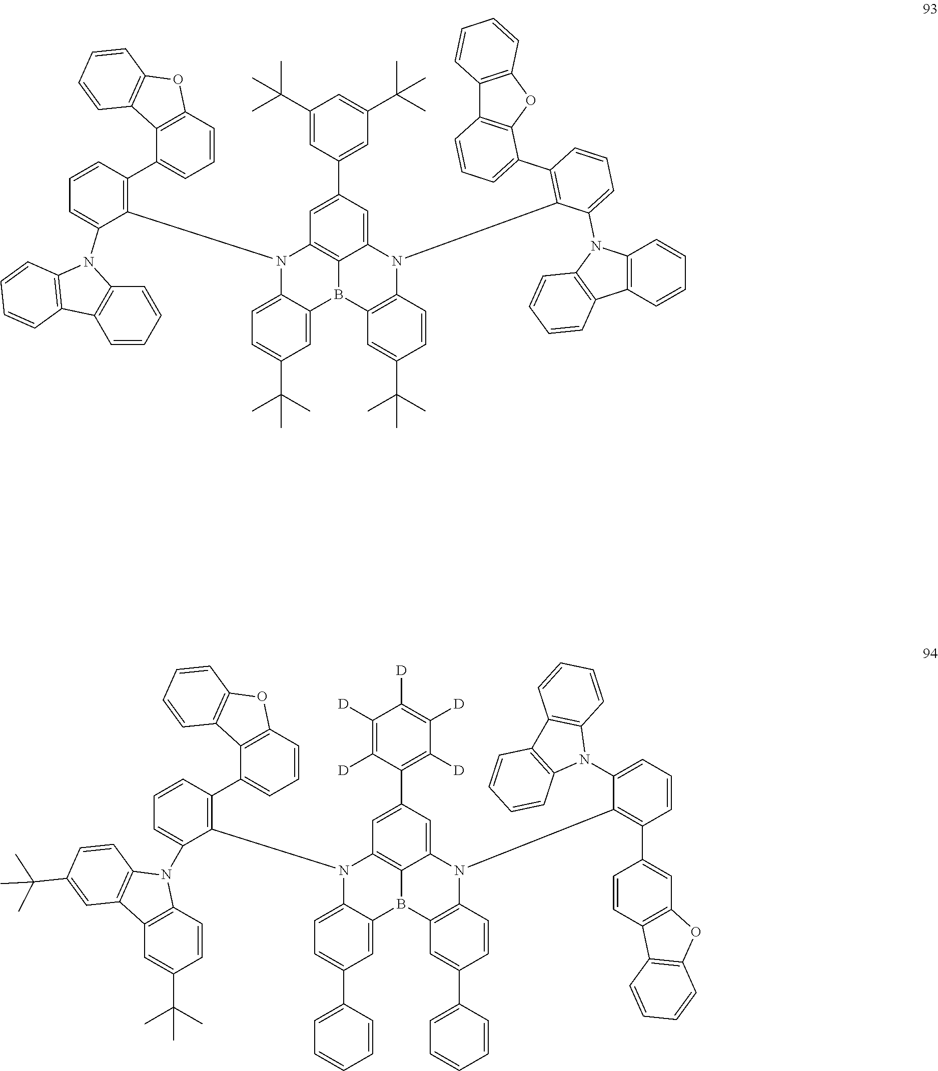 [SMILES: CC(C)(C)c1cc(-c2cc3c4c(c2)N(c2c(-c5cccc6oc7ccccc7c56)cccc2-n2c5ccccc5c5ccccc52)c2ccc(C(C)(C)C)cc2B4c2cc(C(C)(C)C)ccc2N3c2c(-c3cccc4c3oc3ccccc34)cccc2-n2c3ccccc3c3ccccc32)cc(C(C)(C)C)c1 ; [2H]c1c([2H])c([2H])c(-c2cc3c4c(c2)N(c2c(-c5cccc6oc7ccccc7c56)cccc2-n2c5ccc(C(C)(C)C)cc5c5cc(C(C)(C)C)ccc52)c2ccc(-c5ccccc5)cc2B4c2cc(-c4ccccc4)ccc2N3c2c(-c3ccc4c(c3)oc3ccccc34)cccc2-n2c3ccccc3c3ccccc32)c([2H])c1[2H]] 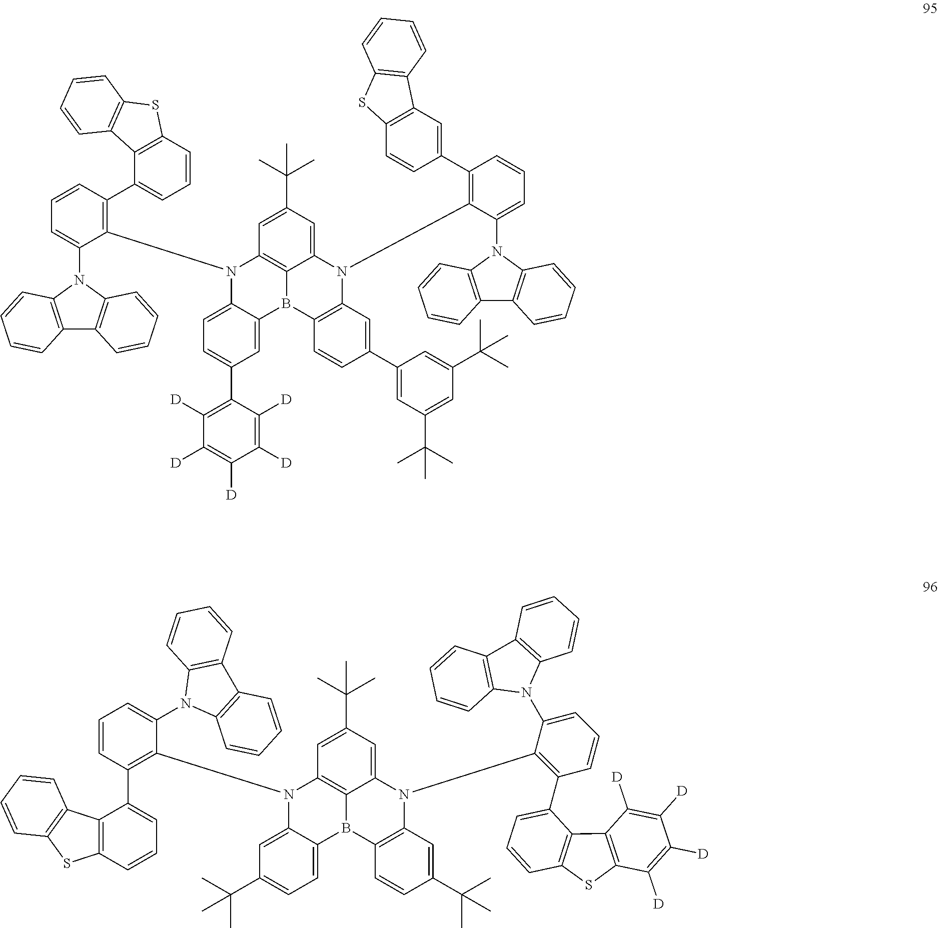 [SMILES: [2H]c1c([2H])c([2H])c(-c2ccc3c(c2)B2c4ccc(-c5cc(C(C)(C)C)cc(C(C)(C)C)c5)cc4N(c4c(-c5ccc6sc7ccccc7c6c5)cccc4-n4c5ccccc5c5ccccc54)c4cc(C(C)(C)C)cc(c42)N3c2c(-c3cccc4sc5ccccc5c34)cccc2-n2c3ccccc3c3ccccc32)c([2H])c1[2H] ; [2H]c1c([2H])c([2H])c2c(sc3cccc(-c4cccc(-n5c6ccccc6c6ccccc65)c4N4c5cc(C(C)(C)C)ccc5B5c6ccc(C(C)(C)C)cc6N(c6c(-c7cccc8sc9ccccc9c78)cccc6-n6c7ccccc7c7ccccc76)c6cc(C(C)(C)C)cc4c65)c32)c1[2H]] 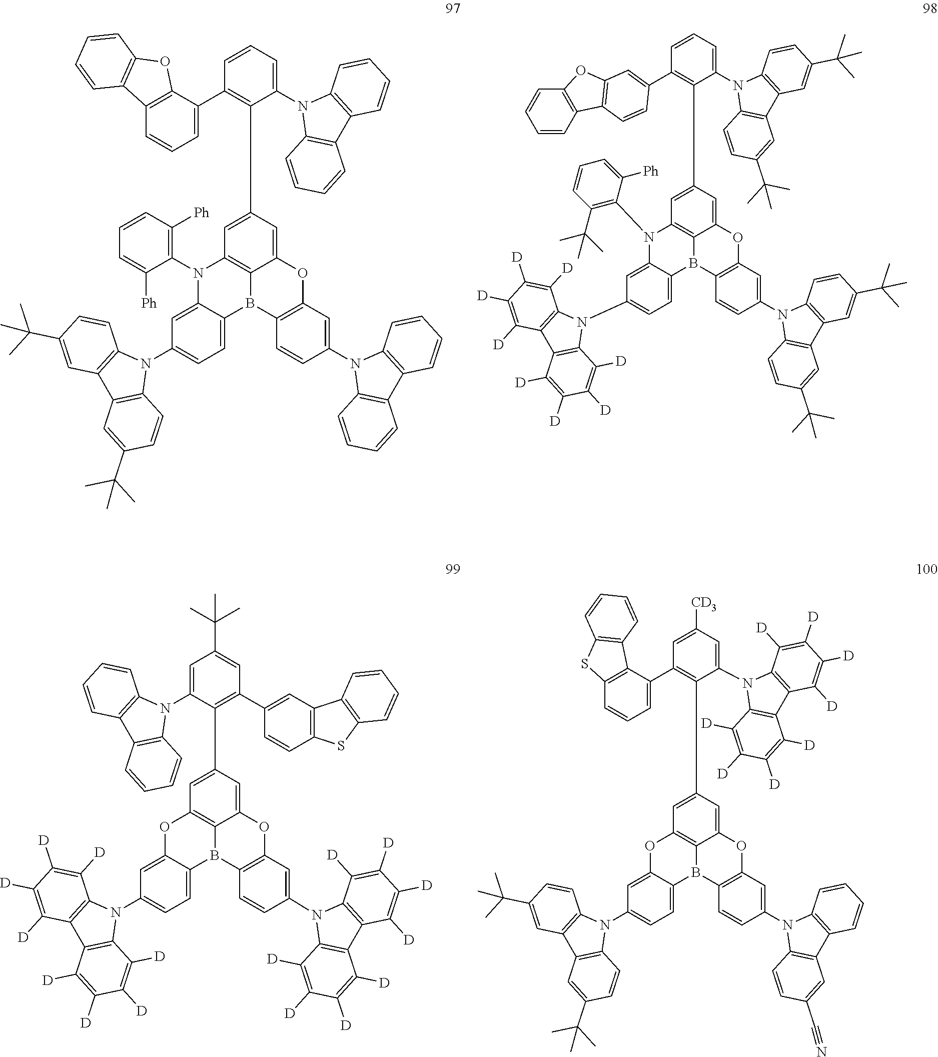 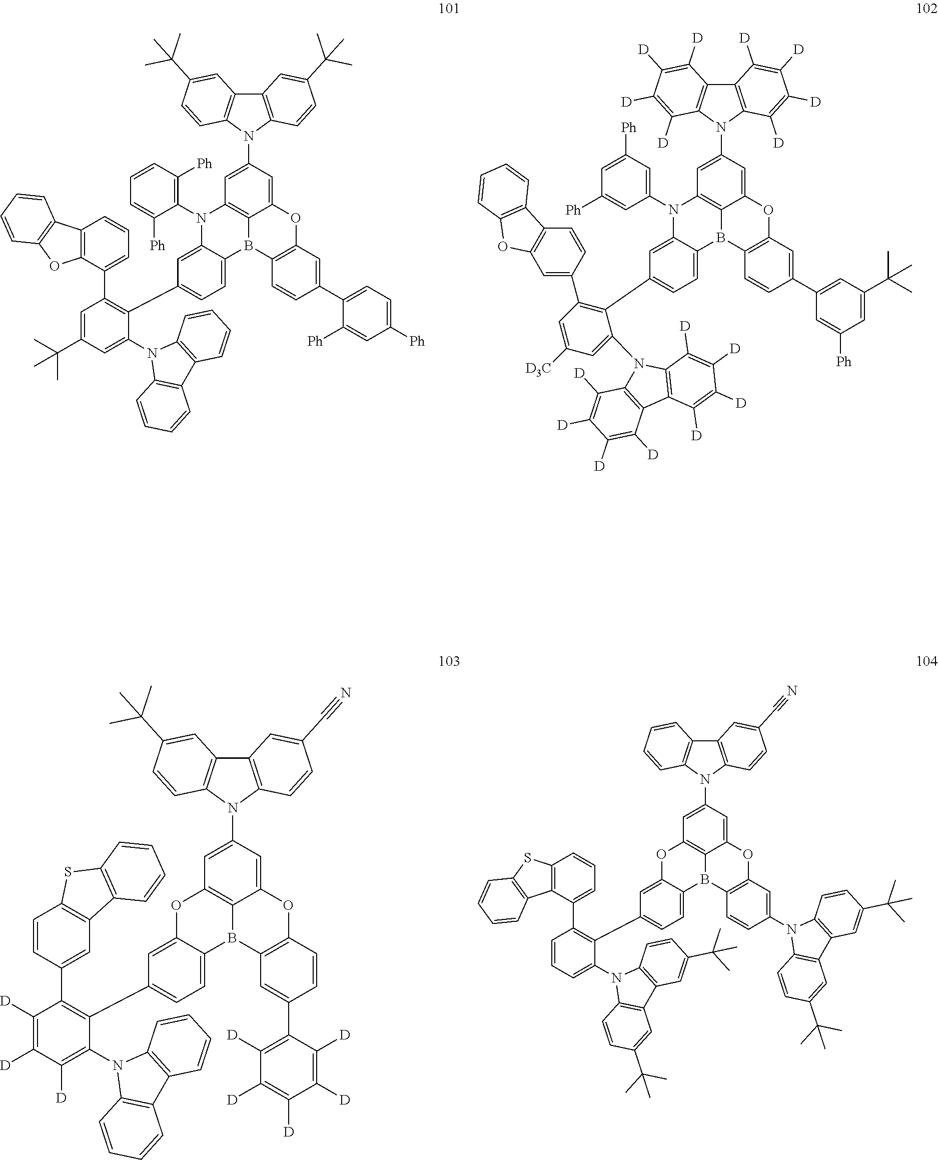 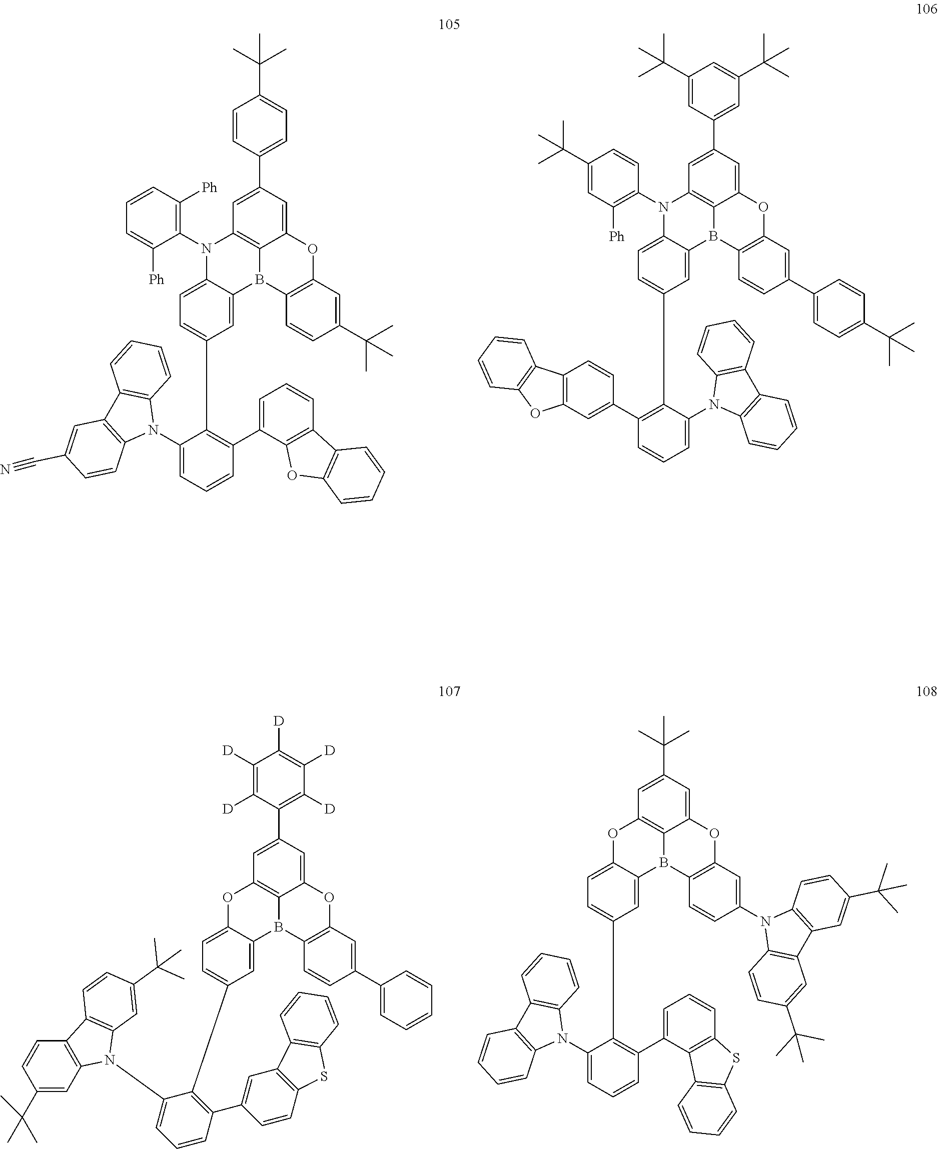 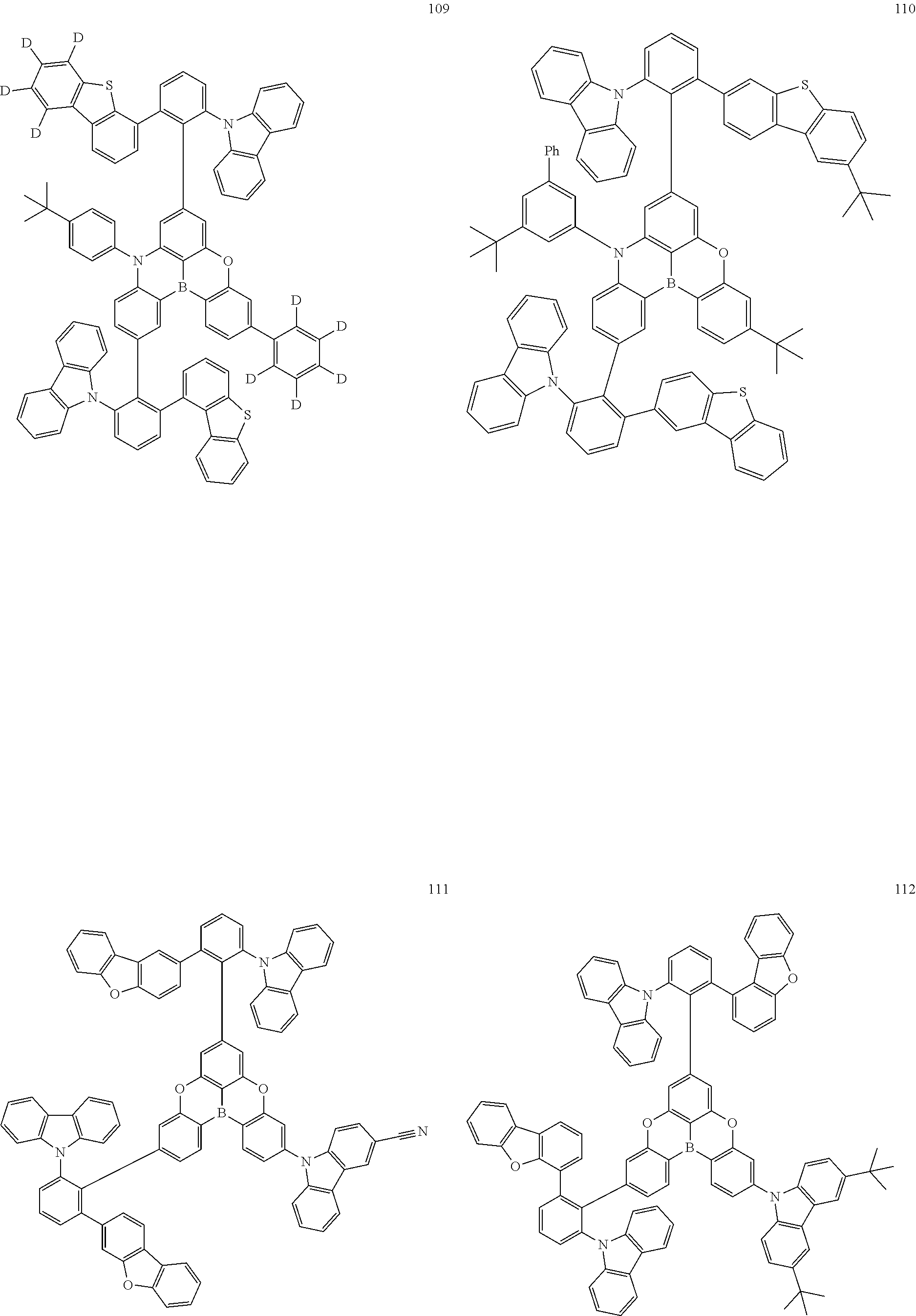 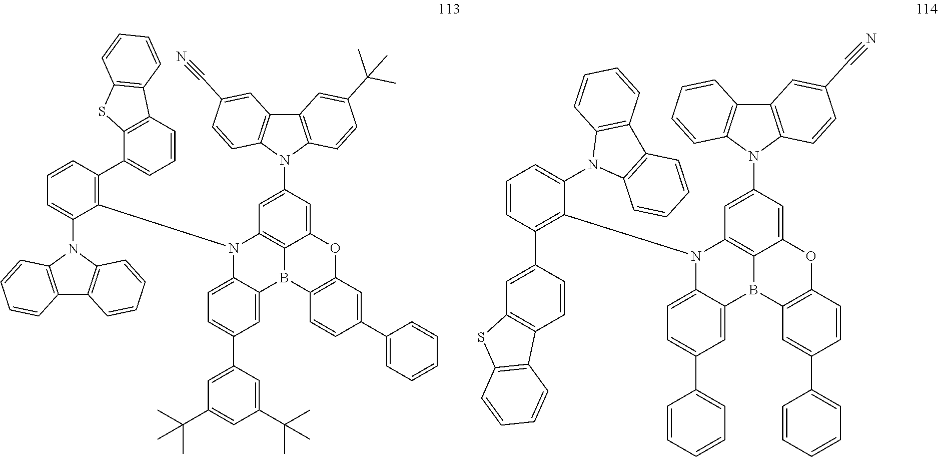 [SMILES: CC(C)(C)c1cc(-c2ccc3c(c2)B2c4ccc(-c5ccccc5)cc4Oc4cc(-n5c6ccc(C#N)cc6c6cc(C(C)(C)C)ccc65)cc(c42)N3c2c(-c3cccc4c3sc3ccccc34)cccc2-n2c3ccccc3c3ccccc32)cc(C(C)(C)C)c1 ; N#Cc1ccc2c(c1)c1ccccc1n2-c1cc2c3c(c1)N(c1c(-c4ccc5c(c4)sc4ccccc45)cccc1-n1c4ccccc4c4ccccc41)c1ccc(-c4ccccc4)cc1B3c1cc(-c3ccccc3)ccc1O2] 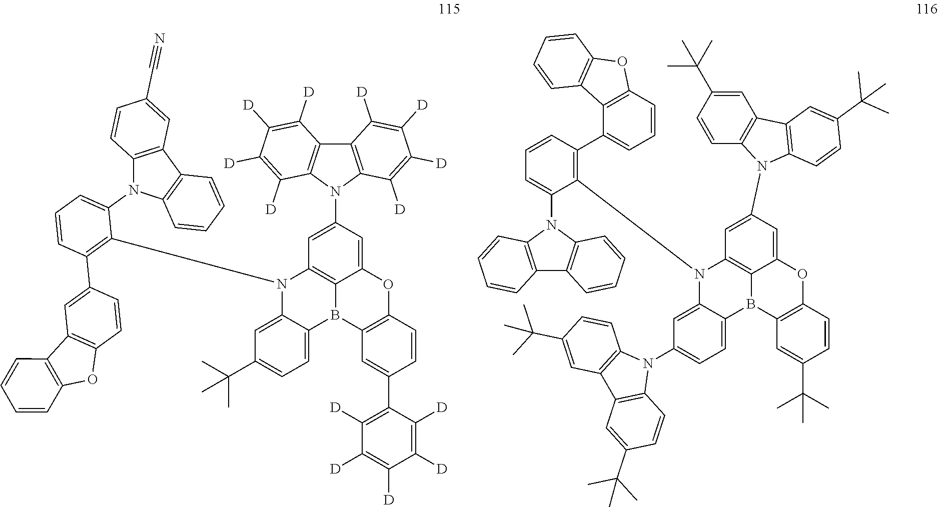 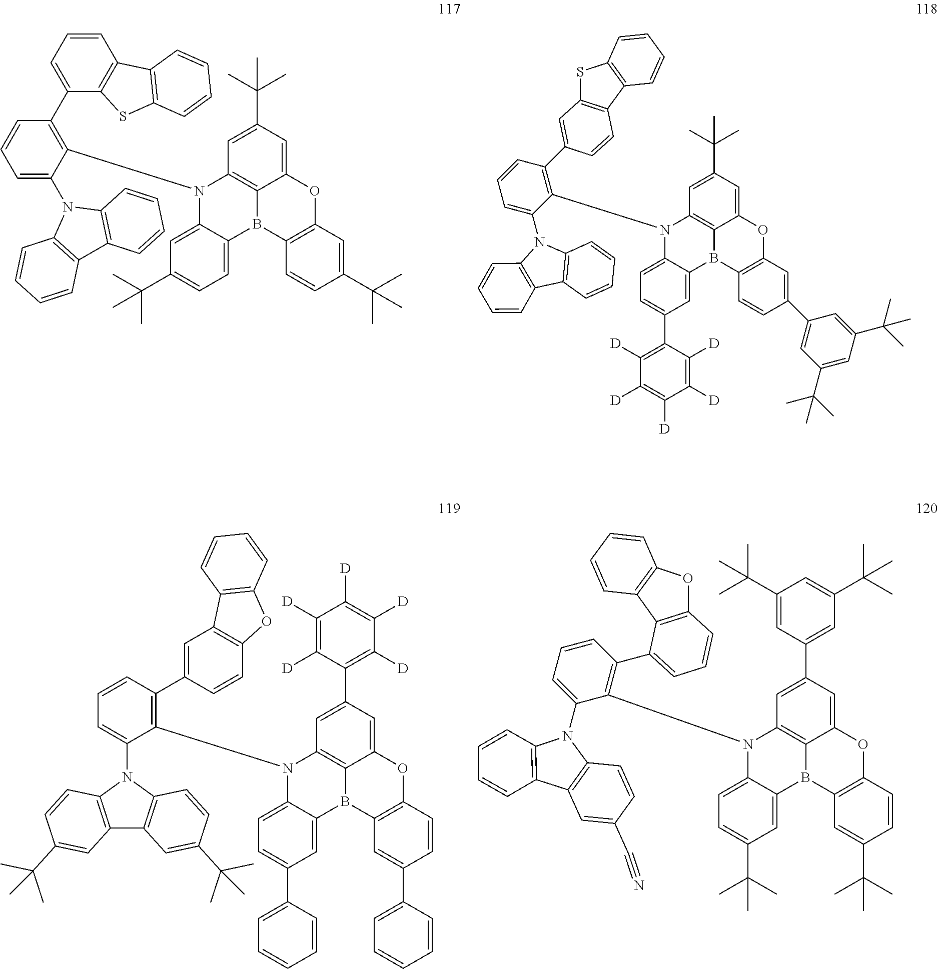 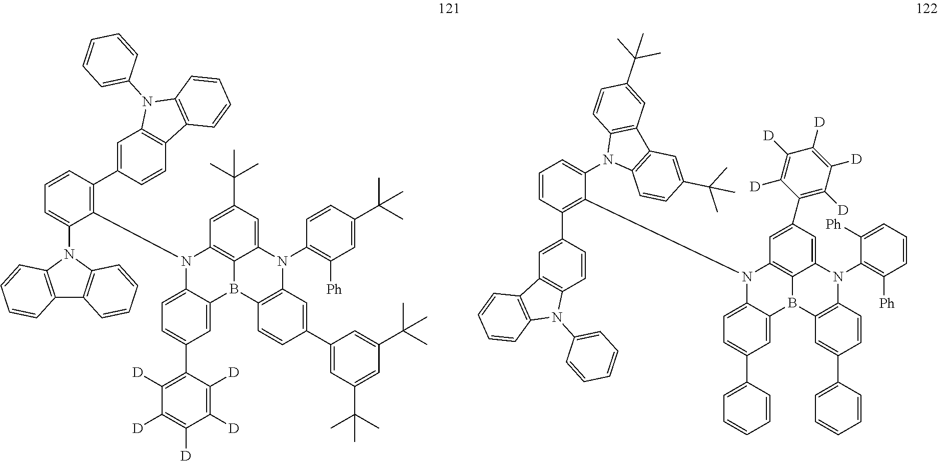 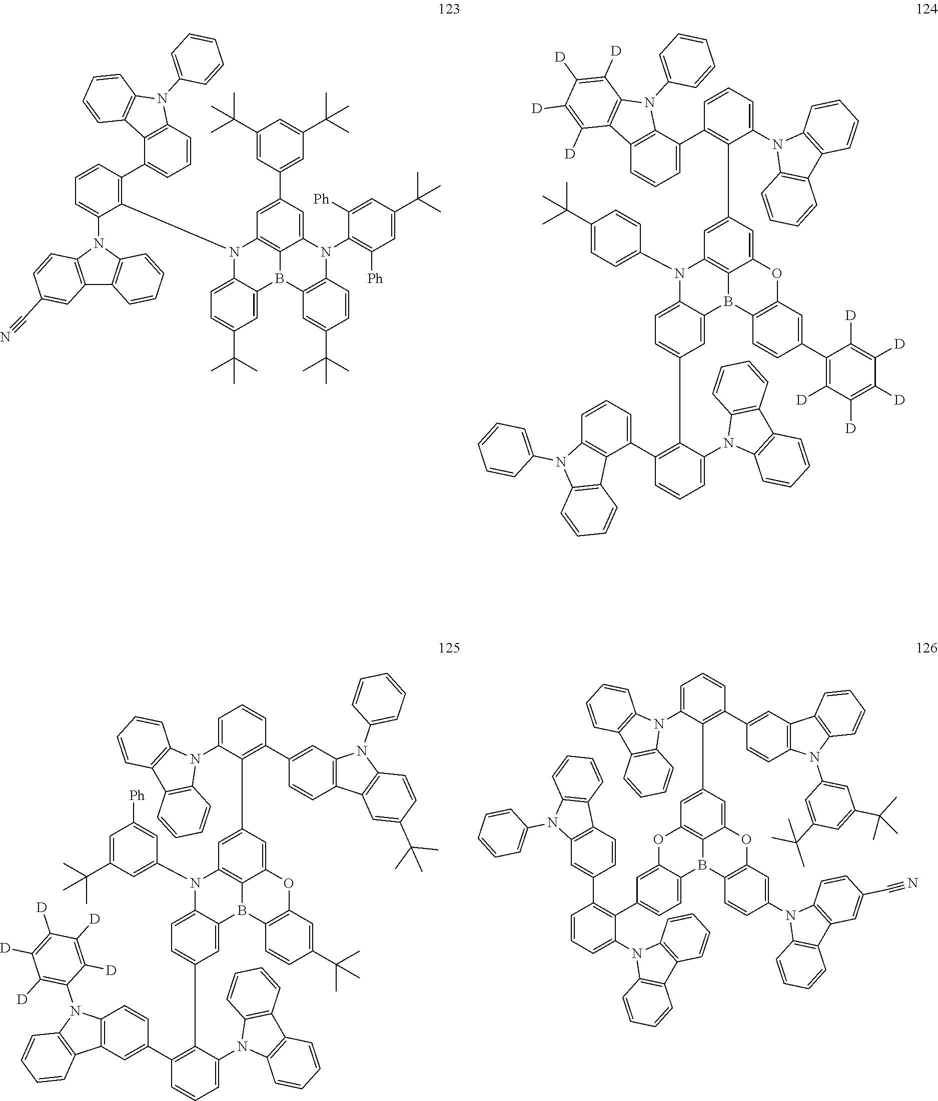 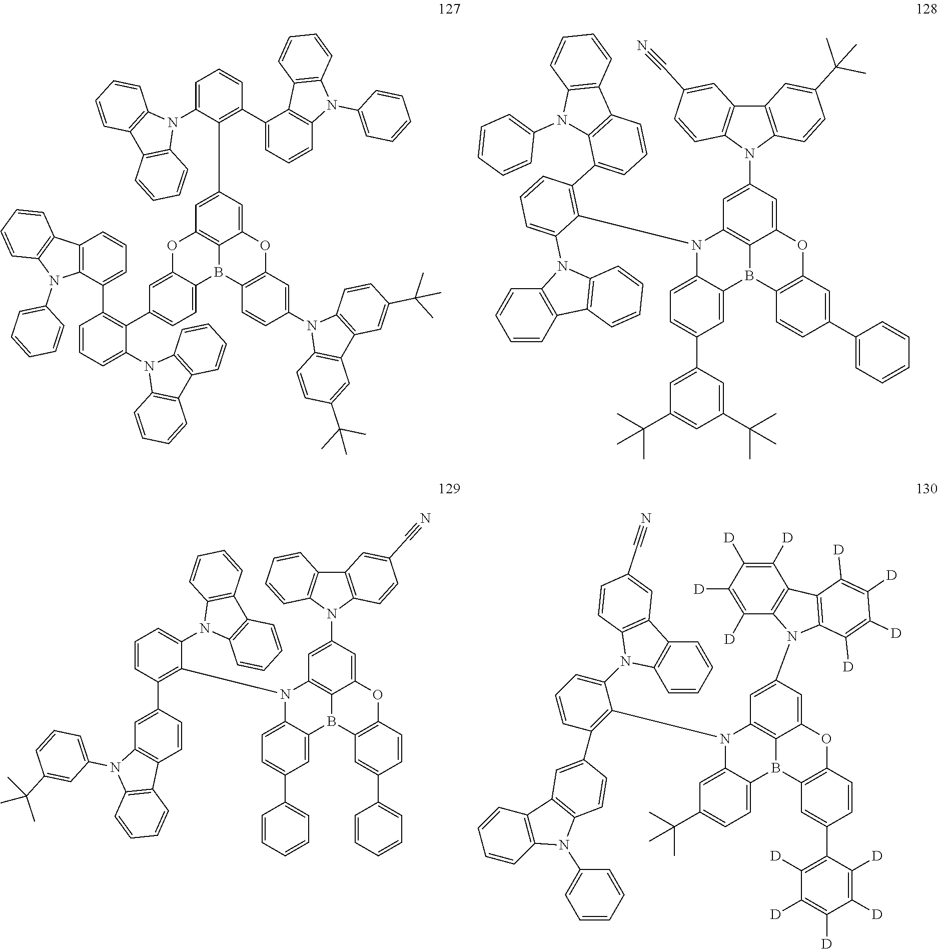 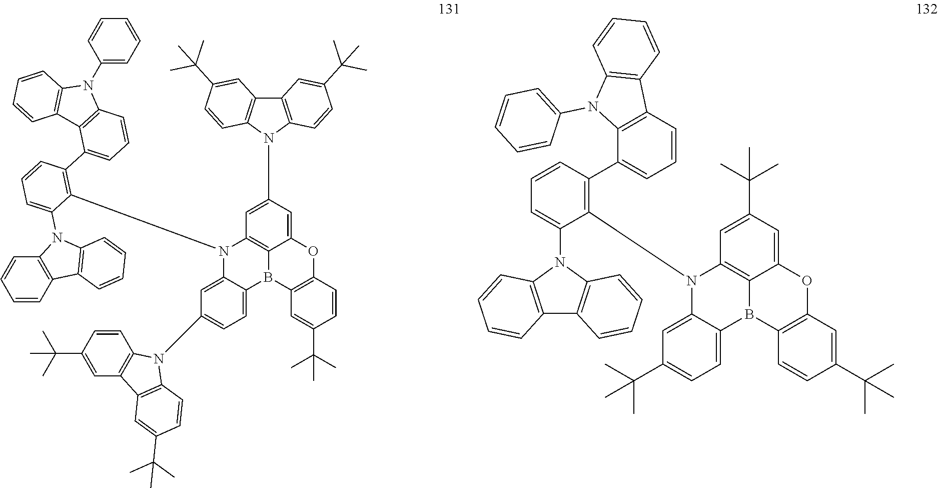 [SMILES: CC(C)(C)c1ccc2c(c1)B1c3ccc(-n4c5ccc(C(C)(C)C)cc5c5cc(C(C)(C)C)ccc54)cc3N(c3c(-c4cccc5c4c4ccccc4n5-c4ccccc4)cccc3-n3c4ccccc4c4ccccc43)c3cc(-n4c5ccc(C(C)(C)C)cc5c5cc(C(C)(C)C)ccc54)cc(c31)O2 ; CC(C)(C)c1ccc2c(c1)Oc1cc(C(C)(C)C)cc3c1B2c1ccc(C(C)(C)C)cc1N3c1c(-c2cccc3c4ccccc4n(-c4ccccc4)c23)cccc1-n1c2ccccc2c2ccccc21]
wherein in Compound Group 1,
Ph is a phenyl group, and
D is a deuterium atom.
